(19) United States
(12) Patent Application Publication
(10) Pub. No.: US 2024/0065100 A1
(43) Pub. Date: Feb. 22, 2024

(54) ORGANIC ELECTROLUMINESCENT DEVICE

(71) Applicant: BEIJING SUMMER SPROUT TECHNOLOGY CO., LTD., Beijing (CN)

(72) Inventors: Qiang Wang, Beijing (CN); Le Wang, Beijing (CN); Ziyan Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/227,583

(22) Filed: Jul. 28, 2023

(30) Foreign Application Priority Data
Jul. 29, 2022 (CN) 202210889343.2
Jun. 15, 2023 (CN) 202310712061.X

(51) Int. Cl. H10K 85/60; H10K 85/40; H10K 85/30; C09K 11/06

(52) U.S. Cl. CPC H10K 85/6572; H10K 85/615; H10K 85/6574; H10K 85/622; H10K 85/6576; H10K 85/654; H10K 85/40; H10K 85/342; C09K 11/06; C07B 2200/05; C09K 2211/1033; C09K 2211/1037; C09K 2211/1096; C09K 2211/185

(57) ABSTRACT

Provided is an organic electroluminescent device. The organic electroluminescent device includes an anode, a cathode and an organic layer disposed between the anode and the cathode, where the organic layer comprises at least a first compound, a second compound and a third compound. The first compound and the second compound can be used as host materials, and the third compound can be used as a light-emitting material. A particular combination of the first compound, the second compound and the third compound can significantly improve device efficiency, significantly improve a device lifetime and obtain more excellent device performance, which has an unexpected unique advantage. Further provided are an electronic apparatus comprising the electroluminescent device and a composition.

### CROSS-REFERENCE TO RELATED APPLICATION(S)

This application claims priority to Chinese Patent Application No. 202210889343.2 filed on Jul. 29, 2022 and Chinese Patent Application No. 202310712061.X filed on Jun. 15, 2023, the disclosure of which are incorporated herein by reference in their entireties.

### TECHNICAL FIELD

The present disclosure relates to an organic electronic device, for example, an organic electroluminescent device. More particularly, the present disclosure relates to an organic electroluminescent device comprising an organic layer comprising a first compound, a second compound and a third compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN111095586A has disclosed an organic electroluminescent device whose light-emitting layer comprises a first compound having a structure of

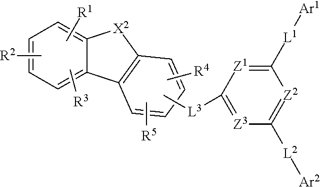

and a second compound formed by fusing

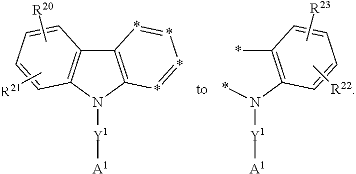

Moreover, a device is disclosed in an example, where the first compound and the second compound are used as hosts, and [Ir(piq)₂acac] is used as a dopant. However, CN111095586A does not disclose or teach use in combination with a metal complex comprising another ligand having a plurality of fused ring structures.

KR20220053508A has disclosed an organic electroluminescent device whose light-emitting layer comprises a compound represented by a structure

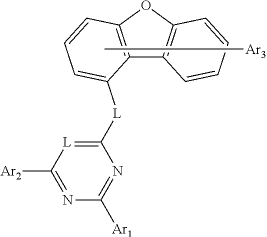

of Formula 1 and a compound represented by a structure

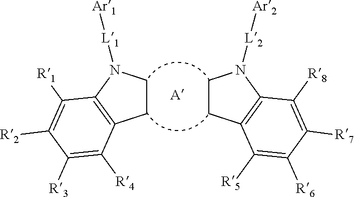

of Formula 2. In a disclosed device example of KR20220053508A, an Ir complex comprising a phenylquinoline ligand is used as a light-emitting material. However, KR20220053508A does not disclose or teach use in combination with a metal complex comprising another ligand having a plurality of fused ring structures.

However, for many device structures reported at present, there is still room for improvement. To meet an increasing requirement of the industry, especially requirements for performance such as higher device efficiency and a longer lifetime, a new material combination still requires further research and development.

### SUMMARY

The present disclosure aims to provide a new electroluminescent device comprising an organic layer comprising a first compound, a second compound and a third compound to solve at least part of the above problems. Since a new compound combination comprising a first compound having a structure of Formula 1, a second compound having a structure of Formula 2 and a third compound comprising a ligand having a structure of Formula 3 is used, the new electroluminescent device has higher device efficiency, a longer device lifetime and better device performance.

According to an embodiment of the present disclosure, disclosed is an electroluminescent device, which comprises:
an anode,
a cathode, and
an organic layer disposed between the anode and the cathode, wherein the organic layer comprises at least a first compound, a second compound and a third compound;
wherein the first compound has a structure represented by Formula 1:

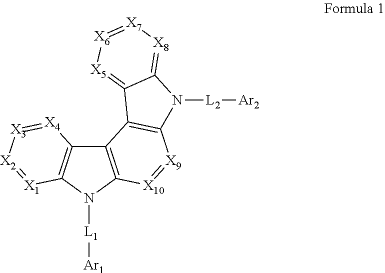

wherein in Formula 1,
X₁ to X₁₀ are, at each occurrence identically or differently, selected from CRₓ or N;
L₁ and L₂ are each independently selected from a single bond, substituted or unsubstituted arylene having 6 to 30 carbon atoms, substituted or unsubstituted heteroarylene having 3 to 30 carbon atoms or a combination thereof;
Ar₁ and Ar₂ are each independently selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 1, adjacent substituents Rₓ can be optionally joined to form a ring;
wherein the second compound has a structure represented by Formula 2:

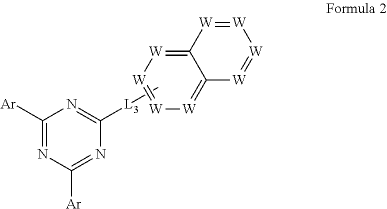

wherein in Formula 2,
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2, adjacent substituents R_{w} can be optionally joined to form a ring;
wherein the third compound is a metal complex, wherein the metal complex comprises a metal with a relative atomic mass greater than 40 and a ligand Lₐ, wherein the ligand Lₐ has a structure represented by Formula 3:

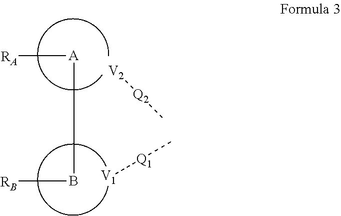

wherein in Formula 3,
the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof;
V₁ and V₂ are each independently selected from C or N, and V₁ is different from V₂;
Q₁ and Q₂ are, at each occurrence identically or differently, selected from a single bond, O, S, Se or NR_{Q};
when both Q₁ and Q₂ are single bonds, the monocyclic ring in the ring A and the ring B that is directly joined to the metal through carbon is a six-membered ring;
R_{A} and R_{B} represent, at each occurrence identically or differently, mono-substitution, multiple substitutions or non-substitution;
R_{Q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 3, adjacent substituents R_{A} and R_{B} can be optionally joined to form a ring.

According to an embodiment of the present disclosure, further disclosed is an electronic apparatus, which comprises the electroluminescent device in the preceding embodiment.

According to an embodiment of the present disclosure, further disclosed is a composition, which comprises the first compound, the second compound and the third compound in the preceding embodiment.

In the new electroluminescent device disclosed in the present disclosure, this particular combination of the first compound having the structure of Formula 1 and the second compound having the structure of Formula 2 which are matched with the third compound comprising the ligand having the structure of Formula 3 is used in the organic layer so that the new electroluminescent device has significantly improved device efficiency, a significantly improved device lifetime, more excellent device performance and an unexpected unique advantage.

### BRIEF DESCRIPTION OF DRAWINGS

FIG. 1 is a schematic diagram of an organic light-emitting apparatus that may comprise an electroluminescent device disclosed herein.

FIG. 2 is a schematic diagram of another organic light-emitting apparatus that may comprise an electroluminescent device disclosed herein.

### DETAILED DESCRIPTION

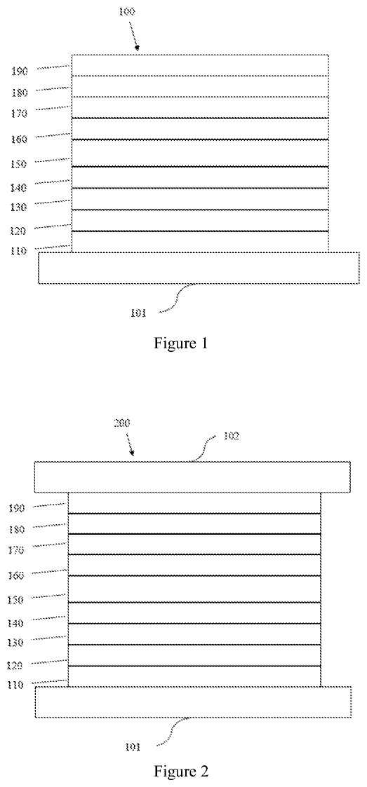

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (Δ_{ES-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

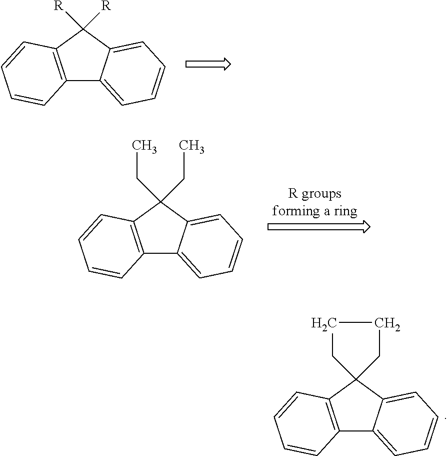

The expression that adjacent substituents can be optionally joined to form a ring is also intended to mean that two substituents bonded to carbon atoms which are directly bonded to each other are joined to each other via a chemical bond to form a ring, which can be exemplified by the following formula:

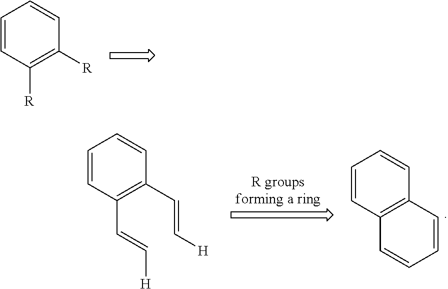

The expression that adjacent substituents can be optionally joined to form a ring is also intended to mean that two substituents bonded to a further distant carbon atom are joined to each other via a chemical bond to form a ring, which can be exemplified by the following formula:

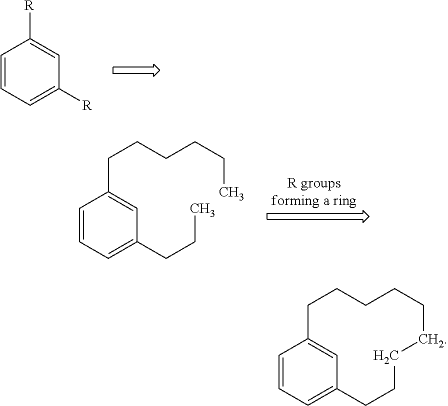

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

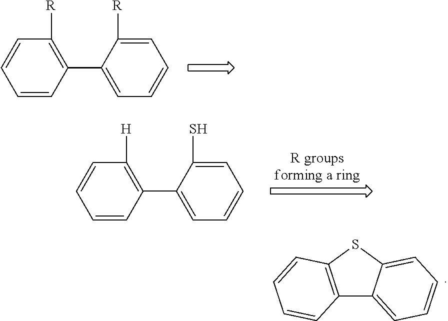

According to an embodiment of the present disclosure, disclosed is an electroluminescent device, which comprises:
an anode,
a cathode, and
an organic layer disposed between the anode and the cathode, wherein the organic layer comprises at least a first compound, a second compound and a third compound;
wherein the first compound has a structure represented by Formula 1:

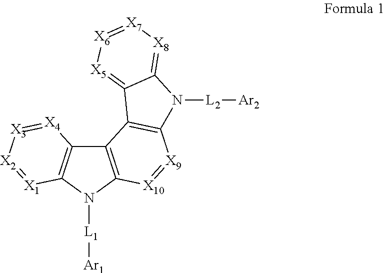

wherein in Formula 1,
X₁ to X₁₀ are, at each occurrence identically or differently, selected from CRₓ or N;
L₁ and L₂ are each independently selected from a single bond, substituted or unsubstituted arylene having 6 to 30 carbon atoms, substituted or unsubstituted heteroarylene having 3 to 30 carbon atoms or a combination thereof;
Ar₁ and Ar₂ are each independently selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 1, adjacent substituents Rₓ can be optionally joined to form a ring;
wherein the second compound has a structure represented by Formula 2:

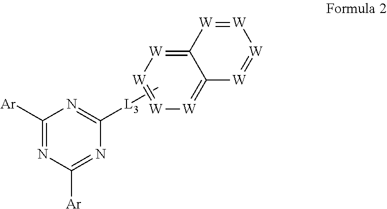

wherein in Formula 2,
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2, adjacent substituents R_{w} can be optionally joined to form a ring;
wherein the third compound is a metal complex, wherein the metal complex comprises a metal with a relative atomic mass greater than 40 and a ligand Lₐ, wherein the ligand Lₐ has a structure represented by Formula 3:

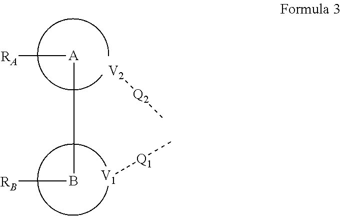

wherein in Formula 3,
the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof;
V₁ and V₂ are each independently selected from C or N, and V₁ is different from V₂;
Q₁ and Q₂ are, at each occurrence identically or differently, selected from a single bond, O, S, Se or NR_{Q};
when both Q₁ and Q₂ are single bonds, the monocyclic ring in the ring A and the ring B that is directly joined to the metal through carbon is a six-membered ring;
R_{A} and R_{B} represent, at each occurrence identically or differently, mono-substitution, multiple substitutions or non-substitution;
R_{Q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 3, adjacent substituents R_{A} and R_{B} can be optionally joined to form a ring.

In the present disclosure, “the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof”, wherein the fused aromatic ring and the fused heteroaromatic ring are intended to mean that the ring A and the ring B are each a structure formed by fusing at least two rings.

In the present disclosure, since both the ring A and the ring B are fused rings, the ring A and the ring B each comprises one monocyclic ring directly joined to the metal, and the expression that “when both Q₁ and Q₂ are single bonds, the monocyclic ring in the ring A and the ring B that is directly joined to the metal through carbon is a six-membered ring” is intended to mean that when both Q₁ and Q₂ are single bonds, the monocyclic ring in the ring A and the ring B that is directly joined to the metal through carbon (V₁ or V₂) is a six-membered ring. For example, when both Q₁ and Q₂ are single bonds, V₁ is C and V₂ is N, then the monocyclic ring directly joined to the metal comprised in the ring B is a six-membered ring, and when both Q₁ and Q₂ are the single bonds, V₁ is N and V₂ is C, then the monocyclic ring directly joined to the metal comprised in the ring A is a six-membered ring.

In the present disclosure, the expression that “adjacent substituents Rₓ can be optionally joined to form a ring” is intended to mean that any adjacent substituents Rₓ can be joined to form a ring. Obviously, it is also possible that any adjacent substituents Rₓ are not joined to form a ring.

In the present disclosure, the expression that “adjacent substituents Rₓ can be optionally joined to form a ring” is intended to mean that any adjacent substituents R_{w} can be joined to form a ring. Obviously, it is also possible that any adjacent substituents R_{w} are not joined to form a ring.

In the present disclosure, the expression that “adjacent substituents R_{A} and R_{B} can be optionally joined to form a ring” is intended to mean that any one or more of groups of adjacent substituents, such as two substituents R_{A}, two substituents R_{B}, and substituents R_{A} and R_{B}, can be joined to form a ring. Obviously, it is also possible that none of these substituents are joined to form a ring.

According to an embodiment of the present disclosure, in Formula 1, at least one of X₁ to X₁₀ is selected from N.

According to an embodiment of the present disclosure, in Formula 1, X₁ to X₁₀ are, at each occurrence identically or differently, selected from CRₓ.

According to an embodiment of the present disclosure, in Formula 1, at least one of Ar₁ and Ar₂ is selected from substituted or unsubstituted heteroaryl having 3 to 30 carbon atoms.

According to an embodiment of the present disclosure, in Formula 1, at least one deuterium is contained in the structures of Ar₁ and Ar₂.

According to an embodiment of the present disclosure, in Formula 1, Ar₁ and Ar₂ are, at each occurrence identically or differently, selected from substituted or unsubstituted aryl having 6 to 18 carbon atoms, substituted or unsubstituted heteroaryl having 3 to 18 carbon atoms or a combination thereof.

According to an embodiment of the present disclosure, in Formula 1, Ar₁ and Ar₂ are, at each occurrence identically or differently, selected from substituted or unsubstituted phenyl, substituted or unsubstituted naphthyl, substituted or unsubstituted pyridyl, substituted or unsubstituted biphenyl, substituted or unsubstituted phenanthryl, substituted or unsubstituted chrysenyl, substituted or unsubstituted terphenyl, substituted or unsubstituted triphenylenyl, substituted or unsubstituted dibenzofuranyl, substituted or unsubstituted dibenzothienyl, substituted or unsubstituted fluorenyl, substituted or unsubstituted quinolyl, substituted or unsubstituted isoquinolyl or a combination thereof.

According to an embodiment of the present disclosure, in Formula 1, Rₓ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof.

According to an embodiment of the present disclosure, in Formula 1, Rₓ is, at each occurrence identically or differently, selected from hydrogen, deuterium, halogen, substituted or unsubstituted aryl having 6 to 30 carbon atoms, substituted or unsubstituted heteroaryl having 3 to 30 carbon atoms or a combination thereof.

According to an embodiment of the present disclosure, in Formula 1, Rₓ is, at each occurrence identically or differently, selected from hydrogen, deuterium, fluorine, substituted or unsubstituted phenyl, substituted or unsubstituted naphthyl, substituted or unsubstituted biphenyl, substituted or unsubstituted pyridyl, substituted or unsubstituted phenanthryl, substituted or unsubstituted triphenylenyl, substituted or unsubstituted dibenzofuranyl, substituted or unsubstituted dibenzothienyl or a combination thereof.

According to an embodiment of the present disclosure, in Formula 1, L₁ and L₂ are, at each occurrence identically or differently, selected from a single bond, substituted or unsubstituted arylene having 6 to 18 carbon atoms, substituted or unsubstituted heteroarylene having 3 to 18 carbon atoms or a combination thereof.

According to an embodiment of the present disclosure, in Formula 1, L₁ and L₂ are, at each occurrence identically or differently, selected from a single bond, substituted or unsubstituted phenylene, substituted or unsubstituted pyridylene, substituted or unsubstituted naphthylene, substituted or unsubstituted biphenylene or a combination thereof.

According to an embodiment of the present disclosure, the first compound is selected from the group consisting of Compound A-1 to Compound A-217, wherein the specific structures of Compound A-1 to Compound A-217 are referred to claim 5.

According to an embodiment of the present disclosure, the first compound is selected from the group consisting of Compound A-1 to Compound A-224, wherein the specific structures of Compound A-1 to Compound A-224 are referred to claim 5.

According to an embodiment of the present disclosure, hydrogens in Compound A-1 to Compound A-217 can be partially or fully substituted with deuterium.

According to an embodiment of the present disclosure, hydrogens in Compound A-1 to Compound A-224 can be partially or fully substituted with deuterium.

According to an embodiment of the present disclosure, the second compound has a structure represented by Formula 2-1:

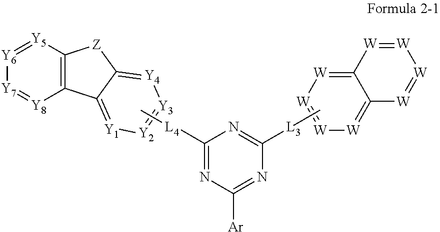

wherein in Formula 2-1,
Z is selected from O, S, CRR, NR, SiRR or Se, wherein when two R are present at the same time, the two R are identical or different;
Y₁ to Y₄ are, at each occurrence identically or differently, selected from C, CR_{y} or N, and one of Y₁ to Y₄ is selected from C and joined to L₄;
Y₅ to Y₈ are, at each occurrence identically or differently, selected from CR_{y} or N;
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
L₄ is, at each occurrence identically or differently, selected from a single bond, substituted or unsubstituted arylene having 6 to 30 carbon atoms, substituted or unsubstituted heteroarylene having 3 to 30 carbon atoms or a combination thereof;
R, R_{y} and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2-1, adjacent substituents R, R_{y} and R_{w} can be optionally joined to form a ring.

In this embodiment, the expression that “adjacent substituents R, R_{y} and R_{w} can be optionally joined to form a ring” is intended to mean that any one or more of groups of adjacent substituents, such as two substituents Rₓ two substituents R_{y}, and two substituents R_{w}, can be joined to form a ring. Obviously, it is also possible that none of these substituents are joined to form a ring.

According to an embodiment of the present disclosure, in Formula 2-1, Z is selected from O, S, CRR, NR or SiRR, and R is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms or a combination thereof.

According to an embodiment of the present disclosure, in Formula 2-1, Z is selected from O, S or NR, and R is, at each occurrence identically or differently, selected from substituted or unsubstituted aryl having 6 to 30 carbon atoms, substituted or unsubstituted heteroaryl having 3 to 30 carbon atoms or a combination thereof.

According to an embodiment of the present disclosure, R is, at each occurrence identically or differently, selected from the group consisting of: substituted or unsubstituted phenyl, substituted or unsubstituted naphthyl, substituted or unsubstituted biphenyl, substituted or unsubstituted pyridyl, substituted or unsubstituted dibenzofuranyl, substituted or unsubstituted dibenzothienyl and combinations thereof.

According to an embodiment of the present disclosure, in Formula 2-1, at least one of Y₁ to Y₈ is selected from N.

According to an embodiment of the present disclosure, in Formula 2-1, Y₁ and Y₅ are, at each occurrence identically or differently, selected from CR_{y}, and W is, at each occurrence identically or differently, selected from CR_{W}.

According to an embodiment of the present disclosure, in Formula 2-1, R_{y} and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, in Formula 2-1, R_{y} and R_{w} are, at each occurrence identically or differently, selected from the group consisting of: hydrogen, deuterium, fluorine, substituted or unsubstituted phenyl, substituted or unsubstituted naphthyl, substituted or unsubstituted biphenyl, substituted or unsubstituted pyridyl, substituted or unsubstituted triphenylenyl, substituted or unsubstituted dibenzofuranyl, substituted or unsubstituted dibenzothienyl, substituted or unsubstituted chrysenyl and combinations thereof.

According to an embodiment of the present disclosure, in Formula 2-1, Ar is, at each occurrence identically or differently, selected from substituted or unsubstituted aryl having 6 to 30 carbon atoms, substituted or unsubstituted heteroaryl having 3 to 30 carbon atoms or a combination thereof.

According to an embodiment of the present disclosure, in Formula 2-1, Ar is, at each occurrence identically or differently, selected from the group consisting of: substituted or unsubstituted phenyl, substituted or unsubstituted naphthyl, substituted or unsubstituted biphenyl, substituted or unsubstituted pyridyl, substituted or unsubstituted phenanthryl, substituted or unsubstituted terphenyl, substituted or unsubstituted triphenylenyl, substituted or unsubstituted dibenzofuranyl, substituted or unsubstituted dibenzothienyl, substituted or unsubstituted fluorenyl, substituted or unsubstituted silafluorenyl, substituted or unsubstituted carbazolyl and combinations thereof.

According to an embodiment of the present disclosure, in Formula 2-1, L₃ is, at each occurrence identically or differently, selected from substituted or unsubstituted arylene having 6 to 18 carbon atoms, substituted or unsubstituted heteroarylene having 3 to 18 carbon atoms or a combination thereof.

According to an embodiment of the present disclosure, in Formula 2-1, L₃ is, at each occurrence identically or differently, selected from substituted or unsubstituted arylene having 6 to 18 carbon atoms.

According to an embodiment of the present disclosure, in Formula 2-1, L₃ is, at each occurrence identically or differently, selected from substituted or unsubstituted phenylene, substituted or unsubstituted naphthylene, substituted or unsubstituted biphenylene or a combination thereof.

According to an embodiment of the present disclosure, in Formula 2-1, L₄ is, at each occurrence identically or differently, selected from a single bond, substituted or unsubstituted arylene having 6 to 18 carbon atoms, substituted or unsubstituted heteroarylene having 3 to 18 carbon atoms or a combination thereof.

According to an embodiment of the present disclosure, in Formula 2-1, L₄ is, at each occurrence identically or differently, selected from a single bond, substituted or unsubstituted phenylene, substituted or unsubstituted naphthylene, substituted or unsubstituted biphenylene, substituted or unsubstituted pyridylene or a combination thereof.

According to an embodiment of the present disclosure, the second compound is selected from the group consisting of Compound B-1 to Compound B-220, wherein the specific structures of Compound B-1 to Compound B-220 are referred to claim 12.

According to an embodiment of the present disclosure, hydrogens in Compound B-1 to Compound B-220 can be partially or fully substituted with deuterium.

According to an embodiment of the present disclosure, the ligand Lₐ has a structure represented by Formula 4:

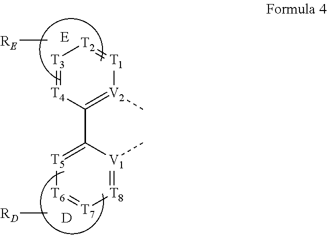

wherein in Formula 4,
the ring D and the ring E are, at each occurrence identically or differently, selected from an aromatic ring having 6 to 30 ring atoms, a heteroaromatic ring having 5 to 30 ring atoms or a combination thereof;
R_{D} and R_{E} represent, at each occurrence identically or differently, mono-substitution, multiple substitutions or non-substitution;
T₁ to T₈ are, at each occurrence identically or differently, selected from C, CR_{T} or N, any adjacent two of T₁ to T₄ are C and fused to the ring E, and any adjacent two of T₈ to T₈ are C and fused to the ring D;
V₁ and V₂ are each independently selected from C or N, and V₁ is different from V₂;
R_{D}, R_{E} and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 4, adjacent substituents R_{D}, R_{E} and R_{T} can be optionally joined to form a ring.

In this embodiment, the expression that “any adjacent two of T₁ to T₄ are C and fused to the ring E, and any adjacent two of T₈ to T₈ are C and fused to the ring D” is intended to mean that the ring E is fused to the six-membered ring comprising T₁ to T₄ in a plurality of manners and the ring D is fused to the six-membered ring comprising T₅ to T₈ in a plurality of manners. For example, when T₁ and T₂ are C, the ring E is fused to the six-membered ring comprising T₁ to T₄ through T₁ and T₂, and when T₇ and T₈ are C, the ring D is fused to the

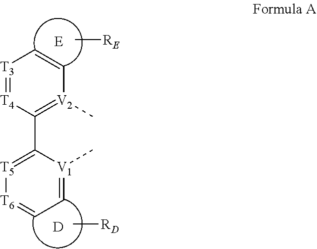

six-membered ring comprising T₇ to T₈ through T₇ and T₈, so that a structure Formula A represented by Formula A can be obtained through this fusion manner. For another example, when T₃ and T₄ are C, the ring E is fused to the six-membered ring comprising T₁ to T₄ through T₃ and T₄, and when T₇ and T₈ are C, the ring D is fused to the six-membered ring comprising T₅ to T₈ through T₇ and T₈, so that a structure

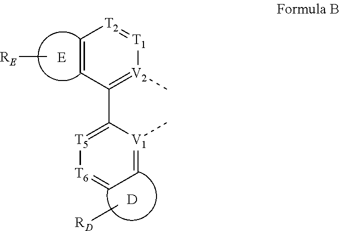

represented by Formula B can be obtained through this fusion manner.

In this embodiment, the expression that “adjacent substituents R_{D}, R_{E} and R_{T} can be optionally joined to form a ring” is intended to mean that any one or more of groups of adjacent substituents, such as two substituents R_{D}, two substituents R_{E}, two substituents R_{T}, two substituents R_{D} and R_{T}, and two substituents R_{E} and R_{T}, can be joined to form a ring. Obviously, it is also possible that none of these substituents are joined to form a ring.

According to an embodiment of the present disclosure, the ligand Lₐ has a structure represented by any one of Formula 4-1 to Formula 4-3:

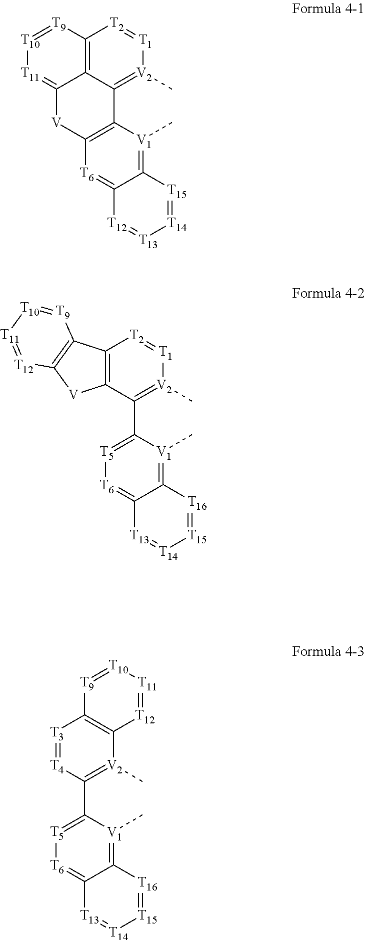

wherein V₁ and V₂ are each independently selected from C or N, and V₁ is different from V₂;
T₁ to T₆ and T₉ to T₁₆ are, at each occurrence identically or differently, selected from CR_{T} or N;
V is selected from the group consisting of: O, S, Se, NR′, CR′R′, SiR′R′ and GeR′R′, wherein when two R′ are present at the same time, the two R′ are identical or different;
R′ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 4-1 to Formula 4-3, adjacent substituents R′ and R_{T} can be optionally joined to form a ring.

In the present disclosure, the expression that “adjacent substituents R′ and R_{T} can be optionally joined to form a ring” is intended to mean that any one or more of groups of adjacent substituents, such as two adjacent substituents R′, and two adjacent substituents R_{T}, can be joined to form a ring. Obviously, it is also possible that none of these adjacent substituents are joined to form a ring.

According to an embodiment of the present disclosure, the ligand Lₐ has a structure represented by any one of Formula 4-4 to Formula 4-7:

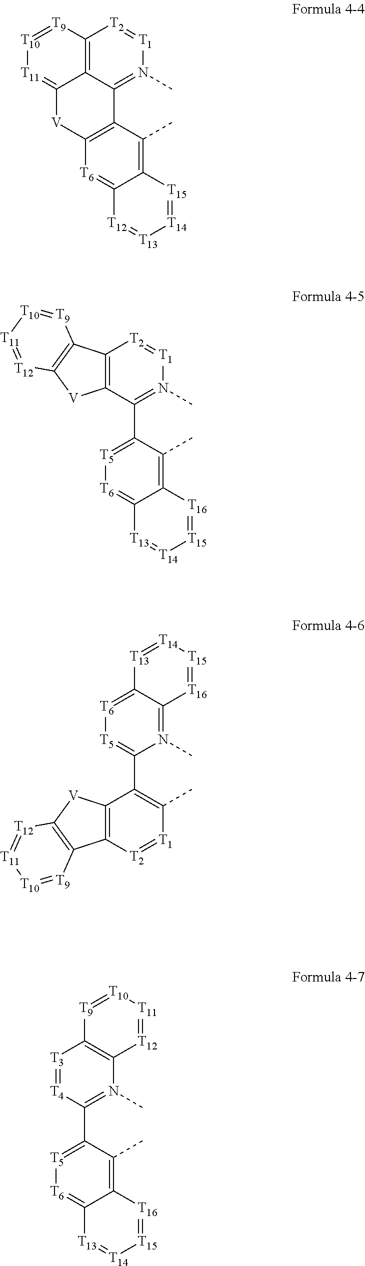

wherein T₁ to T₆ and T₉ to T₁₆ are, at each occurrence identically or differently, selected from CR_{T};
V is selected from the group consisting of: O, S, Se, NR′, CR′R′, SiR′R′ and GeR′R′, wherein when two R′ are present at the same time, the two R′ are identical or different;
R′ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 4-4 to Formula 4-7, adjacent substituents R′ and R_{T} can be optionally joined to form a ring.

According to an embodiment of the present disclosure, T₁ to T₆ and T₉ to T₁₆ are, at each occurrence identically or differently, selected from CR_{T}, and R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, at least one, two or three of R_{T} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, in Formula 4-1, at least one of T₁, T₂ and T₉ to T₁₁ is selected from CR_{T}, and at least one of T₆ and T₁₂ to T₁₅ is selected from CR_{T}; in Formula 4-2, at least one of T₁, T₂ and T₉ to T₁₂ is selected from CR_{T}, and at least one of T₅, T₆ and T₁₃ to T₁₆ is selected from CR_{T}; in Formula 4-3, at least one of T₃, T₄ and T₉ to T₁₂ is selected from CR_{T}, and at least one of T₅, T₆ and T₁₃ to T₁₆ is selected from CR_{T}; and the R_{T} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, in Formula 4-1, T₁, T₂, T₆, T₁₀ and T₁₄ are selected from CR_{T}; in Formula 4-2, T₆, T₁₁ and T₁₂ are selected from CR_{T}; in Formula 4-3, T₃, T₆ and T₉ are selected from CR_{T}; and the R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, the ligand Lₐ is, at each occurrence identically or differently, selected from the group consisting of Lₐ₁ to Lₐ₁₀₉, wherein the specific structures of Lₐ₁ to Lₐ₁₀₉ are referred to claim 17.

According to an embodiment of the present disclosure, the ligand Lₐ is, at each occurrence identically or differently, selected from the group consisting of Lₐ₁ to Lₐ₁₁₀, wherein the specific structures of Lₐ₁ to Lₐ₁₁₀ are referred to claim 17.

According to an embodiment of the present disclosure, the third compound has a general formula of M(Lₐ)ₘ(L_{b})ₙ(L_{c})_{q}, wherein the metal M is selected from a metal with a relative atomic mass greater than 40, Lₐ, L_{b} and L_{c} are a first ligand, a second ligand and a third ligand coordinated to the metal M, respectively, and the ligands Lₐ, L_{b} and L_{c} may be identical or different;
m is 1, 2 or 3, n is 0, 1 or 2, q is 0, 1 or 2, and m+n+q is equal to an oxidation state of the metal M; when m is greater than or equal to 2, a plurality of Lₐ are identical or different; when n is 2, two L_{b} are identical or different; when q is 2, two L_{c} are identical or different;
the ligands Lₐ, L_{b} and L_{c} can be optionally joined to form a multidentate ligand;
the ligands L_{b} and L_{c} are, at each occurrence identically or differently, selected from the group consisting of the following structures:

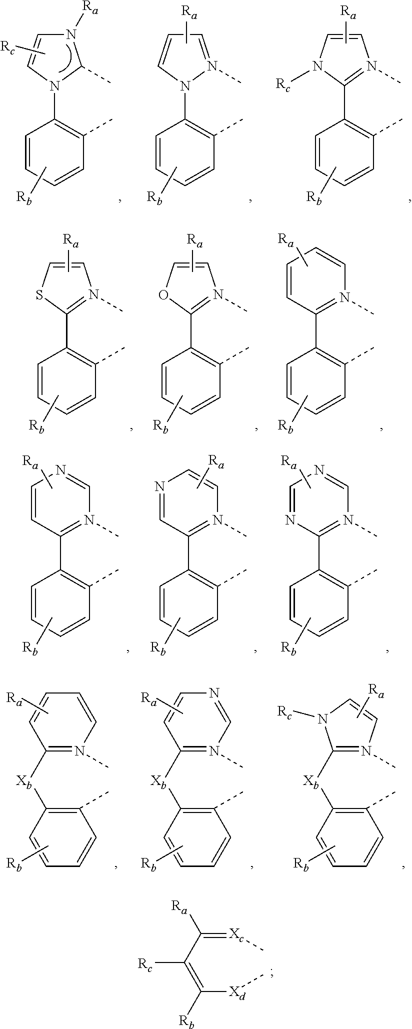

wherein Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

In this embodiment, the expression that adjacent substituents Rₐ, R_{b}, R_{c}, R_{N1}, R_{N2}, R_{C1} and R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

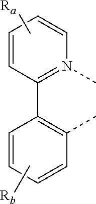

can be optionally joined to form a ring, which can form one or more of structures including but not limited to the following structures:

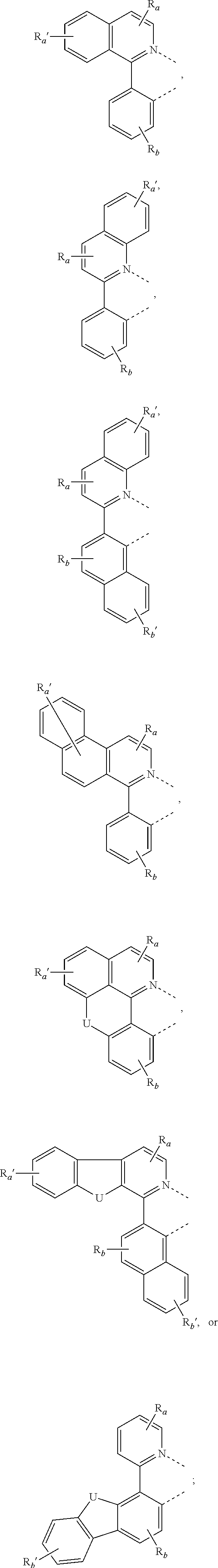

wherein U is selected from O, S, Se, NR″ or CR″R″, wherein a definition of each of R″, Rₐ′ and R_{b}′ is the same as that of Rₐ. Obviously, it is also possible that none of these substituents are joined to form a ring.

According to an embodiment of the present disclosure, the metal M is selected from Ir, Rh, Re, Os, Pt, Au or Cu.

According to an embodiment of the present disclosure, the metal M is selected from Ir or Pt.

According to an embodiment of the present disclosure, the metal M is Ir.

According to an embodiment of the present disclosure, the ligand L_{b} is, at each occurrence identically or differently, selected from the following structure:

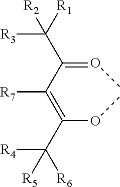

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁ to R₇ can be optionally joined to form a ring.

In this embodiment, the expression that “adjacent substituents R₁, R₂, R₃, R₄, R₅, R₆ and R₇ can be optionally joined to form a ring” is intended to mean that any one or more of groups of adjacent substituents, such as substituents R₁ and R₂, substituents R₁ and R₃, substituents R₂ and R₃, substituents R₄ and R₅, substituents R₄ and R₆, substituents R₅ and R₆, substituents R₁ and R₇, substituents R₂ and R₇, substituents R₃ and R₇, substituents R₄ and R₇, substituents R₅ and R₇, and substituents R₆ and R₇, can be joined to form a ring. Obviously, it is also possible that none of these substituents are joined to form a ring.

According to an embodiment of the present disclosure, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

According to an embodiment of the present disclosure, in the third compound, the ligand L_{b} is, at each occurrence identically or differently, selected from the group consisting of L_{b1} to L_{b322}, wherein the specific structures of L_{b1} to L_{b322} are referred to claim 21.

According to an embodiment of the present disclosure, in the third compound, the ligand L_{c} is, at each occurrence identically or differently, selected from the group consisting of L_{c1} to L_{c231}, wherein the specific structures of L_{c1} to L_{c231} are referred to claim 21.

According to an embodiment of the present disclosure, wherein the third compound is an Ir complex and has a structure of Ir(Lₐ)₂(L_{b}) or Ir(Lₐ)₂(L_{c}) or Ir(Lₐ)(L_{c})₂ or Ir(Lₐ)(L_{b})(L_{c});
wherein when the third compound has a structure of Ir(Lₐ)₂(L_{b}), Lₐ is, at each occurrence identically or differently, selected from any one or any two of the group consisting of Lₐ₁ to Lₐ₁₀₉, and L_{b} is selected from any one of the group consisting of L_{b1} to L_{b322}; when the third compound has a structure of Ir(Lₐ)₂(L_{c}), Lₐ is, at each occurrence identically or differently, selected from any one or any two of the group consisting of Lₐ₁ to Lₐ₁₀₉, and L_{c} is selected from any one of the group consisting of L_{c1} to L_{c231}; when the third compound has a structure of Ir(Lₐ)(L_{c})₂, Lₐ is selected from any one of the group consisting of Lₐ₁ to Lₐ₁₀₉, and L_{c} is, at each occurrence identically or differently, selected from any one or any two of the group consisting of L_{c1} to L_{c231}; when the third compound has a structure of Ir(Lₐ)(L_{b})(L_{c}), Lₐ is selected from any one of the group consisting of Lₐ₁ to Lₐ₁₀₉, L_{b} is selected from any one of the group consisting of L_{b1} to L_{b322}, and L_{c} is selected from any one of the group consisting of L_{c1} to L_{c231}.

According to an embodiment of the present disclosure, wherein the third compound is an Ir complex and has a structure of Ir(Lₐ)₂(L_{b}) or Ir(Lₐ)₂(L_{c}) or Ir(Lₐ)(L_{c})₂ or Ir(Lₐ)(L_{b})(L_{c});
wherein when the third compound has a structure of Ir(Lₐ)₂(L_{b}), Lₐ is, at each occurrence identically or differently, selected from any one or any two of the group consisting of Lₐ₁ to Lₐ₁₁₀, and L_{b} is selected from any one of the group consisting of L_{b1} to L_{b322}; when the third compound has a structure of Ir(Lₐ)₂(L_{c}), Lₐ is, at each occurrence identically or differently, selected from any one or any two of the group consisting of Lₐ₁ to Lₐ₁₁₀, and L_{c} is selected from any one of the group consisting of L_{c1} to L_{c231}; when the third compound has a structure of Ir(Lₐ)(L_{c})₂, Lₐ is selected from any one of the group consisting of Lₐ₁ to Lₐ₁₁₀, and L_{c} is, at each occurrence identically or differently, selected from any one or any two of the group consisting of L_{c1} to L_{c231}; when the third compound has a structure of Ir(Lₐ)(L_{b})(L_{c}), Lₐ is selected from any one of the group consisting of Lₐ₁ to Lₐ₁₁₀, L_{b} is selected from any one of the group consisting of L_{b1} to L_{b322}, and L_{c} is selected from any one of the group consisting of L_{c1} to L_{c231}.

According to an embodiment of the present disclosure, the third compound is selected from the group consisting of Compound RD-1 to Compound RD-51, wherein the specific structures of Compound RD-1 to Compound RD-51 are referred to claim 22.

According to an embodiment of the present disclosure, the third compound is selected from the group consisting of Compound RD-1 to Compound RD-52, wherein the specific structures of Compound RD-1 to Compound RD-52 are referred to claim 22.

According to an embodiment of the present disclosure, the organic layer is a light-emitting layer.

According to an embodiment of the present disclosure, in the device, in the light-emitting layer, the first compound and the second compound are host materials, and the third compound is a light-emitting material.

According to another embodiment of the present disclosure, further disclosed is an electronic apparatus, which comprises an electroluminescent device whose specific structure is as shown in any one of the preceding embodiments.

According to another embodiment of the present disclosure, further disclosed is a composition, which comprises a first compound, a second compound and a third compound;
wherein the first compound has a structure represented by Formula 1:

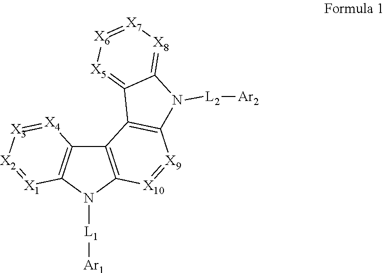

wherein in Formula 1,
X₁ to X₁₀ are, at each occurrence identically or differently, selected from CRₓ or N;
L₁ and L₂ are each independently selected from a single bond, substituted or unsubstituted arylene having 6 to 30 carbon atoms, substituted or unsubstituted heteroarylene having 3 to 30 carbon atoms or a combination thereof;
Ar₁ and Ar₂ are each independently selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 1, adjacent substituents Rₓ can be optionally joined to form a ring;
wherein the second compound has a structure represented by Formula 2:

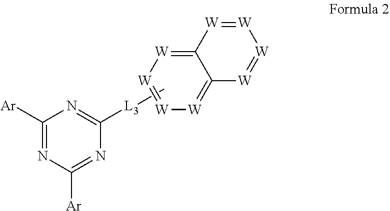

wherein in Formula 2,
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2, adjacent substituents R_{w} can be optionally joined to form a ring;
wherein the third compound is a metal complex, wherein the metal complex comprises a metal with a relative atomic mass greater than 40 and a ligand Lₐ, wherein the ligand Lₐ has a structure represented by Formula 3:

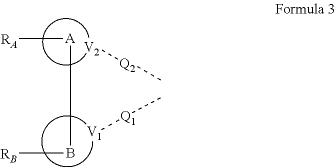

wherein in Formula 3,
the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof;
V₁ and V₂ are each independently selected from C or N, and V₁ is different from V₂;
Q₁ and Q₂ are, at each occurrence identically or differently, selected from a single bond, O, S, Se or NR_{Q}; when both Q₁ and Q₂ are single bonds, the monocyclic ring in the ring A and the ring B that is directly joined to the metal through carbon is a six-membered ring;
R_{A} and R_{B} represent, at each occurrence identically or differently, mono-substitution, multiple substitutions or non-substitution;
R_{Q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 3, adjacent substituents R_{A} and R_{B} can be optionally joined to form a ring.

According to an embodiment of the present disclosure, the composition is a light-emitting layer composition.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

Methods for preparing a first compound, a second compound and a third compound selected herein are not limited in the present disclosure. Those skilled in the art can prepare the first compound, the second compound and the third compound by conventional synthesis methods or can easily prepare the first compound, the second compound and the third compound with reference to Patent Application No. CN111095586A and other patent applications. The preparation methods are not repeated herein. The method for preparing an electroluminescent device is not limited. The preparation methods in the following device examples are merely examples and are not to be construed as limitations. Those skilled in the art can make reasonable improvements on the preparation methods in the following device examples based on the related art. For example, the proportions of various materials in a light-emitting layer are not particularly limited. Those skilled in the art can reasonably select the proportions within a certain range based on the related art. For example, taking the total weight of the materials in the light-emitting layer for reference, a host material may account for 80% to 99% and a light-emitting material may account for 1% to 20%; or the host material may account for 90% to 98% and the light-emitting material may account for 2% to 10%. Further, the host material may include two or more materials, where a ratio of two host materials may be 99:1 to 1:99; or the ratio may be 80:20 to 20:80; or the ratio may be 60:40 to 40:60. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### DEVICE EXAMPLE

Hereinafter, the present disclosure is described in more detail with reference to the following examples. Apparently, the following examples are only for the purpose of illustration and are not intended to limit the scope of the present disclosure. Based on the following examples, those skilled in the art can obtain other examples of the present disclosure by conducting improvements on these examples.

### Example 1

Firstly, a glass substrate having an indium tin oxide (ITO) anode with a thickness of 120 nm was cleaned and then treated with UV ozone and oxygen plasma. After the treatment, the substrate was dried in a nitrogen-filled glovebox to remove moisture. Then, the substrate was mounted on a substrate holder and placed in a vacuum chamber. Organic layers specified below were sequentially deposited through thermal vacuum on the ITO anode at a rate of 0.01 to 5 Å/s and a vacuum degree of about 10-8 Torr. Compound HT and Compound HI were co-deposited for use as a hole injection layer (HIL) (100 Å) at a weight ratio of 97:3. Compound HT was used as a hole transporting layer (HTL) (400 Å). Compound EB was used as an electron blocking layer (EBL) (50 Å). Then, First Compound A-1 as a first host, Second Compound B-1 as a second host and Third Compound RD-11 as a dopant were co-deposited for use as an emissive layer (EML) (400 Å) at a weight ratio of 48.5:48.5:3. Compound HB was used as a hole blocking layer (HBL) (50 Å). On the hole blocking layer, Compound ET and 8-hydroxyquinolinolato-lithium (Liq) were co-deposited as an electron transporting layer (ETL) (350 Å) at a weight ratio of 40:60. Finally, 8-hydroxyquinolinolato-lithium (Liq) was deposited as an electron injection layer (EIL) with a thickness of 10 Å, and aluminum was deposited as a cathode with a thickness of 1200 Å. The device was transferred back to the glovebox and encapsulated with a glass lid to complete the device.

### Example 2

The preparation method in Example 2 was the same as that in Example 1, except that in the emissive layer (EML), Compound RD-11 was replaced with Compound RD-23 as the dopant.

### Example 3

The preparation method in Example 3 was the same as that in Example 1, except that in the emissive layer (EML), Compound B-1 was replaced with Compound B-101 as the second host.

### Example 4

The preparation method in Example 4 was the same as that in Example 3, except that in the emissive layer (EML), Compound RD-11 was replaced with Compound RD-23 as the dopant.

### Example 5

The preparation method in Example 5 was the same as that in Example 1, except that in the emissive layer (EML), Compound A-1 was replaced with Compound A-108 as the first host.

### Example 6

The preparation method in Example 6 was the same as that in Example 1, except that in the emissive layer (EML), Compound A-1 was replaced with Compound A-218 as the first host, Compound B-1 was replaced with Compound B-46 as the second host, Compound RD-11 was replaced with Compound RD-26 as the dopant and the weight ratio of Compound A-218, Compound B-46 and Compound RD-26 was 39.2:58.8:2.

### Example 7

The preparation method in Example 7 was the same as that in Example 2, except that in the emissive layer (EML), Compound B-1 was replaced with Compound B-46 as the second host and the weight ratio of Compound A-1, Compound B-46 and Compound RD-23 was 39.2:58.8:2.

### Example 8

The preparation method in Example 8 was the same as that in Example 4, except that in the emissive layer (EML), Compound A-1 was replaced with Compound A-219 as the first host and the weight ratio of Compound A-219, Compound B-101 and Compound RD-23 was 39.2:58.8:2.

### Example 9

The preparation method in Example 9 was the same as that in Example 1, except that in the emissive layer (EML), Compound RD-11 was replaced with Compound RD-19 as the dopant and the weight ratio of Compound A-1, Compound B-1 and Compound RD-19 was 49:49:2.

### Example 10

The preparation method in Example 10 was the same as that in Example 1, except that in the emissive layer (EML), Compound RD-11 was replaced with Compound RD-52 as the dopant and the weight ratio of Compound A-1, Compound B-1 and Compound RD-52 was 49:49:2.

### Comparative Example 1

The preparation method in Comparative Example 1 was the same as that in Example 1, except that in the emissive layer (EML), Compound RD-11 was replaced with Compound F as the dopant.

### Comparative Example 2

The preparation method in Comparative Example 2 was the same as that in Example 1, except that in the emissive layer (EML), Compound B-1 was replaced with Compound E as the second host.

### Comparative Example 3

The preparation method in Comparative Example 3 was the same as that in Example 1, except that in the emissive layer (EML), Compound B-1 was replaced with Compound D as the second host.

### Comparative Example 4

The preparation method in Comparative Example 4 was the same as that in Example 1, except that in the emissive layer (EML), Compound A-1 and Compound B-1 were replaced with Compound B-1 as the hosts and the weight ratio of Compound B-1 and Compound RD-11 was 97:3.

### Comparative Example 5

The preparation method in Comparative Example 5 was the same as that in Example 1, except that in the emissive layer (EML), Compound A-1 and Compound B-1 were replaced with Compound A-1 as the hosts and the weight ratio of Compound A-1 and Compound RD-11 was 97:3.

Detailed structures and thicknesses of layers of the devices are shown in the following table. A layer using more than one material is obtained by doping different compounds at their weight ratio as recorded.

TABLE 1
Part of device structures in Examples 1 to 10 and Comparative Examples 1 to 5

| Device ID | HIL | HTL | EBL | EML | HBL | ETL |
|---|---|---|---|---|---|---|
| Example 1 | Compound | Compound | Compound | Compound | Compound | Compound |
| | HT: | HT | EB | A-1:Compound | HB | ET:Liq |
| | Compound | (400 Å) | (50 Å) | B-1:Compound | (50 Å) | (40:60) |
| | HI | | | RD-11 | | (350 Å) |
| | (97:3) | | | (48.5:48.5:3) | | |
| | (100 Å) | | | (400 Å) | | |
| Example 2 | Compound | Compound | Compound | Compound | Compound | Compound |
| | HT: | HT | EB | A-1:Compound | HB | ET:Liq |
| | Compound | (400 Å) | (50 Å) | B-1:Compound | (50 Å) | (40:60) |
| | HI | | | RD-23 | | (350 Å) |
| | (97:3) | | | (48.5:48.5:3) | | |
| | (100 Å) | | | (400 Å) | | |
| Example 3 | Compound | Compound | Compound | Compound | Compound | Compound |
| | HT: | HT | EB | A-1:Compound | HB | ET:Liq |
| | Compound | (400 Å) | (50 Å) | B-101:Compound | (50 Å) | (40:60) |
| | HI | | | RD-11 | | (350 Å) |
| | (97:3) | | | (48.5:48.5:3) | | |
| | (100 Å) | | | (400 Å) | | |
| Example 4 | Compound | Compound | Compound | Compound | Compound | Compound |
| | HT: | HT | EB | A-1:Compound | HB | ET:Liq |
| | Compound | (400 Å) | (50 Å) | B-101:Compound | (50 Å) | (40:60) |
| | HI | | | RD-23 | | (350 Å) |
| | (97:3) | | | (48.5:48.5:3) | | |
| | (100 Å) | | | (400 Å) | | |
| Example 5 | Compound | Compound | Compound | Compound | Compound | Compound |
| | HT: | HT | EB | A-108:Compound | HB | ET:Liq |
| | Compound | (400 Å) | (50 Å) | B-1:Compound | (50 Å) | (40:60) |
| | HI | | | RD-11 | | (350 Å) |
| | (97:3) | | | (48.5:48.5:3) | | |
| | (100 Å) | | | (400 Å) | | |
| Example 6 | Compound | Compound | Compound | Compound | Compound | Compound |
| | HT: | HT | EB | A-218:Compound | HB | ET:Liq |
| | Compound | (400 Å) | (50 Å) | B-46:Compound | (50 Å) | (40:60) |
| | HI | | | RD-26 | | (350 Å) |
| | (97:3) | | | (39.2:58.8:2) | | |
| | (100 Å) | | | (400 Å) | | |
| Example 7 | Compound | Compound | Compound | Compound | Compound | Compound |
| | HT: | HT | EB | A-1:Compound | HB | ET:Liq |
| | Compound | (400 Å) | (50 Å) | B-46:Compound | (50 Å) | (40:60) |
| | HI | | | RD-23 | | (350 Å) |
| | (97:3) | | | (39.2:58.8:2) | | |
| | (100 Å) | | | (400 Å) | | |
| Example 8 | Compound | Compound | Compound | Compound | Compound | Compound |
| | HT: | HT | EB | A-219:Compound | HB | ET: Liq |
| | Compound | (400 Å) | (50 Å) | B-101:Compound | (50 Å) | (40:60) |
| | HI | | | RD-23 | | (350 Å) |
| | (97:3) | | | (39.2:58.8:2) | | |
| | (100 Å) | | | (400 Å) | | |
| Example 9 | Compound | Compound | Compound | Compound | Compound | Compound |
| | HT: | HT | EB | A-1:Compound | HB | ET:Liq |
| | Compound | (400 Å) | (50 Å) | B-1:Compound | (50 Å) | (40:60) |
| | HI | | | RD-19 | | (350 Å) |
| | (97:3) | | | (49:49:2) | | |
| | (100 Å) | | | (400 Å) | | |
| Example 10 | Compound | Compound | Compound | Compound | Compound | Compound |
| | HT: | HT | EB | A-1:Compound | HB | ET:Liq |
| | Compound | (400 Å) | (50 Å) | B-1:Compound | (50 Å) | (40:60) |
| | HI | | | RD-52 | | (350 Å) |
| | (97:3) | | | (49:49:2) | | |
| | (100 Å) | | | (400 Å) | | |
| Comparative | Compound | Compound | Compound | Compound | Compound | Compound |
| Example 1 | HT: | HT | EB | A-1:Compound | HB | ET:Liq |
| | Compound | (400 Å) | (50 Å) | B-1:Compound F | (50 Å) | (40:60) |
| | HI | | | (48.5:48.5:3) | | (350 Å) |
| | (97:3) | | | (400 Å) | | |
| | (100 Å) | | | | | |
| Comparative | Compound | Compound | Compound | Compound | Compound | Compound |
| Example 2 | HT: | HT | EB | A-1:Compound | HB | ET:Liq |
| | Compound | (400 Å) | (50 Å) | E:Compound | (50 Å) | (40:60) |
| | HI | | | RD-11 | | (350 Å) |
| | (97:3) | | | (48.5:48.5:3) | | |
| | (100 Å) | | | (400 Å) | | |
| Comparative | Compound | Compound | Compound | Compound | Compound | Compound |
| Example 3 | HT: | HT | EB | A-1:Compound | HB | ET:Liq |
| | Compound | (400 Å) | (50 Å) | D:Compound | (50 Å) | (40:60) |
| | HI | | | RD-11 | | (350 Å) |
| | (97:3) | | | (48.5:48.5:3) | | |
| | (100 Å) | | | (400 Å) | | |
| Comparative | Compound | Compound | Compound | Compound | Compound | Compound |
| Example 4 | HT: | HT | EB | B-1:Compound | HB | ET:Liq |
| | Compound | (400 Å) | (50 Å) | RD-11 | (50 Å) | (40:60) |
| | HI | | | (97:3) | | (350 Å) |
| | (97:3) | | | (400 Å) | | |
| | (100 Å) | | | | | |
| Comparative | Compound | Compound | Compound | Compound | Compound | Compound |
| Example 5 | HT: | HT | EB | A-1:Compound | HB | ET:Liq |
| | Compound | (400 Å) | (50 Å) | RD-11 | (50 Å) | (40:60) |
| | HI | | | (97:3) | | (350 Å) |
| | (97:3) | | | (400 Å) | | |
| | (100 Å) | | | | | |

The materials used in the devices have the following structures:

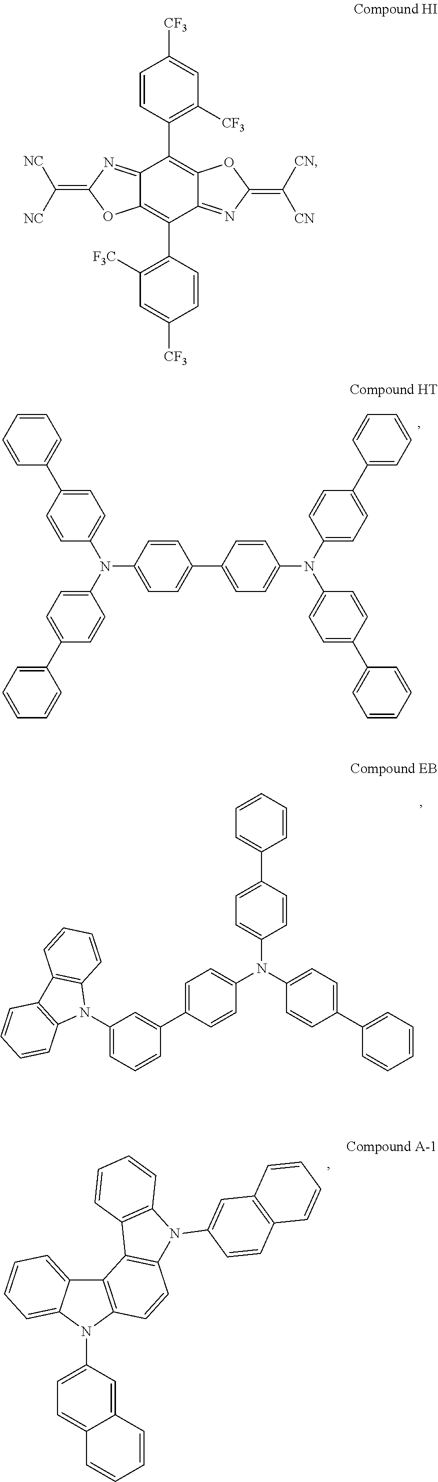 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc2cc(-n3c4ccccc4c4c5c6ccccc6n(-c6ccc7ccccc7c6)c5ccc43)ccc2c1]

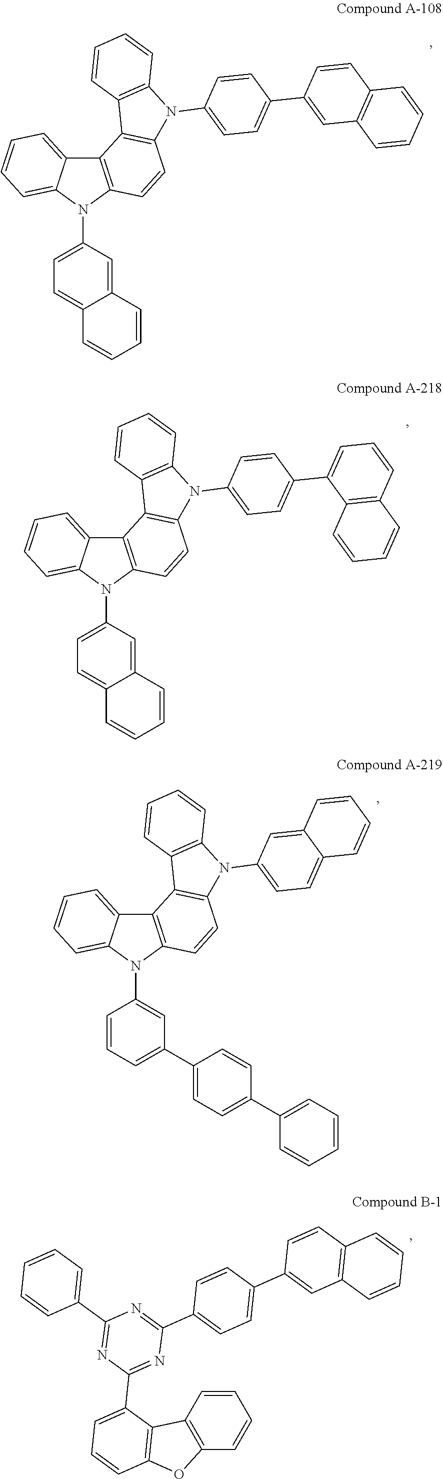 [SMILES: c1ccc2cc(-c3ccc(-n4c5ccccc5c5c6c7ccccc7n(-c7ccc8ccccc8c7)c6ccc54)cc3)ccc2c1 ; c1ccc2cc(-n3c4ccccc4c4c5c6ccccc6n(-c6ccc(-c7cccc8ccccc78)cc6)c5ccc43)ccc2c1 ; c1ccc(-c2ccc(-c3cccc(-n4c5ccccc5c5c6c7ccccc7n(-c7ccc8ccccc8c7)c6ccc54)c3)cc2)cc1 ; c1ccc(-c2nc(-c3ccc(-c4ccc5ccccc5c4)cc3)nc(-c3cccc4oc5ccccc5c34)n2)cc1]

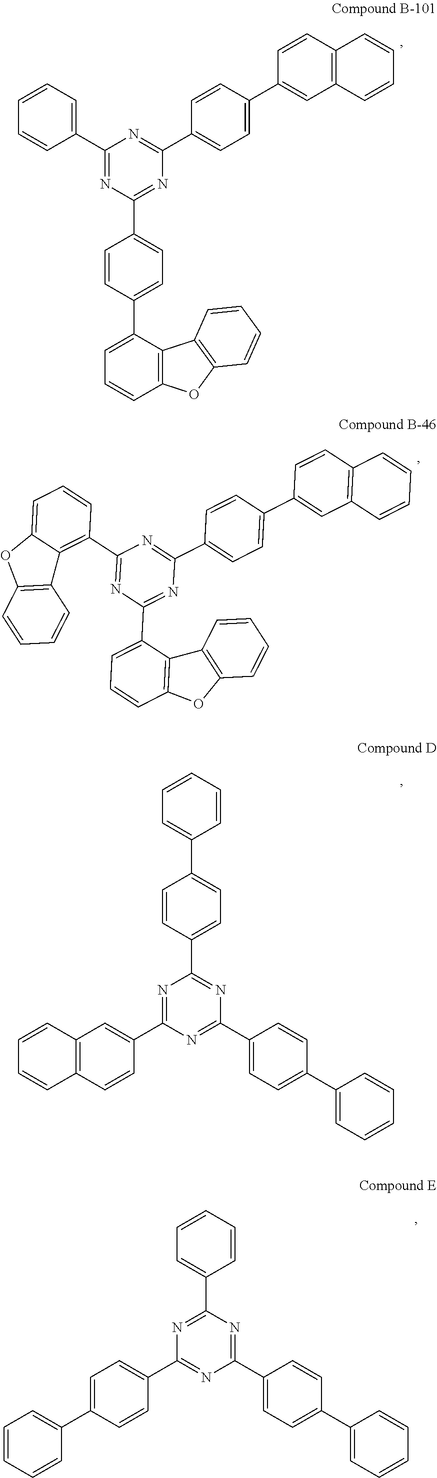 [SMILES: c1ccc(-c2nc(-c3ccc(-c4ccc5ccccc5c4)cc3)nc(-c3ccc(-c4cccc5oc6ccccc6c45)cc3)n2)cc1 ; c1ccc2cc(-c3ccc(-c4nc(-c5cccc6oc7ccccc7c56)nc(-c5cccc6oc7ccccc7c56)n4)cc3)ccc2c1 ; c1ccc(-c2ccc(-c3nc(-c4ccc(-c5ccccc5)cc4)nc(-c4ccc5ccccc5c4)n3)cc2)cc1 ; c1ccc(-c2ccc(-c3nc(-c4ccccc4)nc(-c4ccc(-c5ccccc5)cc4)n3)cc2)cc1]

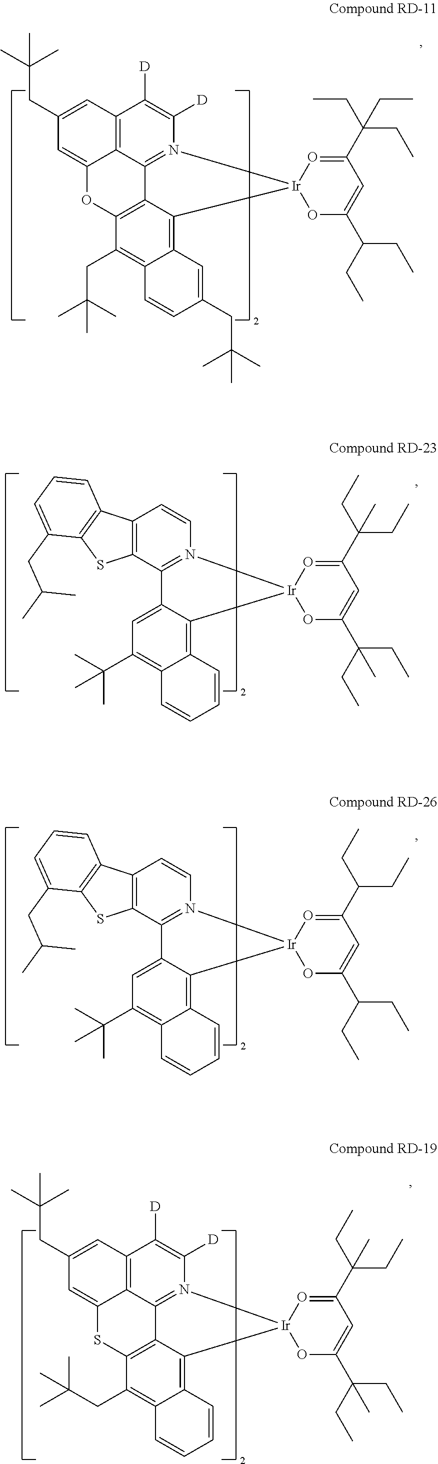

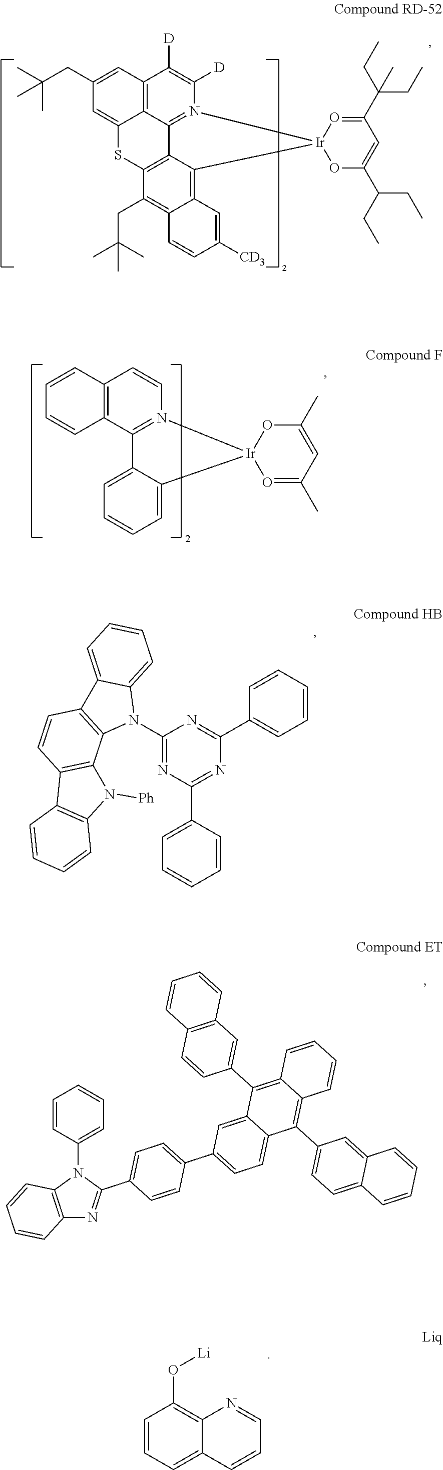

Table 2 lists the maximum emission wavelength (λₘₐₓ) and external quantum efficiency (EQE) of the examples and the comparative examples measured at a constant current of 15 mA/cm² and the device lifetime (LT97) tested at a constant current of 80 mA/cm², where LT97 refers to the time required for the brightness of the device to decay to 9700 of the initial brightness of the device.

TABLE 2
Device data in Examples 1 to 10 and Comparative
Examples 1 to 5

| | | | LT97 |
|---|---|---|---|
| Device ID | λₘₐₓ (nm) | EQE [%] | [h] |
| Example 1 | 620 | 23.38 | 32 |
| Example 2 | 624 | 25.75 | 59 |
| Example 3 | 620 | 23.74 | 70 |
| Example 4 | 625 | 25.66 | 120 |
| Example 5 | 620 | 23.97 | 50 |
| Example 6 | 622 | 26.3 | 129 |
| Example 7 | 624 | 26.3 | 44 |
| Example 8 | 622 | 26.0 | 54 |
| Example 9 | 632 | 25.5 | 38.7 |
| Example 10 | 638 | 25.0 | 84.8 |
| Comparative | 624 | 13.54 | 8 |
| Example 1 | | | |
| Comparative | 620 | 21.17 | 20 |
| Example 2 | | | |
| Comparative | 620 | 22.99 | 8 |
| Example 3 | | | |
| Comparative | 620 | 15.61 | 8 |
| Example 4 | | | |
| Comparative | 620 | 18.73 | 8 |
| Example 5 | | | |

Discussion

As can be seen from the data in Table 2, compared to Comparative Example 1, the maximum emission wavelengths in Example 1, Example 2 and Example 4 were substantially the same as that in Comparative Example 1; the external quantum efficiency in Example 1, Example 2 and Example 4 was significantly improved by 72.7%, 90.2% and 89.5%, respectively; and the lifetimes were even significantly improved by 3 times, 6.3 times and 14 times, respectively. Combinations of the first compound, the second compound and the third compound selected in the present disclosure were used in Example 1, Example 2 and Example 4. Although a first compound and a second compound selected in the present disclosure were used in Comparative Example 1, the light-emitting material (Compound F) used in Comparative Example 1 was a complex [Ir(piq)₂acac] which is commonly used in the related art. While, the light-emitting materials (Compound RD-11 and Compound RD-23) used in Example 1, Example 2 and Example 4 of the present disclosure were each a metal complex having a ligand comprising at least two fused rings. Device performance in Example 1, Example 2 and Example 4 was significantly improved. In particular, in Example 4, the device lifetime was significantly improved, and in the meantime, very high external quantum efficiency was obtained. This indicates that the third compound selected in the present disclosure can be better matched with the first compound and the second compound and the combination of the first compound, the second compound and the third compound has unexpectedly excellent performance.

As can be seen from the data of Comparative Example 2, Comparative Example 3, Example 1 and Example 3 in Table 2, Example 1 and Example 3 differed from Comparative Example 2 and Comparative Example 3 only in the second compound used, device performance in Example 1 and Example 3 was, however, significantly improved. Compared to Comparative Example 2, the maximum emission wavelengths in Example 1 and Example 3 remained to be consistent with that in Comparative Example 2, while the external quantum efficiency was improved by 10% and 12%, respectively, and the lifetimes were even improved by 0.6 times and 2.5 times, respectively. Compared to Comparative Example 3, the maximum emission wavelengths in Example 1 and Example 3 remained to be consistent with that in Comparative Example 3. Compared to Comparative Example 3 which has already achieved a very high level of external quantum efficiency, the external quantum efficiency in Example 1 and Example 3 was further improved and improved by 1.7% and 3.3%, respectively, which is very rare, and more importantly, the device lifetimes were significantly improved by as many as 3 times and 7.7 times, respectively. It indicates that the second compound used in the present disclosure can be better matched with the first compound and the third compound used in the present disclosure, can significantly improve the device performance and exhibits unexpectedly excellent performance.

In Example 1 and Example 5, the first compound and the second compound selected in the present disclosure were used as double host materials and matched with the third compound, and in Comparative Example 4 and Comparative Example 5, the first compound or the second compound selected in the present disclosure was used alone as a single host material and matched with the third compound. As can be seen from the data in Table 2, compared to Comparative Example 4 and Comparative Example 5, the maximum emission wavelength in Example 1 remained to be consistent with those in Comparative Example 4 and Comparative Example 5, the external quantum efficiency was significantly improved by 49.8% and 24.8%, and the lifetime was even improved by up to 3 times; the maximum emission wavelength in Example 5 remained to be consistent with those in Comparative Example 4 and Comparative Example 5, the external quantum efficiency was significantly improved by 53.6% and 28%, and the lifetime was even significantly improved by up to 5 times. This indicates that neither the first compound nor the second compound can be well matched with the third compound when used alone as a host material. However, both Example 1 and Example 5 where the first compound and the second compound selected in the present disclosure were used together as host materials and combined with the third compound had a very significant and unexpected improvement in device performance. Examples 6-10 further employed additional material combinations of the first compound and the second compound matched with the third compound selected in the present disclosure. The data showed that Examples 6-10 also all achieved very high external quantum efficiency and very long device lifetime, and effectively adjusted the emission wavelength, meeting requirements for light-emitting at different wavelength bands. The above data fully indicates that the compound combination of the first compound, the second compound and the third compound selected in the present disclosure has unexpectedly excellent performance.

The data of Examples 1 to 10 indicates that the use of the combinations of the different first compounds, second compounds and third compounds in the emissive layers enables the devices to obtain very excellent performance. This overall improvement in device performance is surprising and reaches an industry-leading level. In particular, in Example 4 and Example 6, an ultra-long lifetime can be obtained while high efficiency is obtained. These results indicate that the material combination of the first compound, the second compound and the third compound selected in the present disclosure has particularly excellent device performance and a broad application prospect.

In conclusion, this material combination of the first compound and the second compound matched with the third compound selected in the present disclosure can significantly improve device efficiency, significantly improve the device lifetime and provide more excellent device performance, which has an unexpectedly unique advantage.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An electroluminescent device, comprising:
an anode,
a cathode, and
an organic layer disposed between the anode and the cathode, wherein the organic layer comprises at least a first compound, a second compound and a third compound;
wherein the first compound has a structure represented by Formula 1: 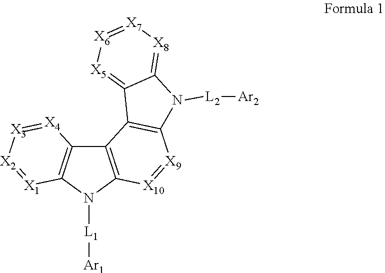
wherein in Formula 1,
X₁ to X₁₀ are, at each occurrence identically or differently, selected from CRₓ or N;
L₁ and L₂ are each independently selected from a single bond, substituted or unsubstituted arylene having 6 to 30 carbon atoms, substituted or unsubstituted heteroarylene having 3 to 30 carbon atoms or a combination thereof;
Ar₁ and Ar₂ are each independently selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 1, adjacent substituents Rₓ can be optionally joined to form a ring;
wherein the second compound has a structure represented by Formula 2: 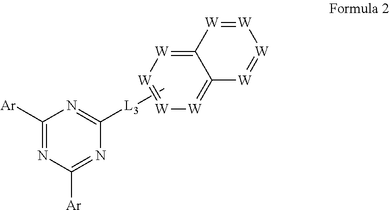
wherein in Formula 2,
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2, adjacent substituents Rₓ can be optionally joined to form a ring;
wherein the third compound is a metal complex, wherein the metal complex comprises a metal with a relative atomic mass greater than 40 and a ligand Lₐ, wherein the ligand Lₐ has a structure represented by Formula 3: 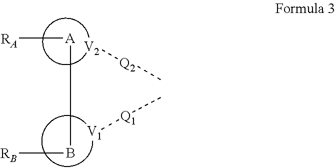
wherein in Formula 3,
the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof;
V₁ and V₂ are each independently selected from C or N, and V₁ is different from V₂;
Q₁ and Q₂ are, at each occurrence identically or differently, selected from a single bond, O, S, Se or NR_{Q};
when both Q₁ and Q₂ are single bonds, the monocyclic ring in the ring A and the ring B that is directly joined to the metal through carbon is a six-membered ring;
R_{A} and R_{B} represent, at each occurrence identically or differently, mono-substitution, multiple substitutions or non-substitution;
R_{Q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 3, adjacent substituents R_{A} and R_{B} can be optionally joined to form a ring.

2. The electroluminescent device according to claim 1, wherein Ar₁ and Ar₂ are, at each occurrence identically or differently, selected from substituted or unsubstituted aryl having 6 to 18 carbon atoms, substituted or unsubstituted heteroaryl having 3 to 18 carbon atoms or a combination thereof; and
preferably, Ar₁ and Ar₂ are, at each occurrence identically or differently, selected from substituted or unsubstituted phenyl, substituted or unsubstituted naphthyl, substituted or unsubstituted pyridyl, substituted or unsubstituted biphenyl, substituted or unsubstituted phenanthryl, substituted or unsubstituted chrysenyl, substituted or unsubstituted terphenyl, substituted or unsubstituted triphenylenyl, substituted or unsubstituted dibenzofuranyl, substituted or unsubstituted dibenzothienyl, substituted or unsubstituted fluorenyl, substituted or unsubstituted quinolyl, substituted or unsubstituted isoquinolyl or a combination thereof.

3. The electroluminescent device according to claim 1, wherein Rₓ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof;
preferably, Rₓ is, at each occurrence identically or differently, selected from hydrogen, deuterium, halogen, substituted or unsubstituted aryl having 6 to 30 carbon atoms, substituted or unsubstituted heteroaryl having 3 to 30 carbon atoms or a combination thereof; and
more preferably, Rₓ is, at each occurrence identically or differently, selected from hydrogen, deuterium, fluorine, substituted or unsubstituted phenyl, substituted or unsubstituted naphthyl, substituted or unsubstituted biphenyl, substituted or unsubstituted pyridyl, substituted or unsubstituted phenanthryl, substituted or unsubstituted triphenylenyl, substituted or unsubstituted dibenzofuranyl, substituted or unsubstituted dibenzothienyl or a combination thereof.

4. The electroluminescent device according to claim 1, wherein L₁ to L₂ are, at each occurrence identically or differently, selected from a single bond, substituted or unsubstituted arylene having 6 to 18 carbon atoms, substituted or unsubstituted heteroarylene having 3 to 18 carbon atoms or a combination thereof; and
preferably, L₁ and L₂ are, at each occurrence identically or differently, selected from a single bond, substituted or unsubstituted phenylene, substituted or unsubstituted pyridylene, substituted or unsubstituted naphthylene, substituted or unsubstituted biphenylene or a combination thereof.

5. The electroluminescent device according to claim 1, wherein the first compound is selected from the group consisting of the following compounds: 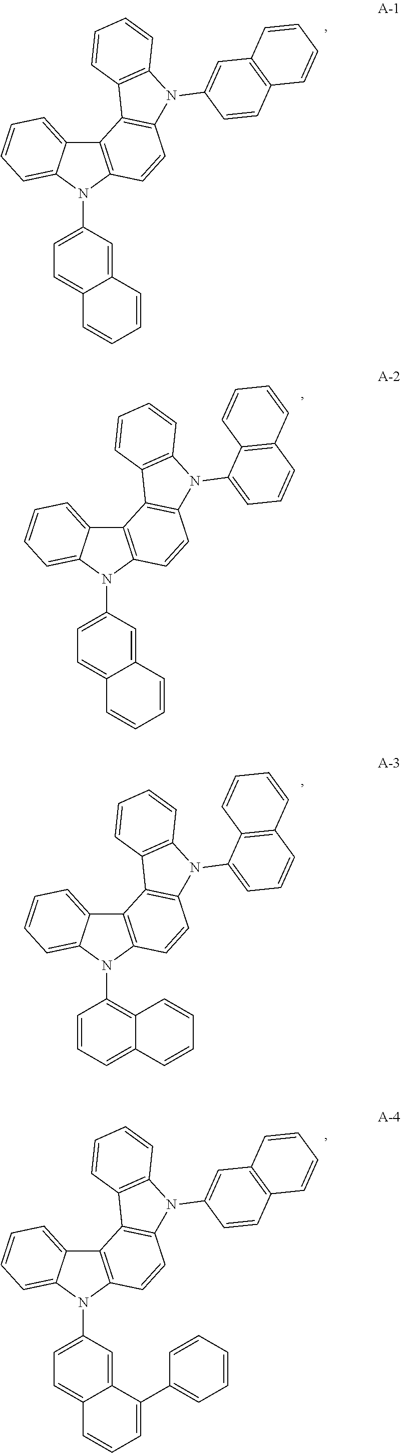 [SMILES: c1ccc2cc(-n3c4ccccc4c4c5c6ccccc6n(-c6ccc7ccccc7c6)c5ccc43)ccc2c1 ; c1ccc2cc(-n3c4ccccc4c4c5c6ccccc6n(-c6cccc7ccccc67)c5ccc43)ccc2c1 ; c1ccc2c(-n3c4ccccc4c4c5c6ccccc6n(-c6cccc7ccccc67)c5ccc43)cccc2c1 ; c1ccc(-c2cccc3ccc(-n4c5ccccc5c5c6c7ccccc7n(-c7ccc8ccccc8c7)c6ccc54)cc23)cc1] 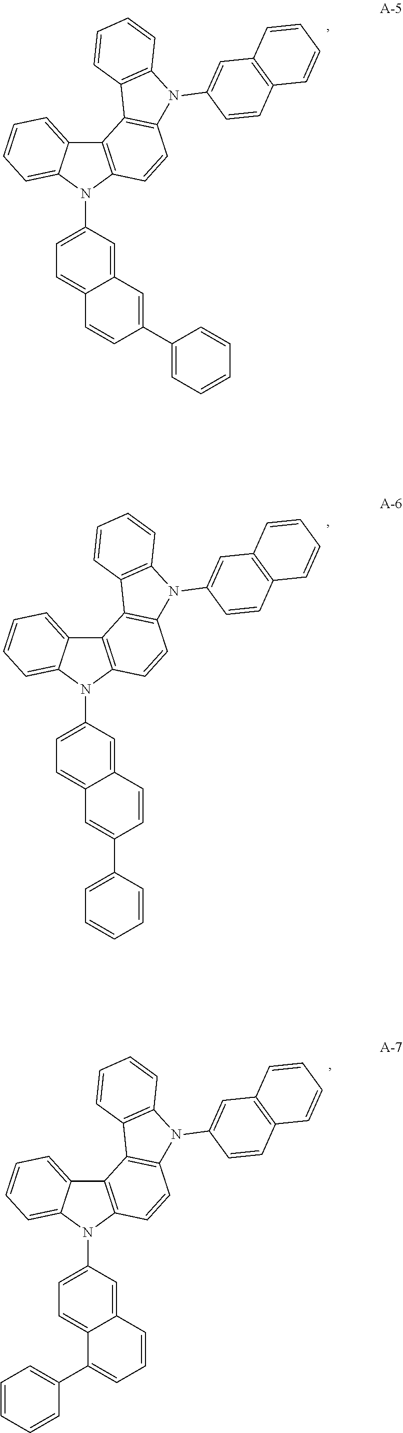 [SMILES: c1ccc(-c2ccc3ccc(-n4c5ccccc5c5c6c7ccccc7n(-c7ccc8ccccc8c7)c6ccc54)cc3c2)cc1 ; c1ccc(-c2ccc3cc(-n4c5ccccc5c5c6c7ccccc7n(-c7ccc8ccccc8c7)c6ccc54)ccc3c2)cc1 ; c1ccc(-c2cccc3cc(-n4c5ccccc5c5c6c7ccccc7n(-c7ccc8ccccc8c7)c6ccc54)ccc23)cc1] 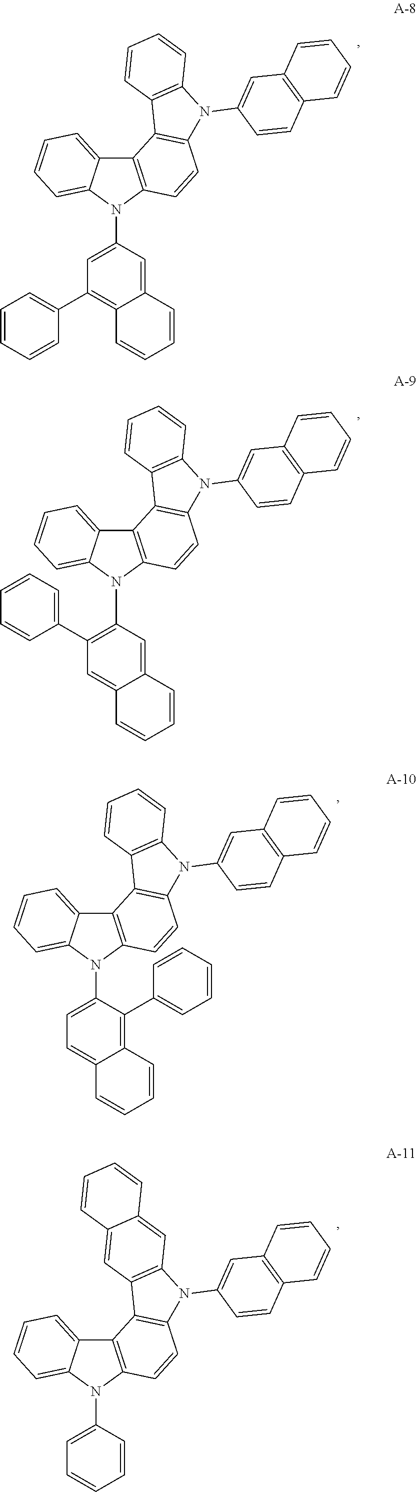 [SMILES: c1ccc(-c2cc(-n3c4ccccc4c4c5c6ccccc6n(-c6ccc7ccccc7c6)c5ccc43)cc3ccccc23)cc1 ; c1ccc(-c2cc3ccccc3cc2-n2c3ccccc3c3c4c5ccccc5n(-c5ccc6ccccc6c5)c4ccc32)cc1 ; c1ccc(-c2c(-n3c4ccccc4c4c5c6ccccc6n(-c6ccc7ccccc7c6)c5ccc43)ccc3ccccc23)cc1 ; c1ccc(-n2c3ccccc3c3c4c5cc6ccccc6cc5n(-c5ccc6ccccc6c5)c4ccc32)cc1] 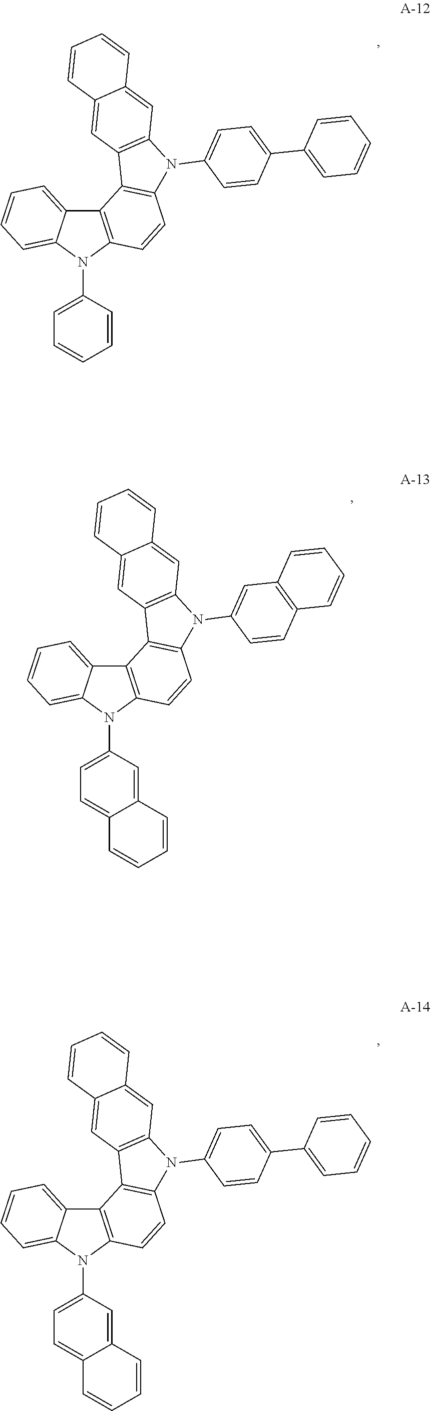 [SMILES: c1ccc(-c2ccc(-n3c4cc5ccccc5cc4c4c5c6ccccc6n(-c6ccccc6)c5ccc43)cc2)cc1 ; c1ccc2cc(-n3c4ccccc4c4c5c6cc7ccccc7cc6n(-c6ccc7ccccc7c6)c5ccc43)ccc2c1 ; c1ccc(-c2ccc(-n3c4cc5ccccc5cc4c4c5c6ccccc6n(-c6ccc7ccccc7c6)c5ccc43)cc2)cc1] 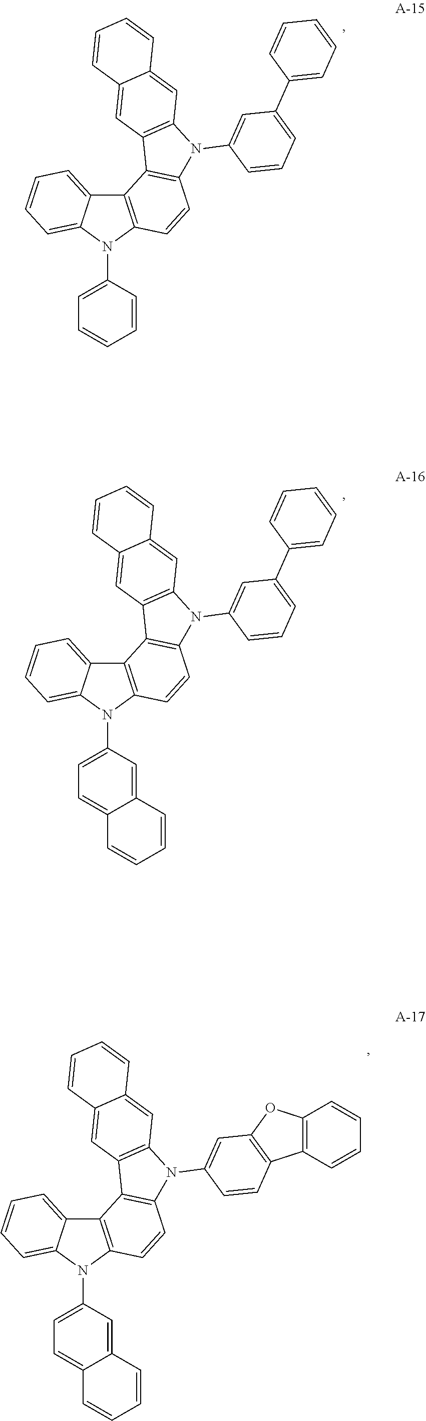 [SMILES: c1ccc(-c2cccc(-n3c4cc5ccccc5cc4c4c5c6ccccc6n(-c6ccccc6)c5ccc43)c2)cc1 ; c1ccc(-c2cccc(-n3c4cc5ccccc5cc4c4c5c6ccccc6n(-c6ccc7ccccc7c6)c5ccc43)c2)cc1 ; c1ccc2cc(-n3c4ccccc4c4c5c6cc7ccccc7cc6n(-c6ccc7c(c6)oc6ccccc67)c5ccc43)ccc2c1] 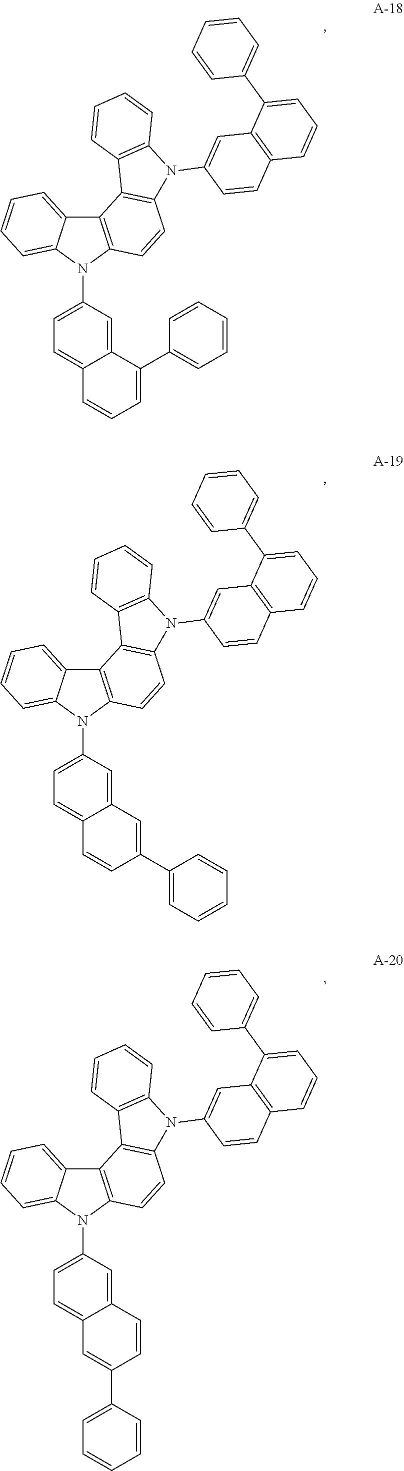 [SMILES: c1ccc(-c2cccc3ccc(-n4c5ccccc5c5c6c7ccccc7n(-c7ccc8cccc(-c9ccccc9)c8c7)c6ccc54)cc23)cc1 ; c1ccc(-c2ccc3ccc(-n4c5ccccc5c5c6c7ccccc7n(-c7ccc8cccc(-c9ccccc9)c8c7)c6ccc54)cc3c2)cc1 ; c1ccc(-c2ccc3cc(-n4c5ccccc5c5c6c7ccccc7n(-c7ccc8cccc(-c9ccccc9)c8c7)c6ccc54)ccc3c2)cc1] 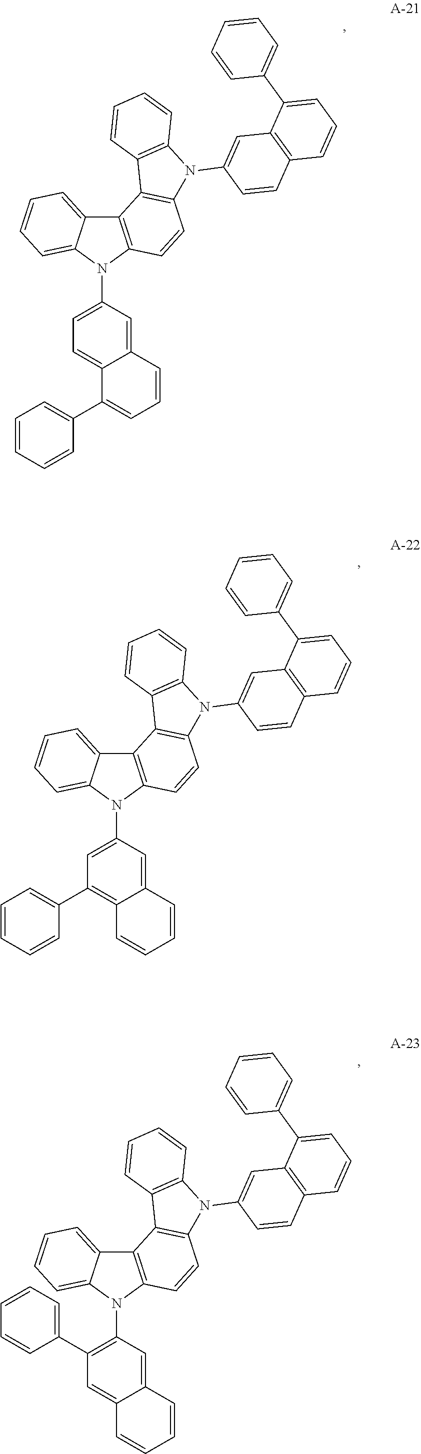 [SMILES: c1ccc(-c2cccc3cc(-n4c5ccccc5c5c6c7ccccc7n(-c7ccc8cccc(-c9ccccc9)c8c7)c6ccc54)ccc23)cc1 ; c1ccc(-c2cc(-n3c4ccccc4c4c5c6ccccc6n(-c6ccc7cccc(-c8ccccc8)c7c6)c5ccc43)cc3ccccc23)cc1 ; c1ccc(-c2cc3ccccc3cc2-n2c3ccccc3c3c4c5ccccc5n(-c5ccc6cccc(-c7ccccc7)c6c5)c4ccc32)cc1] 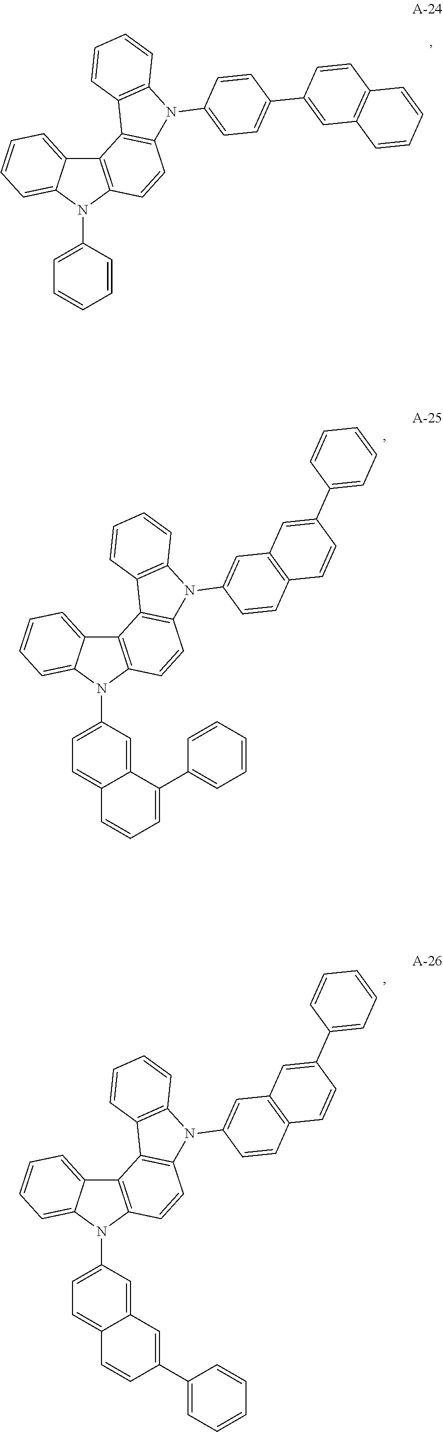 [SMILES: c1ccc(-n2c3ccccc3c3c4c5ccccc5n(-c5ccc(-c6ccc7ccccc7c6)cc5)c4ccc32)cc1 ; c1ccc(-c2ccc3ccc(-n4c5ccccc5c5c6c7ccccc7n(-c7ccc8cccc(-c9ccccc9)c8c7)c6ccc54)cc3c2)cc1 ; c1ccc(-c2ccc3ccc(-n4c5ccccc5c5c6c7ccccc7n(-c7ccc8ccc(-c9ccccc9)cc8c7)c6ccc54)cc3c2)cc1] 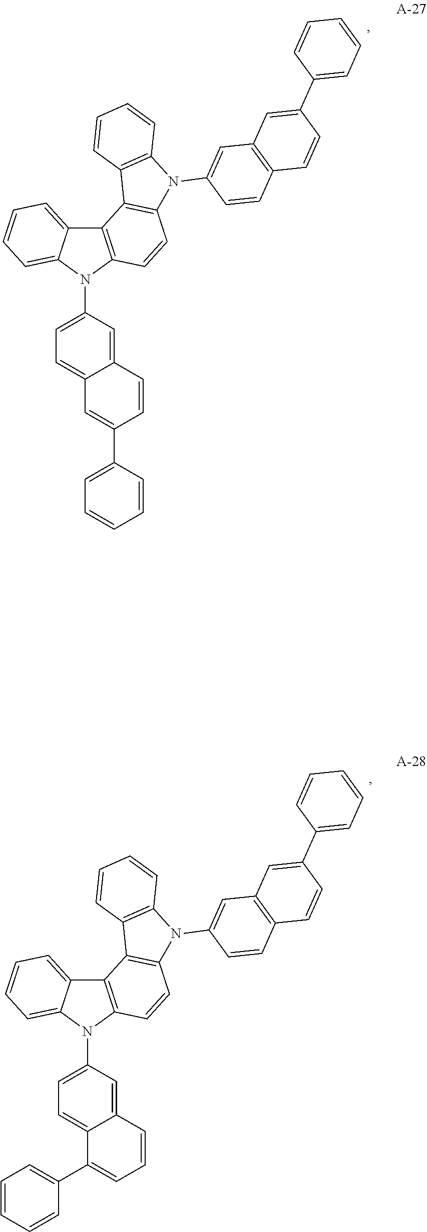 [SMILES: c1ccc(-c2ccc3cc(-n4c5ccccc5c5c6c7ccccc7n(-c7ccc8ccc(-c9ccccc9)cc8c7)c6ccc54)ccc3c2)cc1 ; c1ccc(-c2ccc3ccc(-n4c5ccccc5c5c6c7ccccc7n(-c7ccc8c(-c9ccccc9)cccc8c7)c6ccc54)cc3c2)cc1] 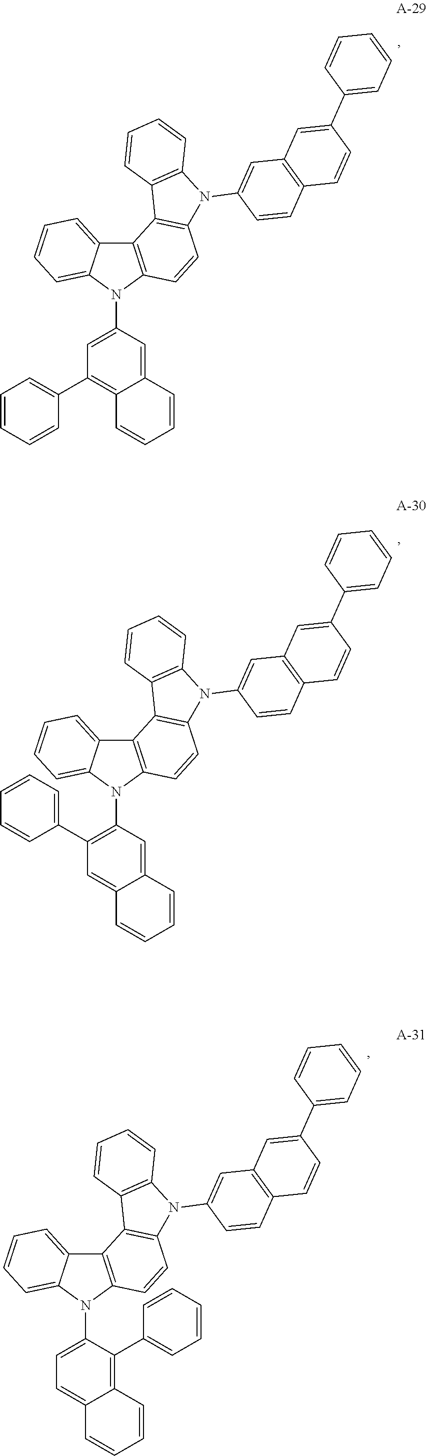 [SMILES: c1ccc(-c2ccc3ccc(-n4c5ccccc5c5c6c7ccccc7n(-c7cc(-c8ccccc8)c8ccccc8c7)c6ccc54)cc3c2)cc1 ; c1ccc(-c2ccc3ccc(-n4c5ccccc5c5c6c7ccccc7n(-c7cc8ccccc8cc7-c7ccccc7)c6ccc54)cc3c2)cc1 ; c1ccc(-c2ccc3ccc(-n4c5ccccc5c5c6c7ccccc7n(-c7ccc8ccccc8c7-c7ccccc7)c6ccc54)cc3c2)cc1] 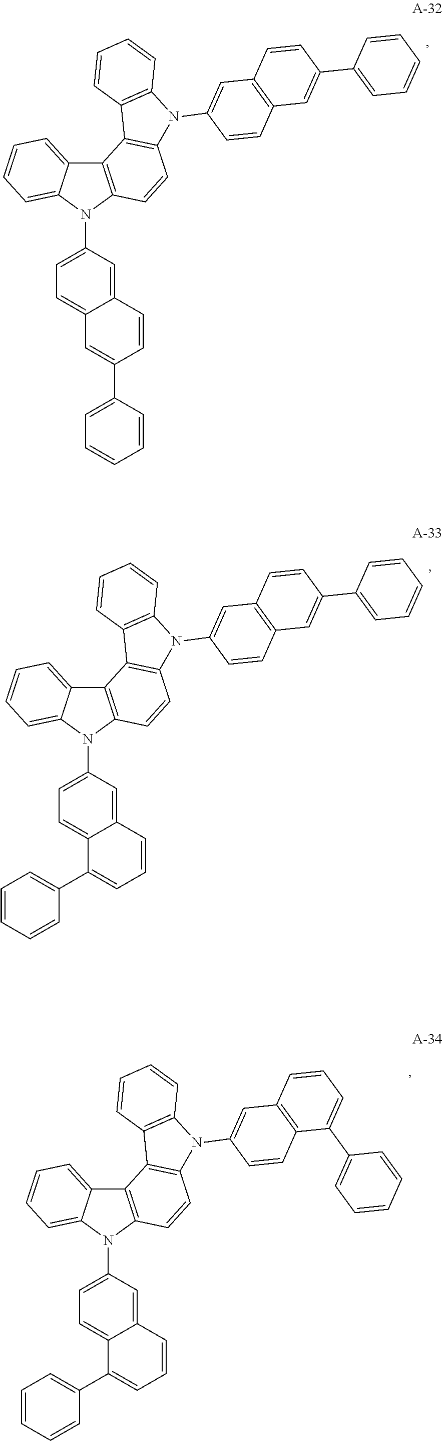 [SMILES: c1ccc(-c2ccc3cc(-n4c5ccccc5c5c6c7ccccc7n(-c7ccc8cc(-c9ccccc9)ccc8c7)c6ccc54)ccc3c2)cc1 ; c1ccc(-c2ccc3cc(-n4c5ccccc5c5c6c7ccccc7n(-c7ccc8c(-c9ccccc9)cccc8c7)c6ccc54)ccc3c2)cc1 ; c1ccc(-c2cccc3cc(-n4c5ccccc5c5c6c7ccccc7n(-c7ccc8c(-c9ccccc9)cccc8c7)c6ccc54)ccc23)cc1] 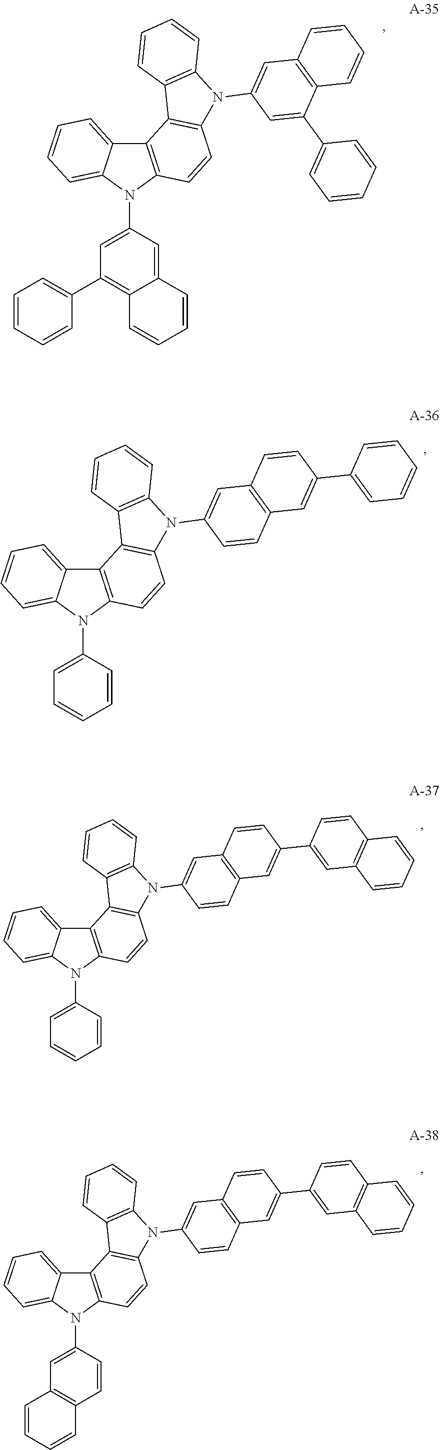 [SMILES: c1ccc(-c2cc(-n3c4ccccc4c4c5c6ccccc6n(-c6cc(-c7ccccc7)c7ccccc7c6)c5ccc43)cc3ccccc23)cc1 ; c1ccc(-c2ccc3cc(-n4c5ccccc5c5c6c7ccccc7n(-c7ccccc7)c6ccc54)ccc3c2)cc1 ; c1ccc(-n2c3ccccc3c3c4c5ccccc5n(-c5ccc6cc(-c7ccc8ccccc8c7)ccc6c5)c4ccc32)cc1 ; c1ccc2cc(-c3ccc4cc(-n5c6ccccc6c6c7c8ccccc8n(-c8ccc9ccccc9c8)c7ccc65)ccc4c3)ccc2c1] 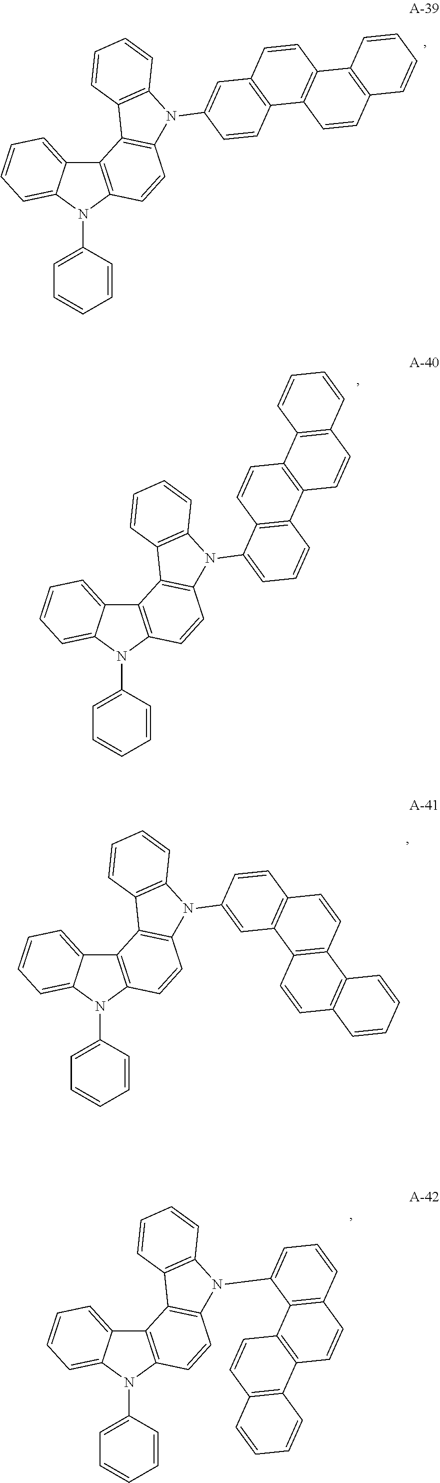 [SMILES: c1ccc(-n2c3ccccc3c3c4c5ccccc5n(-c5ccc6c(ccc7c8ccccc8ccc67)c5)c4ccc32)cc1 ; c1ccc(-n2c3ccccc3c3c4c5ccccc5n(-c5cccc6c5ccc5c7ccccc7ccc65)c4ccc32)cc1 ; c1ccc(-n2c3ccccc3c3c4c5ccccc5n(-c5ccc6ccc7c8ccccc8ccc7c6c5)c4ccc32)cc1 ; c1ccc(-n2c3ccccc3c3c4c5ccccc5n(-c5cccc6ccc7c8ccccc8ccc7c56)c4ccc32)cc1] 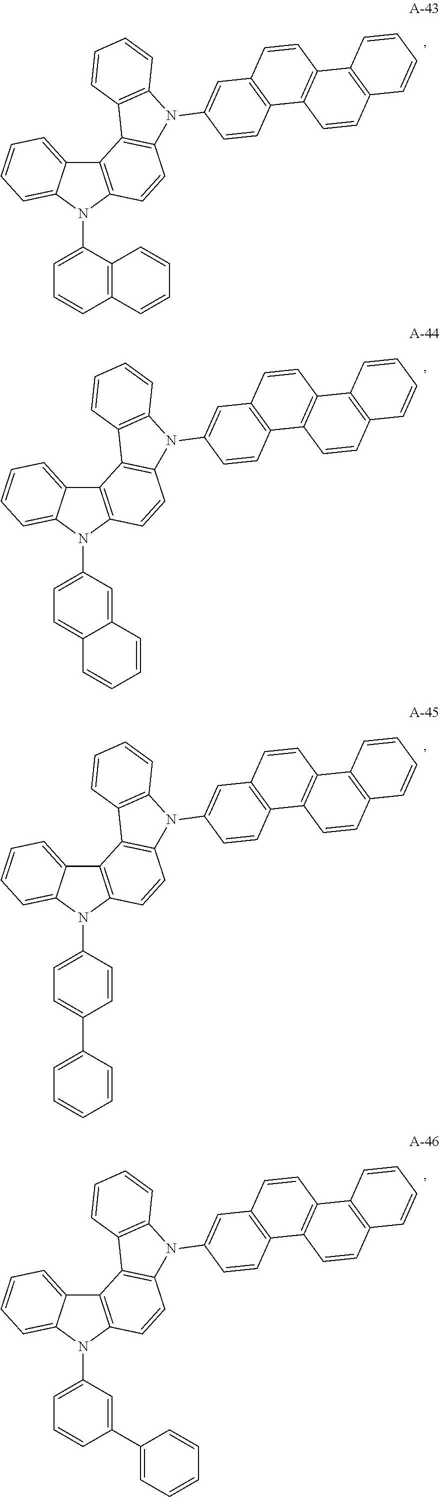 [SMILES: c1ccc2c(-n3c4ccccc4c4c5c6ccccc6n(-c6ccc7c(ccc8c9ccccc9ccc78)c6)c5ccc43)cccc2c1 ; c1ccc2cc(-n3c4ccccc4c4c5c6ccccc6n(-c6ccc7c(ccc8c9ccccc9ccc78)c6)c5ccc43)ccc2c1 ; c1ccc(-c2ccc(-n3c4ccccc4c4c5c6ccccc6n(-c6ccc7c(ccc8c9ccccc9ccc78)c6)c5ccc43)cc2)cc1 ; c1ccc(-c2cccc(-n3c4ccccc4c4c5c6ccccc6n(-c6ccc7c(ccc8c9ccccc9ccc78)c6)c5ccc43)c2)cc1] 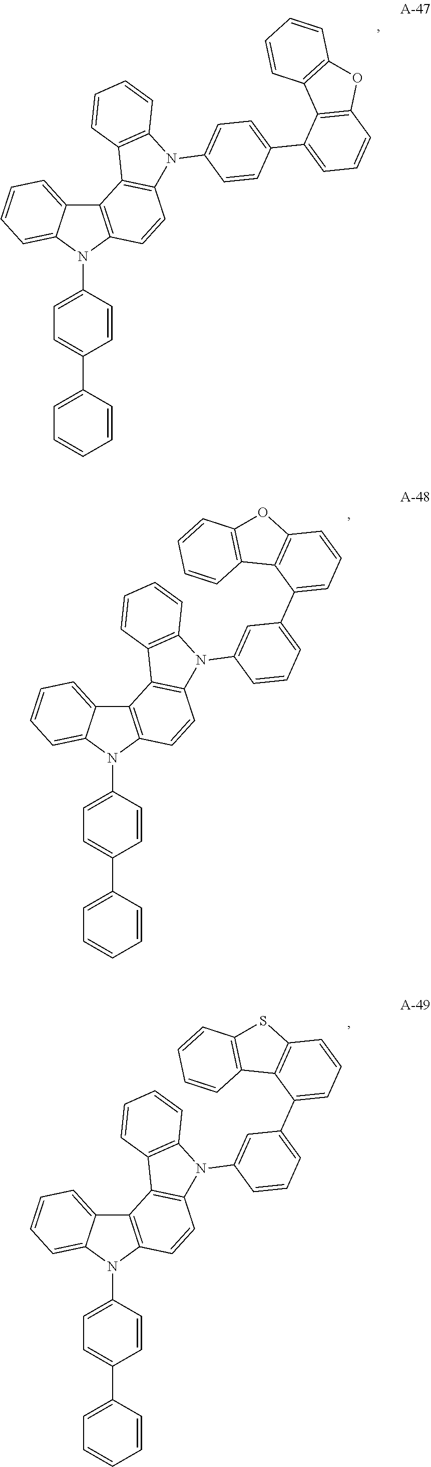 [SMILES: c1ccc(-c2ccc(-n3c4ccccc4c4c5c6ccccc6n(-c6ccc(-c7cccc8oc9ccccc9c78)cc6)c5ccc43)cc2)cc1 ; c1ccc(-c2ccc(-n3c4ccccc4c4c5c6ccccc6n(-c6cccc(-c7cccc8oc9ccccc9c78)c6)c5ccc43)cc2)cc1 ; c1ccc(-c2ccc(-n3c4ccccc4c4c5c6ccccc6n(-c6cccc(-c7cccc8sc9ccccc9c78)c6)c5ccc43)cc2)cc1] 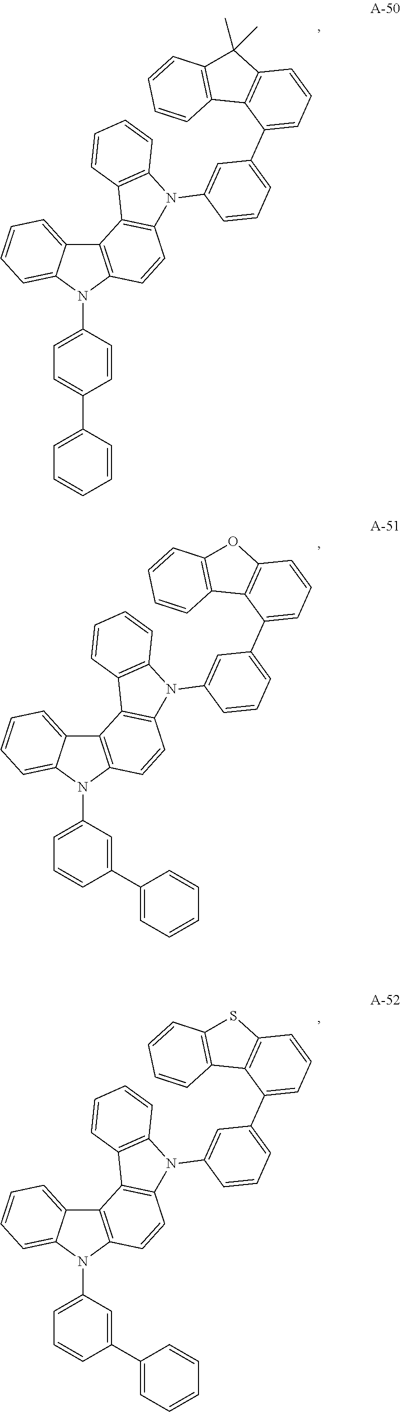 [SMILES: CC1(C)c2ccccc2-c2c(-c3cccc(-n4c5ccccc5c5c6c7ccccc7n(-c7ccc(-c8ccccc8)cc7)c6ccc54)c3)cccc21 ; c1ccc(-c2cccc(-n3c4ccccc4c4c5c6ccccc6n(-c6cccc(-c7cccc8oc9ccccc9c78)c6)c5ccc43)c2)cc1 ; c1ccc(-c2cccc(-n3c4ccccc4c4c5c6ccccc6n(-c6cccc(-c7cccc8sc9ccccc9c78)c6)c5ccc43)c2)cc1] 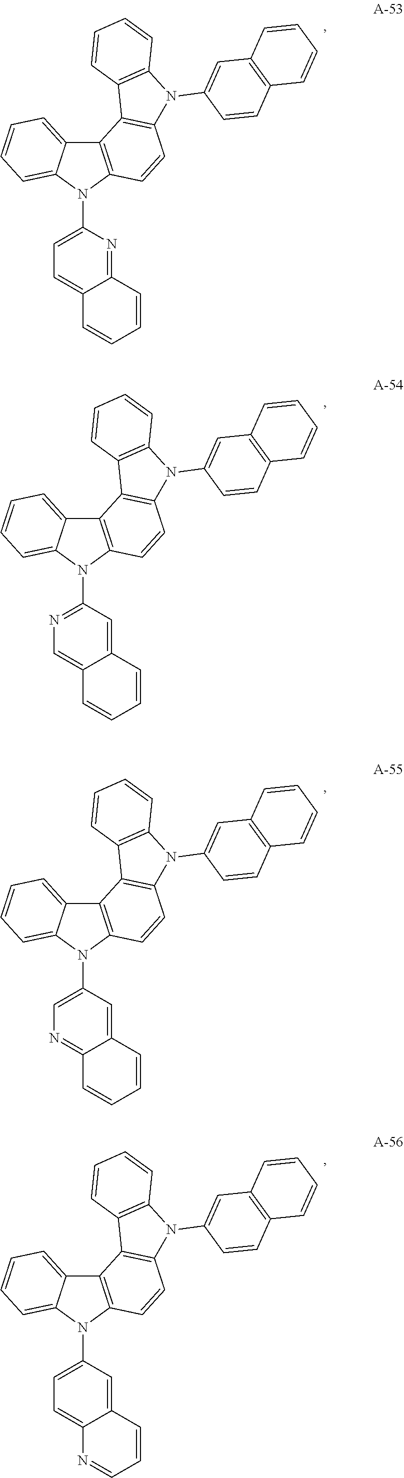 [SMILES: c1ccc2cc(-n3c4ccccc4c4c5c6ccccc6n(-c6ccc7ccccc7n6)c5ccc43)ccc2c1 ; c1ccc2cc(-n3c4ccccc4c4c5c6ccccc6n(-c6cc7ccccc7cn6)c5ccc43)ccc2c1 ; c1ccc2cc(-n3c4ccccc4c4c5c6ccccc6n(-c6cnc7ccccc7c6)c5ccc43)ccc2c1 ; c1ccc2cc(-n3c4ccccc4c4c5c6ccccc6n(-c6ccc7ncccc7c6)c5ccc43)ccc2c1] 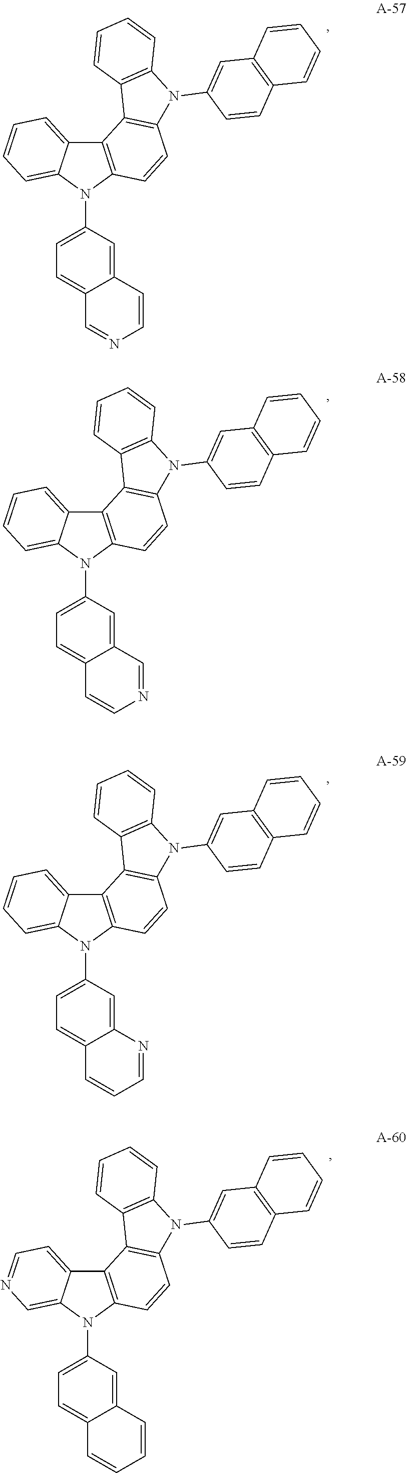 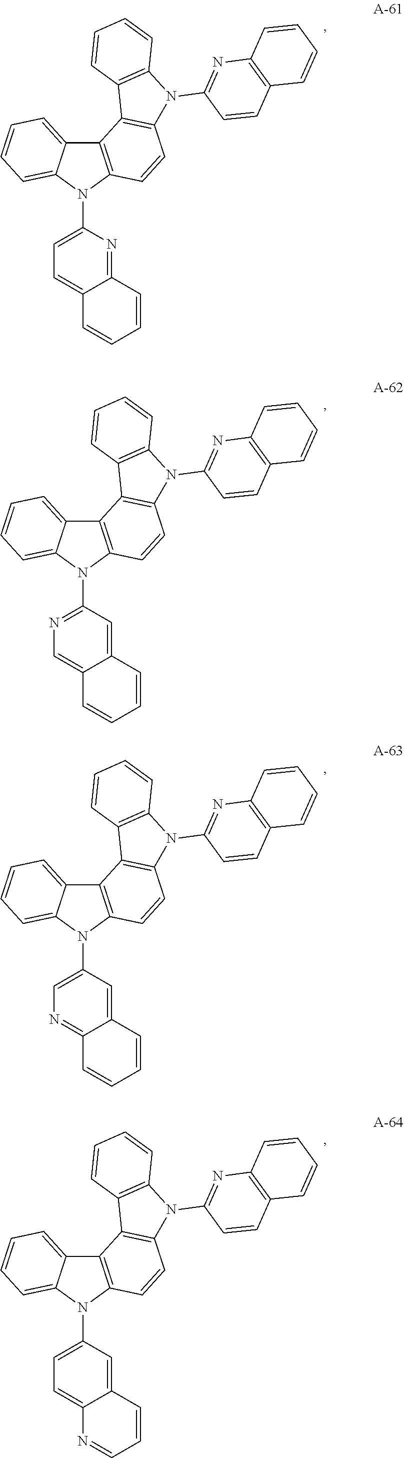 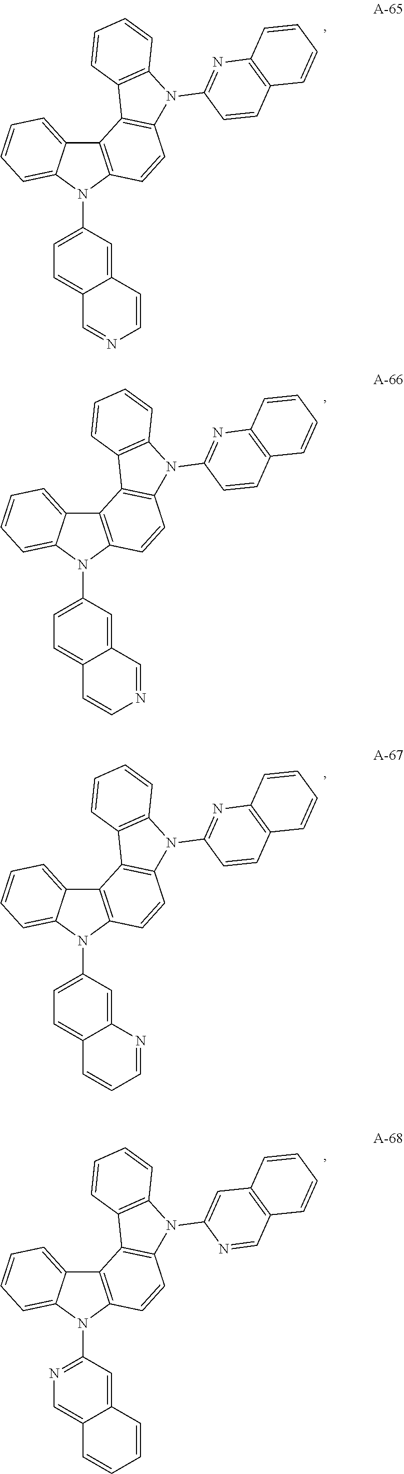 [SMILES: c1ccc2nc(-n3c4ccccc4c4c5c6ccccc6n(-c6ccc7cnccc7c6)c5ccc43)ccc2c1 ; c1ccc2nc(-n3c4ccccc4c4c5c6ccccc6n(-c6ccc7ccncc7c6)c5ccc43)ccc2c1 ; c1cnc2cc(-n3c4ccccc4c4c5c6ccccc6n(-c6ccc7ccccc7n6)c5ccc43)ccc2c1 ; c1ccc2cc(-n3c4ccccc4c4c5c6ccccc6n(-c6cc7ccccc7cn6)c5ccc43)ncc2c1] 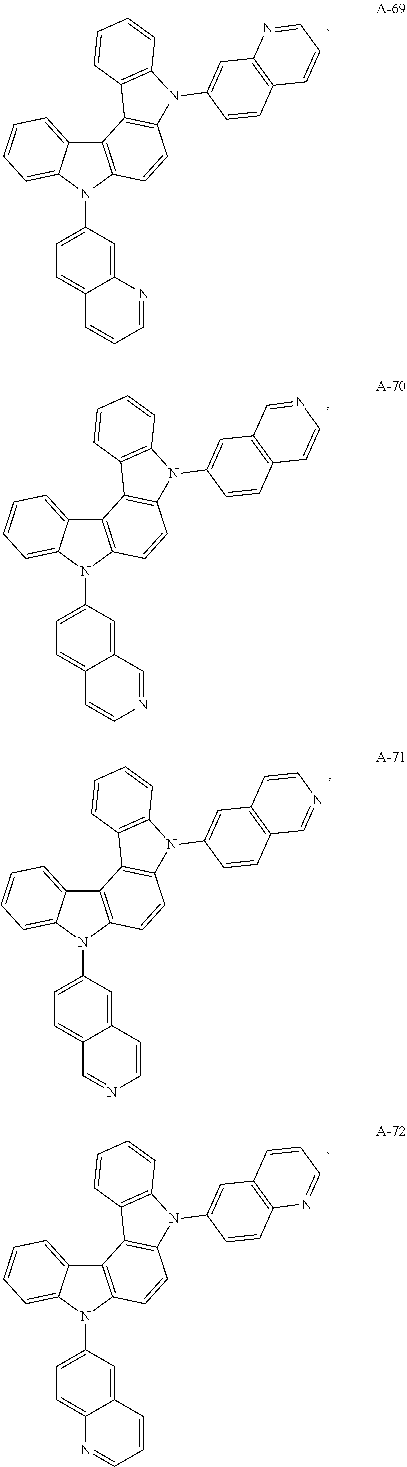 [SMILES: c1cnc2cc(-n3c4ccccc4c4c5c6ccccc6n(-c6ccc7cccnc7c6)c5ccc43)ccc2c1 ; c1ccc2c(c1)c1c3c4ccccc4n(-c4ccc5ccncc5c4)c3ccc1n2-c1ccc2ccncc2c1 ; c1ccc2c(c1)c1c3c4ccccc4n(-c4ccc5cnccc5c4)c3ccc1n2-c1ccc2cnccc2c1 ; c1cnc2ccc(-n3c4ccccc4c4c5c6ccccc6n(-c6ccc7ncccc7c6)c5ccc43)cc2c1] 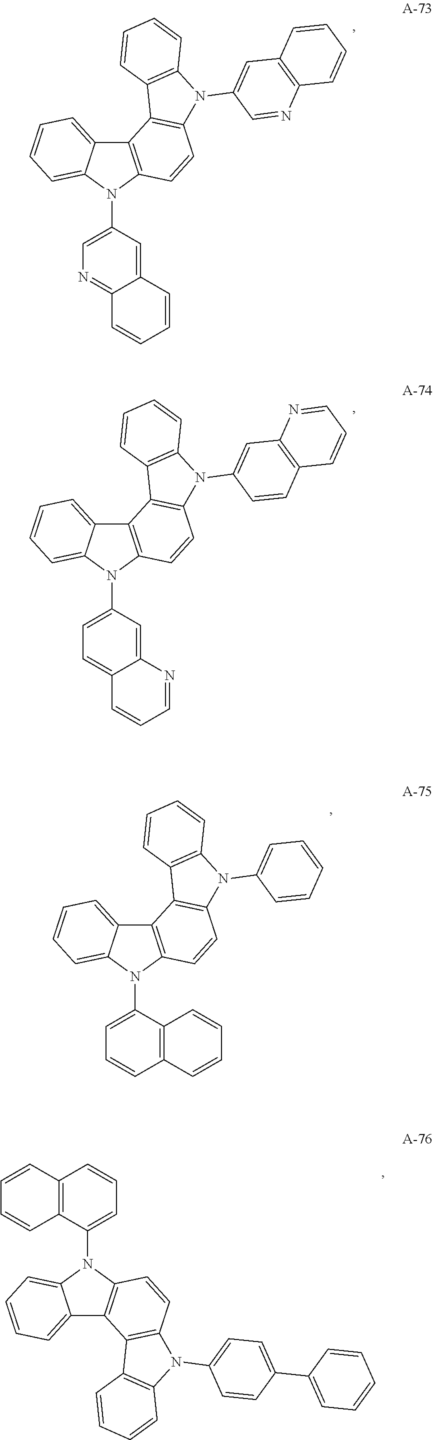 [SMILES: c1ccc2ncc(-n3c4ccccc4c4c5c6ccccc6n(-c6cnc7ccccc7c6)c5ccc43)cc2c1 ; c1cnc2cc(-n3c4ccccc4c4c5c6ccccc6n(-c6ccc7cccnc7c6)c5ccc43)ccc2c1 ; c1ccc(-n2c3ccccc3c3c4c5ccccc5n(-c5cccc6ccccc56)c4ccc32)cc1 ; c1ccc(-c2ccc(-n3c4ccccc4c4c5c6ccccc6n(-c6cccc7ccccc67)c5ccc43)cc2)cc1] 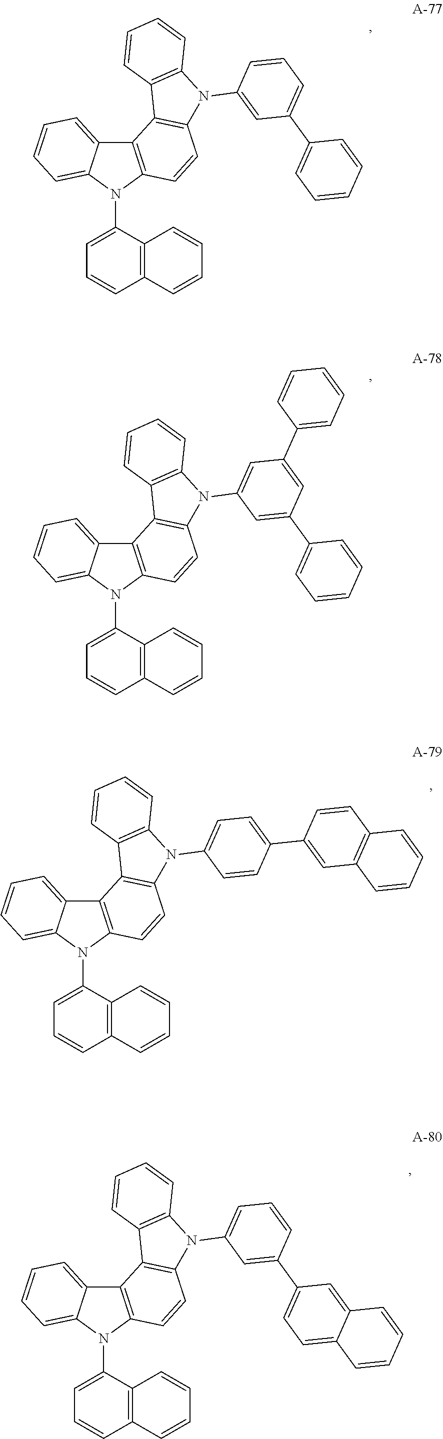 [SMILES: c1ccc(-c2cccc(-n3c4ccccc4c4c5c6ccccc6n(-c6cccc7ccccc67)c5ccc43)c2)cc1 ; c1ccc(-c2cc(-c3ccccc3)cc(-n3c4ccccc4c4c5c6ccccc6n(-c6cccc7ccccc67)c5ccc43)c2)cc1 ; c1ccc2cc(-c3ccc(-n4c5ccccc5c5c6c7ccccc7n(-c7cccc8ccccc78)c6ccc54)cc3)ccc2c1 ; c1cc(-c2ccc3ccccc3c2)cc(-n2c3ccccc3c3c4c5ccccc5n(-c5cccc6ccccc56)c4ccc32)c1] 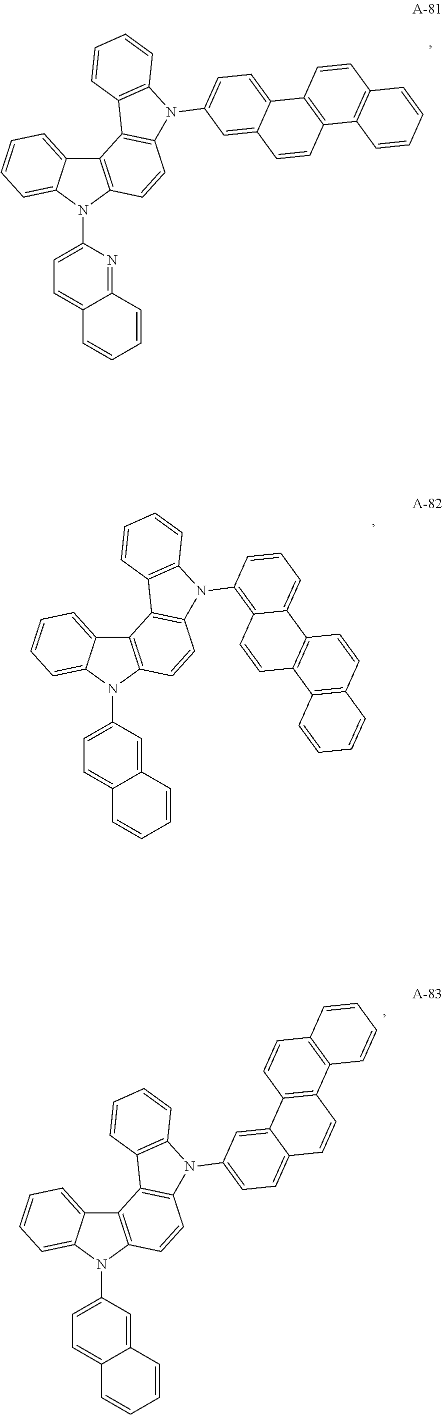 [SMILES: c1ccc2nc(-n3c4ccccc4c4c5c6ccccc6n(-c6ccc7c(ccc8c9ccccc9ccc78)c6)c5ccc43)ccc2c1 ; c1ccc2cc(-n3c4ccccc4c4c5c6ccccc6n(-c6cccc7c6ccc6c8ccccc8ccc76)c5ccc43)ccc2c1 ; c1ccc2cc(-n3c4ccccc4c4c5c6ccccc6n(-c6ccc7ccc8c9ccccc9ccc8c7c6)c5ccc43)ccc2c1] 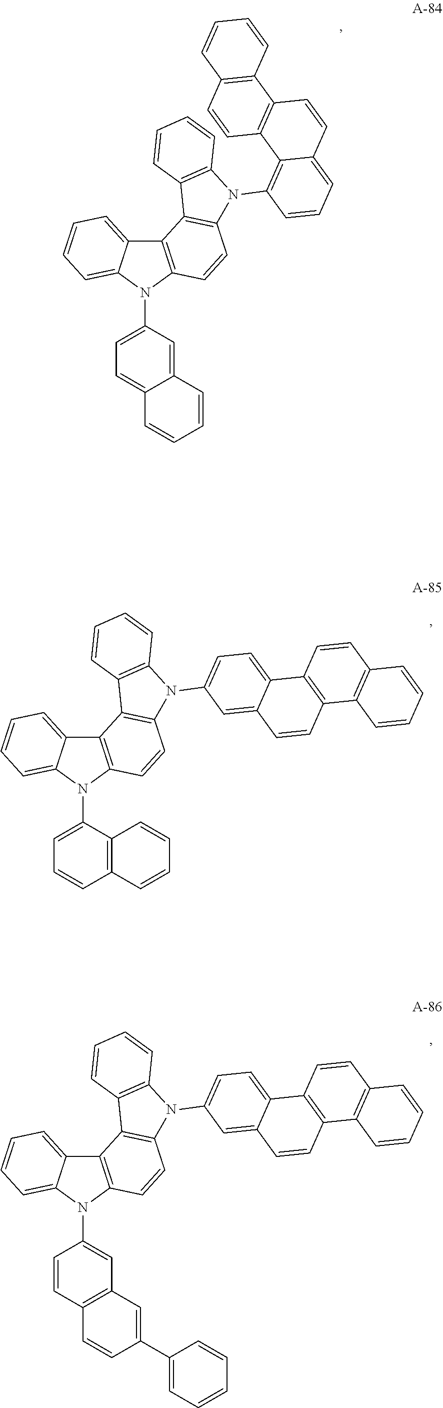 [SMILES: c1ccc2cc(-n3c4ccccc4c4c5c6ccccc6n(-c6cccc7ccc8c9ccccc9ccc8c67)c5ccc43)ccc2c1 ; c1ccc2c(-n3c4ccccc4c4c5c6ccccc6n(-c6ccc7c(ccc8c9ccccc9ccc78)c6)c5ccc43)cccc2c1 ; c1ccc(-c2ccc3ccc(-n4c5ccccc5c5c6c7ccccc7n(-c7ccc8c(ccc9c%10ccccc%10ccc89)c7)c6ccc54)cc3c2)cc1] 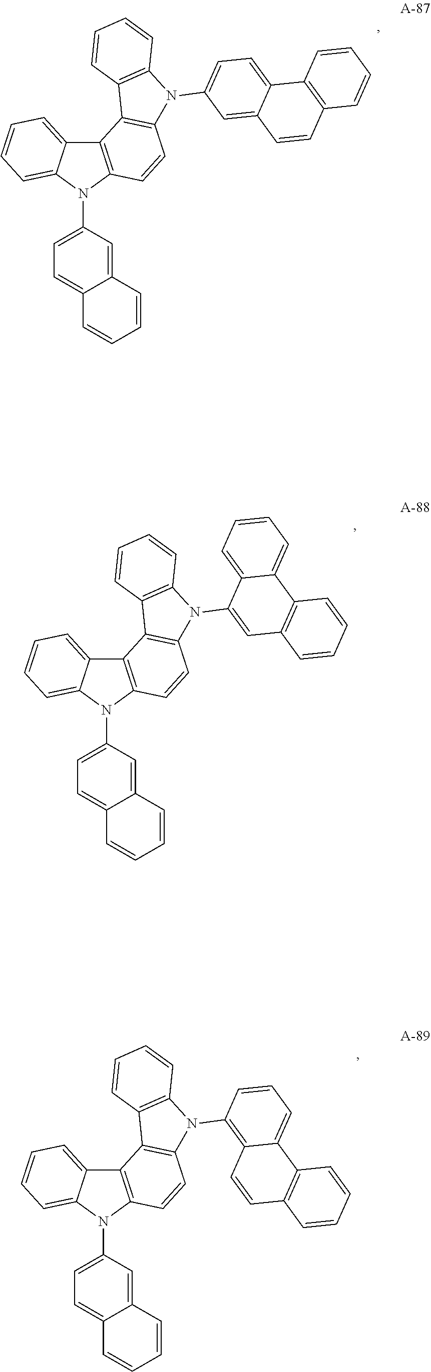 [SMILES: c1ccc2cc(-n3c4ccccc4c4c5c6ccccc6n(-c6ccc7c(ccc8ccccc87)c6)c5ccc43)ccc2c1 ; c1ccc2cc(-n3c4ccccc4c4c5c6ccccc6n(-c6cc7ccccc7c7ccccc67)c5ccc43)ccc2c1 ; c1ccc2cc(-n3c4ccccc4c4c5c6ccccc6n(-c6cccc7c6ccc6ccccc67)c5ccc43)ccc2c1] 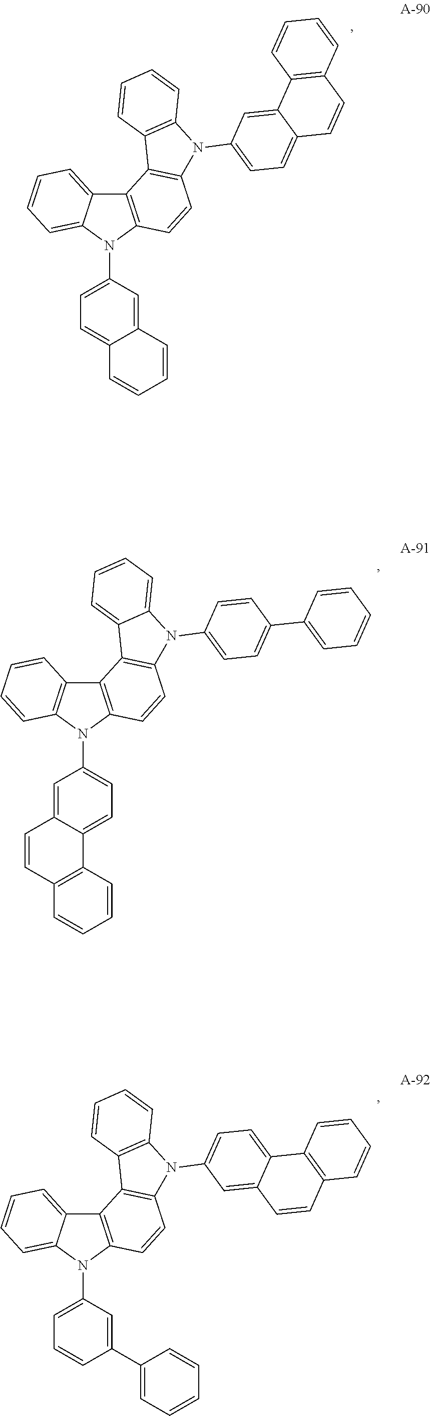 [SMILES: c1ccc2cc(-n3c4ccccc4c4c5c6ccccc6n(-c6ccc7ccc8ccccc8c7c6)c5ccc43)ccc2c1 ; c1ccc(-c2ccc(-n3c4ccccc4c4c5c6ccccc6n(-c6ccc7c(ccc8ccccc87)c6)c5ccc43)cc2)cc1 ; c1ccc(-c2cccc(-n3c4ccccc4c4c5c6ccccc6n(-c6ccc7c(ccc8ccccc87)c6)c5ccc43)c2)cc1] 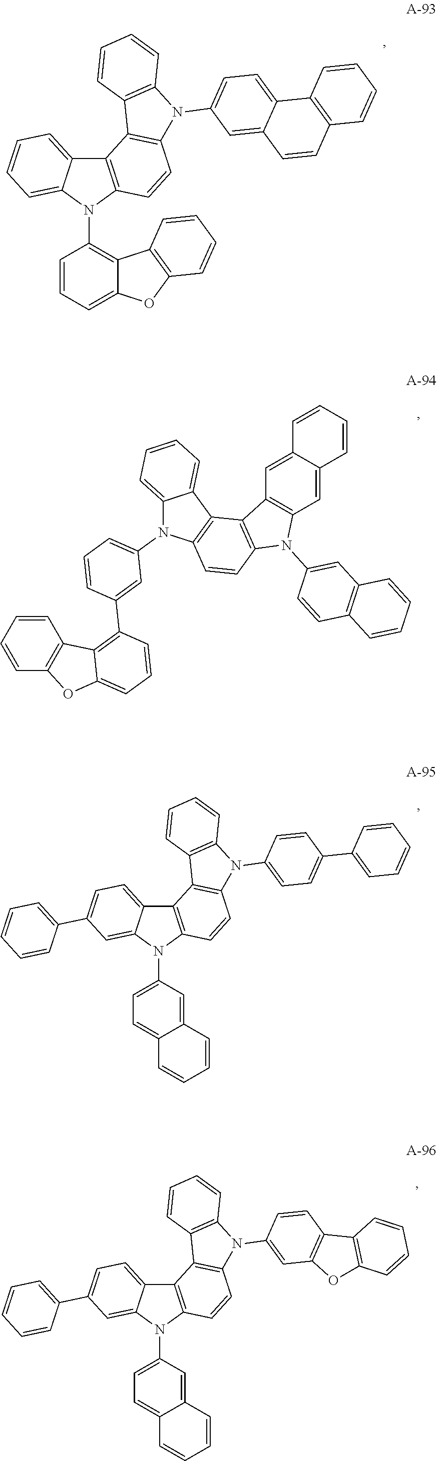 [SMILES: c1ccc2c(c1)ccc1cc(-n3c4ccccc4c4c5c6ccccc6n(-c6cccc7oc8ccccc8c67)c5ccc43)ccc12 ; c1cc(-c2cccc3oc4ccccc4c23)cc(-n2c3ccccc3c3c4c5cc6ccccc6cc5n(-c5ccc6ccccc6c5)c4ccc32)c1 ; c1ccc(-c2ccc(-n3c4ccccc4c4c5c6ccc(-c7ccccc7)cc6n(-c6ccc7ccccc7c6)c5ccc43)cc2)cc1 ; c1ccc(-c2ccc3c4c5c6ccccc6n(-c6ccc7c(c6)oc6ccccc67)c5ccc4n(-c4ccc5ccccc5c4)c3c2)cc1] 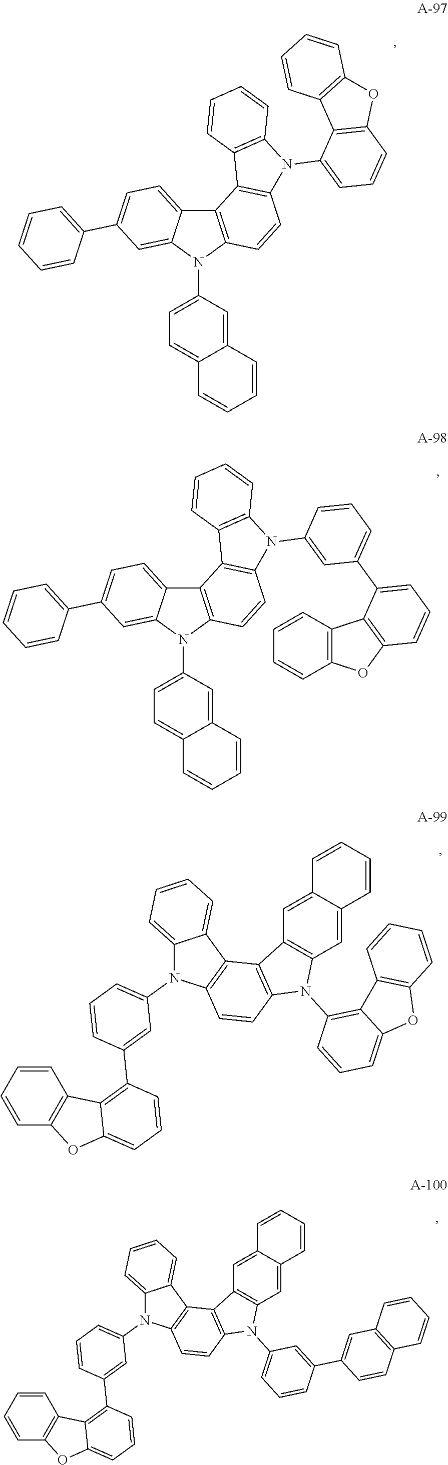 [SMILES: c1ccc(-c2ccc3c4c5c6ccccc6n(-c6cccc7oc8ccccc8c67)c5ccc4n(-c4ccc5ccccc5c4)c3c2)cc1 ; c1ccc(-c2ccc3c4c5c6ccccc6n(-c6cccc(-c7cccc8oc9ccccc9c78)c6)c5ccc4n(-c4ccc5ccccc5c4)c3c2)cc1 ; c1cc(-c2cccc3oc4ccccc4c23)cc(-n2c3ccccc3c3c4c5cc6ccccc6cc5n(-c5cccc6oc7ccccc7c56)c4ccc32)c1 ; c1cc(-c2ccc3ccccc3c2)cc(-n2c3cc4ccccc4cc3c3c4c5ccccc5n(-c5cccc(-c6cccc7oc8ccccc8c67)c5)c4ccc32)c1] 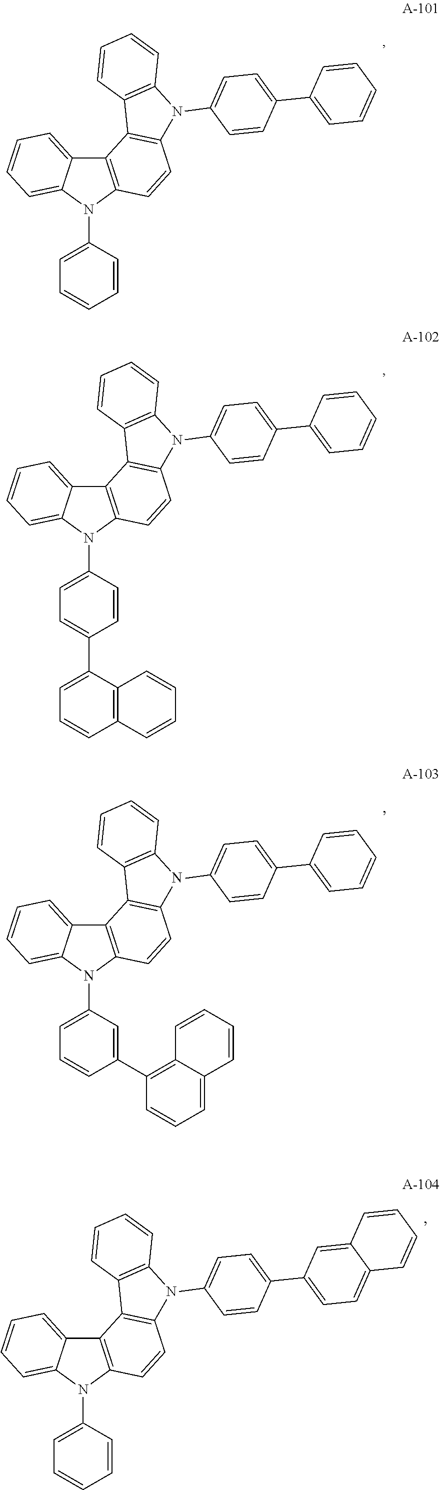 [SMILES: c1ccc(-c2ccc(-n3c4ccccc4c4c5c6ccccc6n(-c6ccccc6)c5ccc43)cc2)cc1 ; c1ccc(-c2ccc(-n3c4ccccc4c4c5c6ccccc6n(-c6ccc(-c7cccc8ccccc78)cc6)c5ccc43)cc2)cc1 ; c1ccc(-c2ccc(-n3c4ccccc4c4c5c6ccccc6n(-c6cccc(-c7cccc8ccccc78)c6)c5ccc43)cc2)cc1 ; c1ccc(-n2c3ccccc3c3c4c5ccccc5n(-c5ccc(-c6ccc7ccccc7c6)cc5)c4ccc32)cc1] 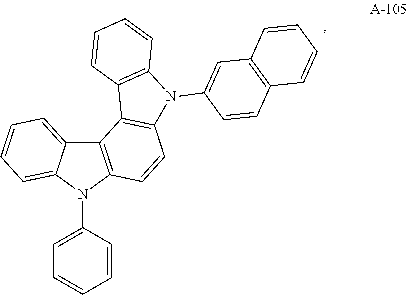 [SMILES: c1ccc(-n2c3ccccc3c3c4c5ccccc5n(-c5ccc6ccccc6c5)c4ccc32)cc1] 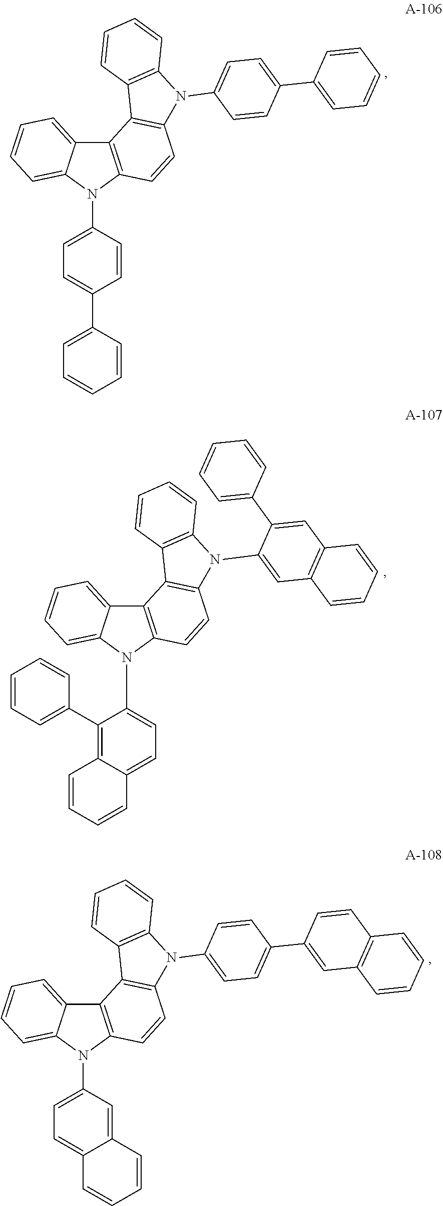 [SMILES: c1ccc(-c2ccc(-n3c4ccccc4c4c5c6ccccc6n(-c6ccc(-c7ccccc7)cc6)c5ccc43)cc2)cc1 ; c1ccc(-c2cc3ccccc3cc2-n2c3ccccc3c3c4c5ccccc5n(-c5ccc6ccccc6c5-c5ccccc5)c4ccc32)cc1 ; c1ccc2cc(-c3ccc(-n4c5ccccc5c5c6c7ccccc7n(-c7ccc8ccccc8c7)c6ccc54)cc3)ccc2c1] 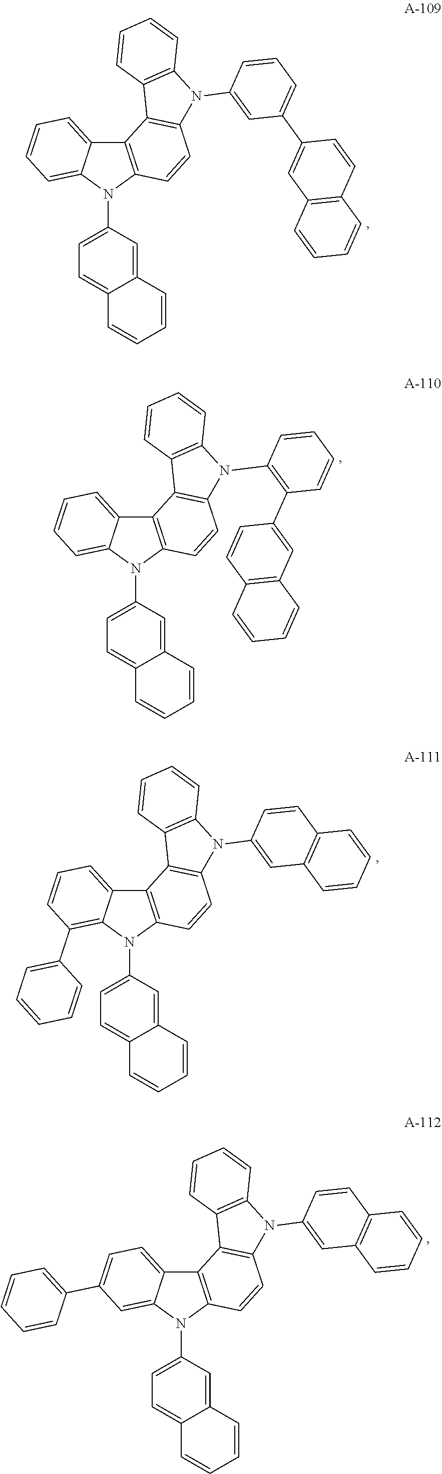 [SMILES: c1cc(-c2ccc3ccccc3c2)cc(-n2c3ccccc3c3c4c5ccccc5n(-c5ccc6ccccc6c5)c4ccc32)c1 ; c1ccc(-n2c3ccccc3c3c4c5ccccc5n(-c5ccc6ccccc6c5)c4ccc32)c(-c2ccc3ccccc3c2)c1 ; c1ccc(-c2cccc3c4c5c6ccccc6n(-c6ccc7ccccc7c6)c5ccc4n(-c4ccc5ccccc5c4)c23)cc1 ; c1ccc(-c2ccc3c4c5c6ccccc6n(-c6ccc7ccccc7c6)c5ccc4n(-c4ccc5ccccc5c4)c3c2)cc1] 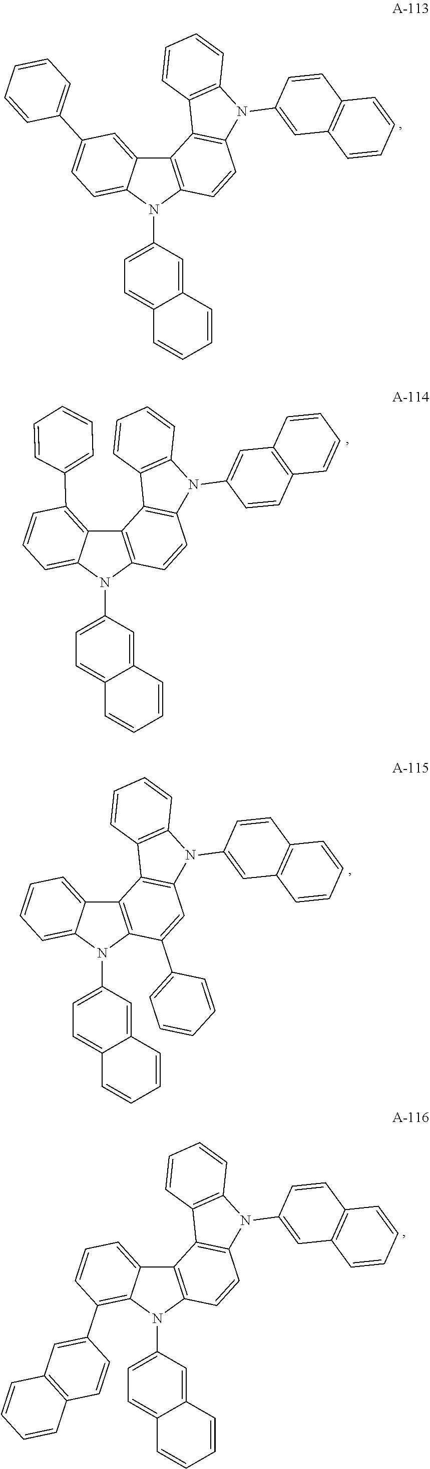 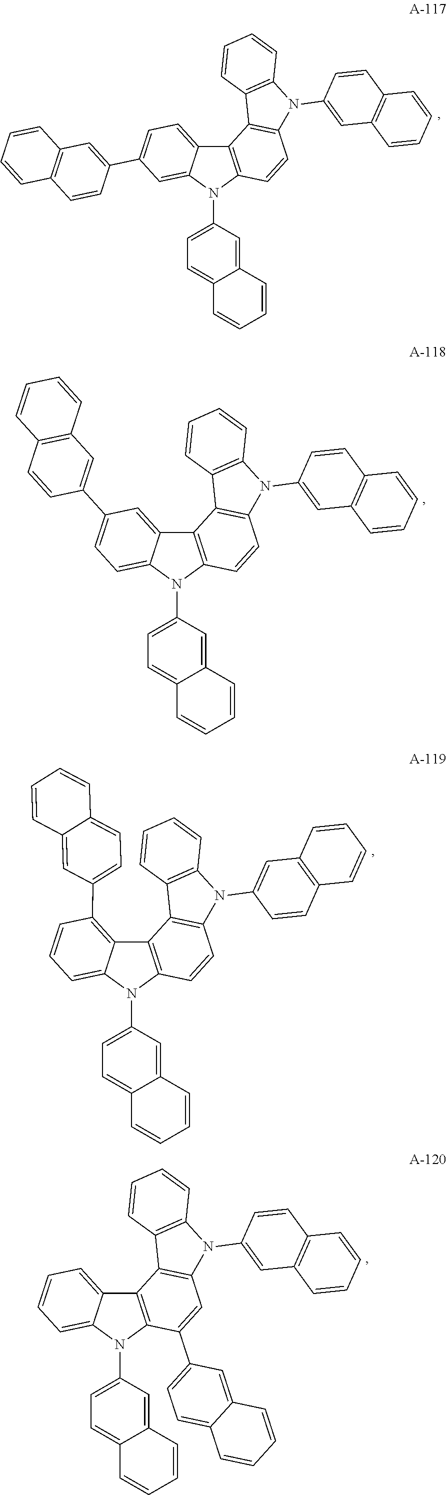 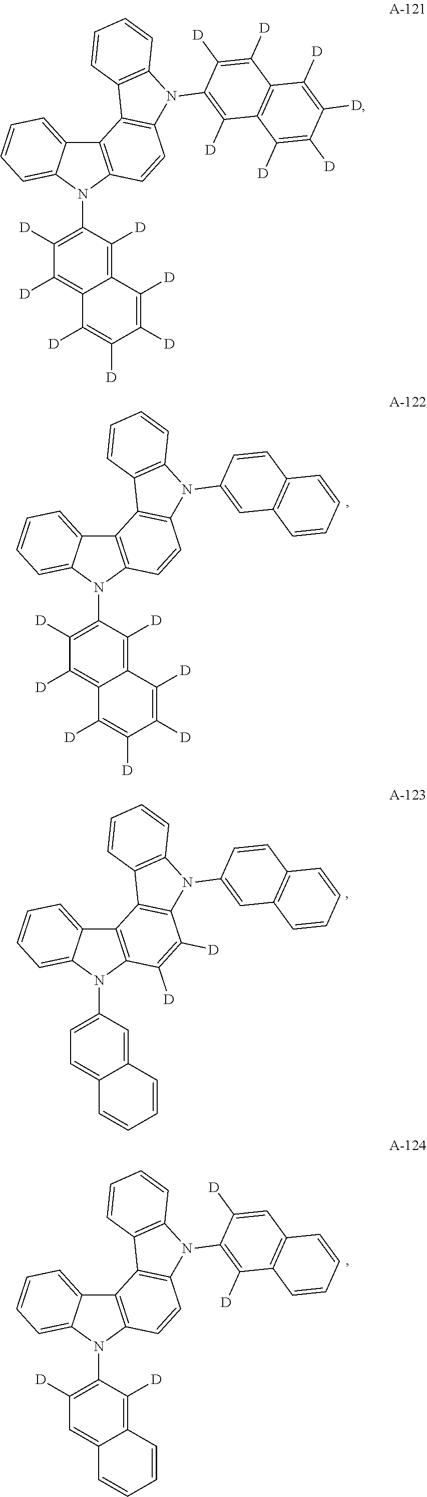 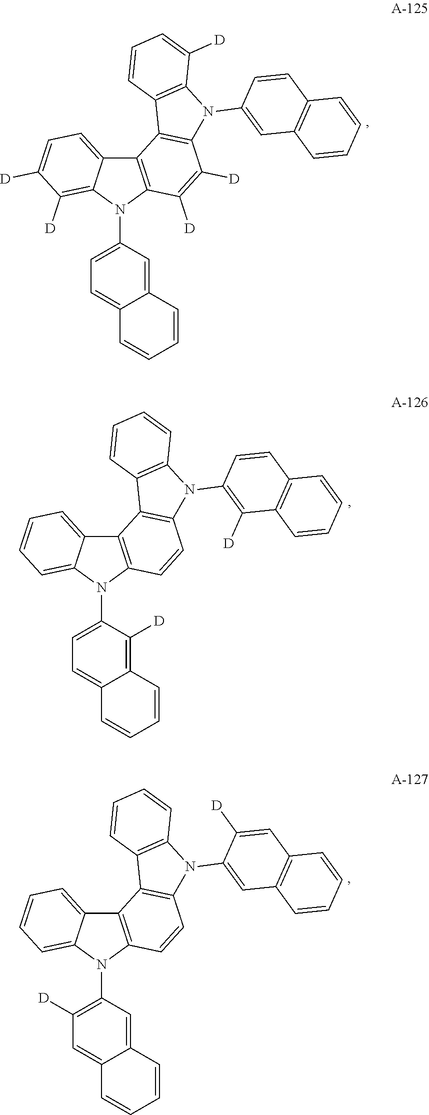 [SMILES: [2H]c1ccc2c3c4c5cccc([2H])c5n(-c5ccc6ccccc6c5)c4c([2H])c([2H])c3n(-c3ccc4ccccc4c3)c2c1[2H] ; [2H]c1c(-n2c3ccccc3c3c4c5ccccc5n(-c5ccc6ccccc6c5[2H])c4ccc32)ccc2ccccc12 ; [2H]c1cc2ccccc2cc1-n1c2ccccc2c2c3c4ccccc4n(-c4cc5ccccc5cc4[2H])c3ccc21] 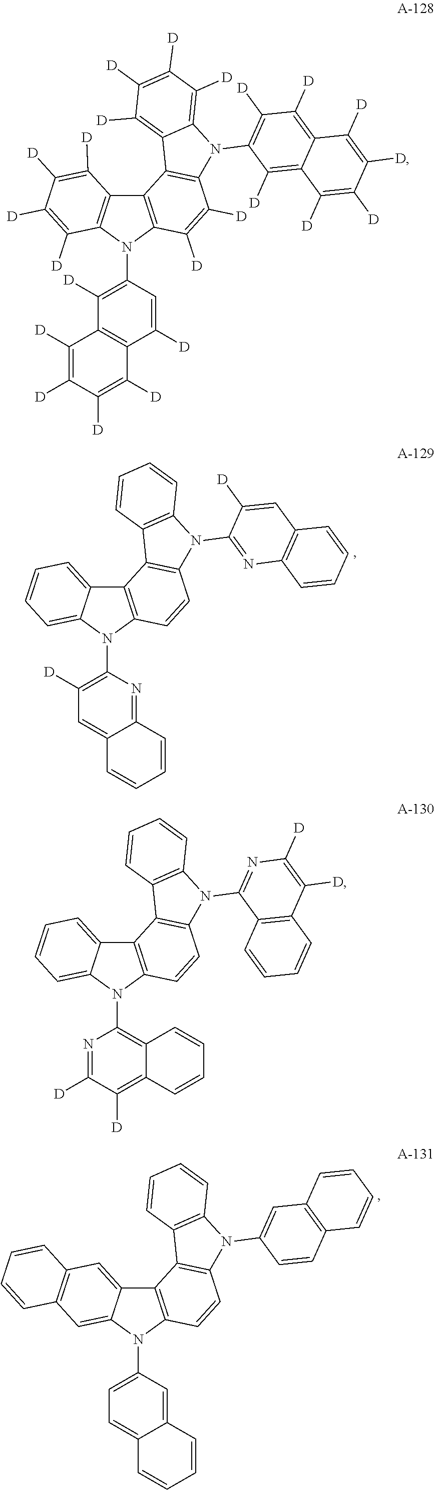 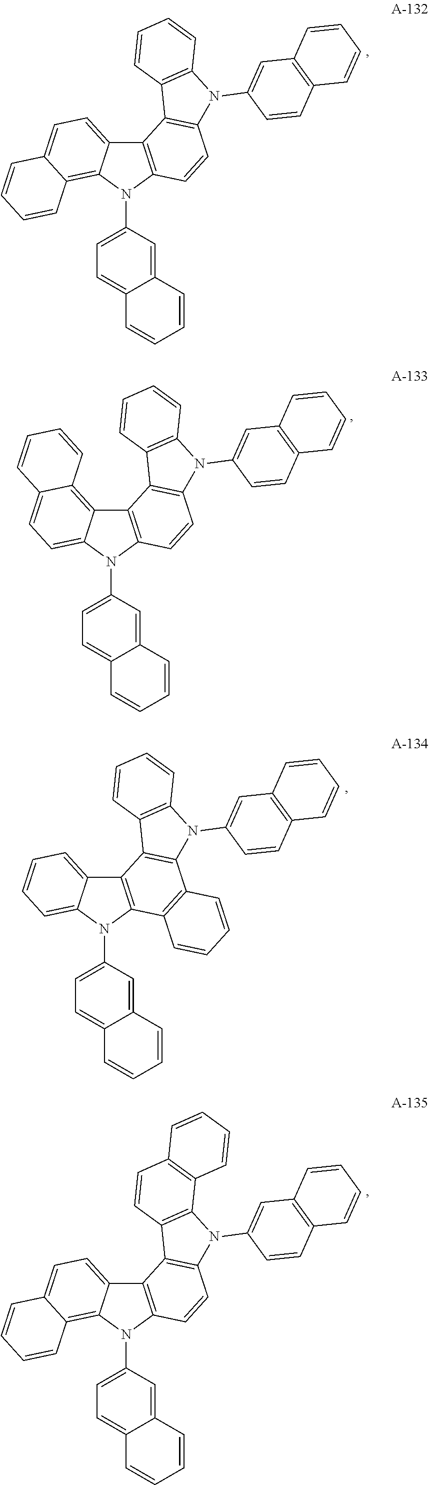 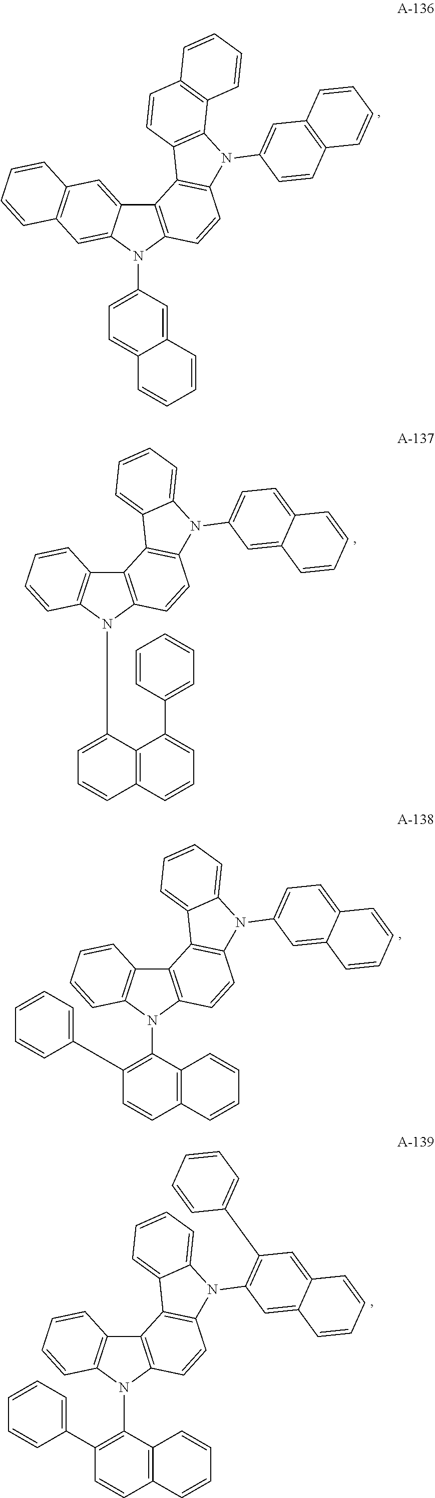 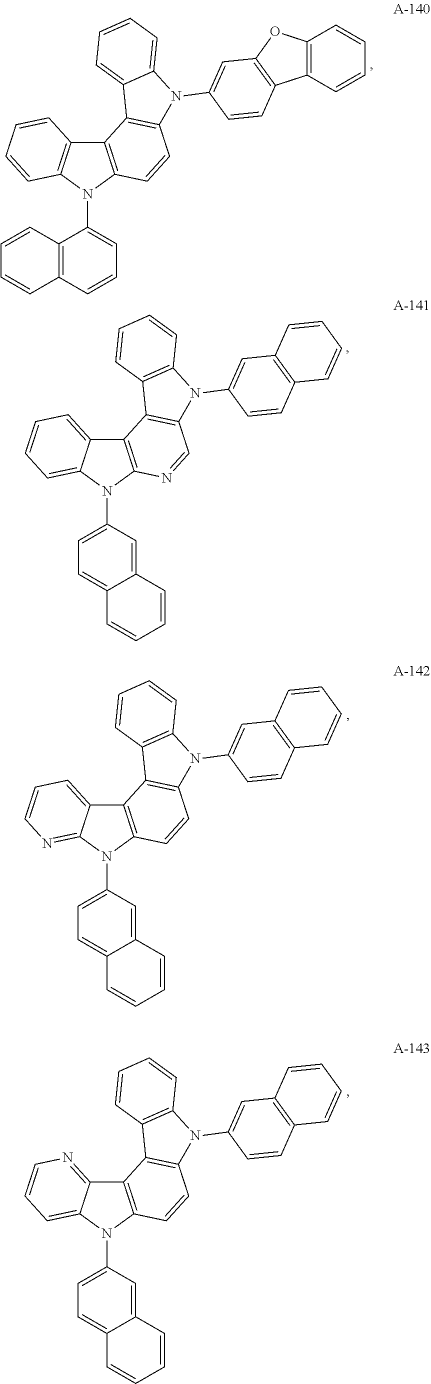 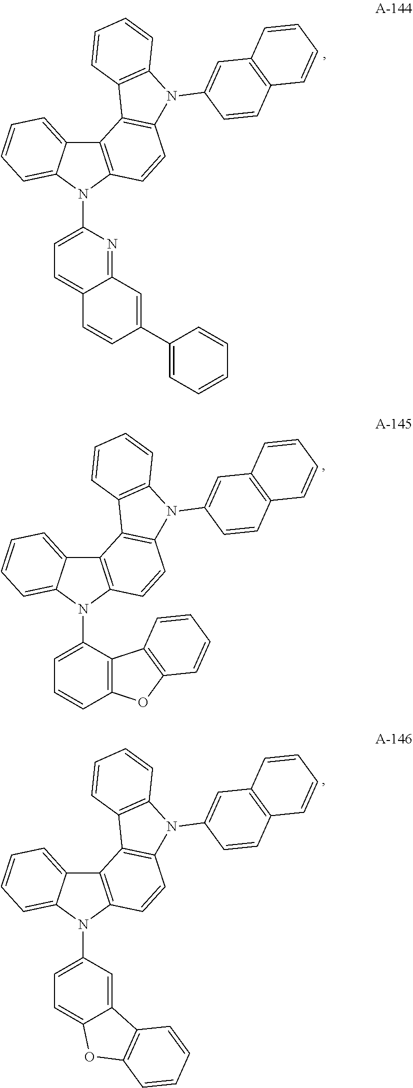 [SMILES: c1ccc(-c2ccc3ccc(-n4c5ccccc5c5c6c7ccccc7n(-c7ccc8ccccc8c7)c6ccc54)nc3c2)cc1 ; c1ccc2cc(-n3c4ccccc4c4c5c6ccccc6n(-c6cccc7oc8ccccc8c67)c5ccc43)ccc2c1 ; c1ccc2cc(-n3c4ccccc4c4c5c6ccccc6n(-c6ccc7oc8ccccc8c7c6)c5ccc43)ccc2c1] 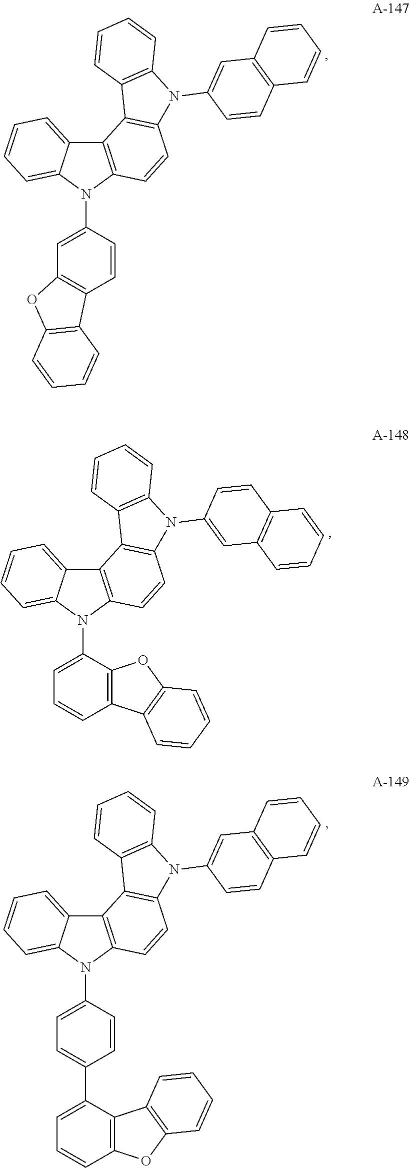 [SMILES: c1ccc2cc(-n3c4ccccc4c4c5c6ccccc6n(-c6ccc7c(c6)oc6ccccc67)c5ccc43)ccc2c1 ; c1ccc2cc(-n3c4ccccc4c4c5c6ccccc6n(-c6cccc7c6oc6ccccc67)c5ccc43)ccc2c1 ; c1ccc2cc(-n3c4ccccc4c4c5c6ccccc6n(-c6ccc(-c7cccc8oc9ccccc9c78)cc6)c5ccc43)ccc2c1] 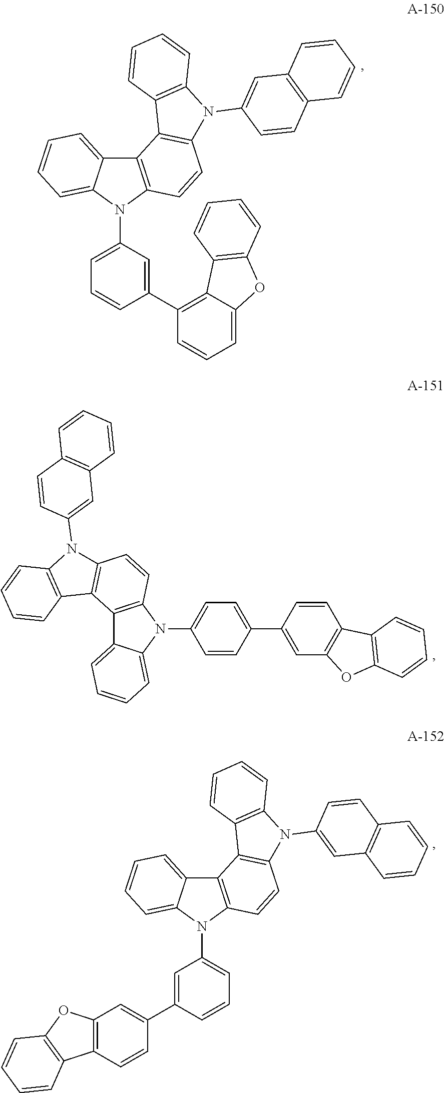 [SMILES: c1cc(-c2cccc3oc4ccccc4c23)cc(-n2c3ccccc3c3c4c5ccccc5n(-c5ccc6ccccc6c5)c4ccc32)c1 ; c1ccc2cc(-n3c4ccccc4c4c5c6ccccc6n(-c6ccc(-c7ccc8c(c7)oc7ccccc78)cc6)c5ccc43)ccc2c1 ; c1cc(-c2ccc3c(c2)oc2ccccc23)cc(-n2c3ccccc3c3c4c5ccccc5n(-c5ccc6ccccc6c5)c4ccc32)c1] 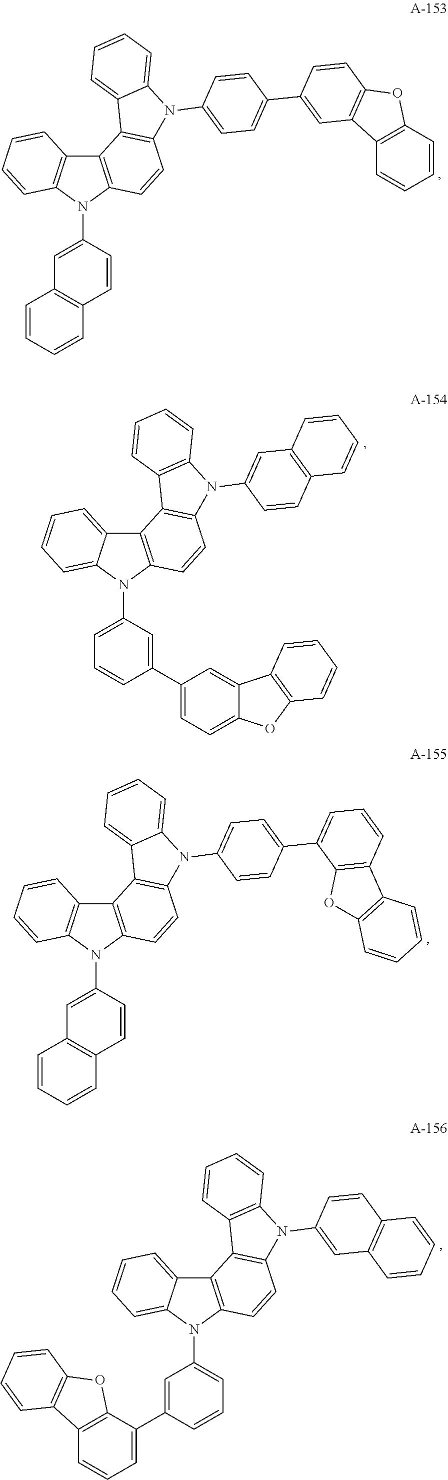 [SMILES: c1ccc2cc(-n3c4ccccc4c4c5c6ccccc6n(-c6ccc(-c7ccc8oc9ccccc9c8c7)cc6)c5ccc43)ccc2c1 ; c1cc(-c2ccc3oc4ccccc4c3c2)cc(-n2c3ccccc3c3c4c5ccccc5n(-c5ccc6ccccc6c5)c4ccc32)c1 ; c1ccc2cc(-n3c4ccccc4c4c5c6ccccc6n(-c6ccc(-c7cccc8c7oc7ccccc78)cc6)c5ccc43)ccc2c1 ; c1cc(-c2cccc3c2oc2ccccc23)cc(-n2c3ccccc3c3c4c5ccccc5n(-c5ccc6ccccc6c5)c4ccc32)c1] 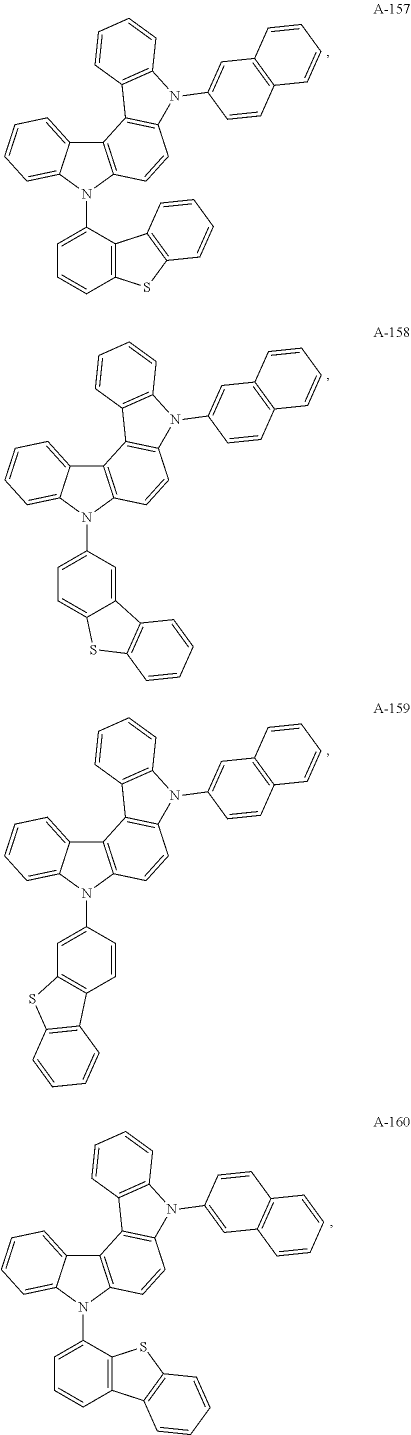 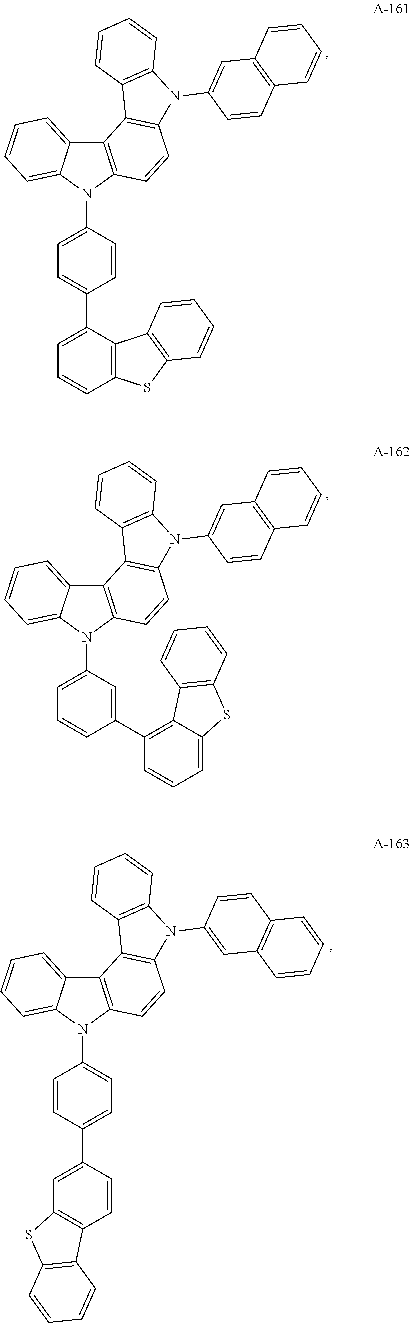 [SMILES: c1ccc2cc(-n3c4ccccc4c4c5c6ccccc6n(-c6ccc(-c7cccc8sc9ccccc9c78)cc6)c5ccc43)ccc2c1 ; c1cc(-c2cccc3sc4ccccc4c23)cc(-n2c3ccccc3c3c4c5ccccc5n(-c5ccc6ccccc6c5)c4ccc32)c1 ; c1ccc2cc(-n3c4ccccc4c4c5c6ccccc6n(-c6ccc(-c7ccc8c(c7)sc7ccccc78)cc6)c5ccc43)ccc2c1] 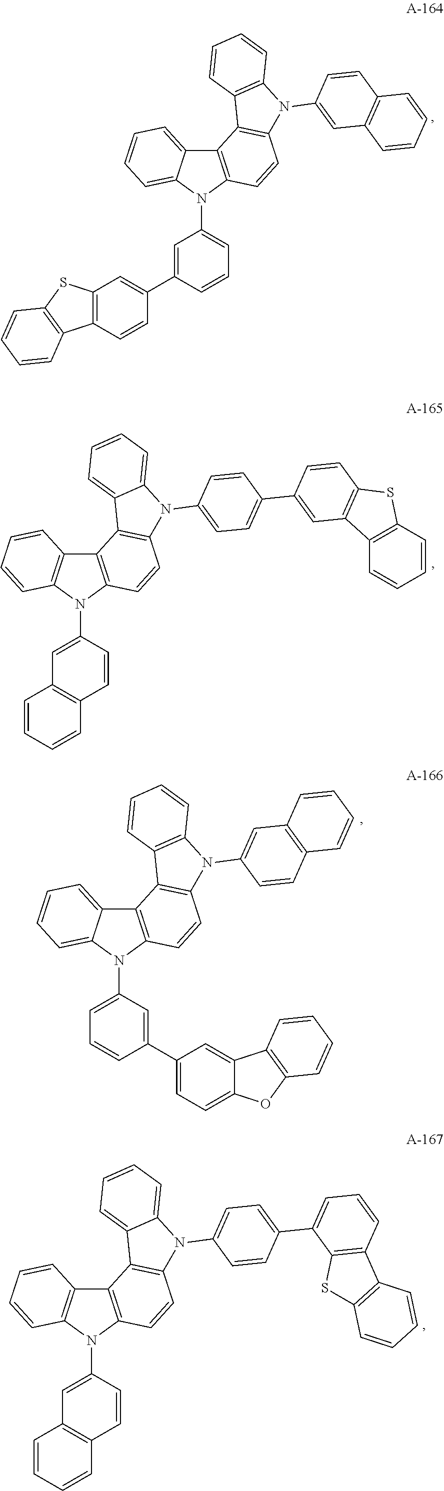 [SMILES: c1cc(-c2ccc3c(c2)sc2ccccc23)cc(-n2c3ccccc3c3c4c5ccccc5n(-c5ccc6ccccc6c5)c4ccc32)c1 ; c1ccc2cc(-n3c4ccccc4c4c5c6ccccc6n(-c6ccc(-c7ccc8sc9ccccc9c8c7)cc6)c5ccc43)ccc2c1 ; c1cc(-c2ccc3oc4ccccc4c3c2)cc(-n2c3ccccc3c3c4c5ccccc5n(-c5ccc6ccccc6c5)c4ccc32)c1 ; c1ccc2cc(-n3c4ccccc4c4c5c6ccccc6n(-c6ccc(-c7cccc8c7sc7ccccc78)cc6)c5ccc43)ccc2c1] 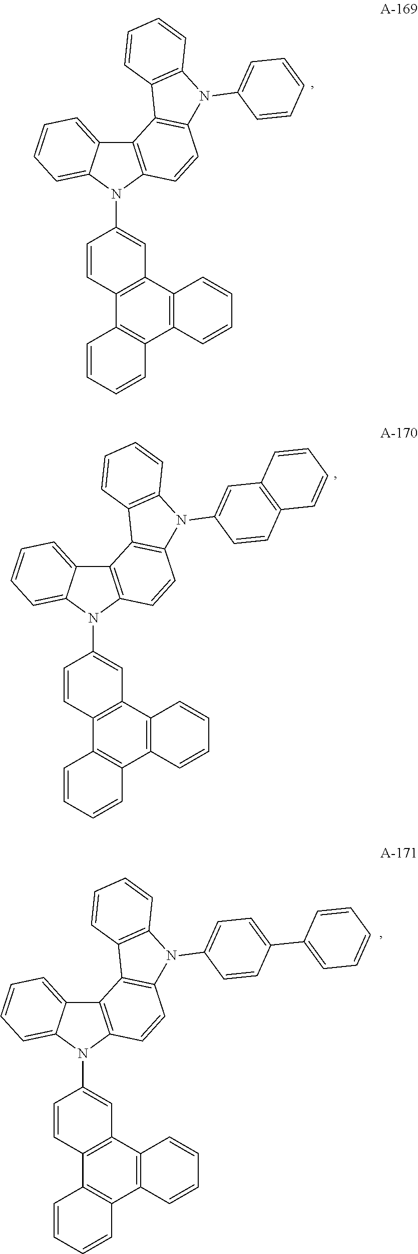 [SMILES: c1ccc(-n2c3ccccc3c3c4c5ccccc5n(-c5ccc6c7ccccc7c7ccccc7c6c5)c4ccc32)cc1 ; c1ccc2cc(-n3c4ccccc4c4c5c6ccccc6n(-c6ccc7c8ccccc8c8ccccc8c7c6)c5ccc43)ccc2c1 ; c1ccc(-c2ccc(-n3c4ccccc4c4c5c6ccccc6n(-c6ccc7c8ccccc8c8ccccc8c7c6)c5ccc43)cc2)cc1] 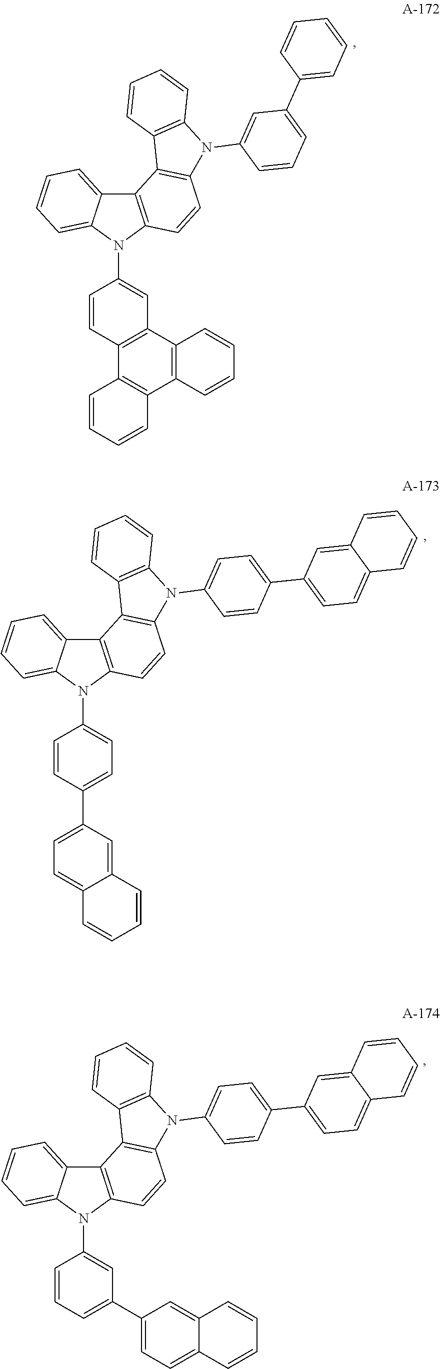 [SMILES: c1ccc(-c2cccc(-n3c4ccccc4c4c5c6ccccc6n(-c6ccc7c8ccccc8c8ccccc8c7c6)c5ccc43)c2)cc1 ; c1ccc2cc(-c3ccc(-n4c5ccccc5c5c6c7ccccc7n(-c7ccc(-c8ccc9ccccc9c8)cc7)c6ccc54)cc3)ccc2c1 ; c1cc(-c2ccc3ccccc3c2)cc(-n2c3ccccc3c3c4c5ccccc5n(-c5ccc(-c6ccc7ccccc7c6)cc5)c4ccc32)c1] 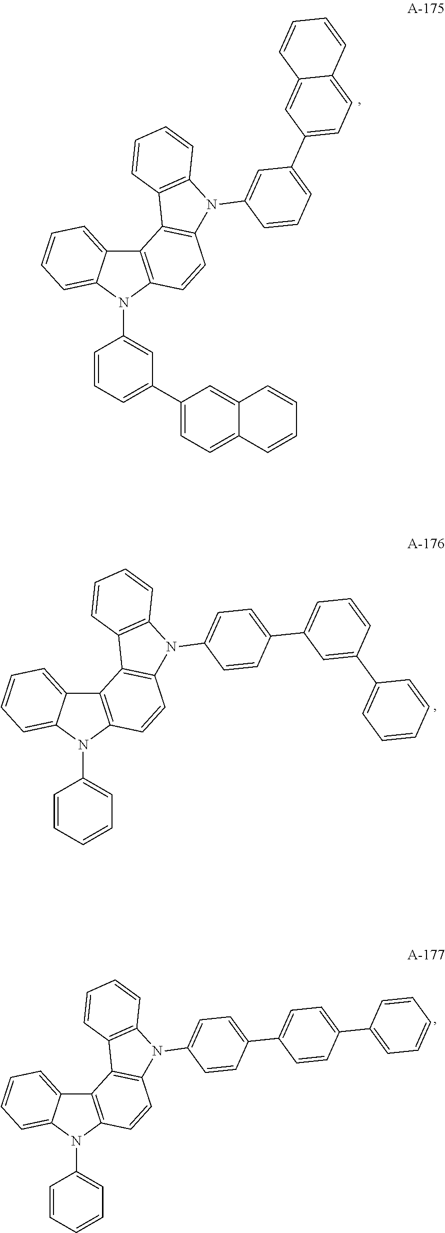 [SMILES: c1cc(-c2ccc3ccccc3c2)cc(-n2c3ccccc3c3c4c5ccccc5n(-c5cccc(-c6ccc7ccccc7c6)c5)c4ccc32)c1 ; c1ccc(-c2cccc(-c3ccc(-n4c5ccccc5c5c6c7ccccc7n(-c7ccccc7)c6ccc54)cc3)c2)cc1 ; c1ccc(-c2ccc(-c3ccc(-n4c5ccccc5c5c6c7ccccc7n(-c7ccccc7)c6ccc54)cc3)cc2)cc1] 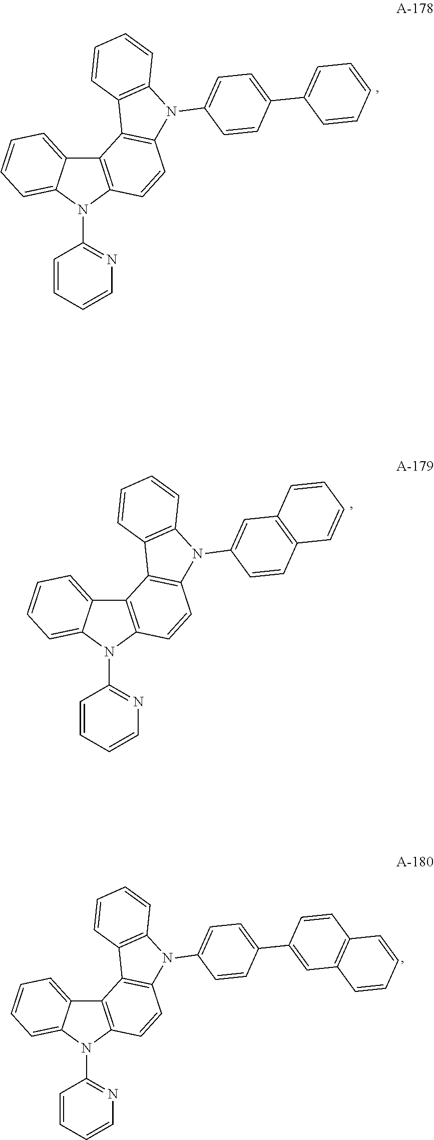 [SMILES: c1ccc(-c2ccc(-n3c4ccccc4c4c5c6ccccc6n(-c6ccccn6)c5ccc43)cc2)cc1 ; c1ccc(-n2c3ccccc3c3c4c5ccccc5n(-c5ccc6ccccc6c5)c4ccc32)nc1 ; c1ccc(-n2c3ccccc3c3c4c5ccccc5n(-c5ccc(-c6ccc7ccccc7c6)cc5)c4ccc32)nc1] 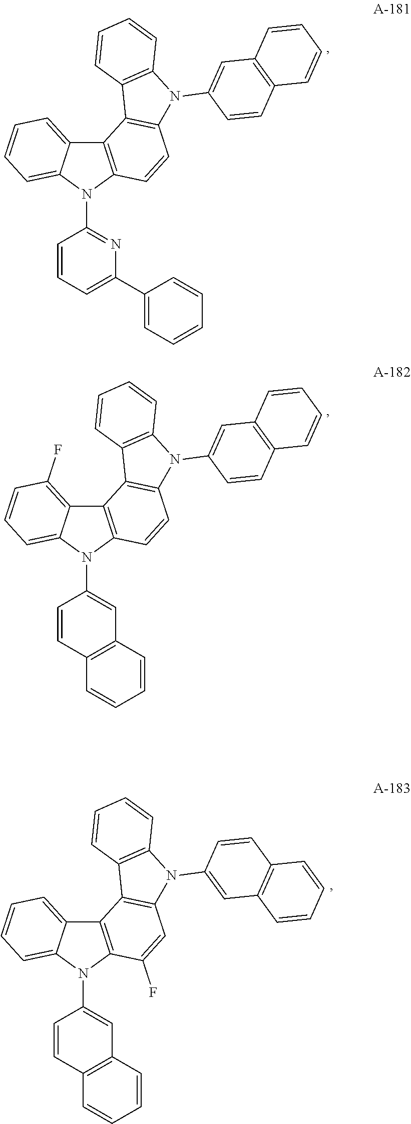 [SMILES: c1ccc(-c2cccc(-n3c4ccccc4c4c5c6ccccc6n(-c6ccc7ccccc7c6)c5ccc43)n2)cc1 ; Fc1cccc2c1c1c3c4ccccc4n(-c4ccc5ccccc5c4)c3ccc1n2-c1ccc2ccccc2c1 ; Fc1cc2c(c3ccccc3n2-c2ccc3ccccc3c2)c2c3ccccc3n(-c3ccc4ccccc4c3)c12] 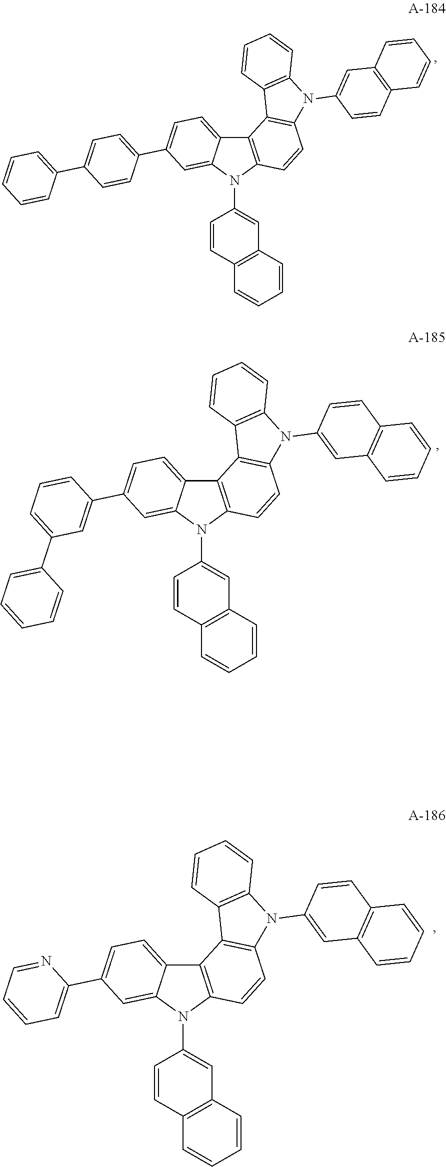 [SMILES: c1ccc(-c2ccc(-c3ccc4c5c6c7ccccc7n(-c7ccc8ccccc8c7)c6ccc5n(-c5ccc6ccccc6c5)c4c3)cc2)cc1 ; c1ccc(-c2cccc(-c3ccc4c5c6c7ccccc7n(-c7ccc8ccccc8c7)c6ccc5n(-c5ccc6ccccc6c5)c4c3)c2)cc1 ; c1ccc(-c2ccc3c4c5c6ccccc6n(-c6ccc7ccccc7c6)c5ccc4n(-c4ccc5ccccc5c4)c3c2)nc1] 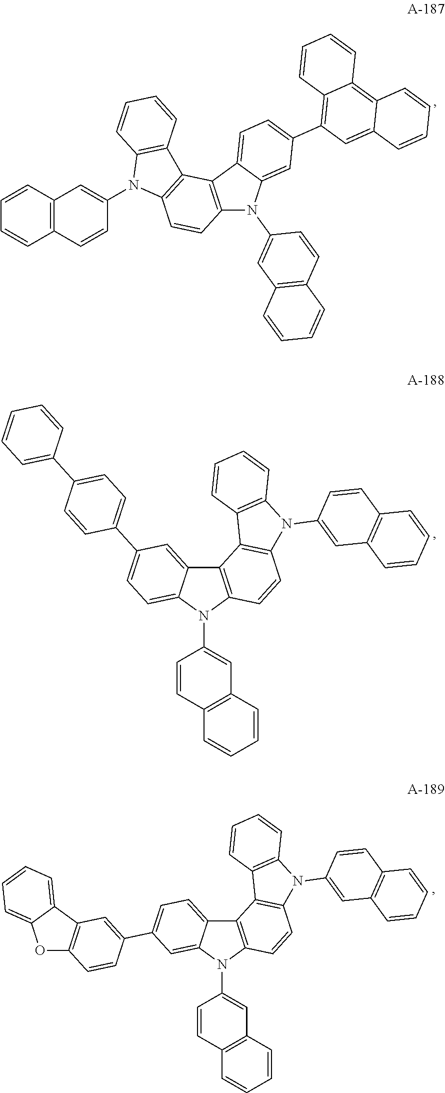 [SMILES: c1ccc2cc(-n3c4ccccc4c4c5c6ccc(-c7cc8ccccc8c8ccccc78)cc6n(-c6ccc7ccccc7c6)c5ccc43)ccc2c1 ; c1ccc(-c2ccc(-c3ccc4c(c3)c3c5c6ccccc6n(-c6ccc7ccccc7c6)c5ccc3n4-c3ccc4ccccc4c3)cc2)cc1 ; c1ccc2cc(-n3c4ccccc4c4c5c6ccc(-c7ccc8oc9ccccc9c8c7)cc6n(-c6ccc7ccccc7c6)c5ccc43)ccc2c1] 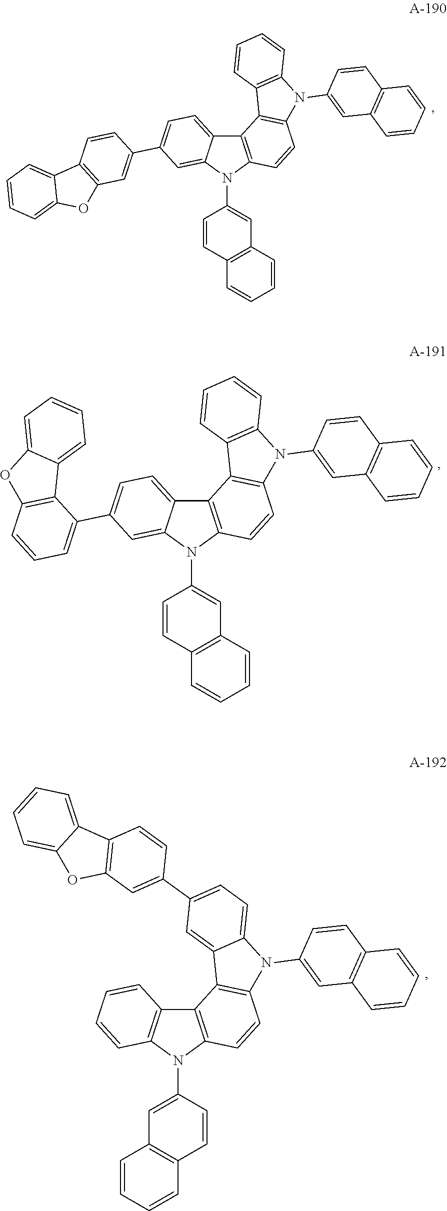 [SMILES: c1ccc2cc(-n3c4ccccc4c4c5c6ccc(-c7ccc8c(c7)oc7ccccc78)cc6n(-c6ccc7ccccc7c6)c5ccc43)ccc2c1 ; c1ccc2cc(-n3c4ccccc4c4c5c6ccc(-c7cccc8oc9ccccc9c78)cc6n(-c6ccc7ccccc7c6)c5ccc43)ccc2c1 ; c1ccc2cc(-n3c4ccccc4c4c5c6cc(-c7ccc8c(c7)oc7ccccc78)ccc6n(-c6ccc7ccccc7c6)c5ccc43)ccc2c1] 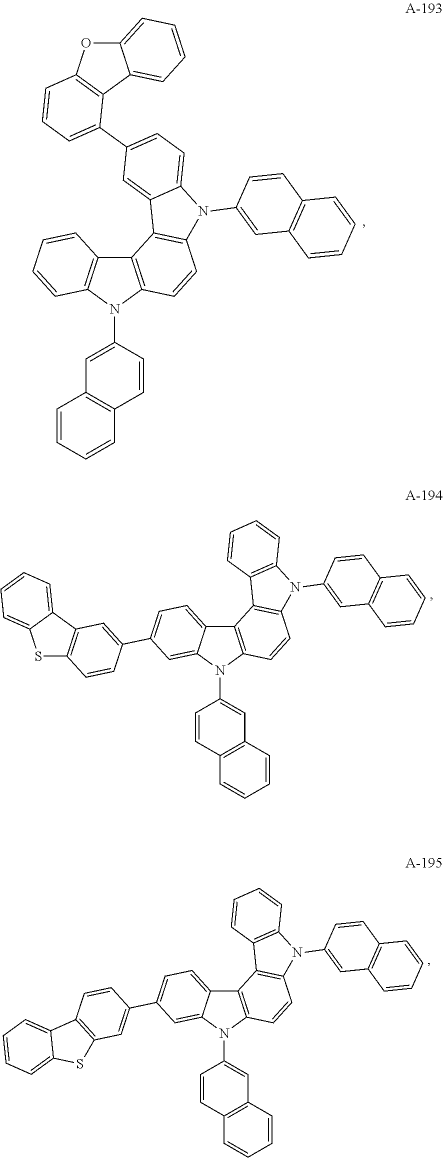 [SMILES: c1ccc2cc(-n3c4ccccc4c4c5c6cc(-c7cccc8oc9ccccc9c78)ccc6n(-c6ccc7ccccc7c6)c5ccc43)ccc2c1 ; c1ccc2cc(-n3c4ccccc4c4c5c6ccc(-c7ccc8sc9ccccc9c8c7)cc6n(-c6ccc7ccccc7c6)c5ccc43)ccc2c1 ; c1ccc2cc(-n3c4ccccc4c4c5c6ccc(-c7ccc8c(c7)sc7ccccc78)cc6n(-c6ccc7ccccc7c6)c5ccc43)ccc2c1] 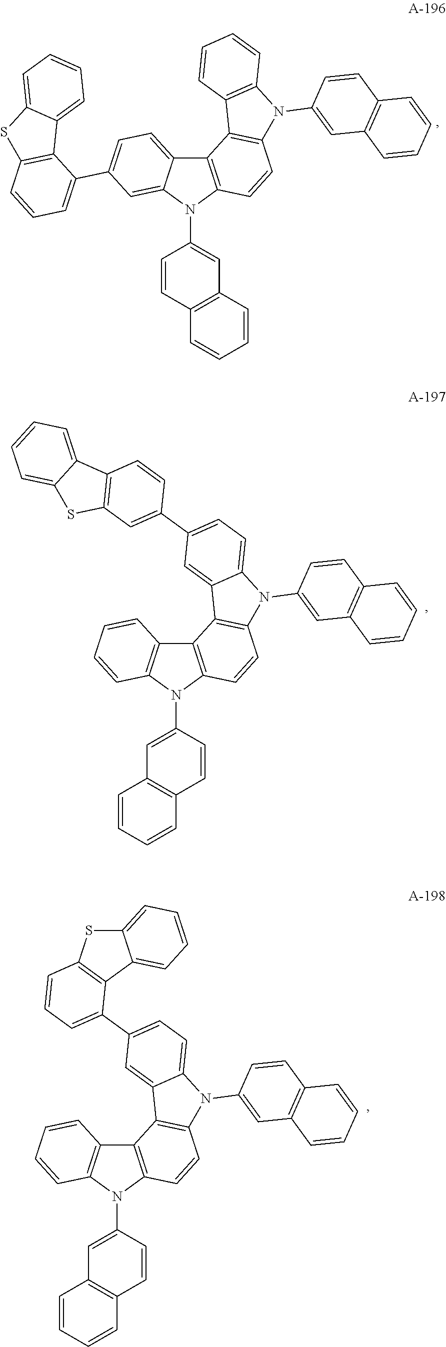 [SMILES: c1ccc2cc(-n3c4ccccc4c4c5c6ccc(-c7cccc8sc9ccccc9c78)cc6n(-c6ccc7ccccc7c6)c5ccc43)ccc2c1 ; c1ccc2cc(-n3c4ccccc4c4c5c6cc(-c7ccc8c(c7)sc7ccccc78)ccc6n(-c6ccc7ccccc7c6)c5ccc43)ccc2c1 ; c1ccc2cc(-n3c4ccccc4c4c5c6cc(-c7cccc8sc9ccccc9c78)ccc6n(-c6ccc7ccccc7c6)c5ccc43)ccc2c1] 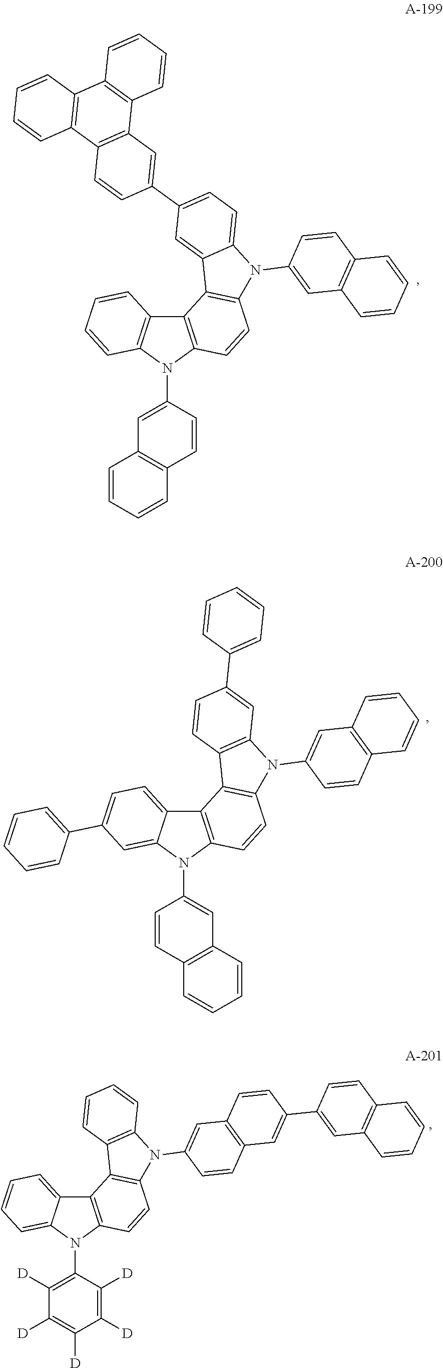 [SMILES: c1ccc2cc(-n3c4ccccc4c4c5c6cc(-c7ccc8c9ccccc9c9ccccc9c8c7)ccc6n(-c6ccc7ccccc7c6)c5ccc43)ccc2c1 ; c1ccc(-c2ccc3c4c5c6ccc(-c7ccccc7)cc6n(-c6ccc7ccccc7c6)c5ccc4n(-c4ccc5ccccc5c4)c3c2)cc1 ; [2H]c1c([2H])c([2H])c(-n2c3ccccc3c3c4c5ccccc5n(-c5ccc6cc(-c7ccc8ccccc8c7)ccc6c5)c4ccc32)c([2H])c1[2H]] 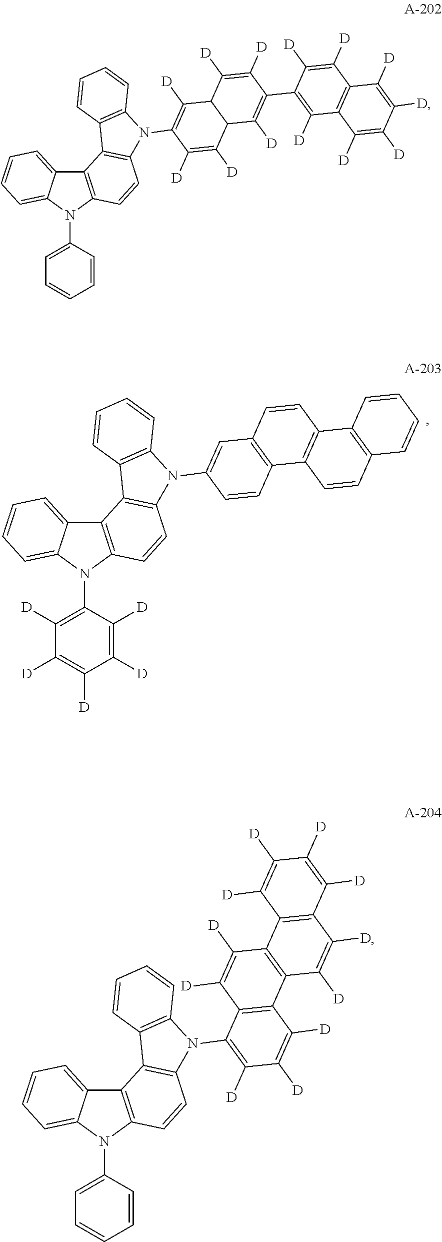 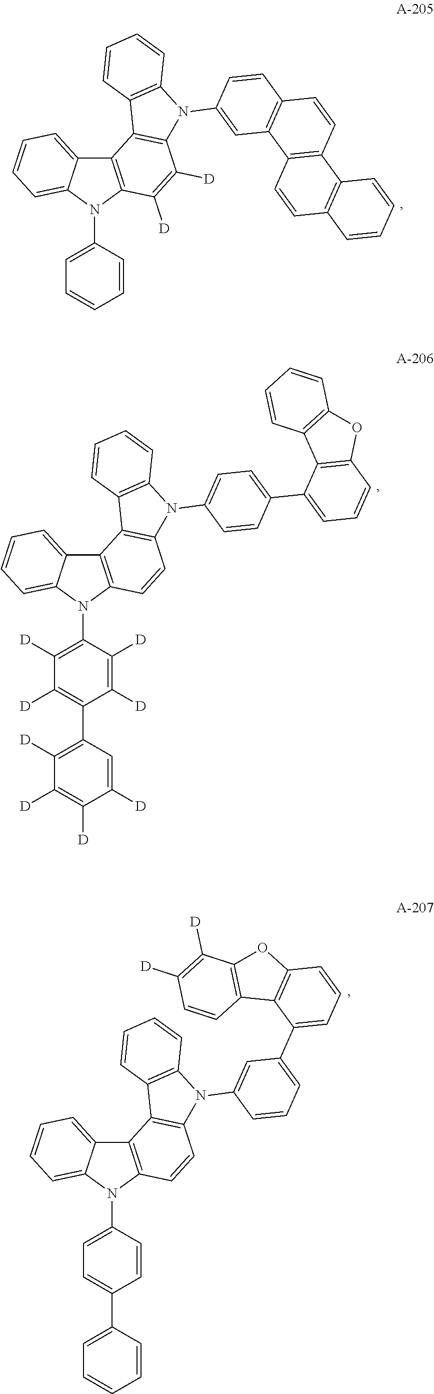 [SMILES: [2H]c1c([2H])c2c(c3ccccc3n2-c2ccc3ccc4c5ccccc5ccc4c3c2)c2c3ccccc3n(-c3ccccc3)c12 ; [2H]c1cc(-c2c([2H])c([2H])c(-n3c4ccccc4c4c5c6ccccc6n(-c6ccc(-c7cccc8oc9ccccc9c78)cc6)c5ccc43)c([2H])c2[2H])c([2H])c([2H])c1[2H] ; [2H]c1ccc2c(oc3cccc(-c4cccc(-n5c6ccccc6c6c7c8ccccc8n(-c8ccc(-c9ccccc9)cc8)c7ccc65)c4)c32)c1[2H]] 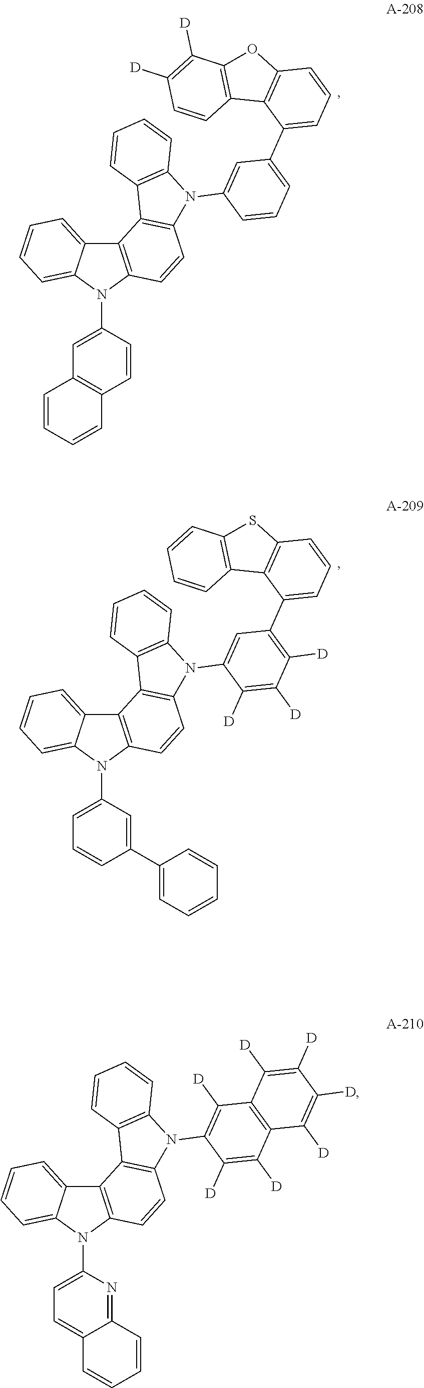 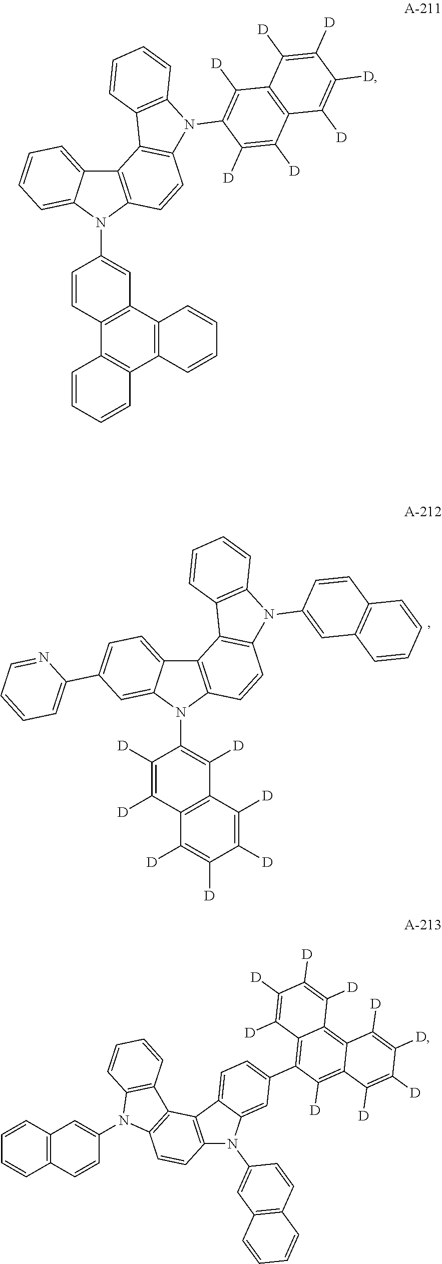 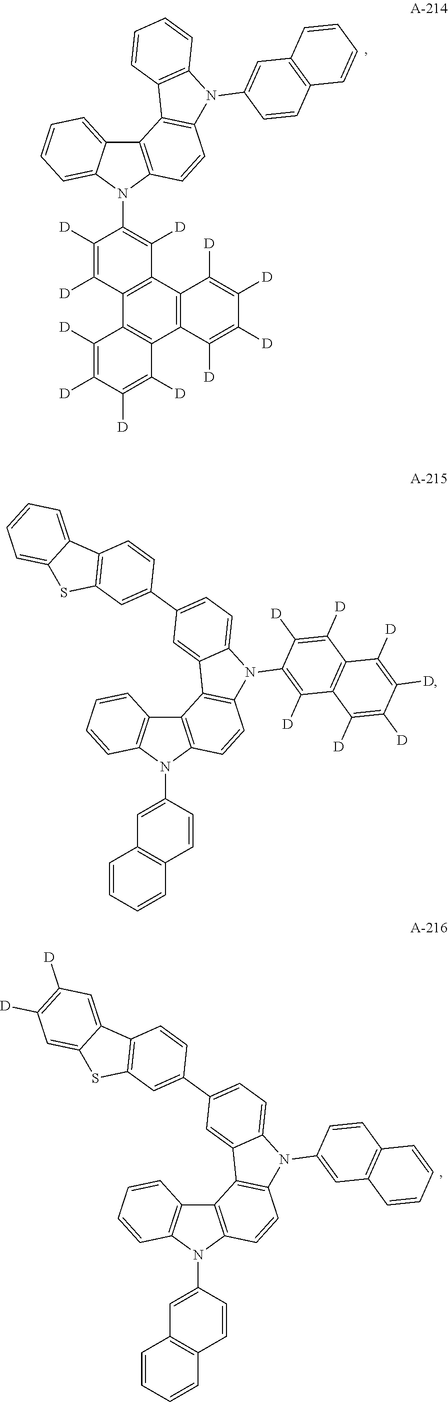 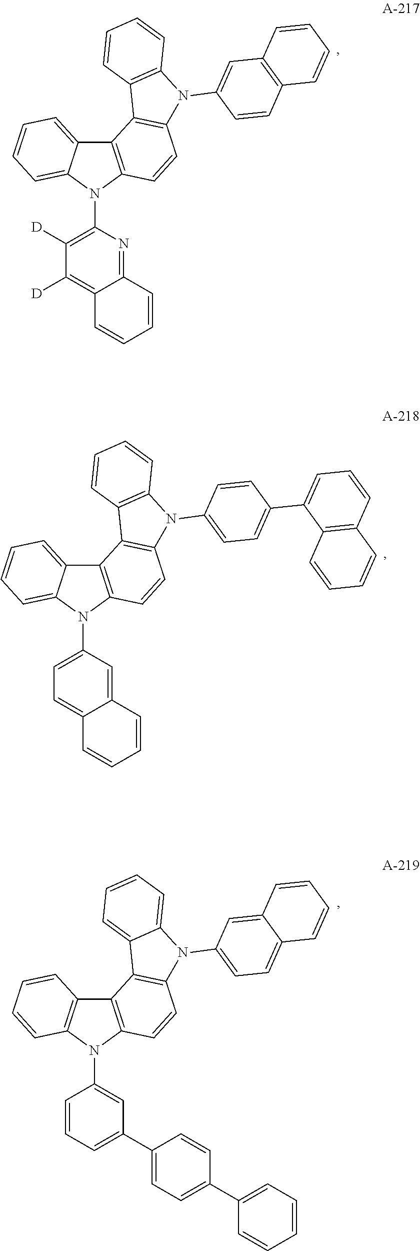 [SMILES: [2H]c1c(-n2c3ccccc3c3c4c5ccccc5n(-c5ccc6ccccc6c5)c4ccc32)nc2ccccc2c1[2H] ; c1ccc2cc(-n3c4ccccc4c4c5c6ccccc6n(-c6ccc(-c7cccc8ccccc78)cc6)c5ccc43)ccc2c1 ; c1ccc(-c2ccc(-c3cccc(-n4c5ccccc5c5c6c7ccccc7n(-c7ccc8ccccc8c7)c6ccc54)c3)cc2)cc1] 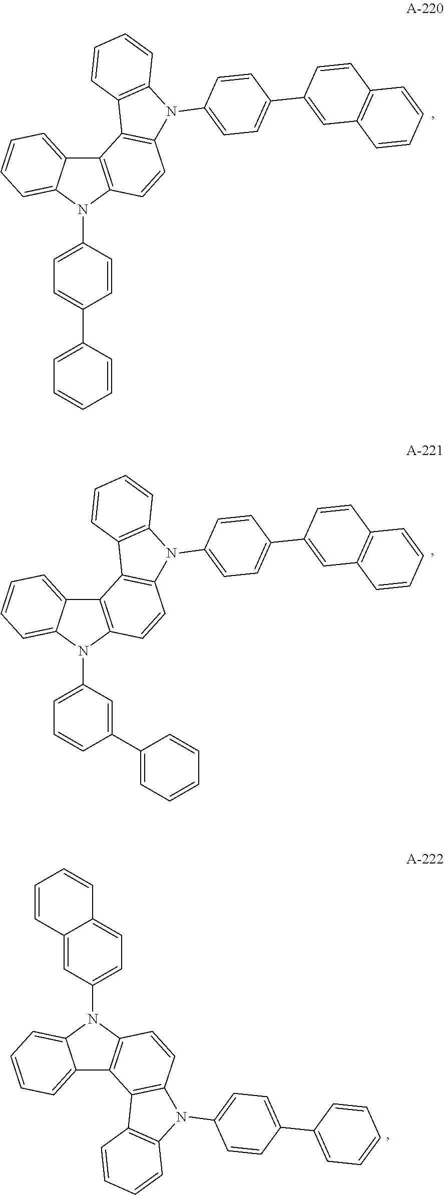 [SMILES: c1ccc(-c2ccc(-n3c4ccccc4c4c5c6ccccc6n(-c6ccc(-c7ccc8ccccc8c7)cc6)c5ccc43)cc2)cc1 ; c1ccc(-c2cccc(-n3c4ccccc4c4c5c6ccccc6n(-c6ccc(-c7ccc8ccccc8c7)cc6)c5ccc43)c2)cc1 ; c1ccc(-c2ccc(-n3c4ccccc4c4c5c6ccccc6n(-c6ccc7ccccc7c6)c5ccc43)cc2)cc1] 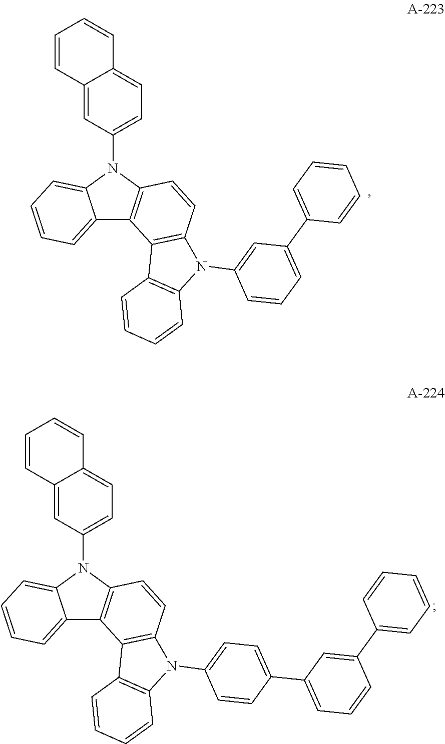 [SMILES: c1ccc(-c2cccc(-n3c4ccccc4c4c5c6ccccc6n(-c6ccc7ccccc7c6)c5ccc43)c2)cc1 ; c1ccc(-c2cccc(-c3ccc(-n4c5ccccc5c5c6c7ccccc7n(-c7ccc8ccccc8c7)c6ccc54)cc3)c2)cc1]
wherein optionally, hydrogens in Compound A-1 to Compound A-224 can be partially or fully substituted with deuterium.

6. The electroluminescent device according to claim 1, wherein the second compound has a structure represented by Formula 2-1: 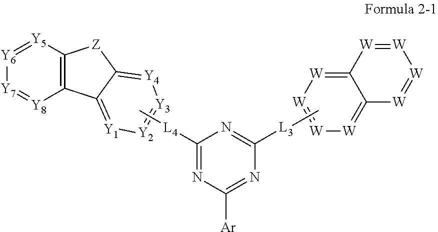
wherein in Formula 2-1,
Z is selected from O, S, CRR, NR, SiRR or Se, wherein when two R are present at the same time, the two R are identical or different;
Y₁ to Y₄ are, at each occurrence identically or differently, selected from C, CR_{y} or N, and one of Y₁ to Y₄ is selected from C and joined to L₄;
Y₅ to Y₈ are, at each occurrence identically or differently, selected from CR_{y} or N;
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
L₄ is, at each occurrence identically or differently, selected from a single bond, substituted or unsubstituted arylene having 6 to 30 carbon atoms, substituted or unsubstituted heteroarylene having 3 to 30 carbon atoms or a combination thereof;
R, R_{y} and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2-1, adjacent substituents R, R_{y} and R_{w} can be optionally joined to form a ring.

7. The electroluminescent device according to claim 6, wherein Z is selected from O, S, CRR, NR or SiRR, and the R is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms or a combination thereof;
preferably, Z is selected from O, S or NR, and the R is, at each occurrence identically or differently, selected from substituted or unsubstituted aryl having 6 to 30 carbon atoms, substituted or unsubstituted heteroaryl having 3 to 30 carbon atoms or a combination thereof; and
more preferably, the R is, at each occurrence identically or differently, selected from the group consisting of: substituted or unsubstituted phenyl, substituted or unsubstituted naphthyl, substituted or unsubstituted biphenyl, substituted or unsubstituted pyridyl, substituted or unsubstituted dibenzofuranyl, substituted or unsubstituted dibenzothienyl and combinations thereof.

8. The electroluminescent device according to claim 6, wherein R_{y} and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof; and
preferably, R_{y} and R_{w} are, at each occurrence identically or differently, selected from the group consisting of: hydrogen, deuterium, fluorine, substituted or unsubstituted phenyl, substituted or unsubstituted naphthyl, substituted or unsubstituted biphenyl, substituted or unsubstituted pyridyl, substituted or unsubstituted triphenylenyl, substituted or unsubstituted dibenzofuranyl, substituted or unsubstituted dibenzothienyl, substituted or unsubstituted chrysenyl and combinations thereof.

9. The electroluminescent device according to claim 6, wherein Ar is, at each occurrence identically or differently, selected from substituted or unsubstituted aryl having 6 to 30 carbon atoms, substituted or unsubstituted heteroaryl having 3 to 30 carbon atoms or a combination thereof; and
preferably, Ar is, at each occurrence identically or differently, selected from the group consisting of: substituted or unsubstituted phenyl, substituted or unsubstituted naphthyl, substituted or unsubstituted biphenyl, substituted or unsubstituted pyridyl, substituted or unsubstituted phenanthryl, substituted or unsubstituted terphenyl, substituted or unsubstituted triphenylenyl, substituted or unsubstituted dibenzofuranyl, substituted or unsubstituted dibenzothienyl, substituted or unsubstituted fluorenyl, substituted or unsubstituted silafluorenyl, substituted or unsubstituted carbazolyl and combinations thereof.

10. The electroluminescent device according to claim 6, wherein L₃ is, at each occurrence identically or differently, selected from substituted or unsubstituted arylene having 6 to 18 carbon atoms, substituted or unsubstituted heteroarylene having 3 to 18 carbon atoms or a combination thereof;
preferably, L₃ is, at each occurrence identically or differently, selected from substituted or unsubstituted arylene having 6 to 18 carbon atoms; and
more preferably, L₃ is, at each occurrence identically or differently, selected from substituted or unsubstituted phenylene, substituted or unsubstituted naphthylene, substituted or unsubstituted biphenylene or a combination thereof.

11. The electroluminescent device according to claim 6, wherein L₄ is, at each occurrence identically or differently, selected from a single bond, substituted or unsubstituted arylene having 6 to 18 carbon atoms, substituted or unsubstituted heteroarylene having 3 to 18 carbon atoms or a combination thereof; and
preferably, L₄ is, at each occurrence identically or differently, selected from a single bond, substituted or unsubstituted phenylene, substituted or unsubstituted naphthylene, substituted or unsubstituted biphenylene, substituted or unsubstituted pyridylene or a combination thereof.

12. The electroluminescent device according to claim 1, wherein the second compound is selected from the group consisting of the following compounds: 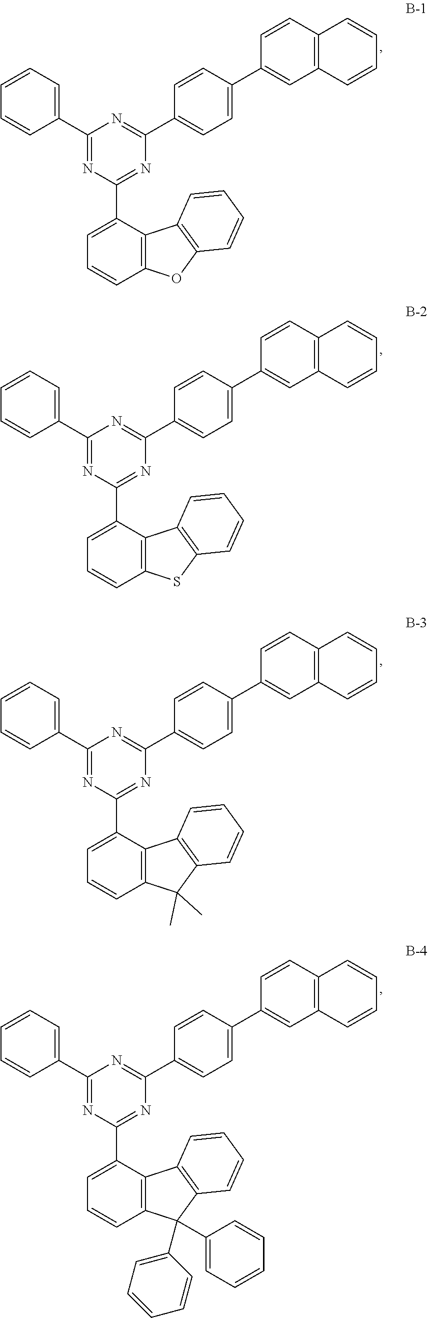 [SMILES: c1ccc(-c2nc(-c3ccc(-c4ccc5ccccc5c4)cc3)nc(-c3cccc4oc5ccccc5c34)n2)cc1 ; c1ccc(-c2nc(-c3ccc(-c4ccc5ccccc5c4)cc3)nc(-c3cccc4sc5ccccc5c34)n2)cc1 ; CC1(C)c2ccccc2-c2c(-c3nc(-c4ccccc4)nc(-c4ccc(-c5ccc6ccccc6c5)cc4)n3)cccc21 ; c1ccc(-c2nc(-c3ccc(-c4ccc5ccccc5c4)cc3)nc(-c3cccc4c3-c3ccccc3C4(c3ccccc3)c3ccccc3)n2)cc1] 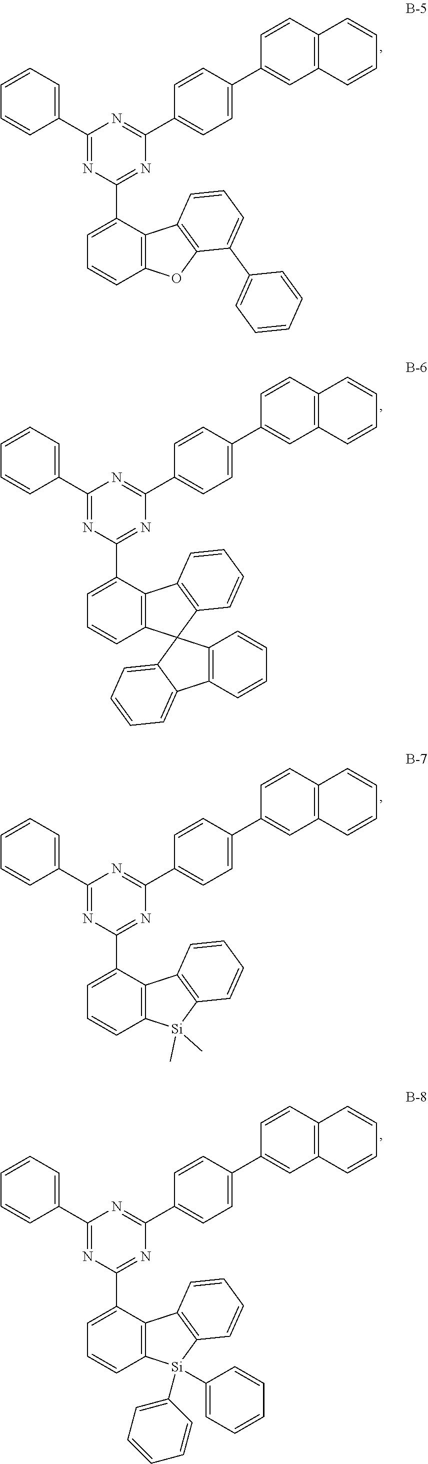 [SMILES: c1ccc(-c2nc(-c3ccc(-c4ccc5ccccc5c4)cc3)nc(-c3cccc4oc5c(-c6ccccc6)cccc5c34)n2)cc1 ; c1ccc(-c2nc(-c3ccc(-c4ccc5ccccc5c4)cc3)nc(-c3cccc4c3-c3ccccc3C43c4ccccc4-c4ccccc43)n2)cc1 ; C[Si]1(C)c2ccccc2-c2c(-c3nc(-c4ccccc4)nc(-c4ccc(-c5ccc6ccccc6c5)cc4)n3)cccc21 ; c1ccc(-c2nc(-c3ccc(-c4ccc5ccccc5c4)cc3)nc(-c3cccc4c3-c3ccccc3[Si]4(c3ccccc3)c3ccccc3)n2)cc1] 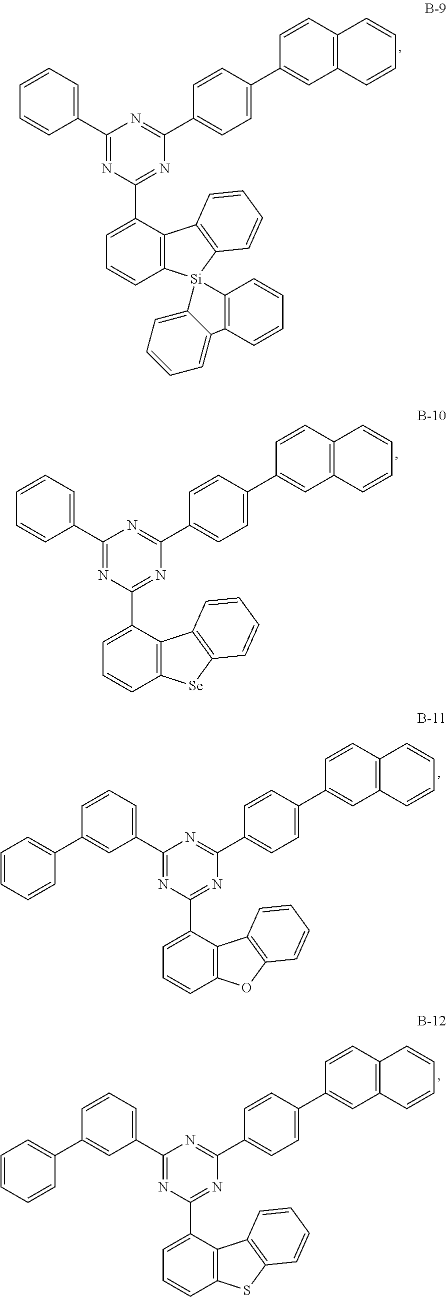 [SMILES: c1ccc(-c2nc(-c3ccc(-c4ccc5ccccc5c4)cc3)nc(-c3cccc4c3-c3ccccc3[Si]43c4ccccc4-c4ccccc43)n2)cc1 ; c1ccc(-c2nc(-c3ccc(-c4ccc5ccccc5c4)cc3)nc(-c3cccc4[se]c5ccccc5c34)n2)cc1 ; c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3nc(-c4ccc(-c5ccc6ccccc6c5)cc4)nc(-c4cccc5sc6ccccc6c45)n3)c2)cc1] 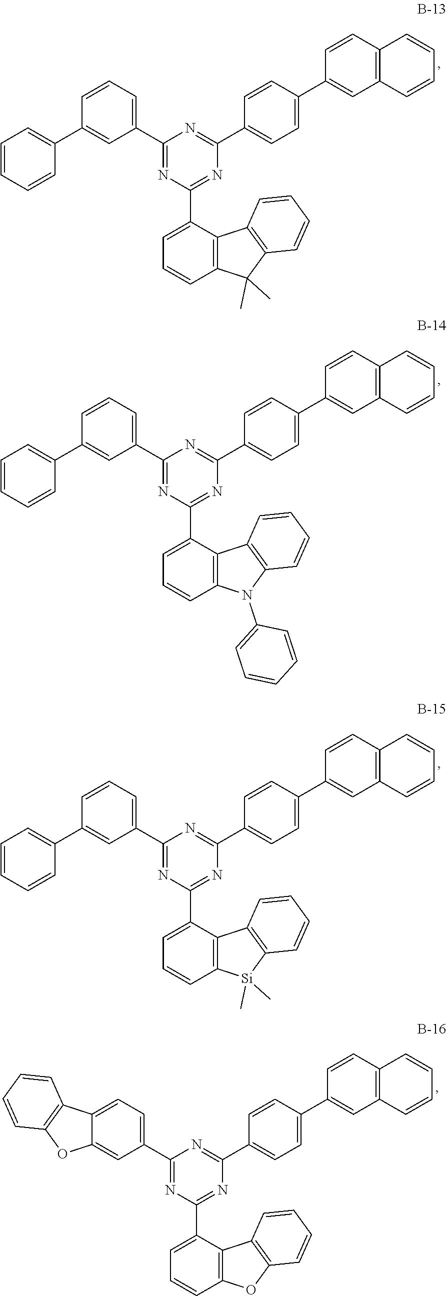 [SMILES: CC1(C)c2ccccc2-c2c(-c3nc(-c4ccc(-c5ccc6ccccc6c5)cc4)nc(-c4cccc(-c5ccccc5)c4)n3)cccc21 ; c1ccc(-c2cccc(-c3nc(-c4ccc(-c5ccc6ccccc6c5)cc4)nc(-c4cccc5c4c4ccccc4n5-c4ccccc4)n3)c2)cc1 ; C[Si]1(C)c2ccccc2-c2c(-c3nc(-c4ccc(-c5ccc6ccccc6c5)cc4)nc(-c4cccc(-c5ccccc5)c4)n3)cccc21 ; c1ccc2cc(-c3ccc(-c4nc(-c5ccc6c(c5)oc5ccccc56)nc(-c5cccc6oc7ccccc7c56)n4)cc3)ccc2c1] 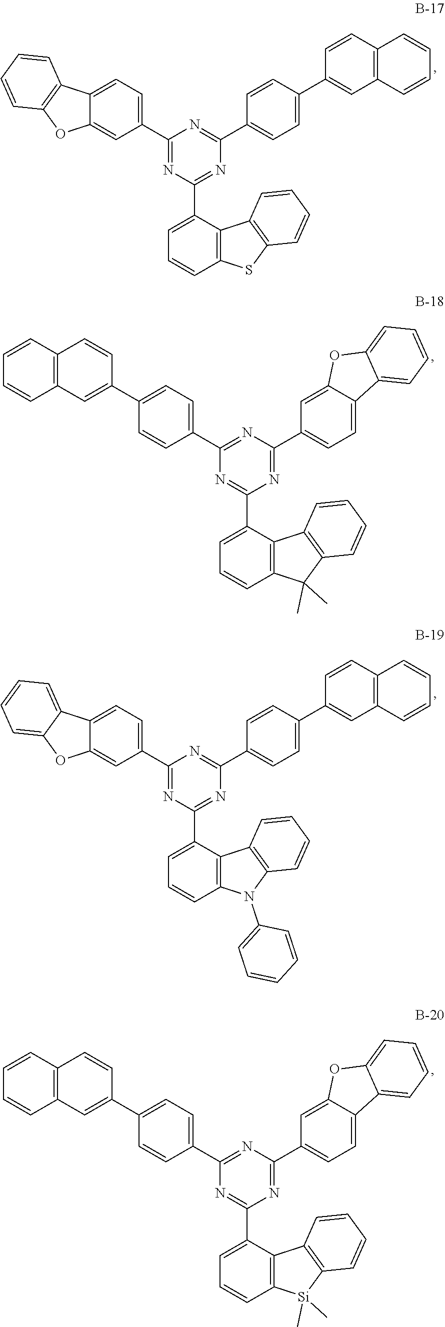 [SMILES: c1ccc2cc(-c3ccc(-c4nc(-c5ccc6c(c5)oc5ccccc56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4ccc5c(c4)oc4ccccc45)n3)cccc21 ; c1ccc(-n2c3ccccc3c3c(-c4nc(-c5ccc(-c6ccc7ccccc7c6)cc5)nc(-c5ccc6c(c5)oc5ccccc56)n4)cccc32)cc1 ; C[Si]1(C)c2ccccc2-c2c(-c3nc(-c4ccc(-c5ccc6ccccc6c5)cc4)nc(-c4ccc5c(c4)oc4ccccc45)n3)cccc21] 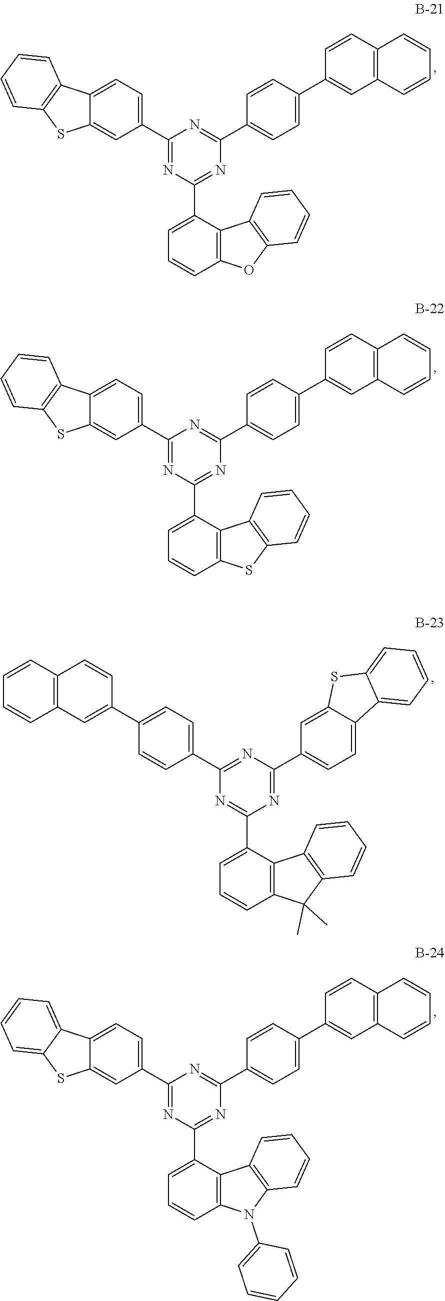 [SMILES: c1ccc2cc(-c3ccc(-c4nc(-c5ccc6c(c5)sc5ccccc56)nc(-c5cccc6oc7ccccc7c56)n4)cc3)ccc2c1 ; c1ccc2cc(-c3ccc(-c4nc(-c5ccc6c(c5)sc5ccccc56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4ccc5c(c4)sc4ccccc45)n3)cccc21 ; c1ccc(-n2c3ccccc3c3c(-c4nc(-c5ccc(-c6ccc7ccccc7c6)cc5)nc(-c5ccc6c(c5)sc5ccccc56)n4)cccc32)cc1] 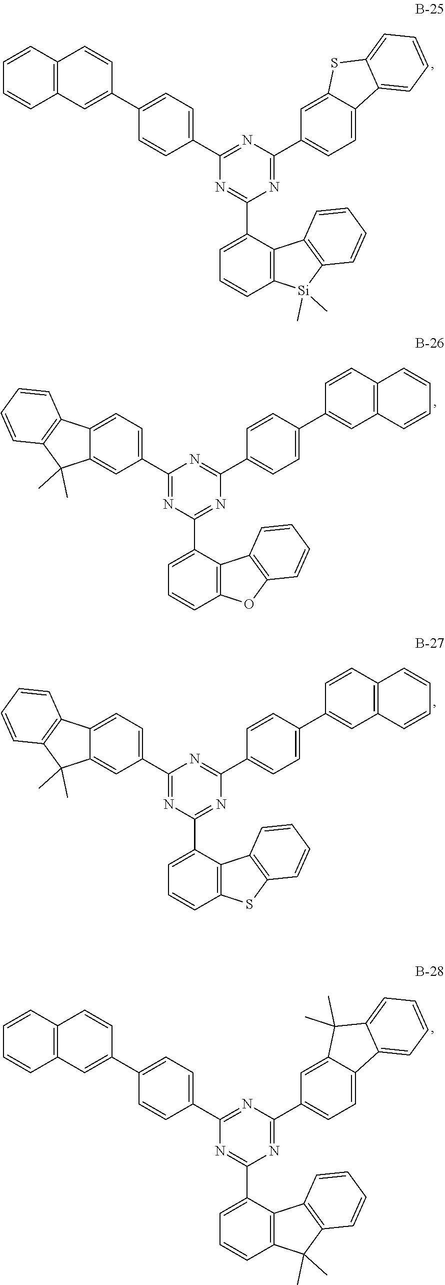 [SMILES: C[Si]1(C)c2ccccc2-c2c(-c3nc(-c4ccc(-c5ccc6ccccc6c5)cc4)nc(-c4ccc5c(c4)sc4ccccc45)n3)cccc21 ; CC1(C)c2ccccc2-c2ccc(-c3nc(-c4ccc(-c5ccc6ccccc6c5)cc4)nc(-c4cccc5oc6ccccc6c45)n3)cc21 ; CC1(C)c2ccccc2-c2ccc(-c3nc(-c4ccc(-c5ccc6ccccc6c5)cc4)nc(-c4cccc5sc6ccccc6c45)n3)cc21 ; CC1(C)c2ccccc2-c2ccc(-c3nc(-c4ccc(-c5ccc6ccccc6c5)cc4)nc(-c4cccc5c4-c4ccccc4C5(C)C)n3)cc21] 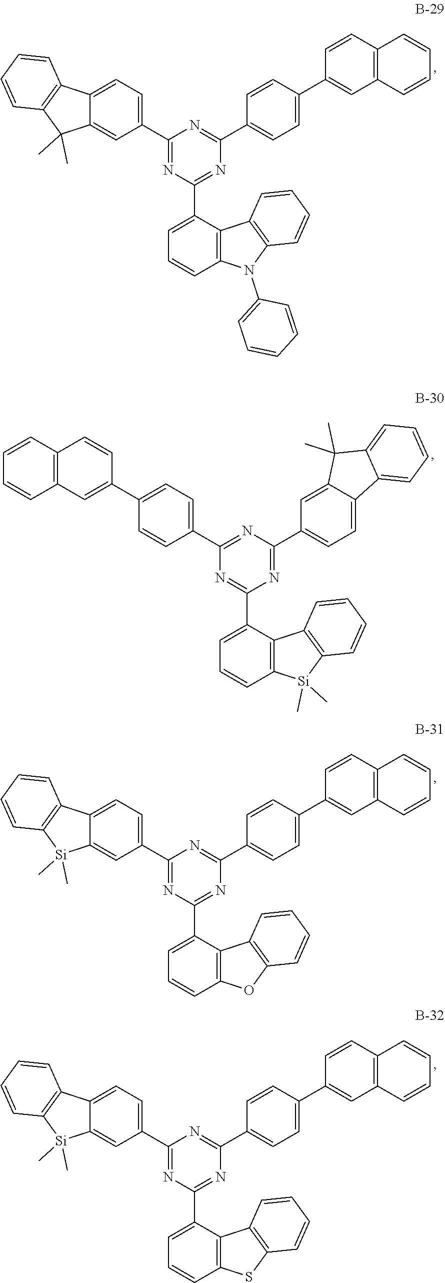 [SMILES: CC1(C)c2ccccc2-c2ccc(-c3nc(-c4ccc(-c5ccc6ccccc6c5)cc4)nc(-c4cccc5c4c4ccccc4n5-c4ccccc4)n3)cc21 ; CC1(C)c2ccccc2-c2ccc(-c3nc(-c4ccc(-c5ccc6ccccc6c5)cc4)nc(-c4cccc5c4-c4ccccc4[Si]5(C)C)n3)cc21 ; C[Si]1(C)c2ccccc2-c2ccc(-c3nc(-c4ccc(-c5ccc6ccccc6c5)cc4)nc(-c4cccc5oc6ccccc6c45)n3)cc21 ; C[Si]1(C)c2ccccc2-c2ccc(-c3nc(-c4ccc(-c5ccc6ccccc6c5)cc4)nc(-c4cccc5sc6ccccc6c45)n3)cc21] 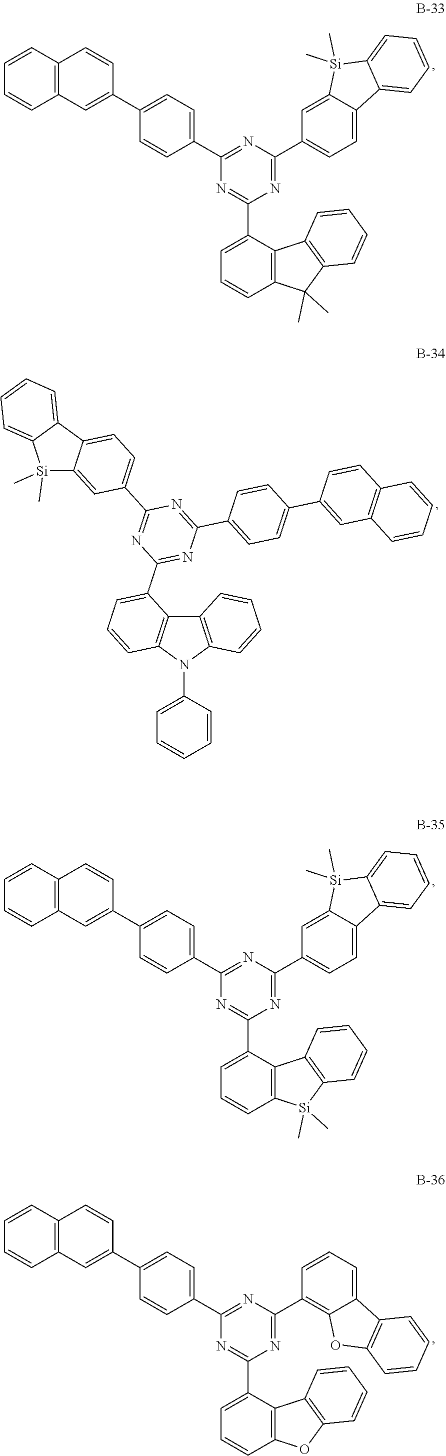 [SMILES: CC1(C)c2ccccc2-c2c(-c3nc(-c4ccc(-c5ccc6ccccc6c5)cc4)nc(-c4ccc5c(c4)[Si](C)(C)c4ccccc4-5)n3)cccc21 ; C[Si]1(C)c2ccccc2-c2ccc(-c3nc(-c4ccc(-c5ccc6ccccc6c5)cc4)nc(-c4cccc5c4c4ccccc4n5-c4ccccc4)n3)cc21 ; C[Si]1(C)c2ccccc2-c2ccc(-c3nc(-c4ccc(-c5ccc6ccccc6c5)cc4)nc(-c4cccc5c4-c4ccccc4[Si]5(C)C)n3)cc21 ; c1ccc2cc(-c3ccc(-c4nc(-c5cccc6c5oc5ccccc56)nc(-c5cccc6oc7ccccc7c56)n4)cc3)ccc2c1] 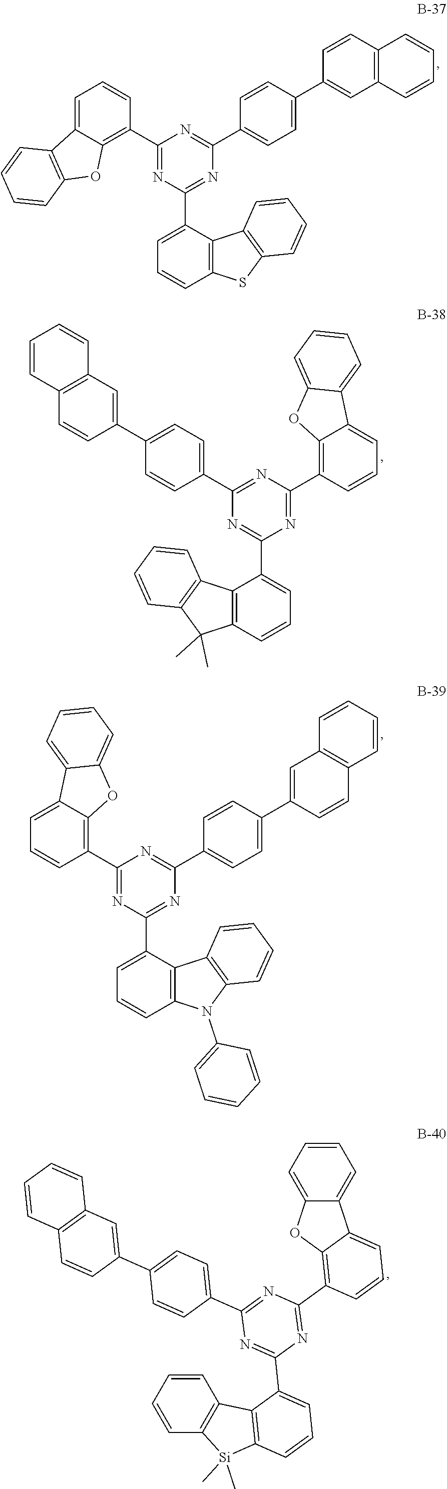 [SMILES: c1ccc2cc(-c3ccc(-c4nc(-c5cccc6c5oc5ccccc56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4cccc5c4oc4ccccc45)n3)cccc21 ; c1ccc(-n2c3ccccc3c3c(-c4nc(-c5ccc(-c6ccc7ccccc7c6)cc5)nc(-c5cccc6c5oc5ccccc56)n4)cccc32)cc1 ; C[Si]1(C)c2ccccc2-c2c(-c3nc(-c4ccc(-c5ccc6ccccc6c5)cc4)nc(-c4cccc5c4oc4ccccc45)n3)cccc21] 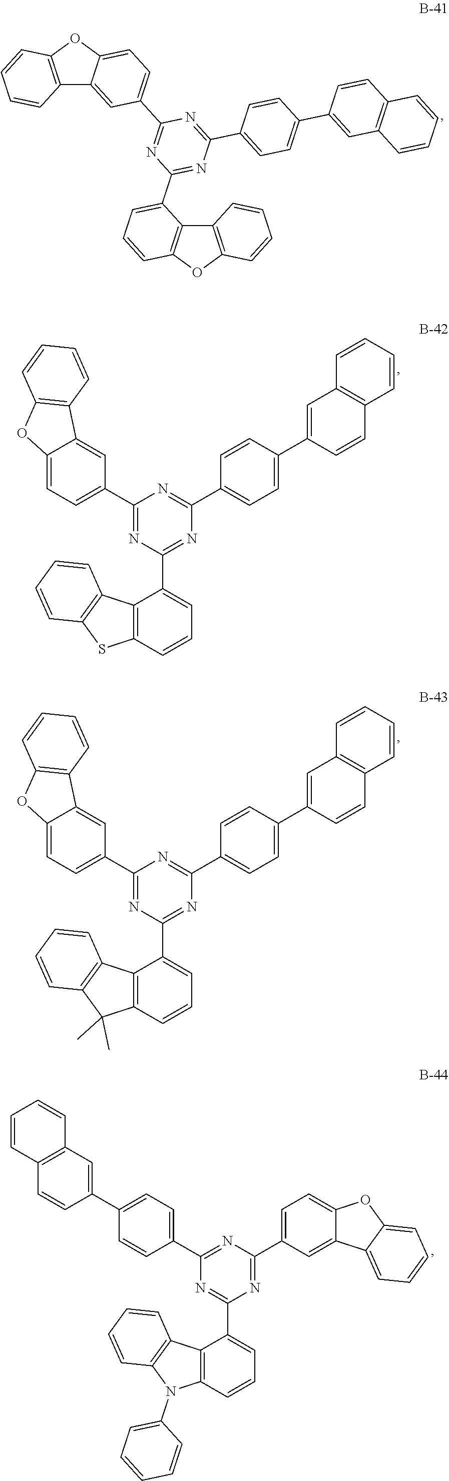 [SMILES: c1ccc2cc(-c3ccc(-c4nc(-c5ccc6oc7ccccc7c6c5)nc(-c5cccc6oc7ccccc7c56)n4)cc3)ccc2c1 ; c1ccc2cc(-c3ccc(-c4nc(-c5ccc6oc7ccccc7c6c5)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4ccc5oc6ccccc6c5c4)n3)cccc21 ; c1ccc(-n2c3ccccc3c3c(-c4nc(-c5ccc(-c6ccc7ccccc7c6)cc5)nc(-c5ccc6oc7ccccc7c6c5)n4)cccc32)cc1] 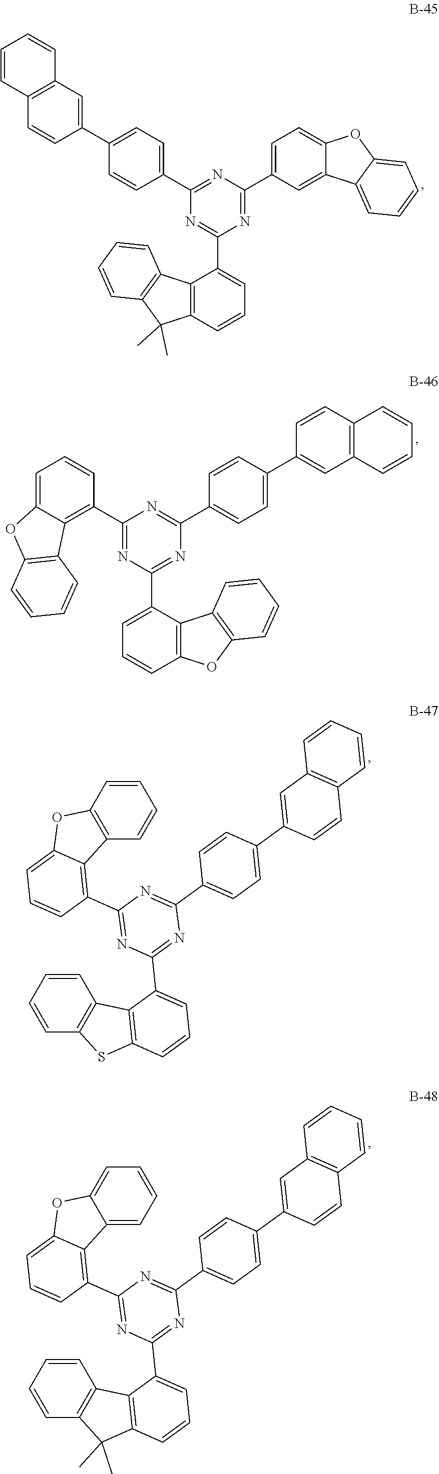 [SMILES: CC1(C)c2ccccc2-c2c(-c3nc(-c4ccc(-c5ccc6ccccc6c5)cc4)nc(-c4ccc5oc6ccccc6c5c4)n3)cccc21 ; c1ccc2cc(-c3ccc(-c4nc(-c5cccc6oc7ccccc7c56)nc(-c5cccc6oc7ccccc7c56)n4)cc3)ccc2c1 ; c1ccc2cc(-c3ccc(-c4nc(-c5cccc6oc7ccccc7c56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4cccc5oc6ccccc6c45)n3)cccc21] 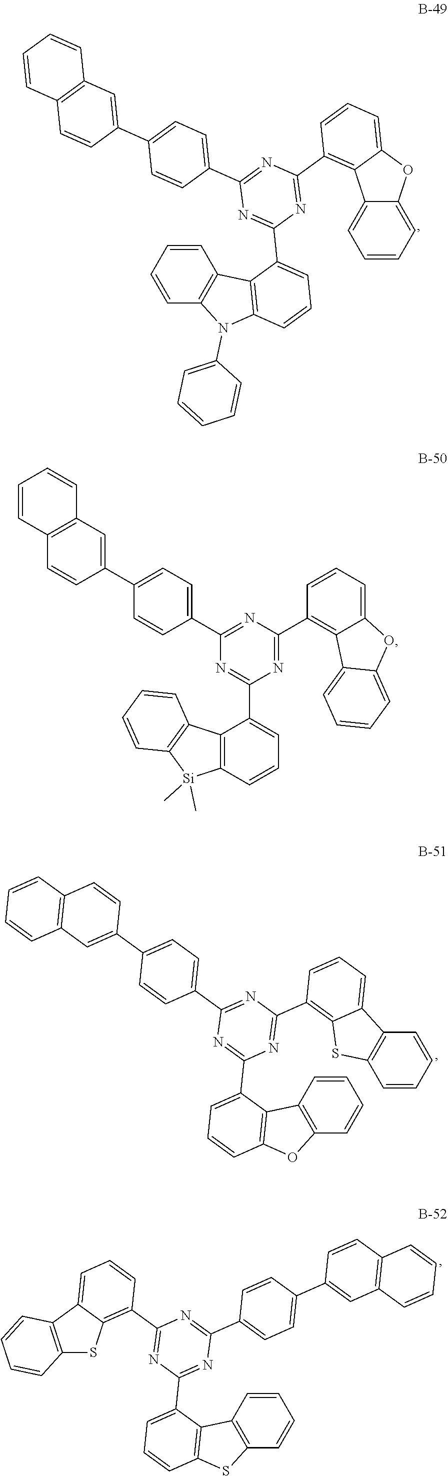 [SMILES: c1ccc(-n2c3ccccc3c3c(-c4nc(-c5ccc(-c6ccc7ccccc7c6)cc5)nc(-c5cccc6oc7ccccc7c56)n4)cccc32)cc1 ; C[Si]1(C)c2ccccc2-c2c(-c3nc(-c4ccc(-c5ccc6ccccc6c5)cc4)nc(-c4cccc5oc6ccccc6c45)n3)cccc21 ; c1ccc2cc(-c3ccc(-c4nc(-c5cccc6c5sc5ccccc56)nc(-c5cccc6oc7ccccc7c56)n4)cc3)ccc2c1 ; c1ccc2cc(-c3ccc(-c4nc(-c5cccc6c5sc5ccccc56)nc(-c5cccc6sc7ccccc7c56)n4)cc3)ccc2c1] 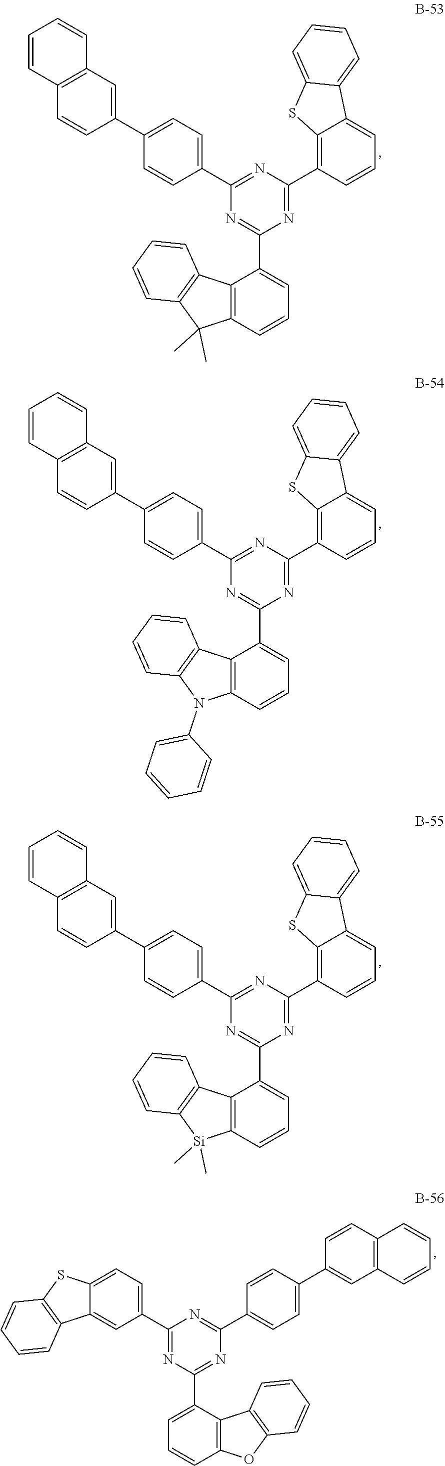 [SMILES: CC1(C)c2ccccc2-c2c(-c3nc(-c4ccc(-c5ccc6ccccc6c5)cc4)nc(-c4cccc5c4sc4ccccc45)n3)cccc21 ; c1ccc(-n2c3ccccc3c3c(-c4nc(-c5ccc(-c6ccc7ccccc7c6)cc5)nc(-c5cccc6c5sc5ccccc56)n4)cccc32)cc1 ; C[Si]1(C)c2ccccc2-c2c(-c3nc(-c4ccc(-c5ccc6ccccc6c5)cc4)nc(-c4cccc5c4sc4ccccc45)n3)cccc21 ; c1ccc2cc(-c3ccc(-c4nc(-c5ccc6sc7ccccc7c6c5)nc(-c5cccc6oc7ccccc7c56)n4)cc3)ccc2c1] 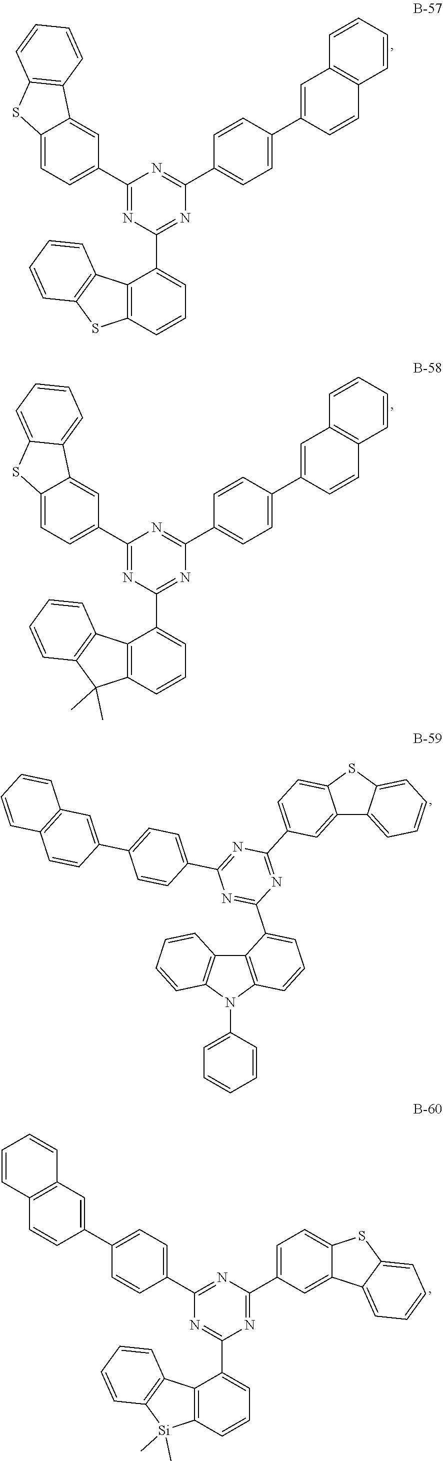 [SMILES: c1ccc2cc(-c3ccc(-c4nc(-c5ccc6sc7ccccc7c6c5)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4ccc5sc6ccccc6c5c4)n3)cccc21 ; c1ccc(-n2c3ccccc3c3c(-c4nc(-c5ccc(-c6ccc7ccccc7c6)cc5)nc(-c5ccc6sc7ccccc7c6c5)n4)cccc32)cc1 ; C[Si]1(C)c2ccccc2-c2c(-c3nc(-c4ccc(-c5ccc6ccccc6c5)cc4)nc(-c4ccc5sc6ccccc6c5c4)n3)cccc21] 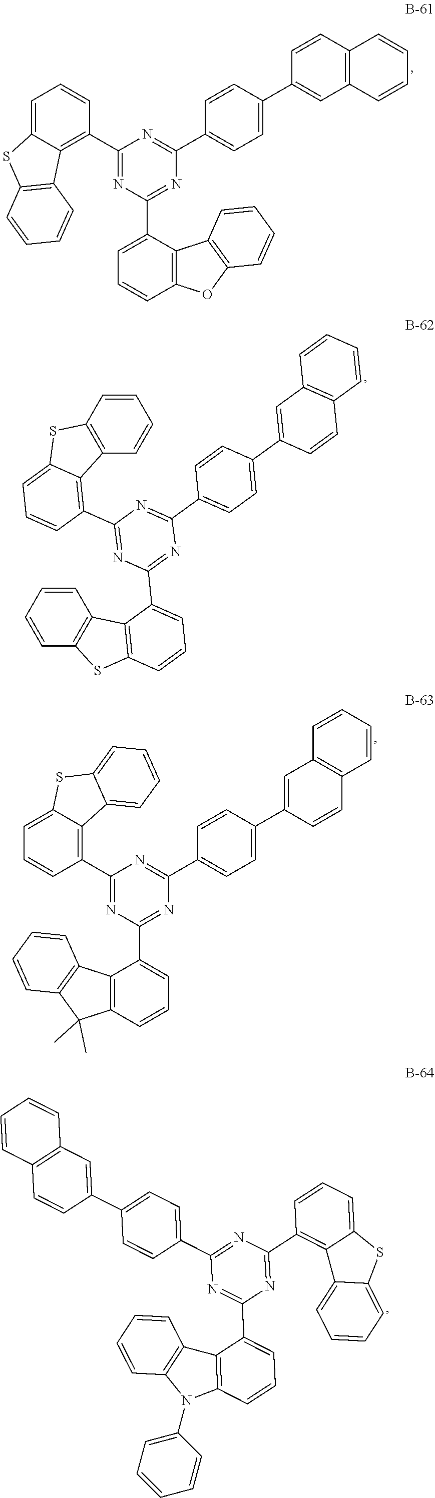 [SMILES: c1ccc2cc(-c3ccc(-c4nc(-c5cccc6oc7ccccc7c56)nc(-c5cccc6sc7ccccc7c56)n4)cc3)ccc2c1 ; c1ccc2cc(-c3ccc(-c4nc(-c5cccc6sc7ccccc7c56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4cccc5sc6ccccc6c45)n3)cccc21 ; c1ccc(-n2c3ccccc3c3c(-c4nc(-c5ccc(-c6ccc7ccccc7c6)cc5)nc(-c5cccc6sc7ccccc7c56)n4)cccc32)cc1] 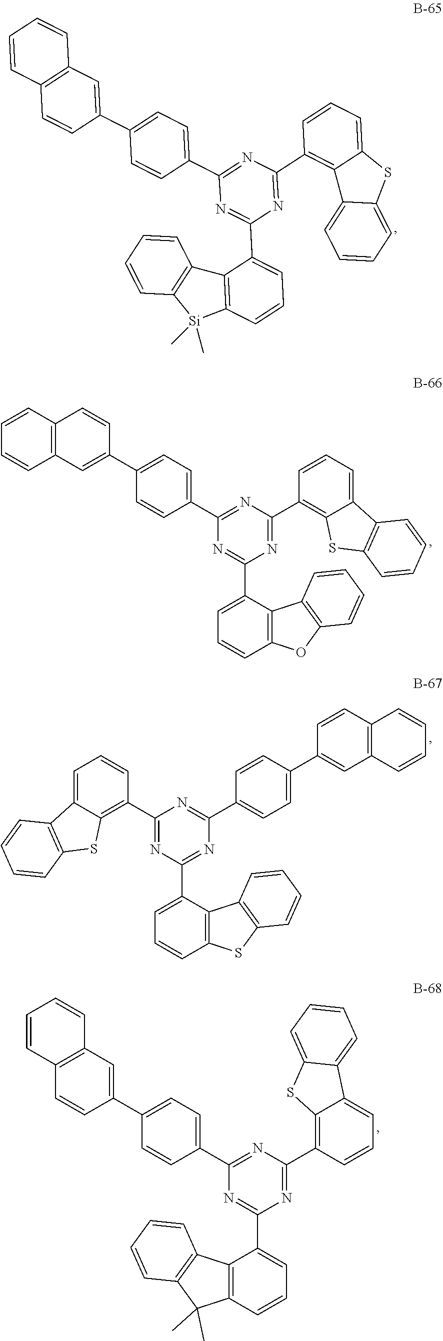 [SMILES: C[Si]1(C)c2ccccc2-c2c(-c3nc(-c4ccc(-c5ccc6ccccc6c5)cc4)nc(-c4cccc5sc6ccccc6c45)n3)cccc21 ; c1ccc2cc(-c3ccc(-c4nc(-c5cccc6c5sc5ccccc56)nc(-c5cccc6oc7ccccc7c56)n4)cc3)ccc2c1 ; c1ccc2cc(-c3ccc(-c4nc(-c5cccc6c5sc5ccccc56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4cccc5c4sc4ccccc45)n3)cccc21] 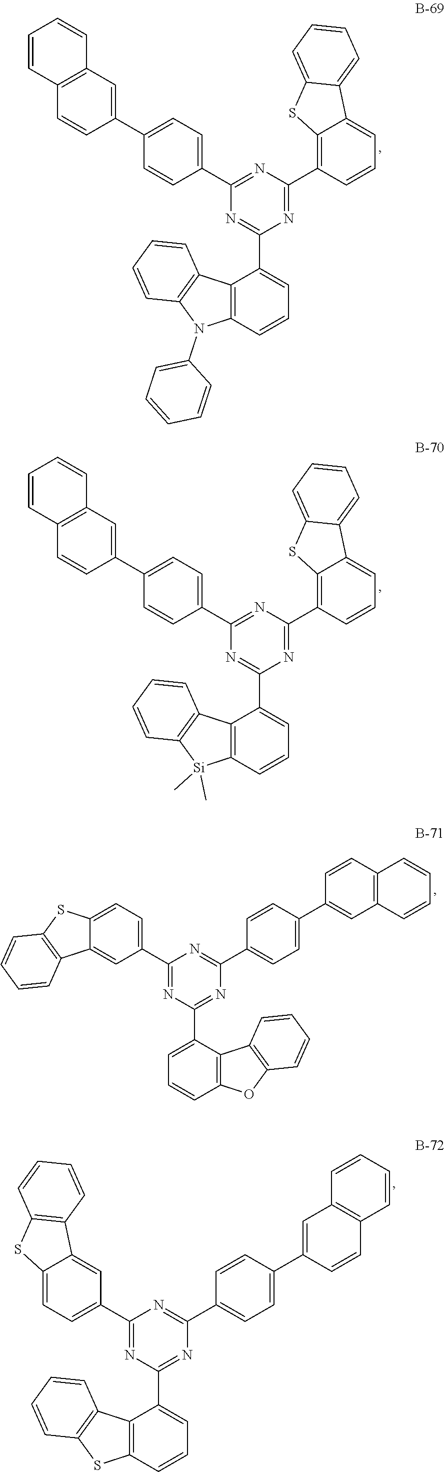 [SMILES: c1ccc(-n2c3ccccc3c3c(-c4nc(-c5ccc(-c6ccc7ccccc7c6)cc5)nc(-c5cccc6c5sc5ccccc56)n4)cccc32)cc1 ; C[Si]1(C)c2ccccc2-c2c(-c3nc(-c4ccc(-c5ccc6ccccc6c5)cc4)nc(-c4cccc5c4sc4ccccc45)n3)cccc21 ; c1ccc2cc(-c3ccc(-c4nc(-c5ccc6sc7ccccc7c6c5)nc(-c5cccc6oc7ccccc7c56)n4)cc3)ccc2c1 ; c1ccc2cc(-c3ccc(-c4nc(-c5ccc6sc7ccccc7c6c5)nc(-c5cccc6sc7ccccc7c56)n4)cc3)ccc2c1] 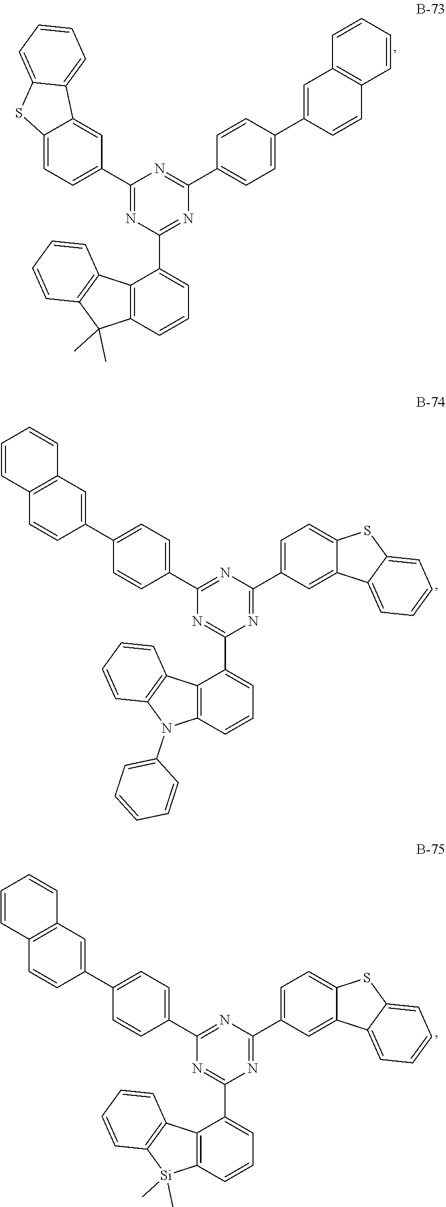 [SMILES: CC1(C)c2ccccc2-c2c(-c3nc(-c4ccc(-c5ccc6ccccc6c5)cc4)nc(-c4ccc5sc6ccccc6c5c4)n3)cccc21 ; c1ccc(-n2c3ccccc3c3c(-c4nc(-c5ccc(-c6ccc7ccccc7c6)cc5)nc(-c5ccc6sc7ccccc7c6c5)n4)cccc32)cc1 ; C[Si]1(C)c2ccccc2-c2c(-c3nc(-c4ccc(-c5ccc6ccccc6c5)cc4)nc(-c4ccc5sc6ccccc6c5c4)n3)cccc21] 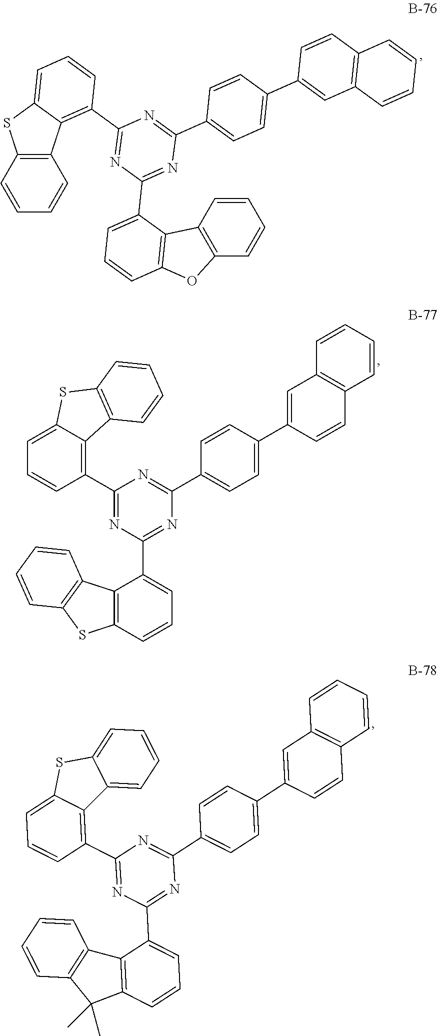 [SMILES: c1ccc2cc(-c3ccc(-c4nc(-c5cccc6oc7ccccc7c56)nc(-c5cccc6sc7ccccc7c56)n4)cc3)ccc2c1 ; c1ccc2cc(-c3ccc(-c4nc(-c5cccc6sc7ccccc7c56)nc(-c5cccc6sc7ccccc7c56)n4)cc3)ccc2c1 ; CC1(C)c2ccccc2-c2c(-c3nc(-c4ccc(-c5ccc6ccccc6c5)cc4)nc(-c4cccc5sc6ccccc6c45)n3)cccc21] 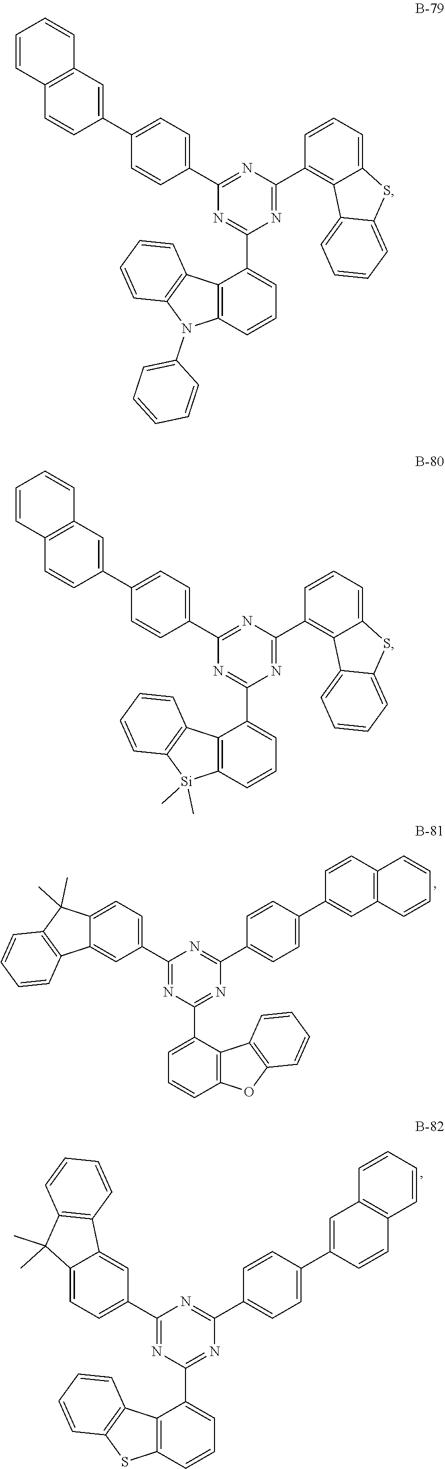 [SMILES: c1ccc(-n2c3ccccc3c3c(-c4nc(-c5ccc(-c6ccc7ccccc7c6)cc5)nc(-c5cccc6sc7ccccc7c56)n4)cccc32)cc1 ; C[Si]1(C)c2ccccc2-c2c(-c3nc(-c4ccc(-c5ccc6ccccc6c5)cc4)nc(-c4cccc5sc6ccccc6c45)n3)cccc21 ; CC1(C)c2ccccc2-c2cc(-c3nc(-c4ccc(-c5ccc6ccccc6c5)cc4)nc(-c4cccc5oc6ccccc6c45)n3)ccc21 ; CC1(C)c2ccccc2-c2cc(-c3nc(-c4ccc(-c5ccc6ccccc6c5)cc4)nc(-c4cccc5sc6ccccc6c45)n3)ccc21] 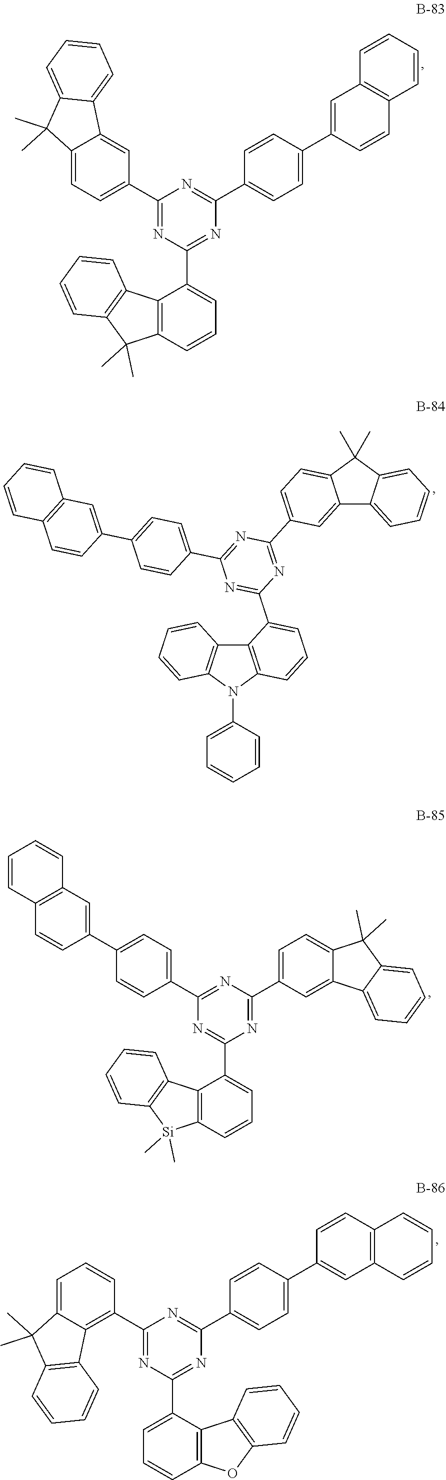 [SMILES: CC1(C)c2ccccc2-c2cc(-c3nc(-c4ccc(-c5ccc6ccccc6c5)cc4)nc(-c4cccc5c4-c4ccccc4C5(C)C)n3)ccc21 ; CC1(C)c2ccccc2-c2cc(-c3nc(-c4ccc(-c5ccc6ccccc6c5)cc4)nc(-c4cccc5c4c4ccccc4n5-c4ccccc4)n3)ccc21 ; CC1(C)c2ccccc2-c2cc(-c3nc(-c4ccc(-c5ccc6ccccc6c5)cc4)nc(-c4cccc5c4-c4ccccc4[Si]5(C)C)n3)ccc21 ; CC1(C)c2ccccc2-c2c(-c3nc(-c4ccc(-c5ccc6ccccc6c5)cc4)nc(-c4cccc5oc6ccccc6c45)n3)cccc21] 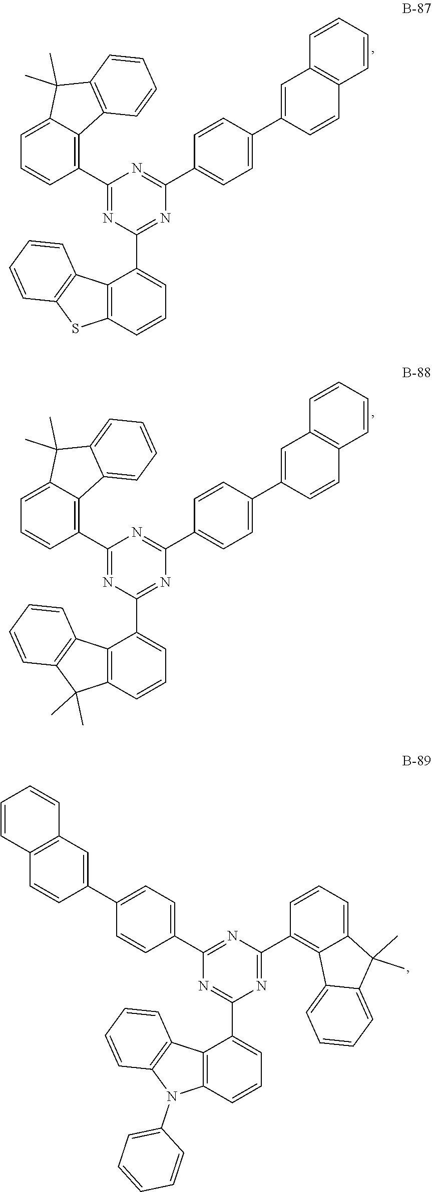 [SMILES: CC1(C)c2ccccc2-c2c(-c3nc(-c4ccc(-c5ccc6ccccc6c5)cc4)nc(-c4cccc5sc6ccccc6c45)n3)cccc21 ; CC1(C)c2ccccc2-c2c(-c3nc(-c4ccc(-c5ccc6ccccc6c5)cc4)nc(-c4cccc5c4-c4ccccc4C5(C)C)n3)cccc21 ; CC1(C)c2ccccc2-c2c(-c3nc(-c4ccc(-c5ccc6ccccc6c5)cc4)nc(-c4cccc5c4c4ccccc4n5-c4ccccc4)n3)cccc21] 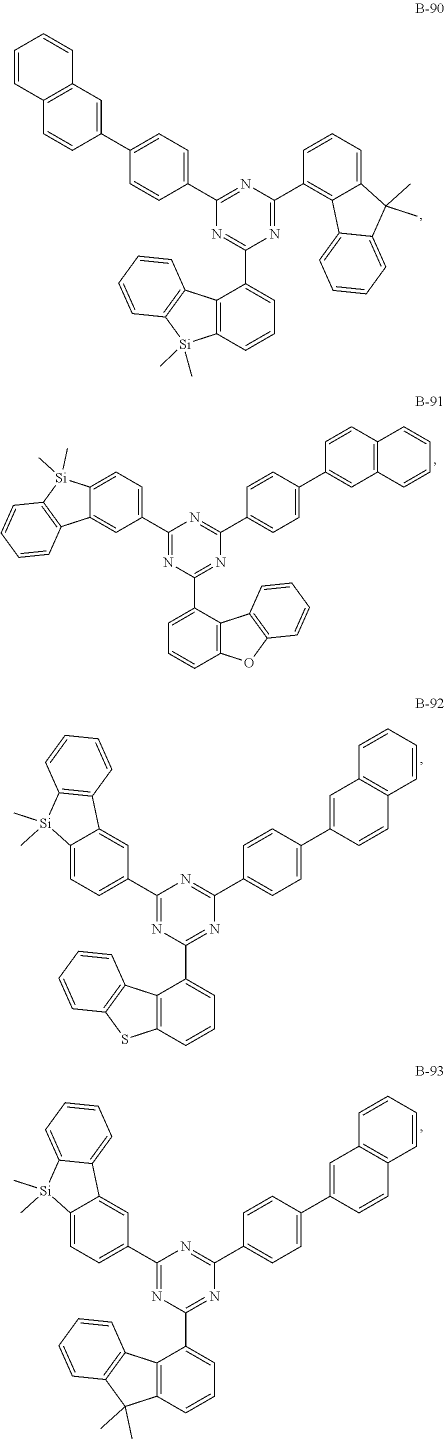 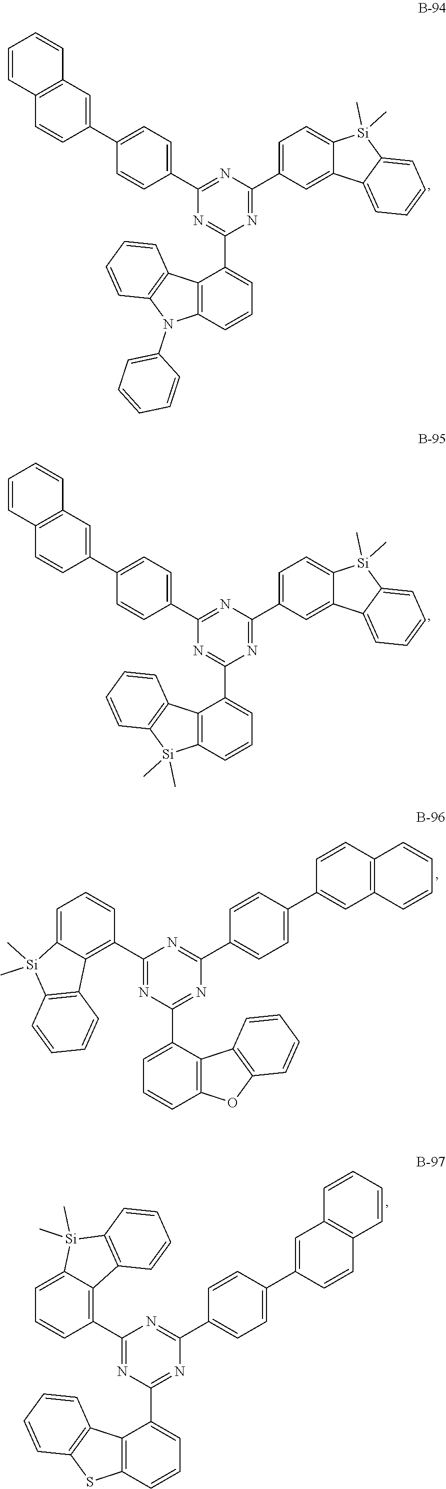 [SMILES: C[Si]1(C)c2ccccc2-c2cc(-c3nc(-c4ccc(-c5ccc6ccccc6c5)cc4)nc(-c4cccc5c4c4ccccc4n5-c4ccccc4)n3)ccc21 ; C[Si]1(C)c2ccccc2-c2cc(-c3nc(-c4ccc(-c5ccc6ccccc6c5)cc4)nc(-c4cccc5c4-c4ccccc4[Si]5(C)C)n3)ccc21 ; C[Si]1(C)c2ccccc2-c2c(-c3nc(-c4ccc(-c5ccc6ccccc6c5)cc4)nc(-c4cccc5oc6ccccc6c45)n3)cccc21 ; C[Si]1(C)c2ccccc2-c2c(-c3nc(-c4ccc(-c5ccc6ccccc6c5)cc4)nc(-c4cccc5sc6ccccc6c45)n3)cccc21] 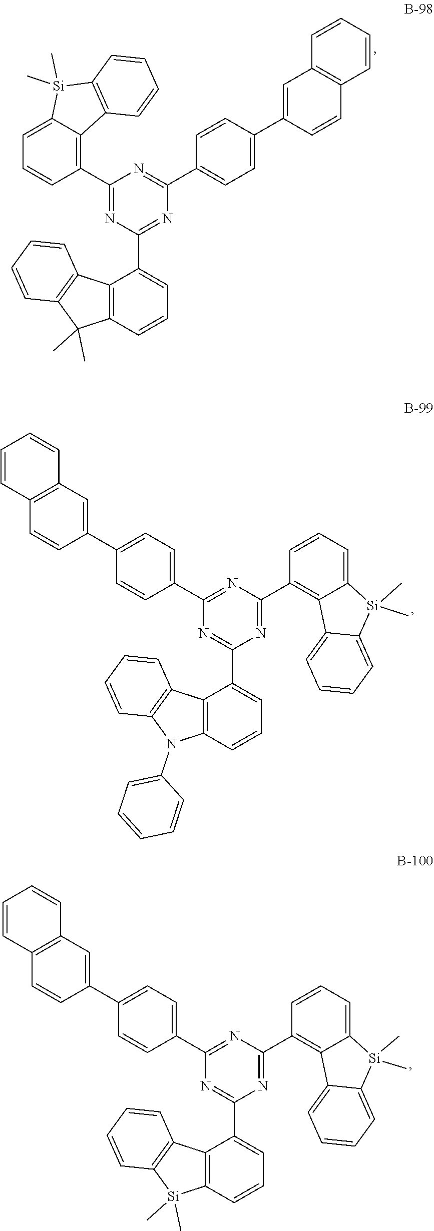 [SMILES: CC1(C)c2ccccc2-c2c(-c3nc(-c4ccc(-c5ccc6ccccc6c5)cc4)nc(-c4cccc5c4-c4ccccc4[Si]5(C)C)n3)cccc21 ; C[Si]1(C)c2ccccc2-c2c(-c3nc(-c4ccc(-c5ccc6ccccc6c5)cc4)nc(-c4cccc5c4c4ccccc4n5-c4ccccc4)n3)cccc21 ; C[Si]1(C)c2ccccc2-c2c(-c3nc(-c4ccc(-c5ccc6ccccc6c5)cc4)nc(-c4cccc5c4-c4ccccc4[Si]5(C)C)n3)cccc21] 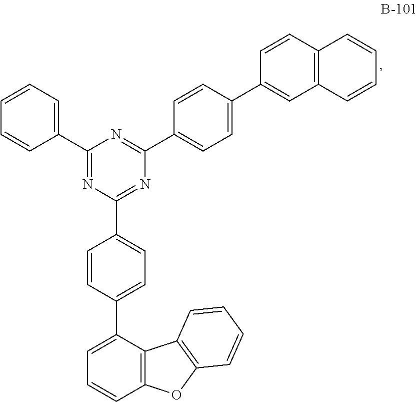 [SMILES: c1ccc(-c2nc(-c3ccc(-c4ccc5ccccc5c4)cc3)nc(-c3ccc(-c4cccc5oc6ccccc6c45)cc3)n2)cc1] 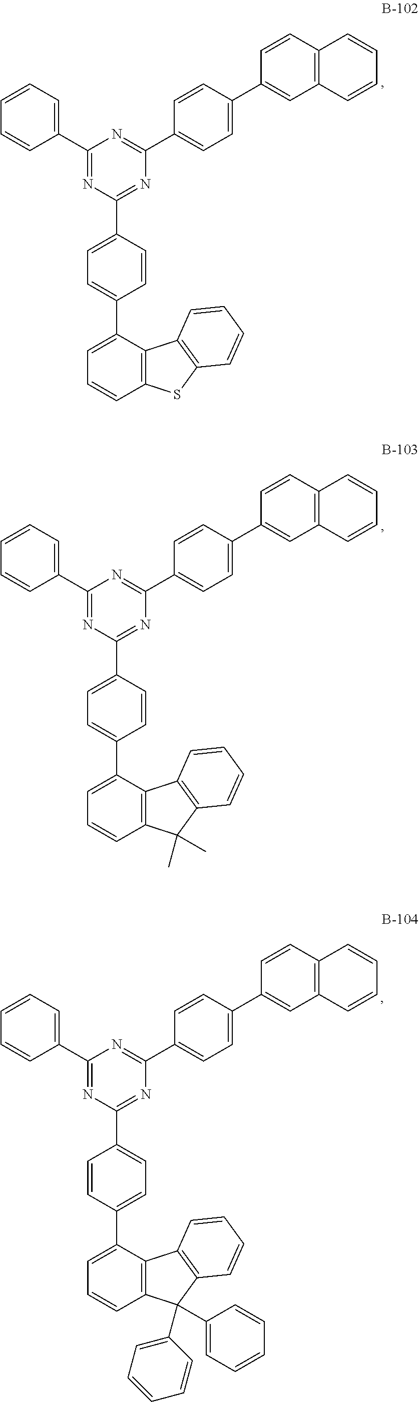 [SMILES: c1ccc(-c2nc(-c3ccc(-c4ccc5ccccc5c4)cc3)nc(-c3ccc(-c4cccc5sc6ccccc6c45)cc3)n2)cc1 ; CC1(C)c2ccccc2-c2c(-c3ccc(-c4nc(-c5ccccc5)nc(-c5ccc(-c6ccc7ccccc7c6)cc5)n4)cc3)cccc21 ; c1ccc(-c2nc(-c3ccc(-c4ccc5ccccc5c4)cc3)nc(-c3ccc(-c4cccc5c4-c4ccccc4C5(c4ccccc4)c4ccccc4)cc3)n2)cc1] 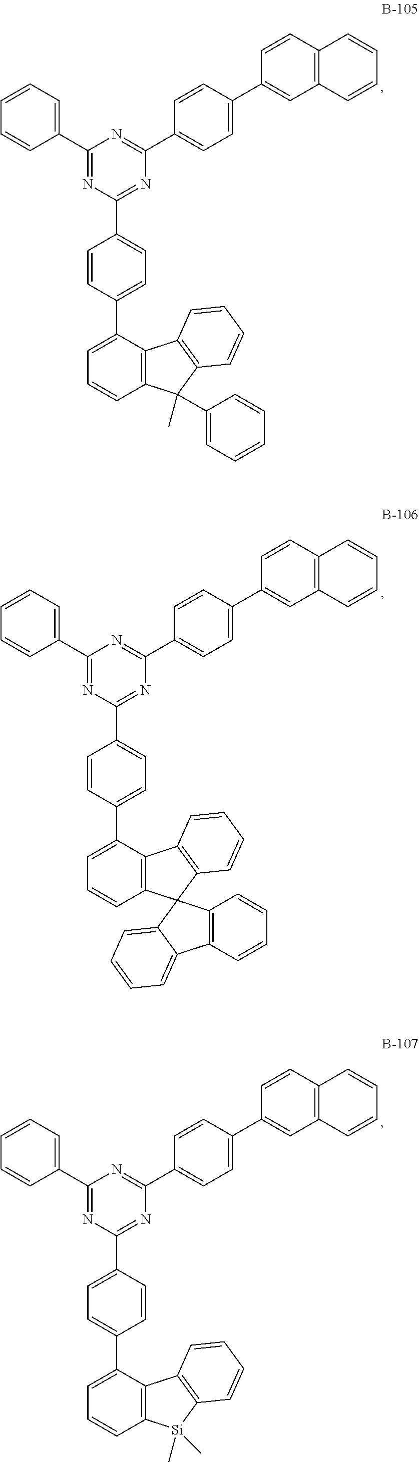 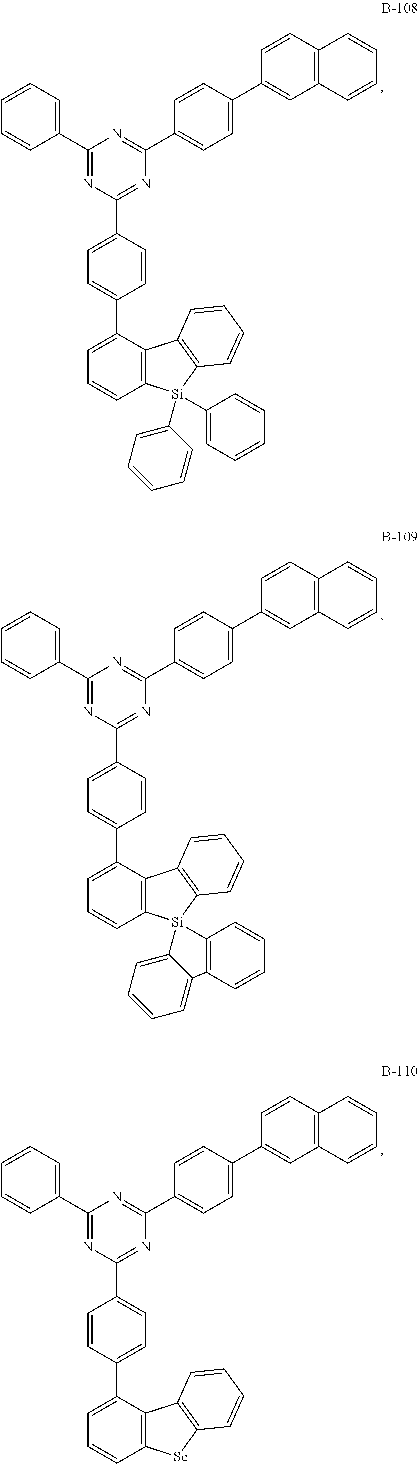 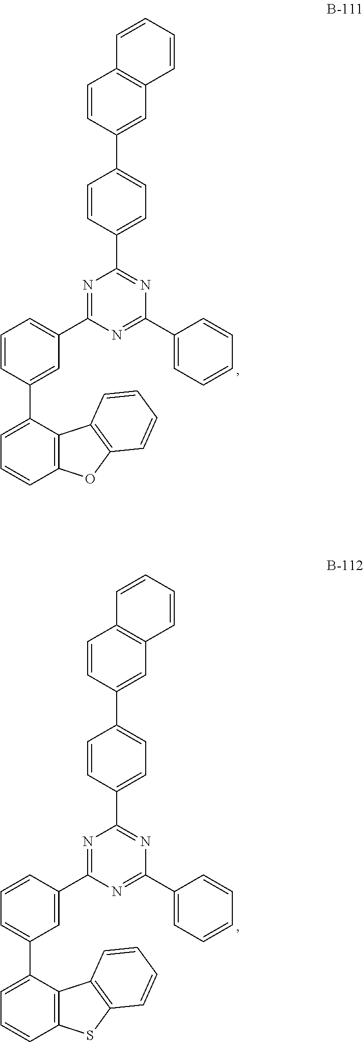 [SMILES: c1ccc(-c2nc(-c3ccc(-c4ccc5ccccc5c4)cc3)nc(-c3cccc(-c4cccc5oc6ccccc6c45)c3)n2)cc1 ; c1ccc(-c2nc(-c3ccc(-c4ccc5ccccc5c4)cc3)nc(-c3cccc(-c4cccc5sc6ccccc6c45)c3)n2)cc1] 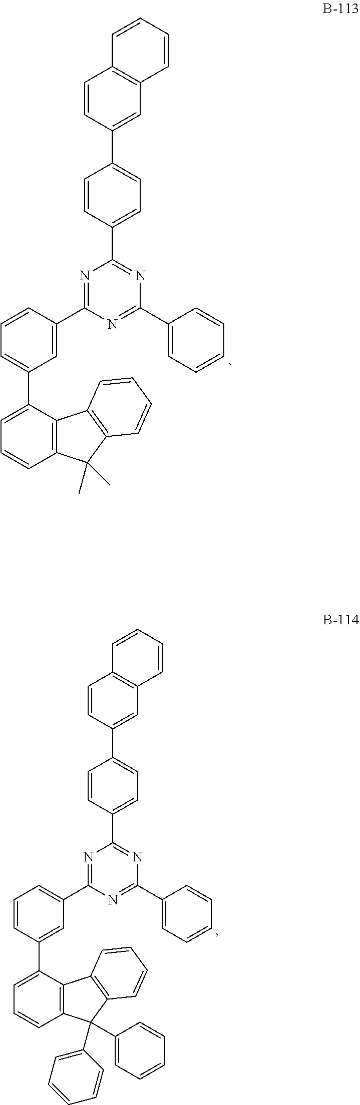 [SMILES: CC1(C)c2ccccc2-c2c(-c3cccc(-c4nc(-c5ccccc5)nc(-c5ccc(-c6ccc7ccccc7c6)cc5)n4)c3)cccc21 ; c1ccc(-c2nc(-c3ccc(-c4ccc5ccccc5c4)cc3)nc(-c3cccc(-c4cccc5c4-c4ccccc4C5(c4ccccc4)c4ccccc4)c3)n2)cc1] 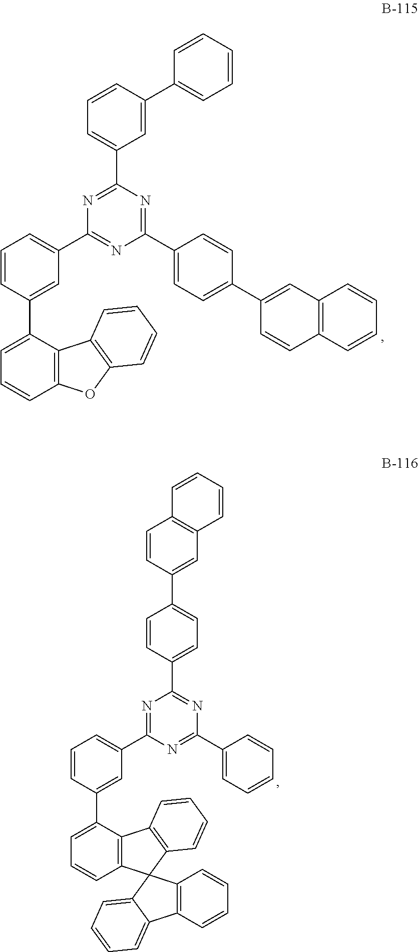 [SMILES: c1ccc(-c2cccc(-c3nc(-c4ccc(-c5ccc6ccccc6c5)cc4)nc(-c4cccc(-c5cccc6oc7ccccc7c56)c4)n3)c2)cc1 ; c1ccc(-c2nc(-c3ccc(-c4ccc5ccccc5c4)cc3)nc(-c3cccc(-c4cccc5c4-c4ccccc4C54c5ccccc5-c5ccccc54)c3)n2)cc1] 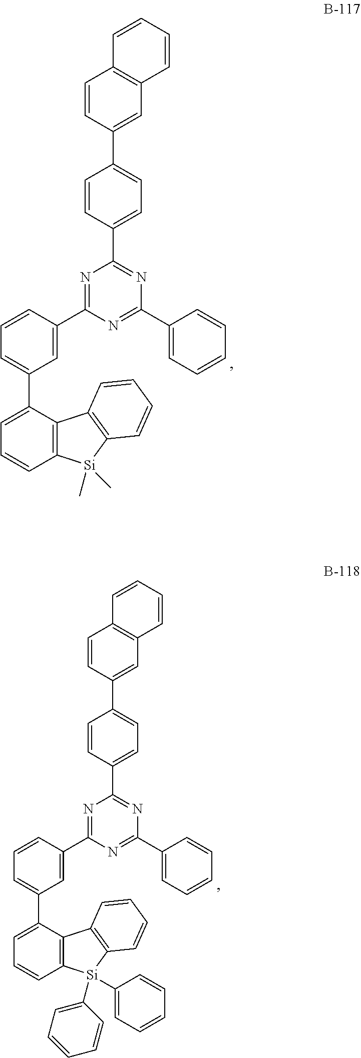 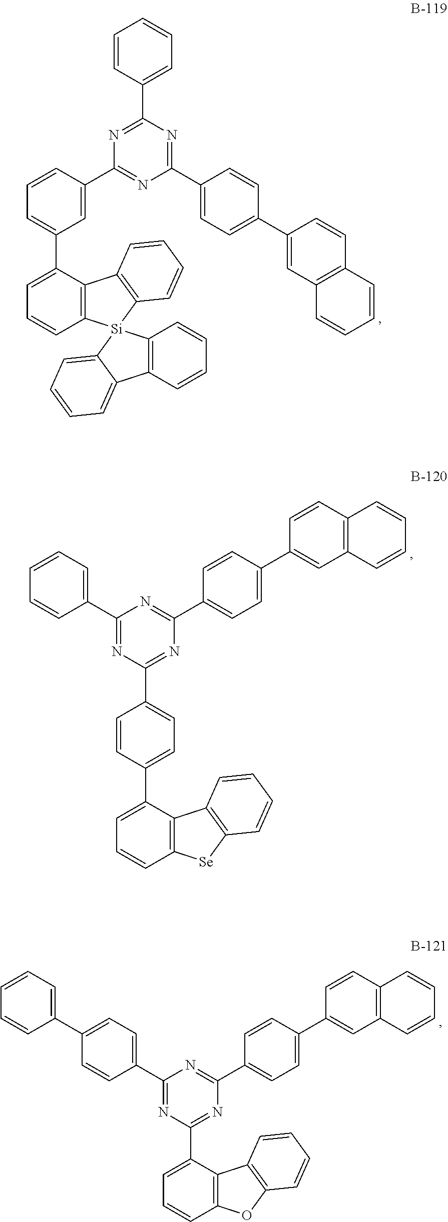 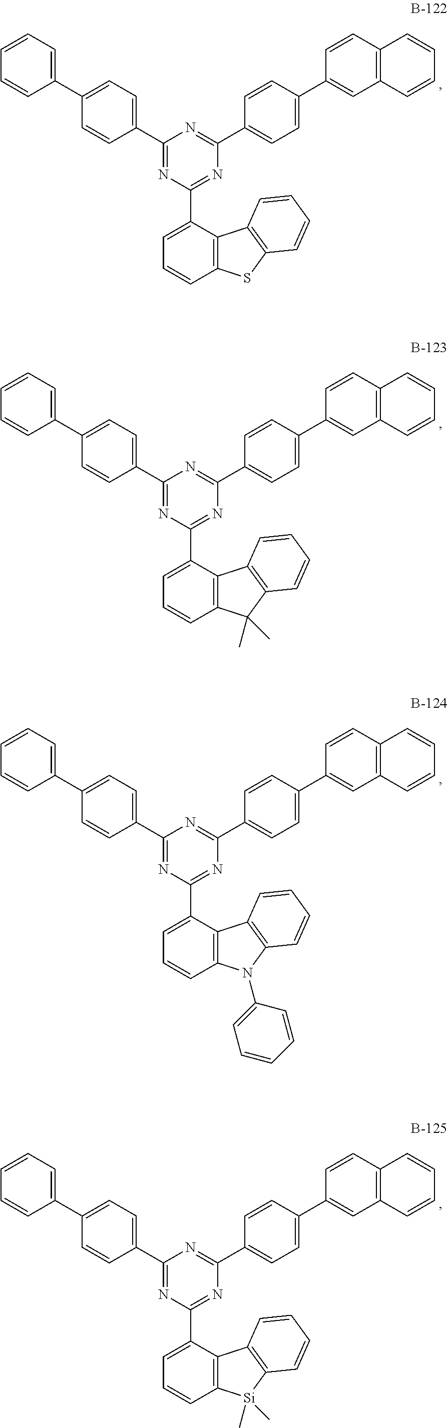 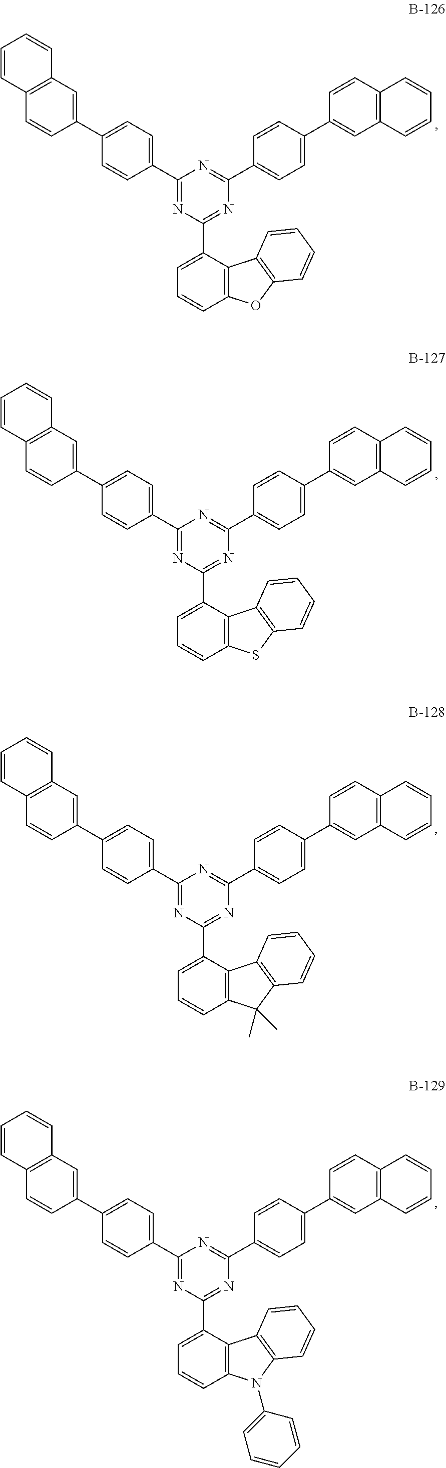 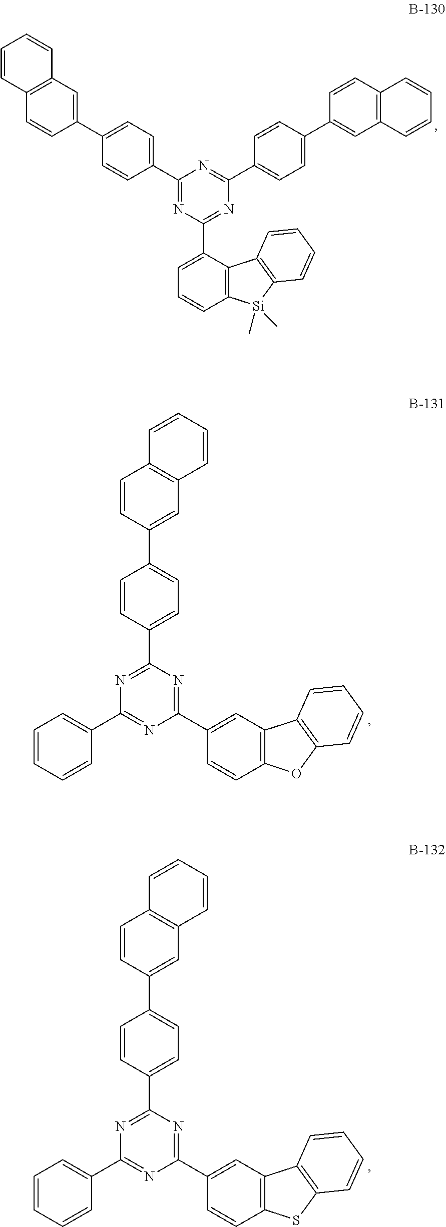 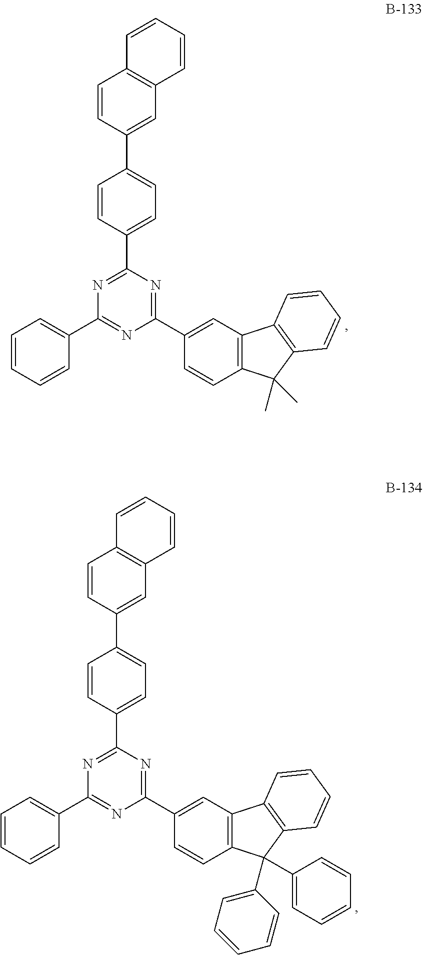 [SMILES: CC1(C)c2ccccc2-c2cc(-c3nc(-c4ccccc4)nc(-c4ccc(-c5ccc6ccccc6c5)cc4)n3)ccc21 ; c1ccc(-c2nc(-c3ccc(-c4ccc5ccccc5c4)cc3)nc(-c3ccc4c(c3)-c3ccccc3C4(c3ccccc3)c3ccccc3)n2)cc1] 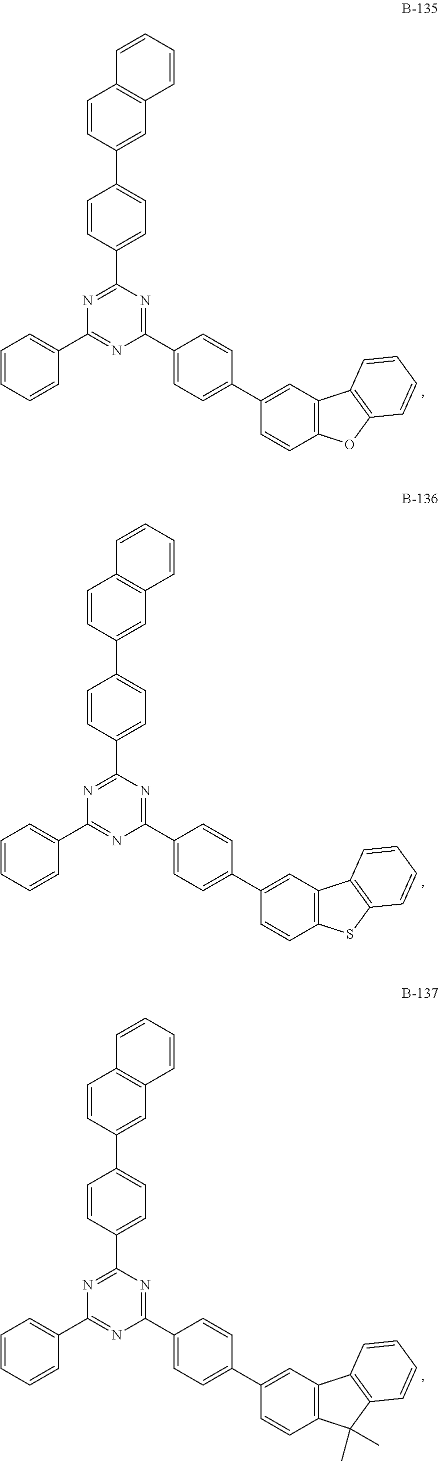 [SMILES: c1ccc(-c2nc(-c3ccc(-c4ccc5ccccc5c4)cc3)nc(-c3ccc(-c4ccc5oc6ccccc6c5c4)cc3)n2)cc1 ; c1ccc(-c2nc(-c3ccc(-c4ccc5ccccc5c4)cc3)nc(-c3ccc(-c4ccc5sc6ccccc6c5c4)cc3)n2)cc1 ; CC1(C)c2ccccc2-c2cc(-c3ccc(-c4nc(-c5ccccc5)nc(-c5ccc(-c6ccc7ccccc7c6)cc5)n4)cc3)ccc21] 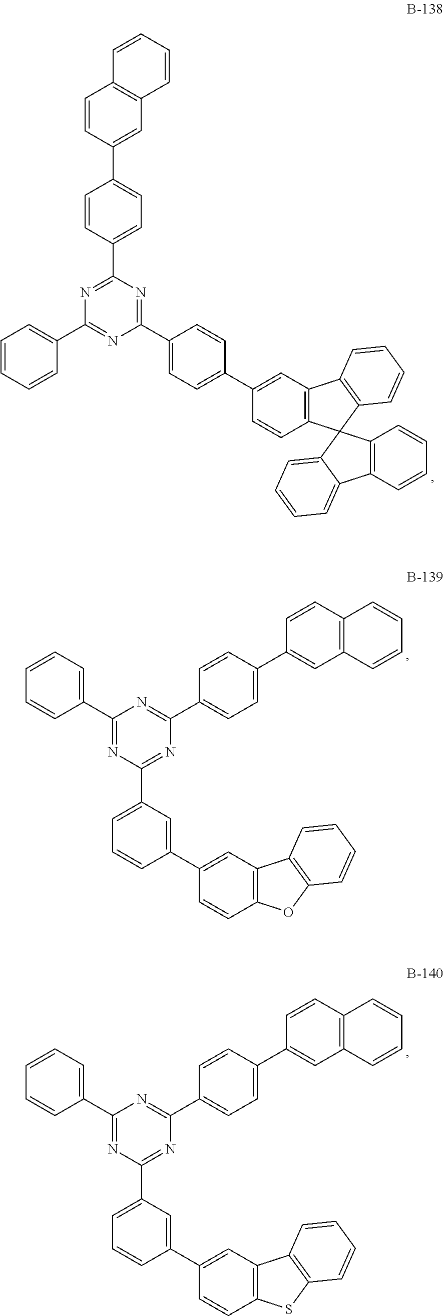 [SMILES: c1ccc(-c2nc(-c3ccc(-c4ccc5c(c4)-c4ccccc4C54c5ccccc5-c5ccccc54)cc3)nc(-c3ccc(-c4ccc5ccccc5c4)cc3)n2)cc1 ; c1ccc(-c2nc(-c3ccc(-c4ccc5ccccc5c4)cc3)nc(-c3cccc(-c4ccc5oc6ccccc6c5c4)c3)n2)cc1 ; c1ccc(-c2nc(-c3ccc(-c4ccc5ccccc5c4)cc3)nc(-c3cccc(-c4ccc5sc6ccccc6c5c4)c3)n2)cc1] 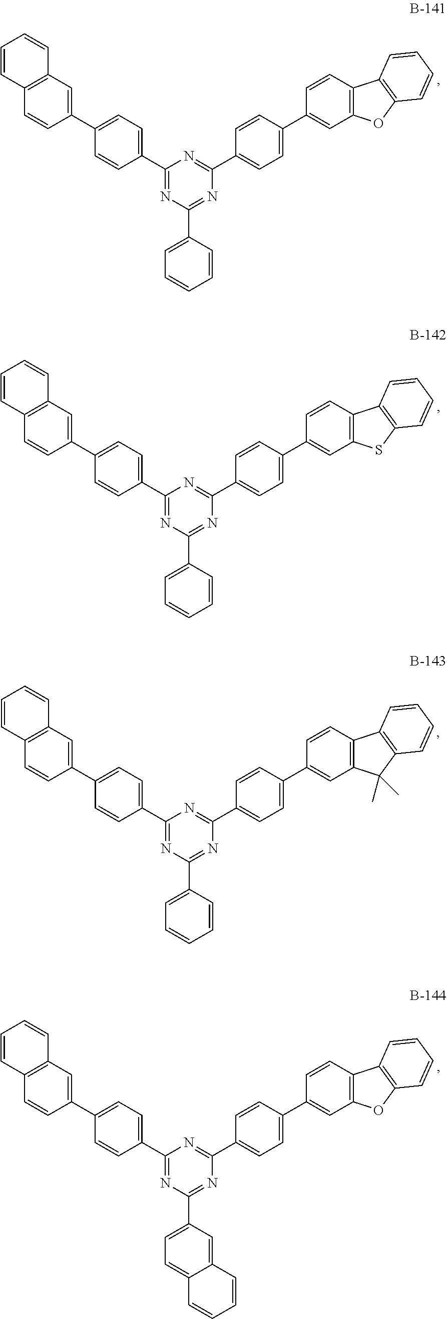 [SMILES: c1ccc(-c2nc(-c3ccc(-c4ccc5ccccc5c4)cc3)nc(-c3ccc(-c4ccc5c(c4)oc4ccccc45)cc3)n2)cc1 ; c1ccc(-c2nc(-c3ccc(-c4ccc5ccccc5c4)cc3)nc(-c3ccc(-c4ccc5c(c4)sc4ccccc45)cc3)n2)cc1 ; CC1(C)c2ccccc2-c2ccc(-c3ccc(-c4nc(-c5ccccc5)nc(-c5ccc(-c6ccc7ccccc7c6)cc5)n4)cc3)cc21 ; c1ccc2cc(-c3ccc(-c4nc(-c5ccc(-c6ccc7c(c6)oc6ccccc67)cc5)nc(-c5ccc6ccccc6c5)n4)cc3)ccc2c1] 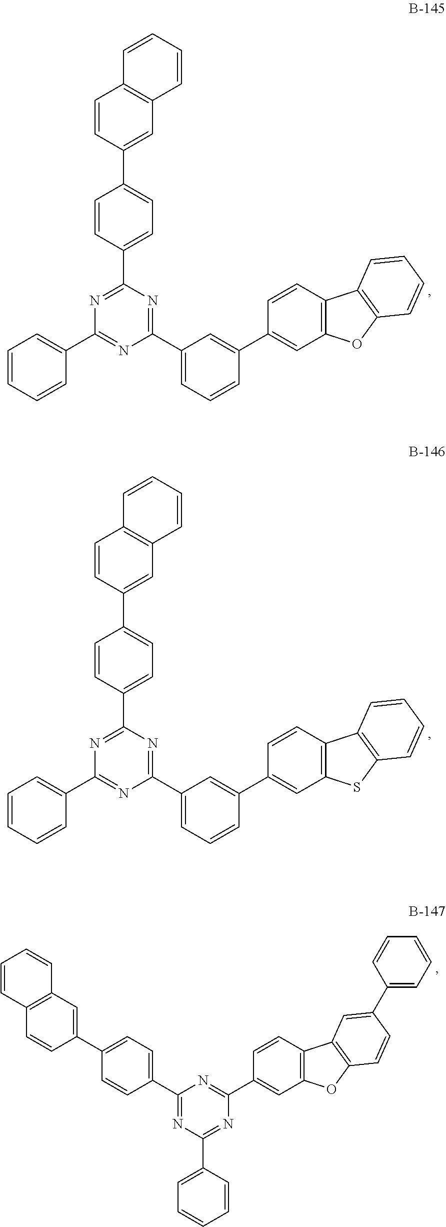 [SMILES: c1ccc(-c2nc(-c3ccc(-c4ccc5ccccc5c4)cc3)nc(-c3cccc(-c4ccc5c(c4)oc4ccccc45)c3)n2)cc1 ; c1ccc(-c2nc(-c3ccc(-c4ccc5ccccc5c4)cc3)nc(-c3cccc(-c4ccc5c(c4)sc4ccccc45)c3)n2)cc1 ; c1ccc(-c2ccc3oc4cc(-c5nc(-c6ccccc6)nc(-c6ccc(-c7ccc8ccccc8c7)cc6)n5)ccc4c3c2)cc1] 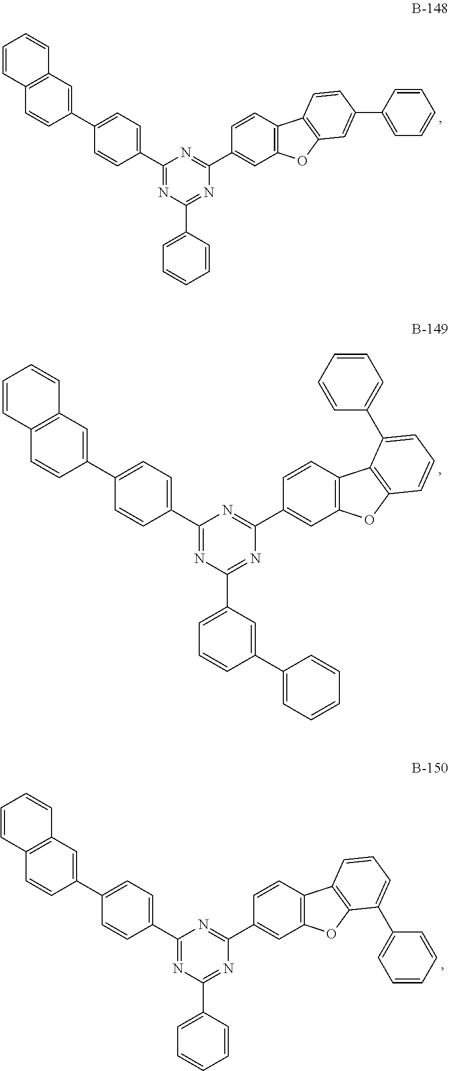 [SMILES: c1ccc(-c2ccc3c(c2)oc2cc(-c4nc(-c5ccccc5)nc(-c5ccc(-c6ccc7ccccc7c6)cc5)n4)ccc23)cc1 ; c1ccc(-c2cccc(-c3nc(-c4ccc(-c5ccc6ccccc6c5)cc4)nc(-c4ccc5c(c4)oc4cccc(-c6ccccc6)c45)n3)c2)cc1 ; c1ccc(-c2nc(-c3ccc(-c4ccc5ccccc5c4)cc3)nc(-c3ccc4c(c3)oc3c(-c5ccccc5)cccc34)n2)cc1] 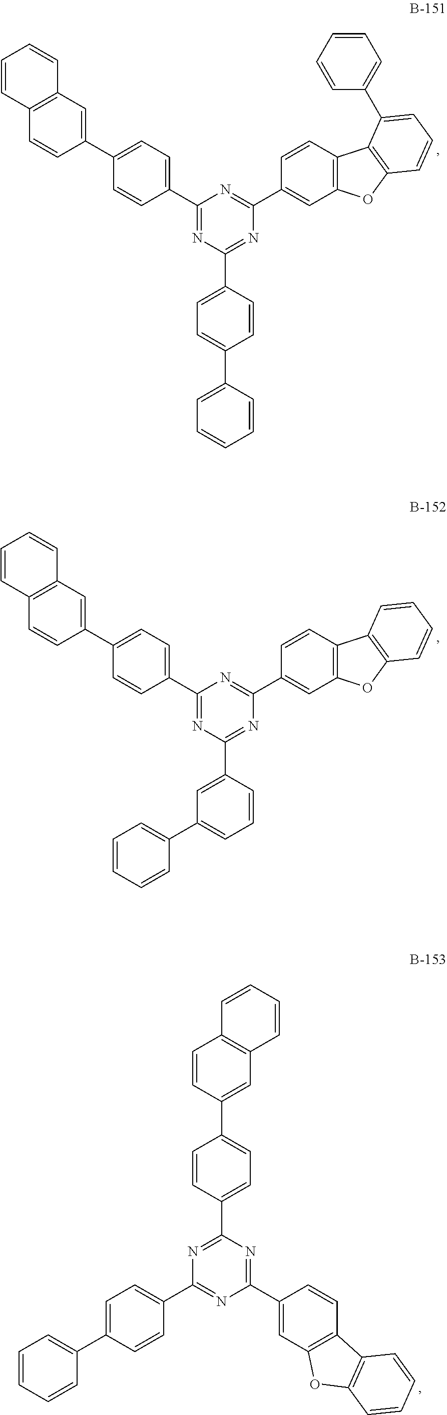 [SMILES: c1ccc(-c2ccc(-c3nc(-c4ccc(-c5ccc6ccccc6c5)cc4)nc(-c4ccc5c(c4)oc4cccc(-c6ccccc6)c45)n3)cc2)cc1 ; c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2ccc(-c3nc(-c4ccc(-c5ccc6ccccc6c5)cc4)nc(-c4ccc5c(c4)oc4ccccc45)n3)cc2)cc1] 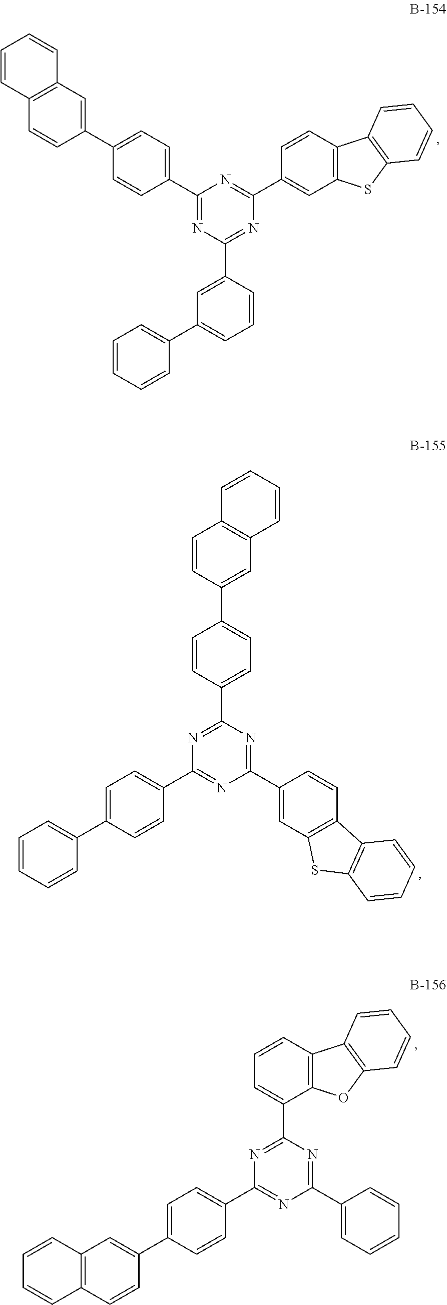 [SMILES: c1ccc(-c2cccc(-c3nc(-c4ccc(-c5ccc6ccccc6c5)cc4)nc(-c4ccc5c(c4)sc4ccccc45)n3)c2)cc1 ; c1ccc(-c2ccc(-c3nc(-c4ccc(-c5ccc6ccccc6c5)cc4)nc(-c4ccc5c(c4)sc4ccccc45)n3)cc2)cc1 ; c1ccc(-c2nc(-c3ccc(-c4ccc5ccccc5c4)cc3)nc(-c3cccc4c3oc3ccccc34)n2)cc1] 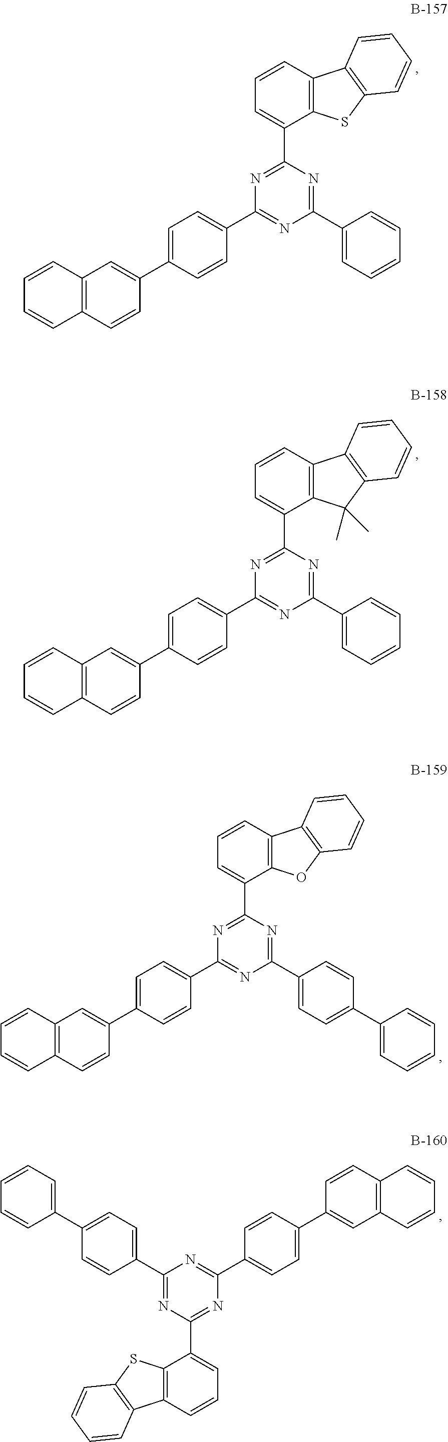 [SMILES: c1ccc(-c2nc(-c3ccc(-c4ccc5ccccc5c4)cc3)nc(-c3cccc4c3sc3ccccc34)n2)cc1 ; CC1(C)c2ccccc2-c2cccc(-c3nc(-c4ccccc4)nc(-c4ccc(-c5ccc6ccccc6c5)cc4)n3)c21 ; c1ccc(-c2ccc(-c3nc(-c4ccc(-c5ccc6ccccc6c5)cc4)nc(-c4cccc5c4oc4ccccc45)n3)cc2)cc1 ; c1ccc(-c2ccc(-c3nc(-c4ccc(-c5ccc6ccccc6c5)cc4)nc(-c4cccc5c4sc4ccccc45)n3)cc2)cc1] 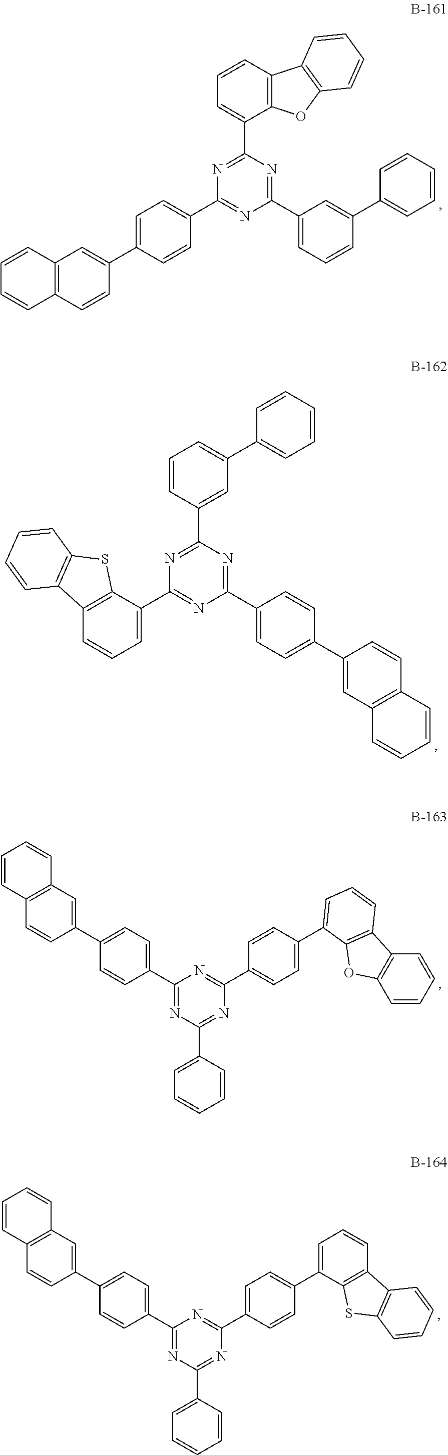 [SMILES: c1ccc(-c2cccc(-c3nc(-c4ccc(-c5ccc6ccccc6c5)cc4)nc(-c4cccc5c4oc4ccccc45)n3)c2)cc1 ; c1ccc(-c2cccc(-c3nc(-c4ccc(-c5ccc6ccccc6c5)cc4)nc(-c4cccc5c4sc4ccccc45)n3)c2)cc1 ; c1ccc(-c2nc(-c3ccc(-c4ccc5ccccc5c4)cc3)nc(-c3ccc(-c4cccc5c4oc4ccccc45)cc3)n2)cc1 ; c1ccc(-c2nc(-c3ccc(-c4ccc5ccccc5c4)cc3)nc(-c3ccc(-c4cccc5c4sc4ccccc45)cc3)n2)cc1] 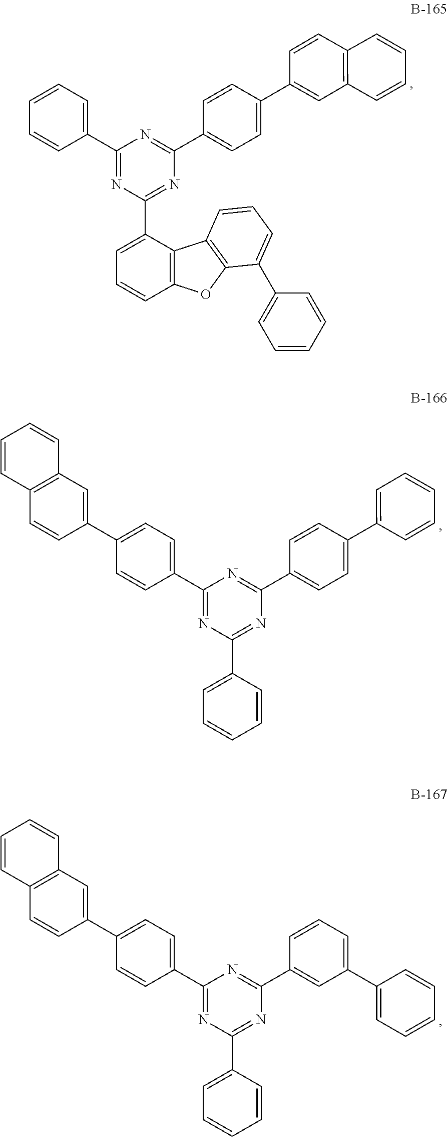 [SMILES: c1ccc(-c2nc(-c3ccc(-c4ccc5ccccc5c4)cc3)nc(-c3cccc4oc5c(-c6ccccc6)cccc5c34)n2)cc1 ; c1ccc(-c2ccc(-c3nc(-c4ccccc4)nc(-c4ccc(-c5ccc6ccccc6c5)cc4)n3)cc2)cc1 ; c1ccc(-c2cccc(-c3nc(-c4ccccc4)nc(-c4ccc(-c5ccc6ccccc6c5)cc4)n3)c2)cc1] 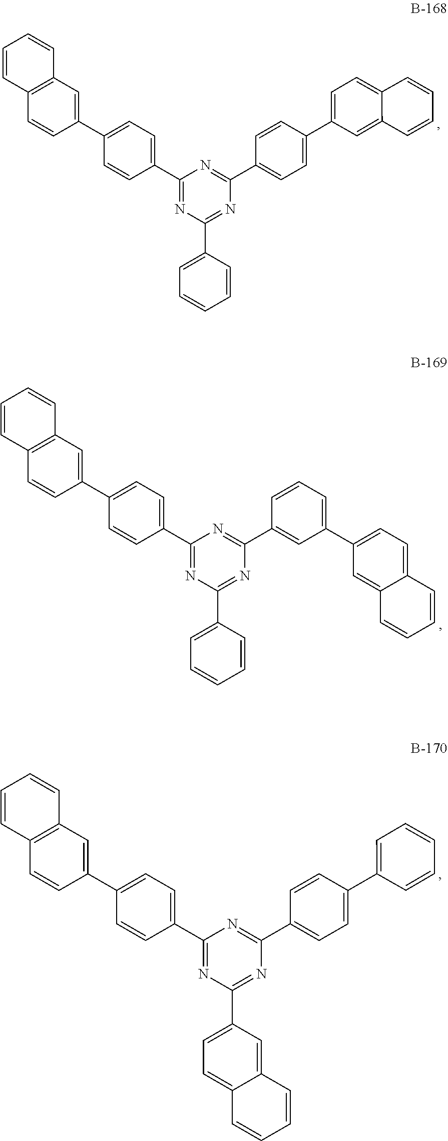 [SMILES: c1ccc(-c2nc(-c3ccc(-c4ccc5ccccc5c4)cc3)nc(-c3ccc(-c4ccc5ccccc5c4)cc3)n2)cc1 ; c1ccc(-c2nc(-c3ccc(-c4ccc5ccccc5c4)cc3)nc(-c3cccc(-c4ccc5ccccc5c4)c3)n2)cc1 ; c1ccc(-c2ccc(-c3nc(-c4ccc(-c5ccc6ccccc6c5)cc4)nc(-c4ccc5ccccc5c4)n3)cc2)cc1] 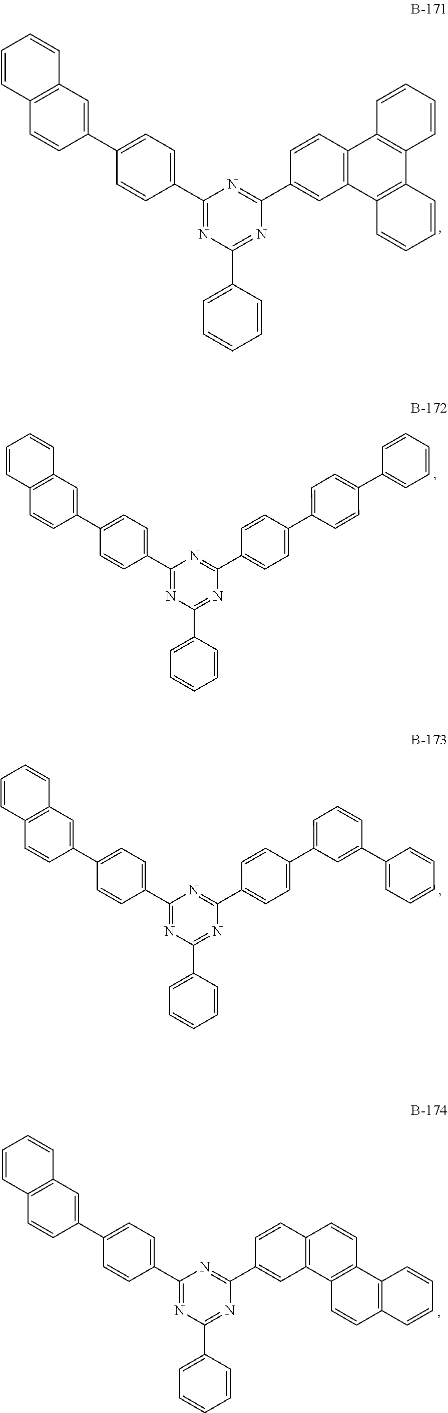 [SMILES: c1ccc(-c2nc(-c3ccc(-c4ccc5ccccc5c4)cc3)nc(-c3ccc4c5ccccc5c5ccccc5c4c3)n2)cc1 ; c1ccc(-c2ccc(-c3ccc(-c4nc(-c5ccccc5)nc(-c5ccc(-c6ccc7ccccc7c6)cc5)n4)cc3)cc2)cc1 ; c1ccc(-c2cccc(-c3ccc(-c4nc(-c5ccccc5)nc(-c5ccc(-c6ccc7ccccc7c6)cc5)n4)cc3)c2)cc1 ; c1ccc(-c2nc(-c3ccc(-c4ccc5ccccc5c4)cc3)nc(-c3ccc4ccc5c6ccccc6ccc5c4c3)n2)cc1] 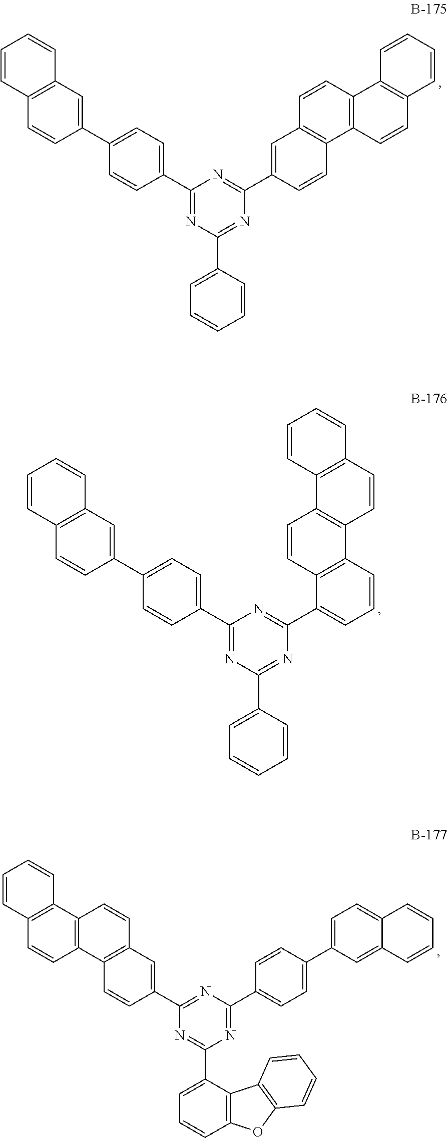 [SMILES: c1ccc(-c2nc(-c3ccc(-c4ccc5ccccc5c4)cc3)nc(-c3ccc4c(ccc5c6ccccc6ccc45)c3)n2)cc1 ; c1ccc(-c2nc(-c3ccc(-c4ccc5ccccc5c4)cc3)nc(-c3cccc4c3ccc3c5ccccc5ccc43)n2)cc1 ; c1ccc2cc(-c3ccc(-c4nc(-c5ccc6c(ccc7c8ccccc8ccc67)c5)nc(-c5cccc6oc7ccccc7c56)n4)cc3)ccc2c1] 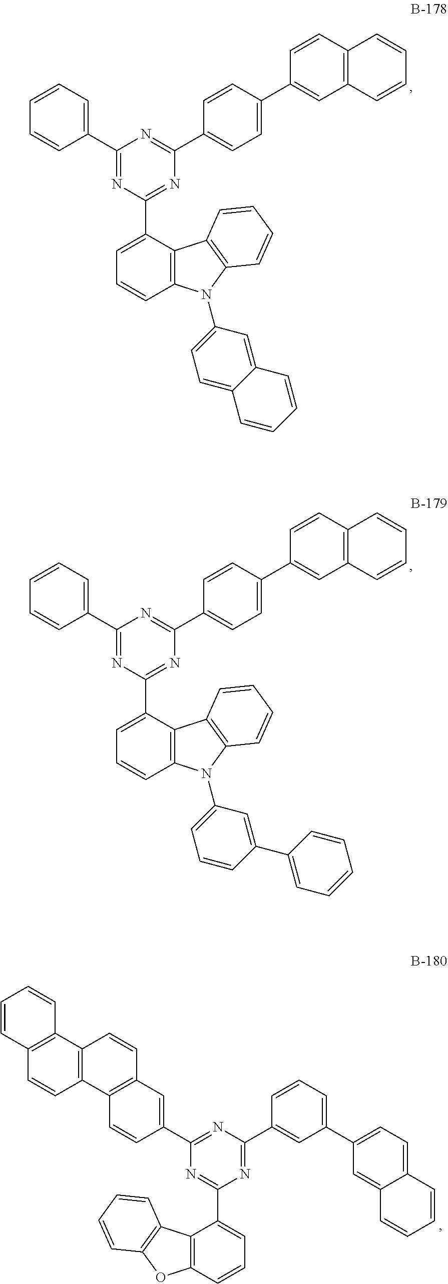 [SMILES: c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2cccc(-n3c4ccccc4c4c(-c5nc(-c6ccccc6)nc(-c6ccc(-c7ccc8ccccc8c7)cc6)n5)cccc43)c2)cc1 ; c1cc(-c2ccc3ccccc3c2)cc(-c2nc(-c3ccc4c(ccc5c6ccccc6ccc45)c3)nc(-c3cccc4oc5ccccc5c34)n2)c1] 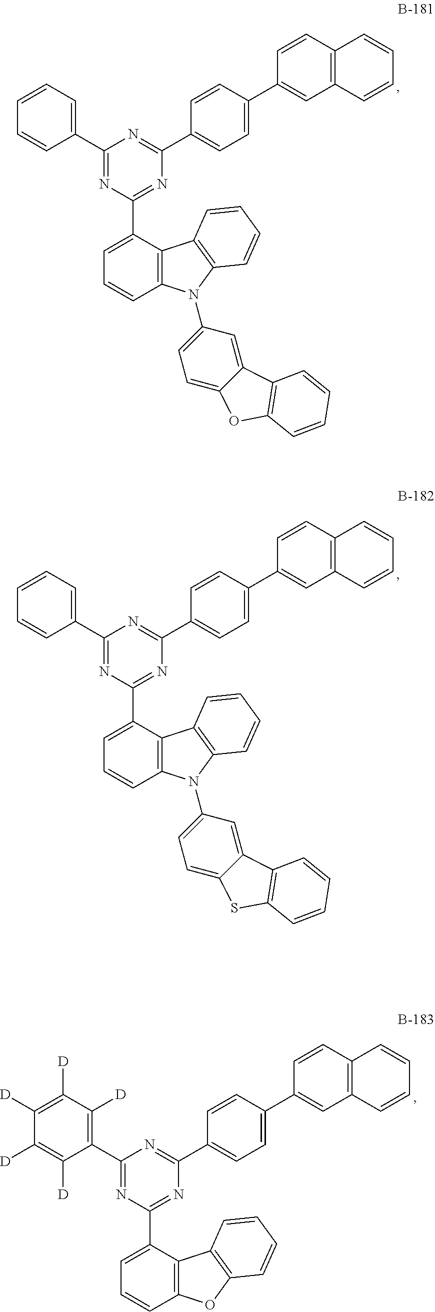 [SMILES: c1ccc(-c2nc(-c3ccc(-c4ccc5ccccc5c4)cc3)nc(-c3cccc4c3c3ccccc3n4-c3ccc4oc5ccccc5c4c3)n2)cc1 ; c1ccc(-c2nc(-c3ccc(-c4ccc5ccccc5c4)cc3)nc(-c3cccc4c3c3ccccc3n4-c3ccc4sc5ccccc5c4c3)n2)cc1 ; [2H]c1c([2H])c([2H])c(-c2nc(-c3ccc(-c4ccc5ccccc5c4)cc3)nc(-c3cccc4oc5ccccc5c34)n2)c([2H])c1[2H]] 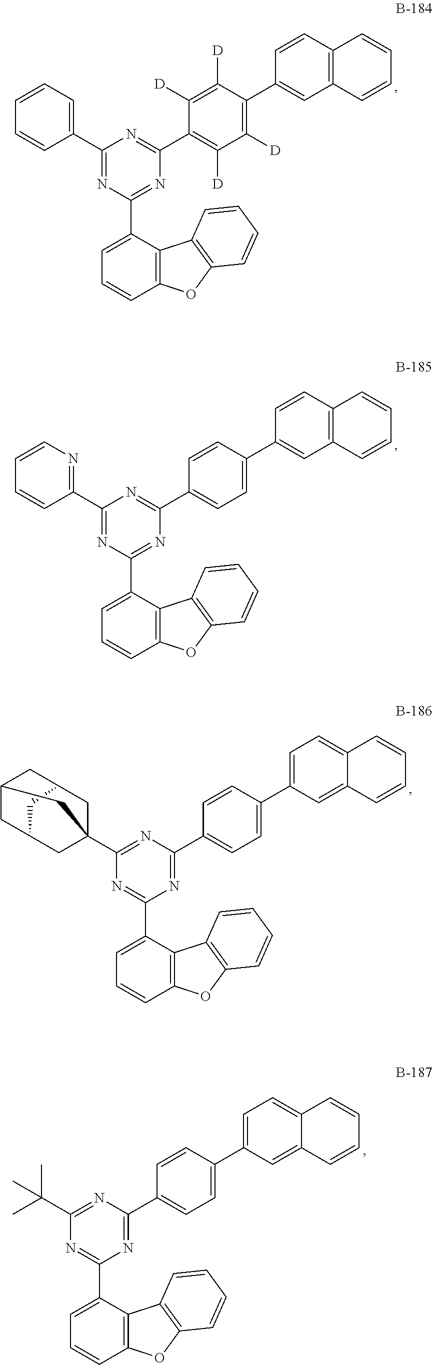 [SMILES: [2H]c1c([2H])c(-c2nc(-c3ccccc3)nc(-c3cccc4oc5ccccc5c34)n2)c([2H])c([2H])c1-c1ccc2ccccc2c1 ; c1ccc(-c2nc(-c3ccc(-c4ccc5ccccc5c4)cc3)nc(-c3cccc4oc5ccccc5c34)n2)nc1 ; c1ccc2cc(-c3ccc(-c4nc(-c5cccc6oc7ccccc7c56)nc([C@]56CC7C[C@H](C[C@H](C7)C5)C6)n4)cc3)ccc2c1 ; CC(C)(C)c1nc(-c2ccc(-c3ccc4ccccc4c3)cc2)nc(-c2cccc3oc4ccccc4c23)n1] 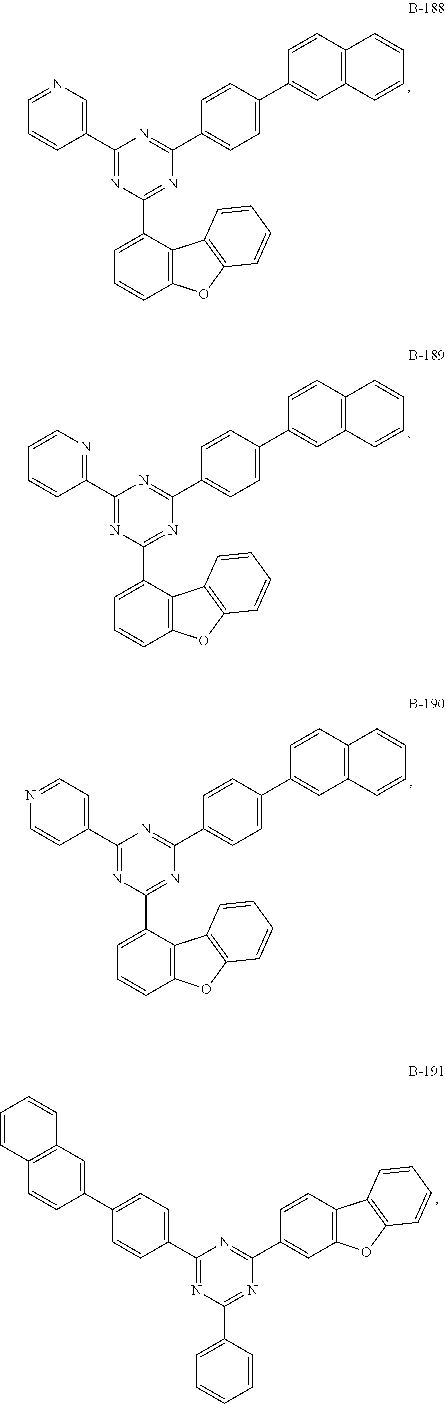 [SMILES: c1cncc(-c2nc(-c3ccc(-c4ccc5ccccc5c4)cc3)nc(-c3cccc4oc5ccccc5c34)n2)c1 ; c1ccc(-c2nc(-c3ccc(-c4ccc5ccccc5c4)cc3)nc(-c3cccc4oc5ccccc5c34)n2)nc1 ; c1ccc2cc(-c3ccc(-c4nc(-c5ccncc5)nc(-c5cccc6oc7ccccc7c56)n4)cc3)ccc2c1 ; c1ccc(-c2nc(-c3ccc(-c4ccc5ccccc5c4)cc3)nc(-c3ccc4c(c3)oc3ccccc34)n2)cc1] 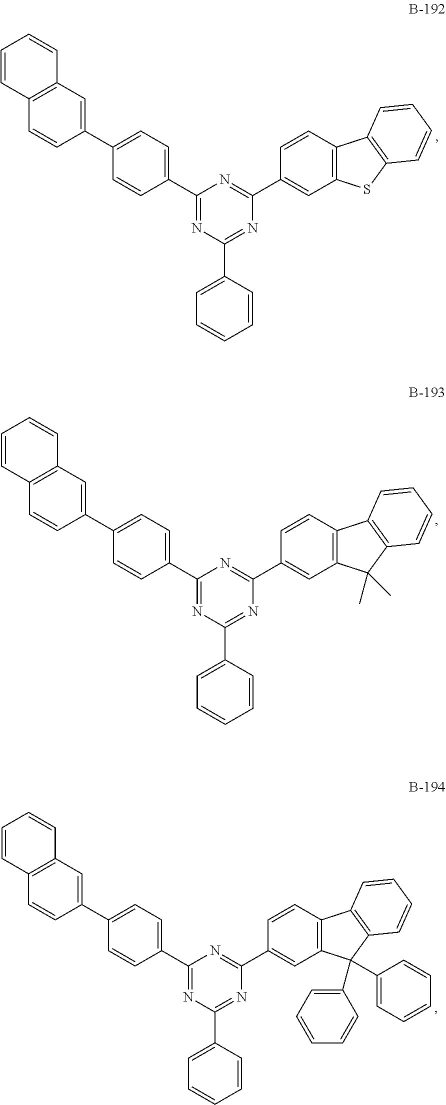 [SMILES: c1ccc(-c2nc(-c3ccc(-c4ccc5ccccc5c4)cc3)nc(-c3ccc4c(c3)sc3ccccc34)n2)cc1 ; CC1(C)c2ccccc2-c2ccc(-c3nc(-c4ccccc4)nc(-c4ccc(-c5ccc6ccccc6c5)cc4)n3)cc21 ; c1ccc(-c2nc(-c3ccc(-c4ccc5ccccc5c4)cc3)nc(-c3ccc4c(c3)C(c3ccccc3)(c3ccccc3)c3ccccc3-4)n2)cc1] 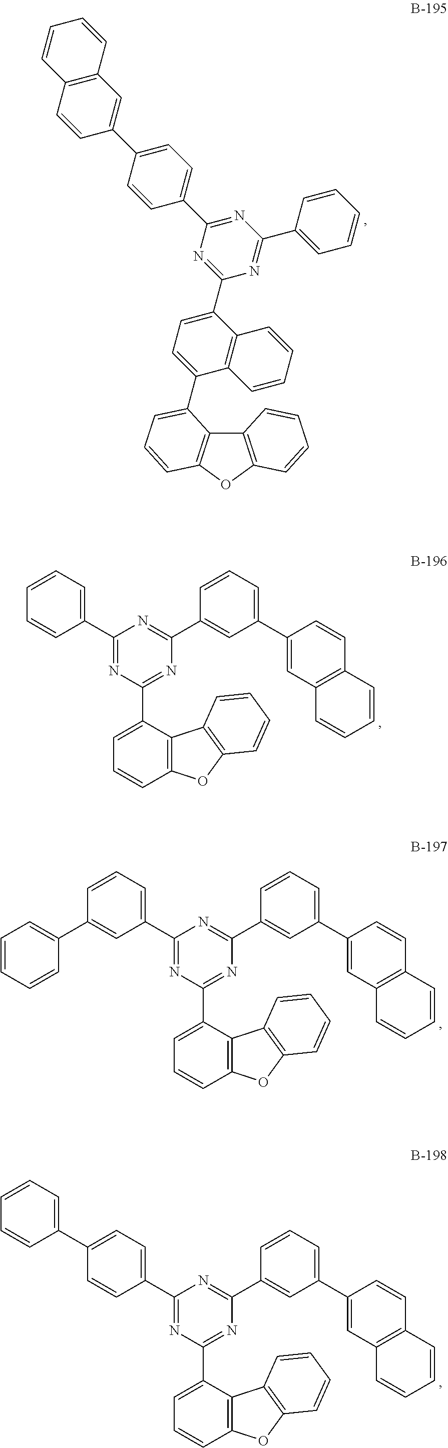 [SMILES: c1ccc(-c2nc(-c3ccc(-c4ccc5ccccc5c4)cc3)nc(-c3ccc(-c4cccc5oc6ccccc6c45)c4ccccc34)n2)cc1 ; c1ccc(-c2nc(-c3cccc(-c4ccc5ccccc5c4)c3)nc(-c3cccc4oc5ccccc5c34)n2)cc1 ; c1ccc(-c2cccc(-c3nc(-c4cccc(-c5ccc6ccccc6c5)c4)nc(-c4cccc5oc6ccccc6c45)n3)c2)cc1 ; c1ccc(-c2ccc(-c3nc(-c4cccc(-c5ccc6ccccc6c5)c4)nc(-c4cccc5oc6ccccc6c45)n3)cc2)cc1] 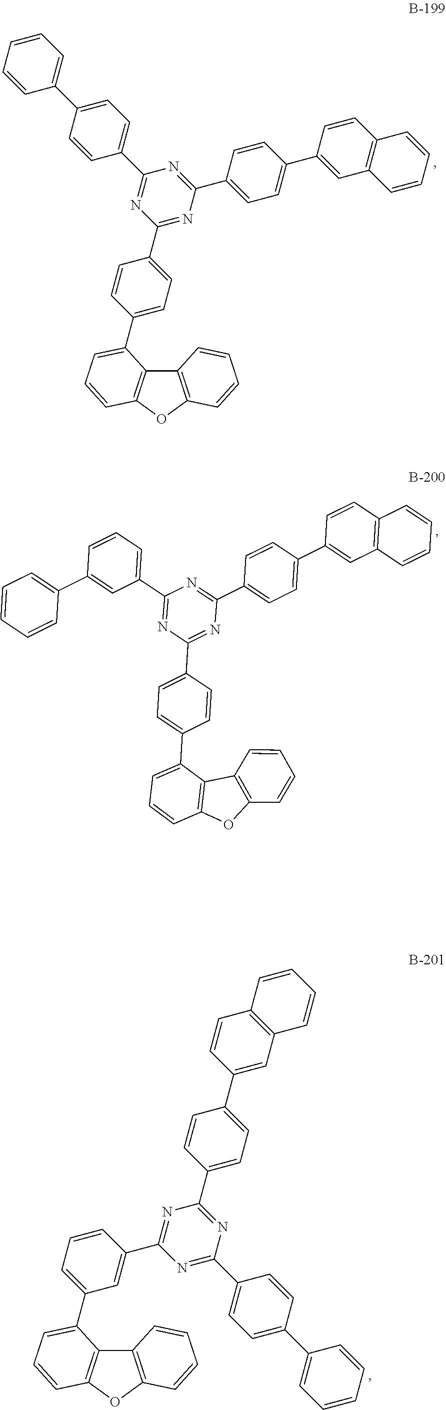 [SMILES: c1ccc(-c2ccc(-c3nc(-c4ccc(-c5ccc6ccccc6c5)cc4)nc(-c4ccc(-c5cccc6oc7ccccc7c56)cc4)n3)cc2)cc1 ; c1ccc(-c2cccc(-c3nc(-c4ccc(-c5ccc6ccccc6c5)cc4)nc(-c4ccc(-c5cccc6oc7ccccc7c56)cc4)n3)c2)cc1 ; c1ccc(-c2ccc(-c3nc(-c4ccc(-c5ccc6ccccc6c5)cc4)nc(-c4cccc(-c5cccc6oc7ccccc7c56)c4)n3)cc2)cc1] 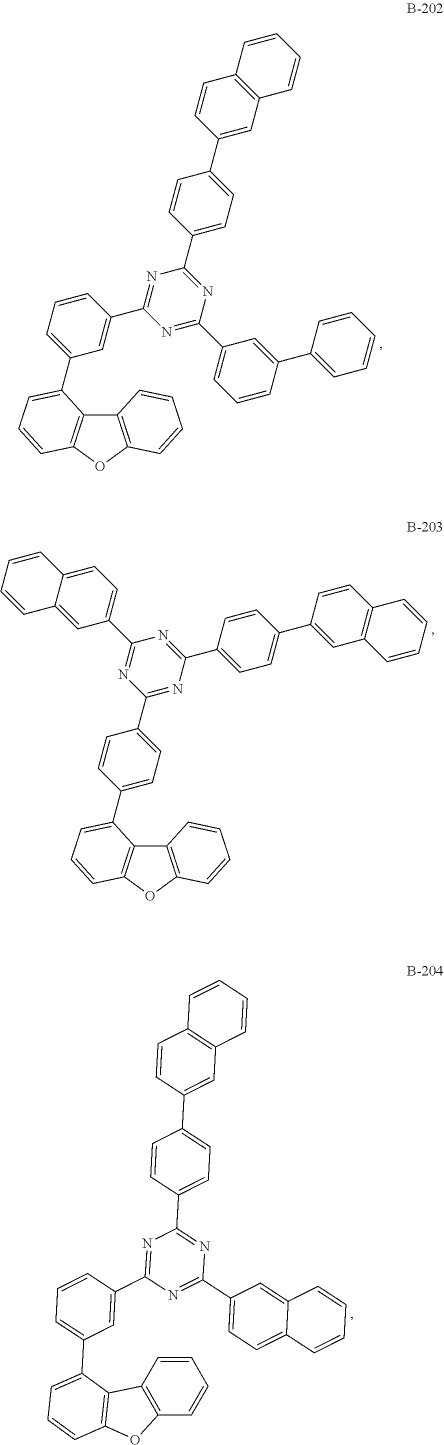 [SMILES: c1ccc(-c2cccc(-c3nc(-c4ccc(-c5ccc6ccccc6c5)cc4)nc(-c4cccc(-c5cccc6oc7ccccc7c56)c4)n3)c2)cc1 ; c1ccc2cc(-c3ccc(-c4nc(-c5ccc(-c6cccc7oc8ccccc8c67)cc5)nc(-c5ccc6ccccc6c5)n4)cc3)ccc2c1 ; c1cc(-c2nc(-c3ccc(-c4ccc5ccccc5c4)cc3)nc(-c3ccc4ccccc4c3)n2)cc(-c2cccc3oc4ccccc4c23)c1] 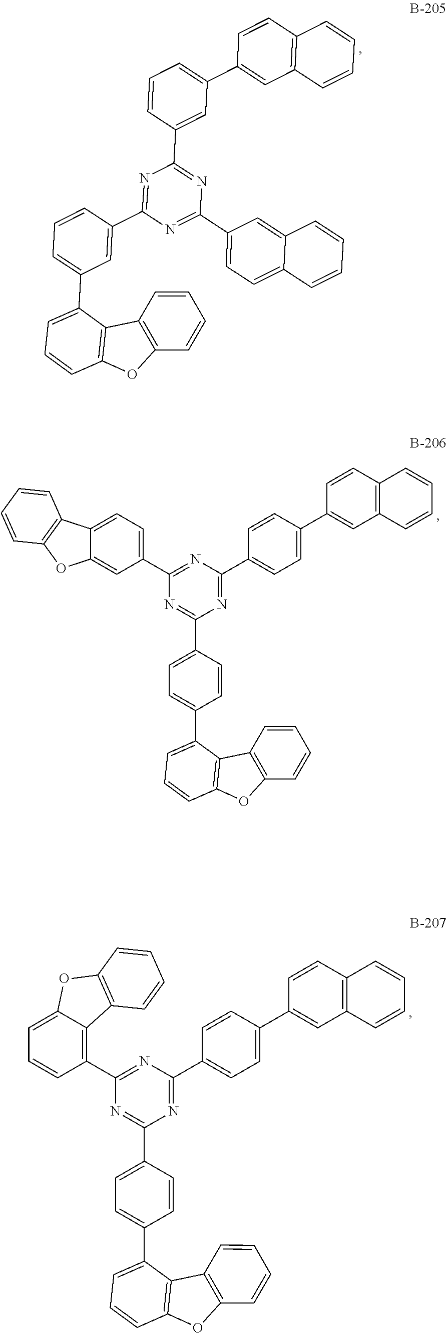 [SMILES: c1cc(-c2ccc3ccccc3c2)cc(-c2nc(-c3cccc(-c4cccc5oc6ccccc6c45)c3)nc(-c3ccc4ccccc4c3)n2)c1 ; c1ccc2cc(-c3ccc(-c4nc(-c5ccc(-c6cccc7oc8ccccc8c67)cc5)nc(-c5ccc6c(c5)oc5ccccc56)n4)cc3)ccc2c1 ; c1ccc2cc(-c3ccc(-c4nc(-c5ccc(-c6cccc7oc8ccccc8c67)cc5)nc(-c5cccc6oc7ccccc7c56)n4)cc3)ccc2c1] 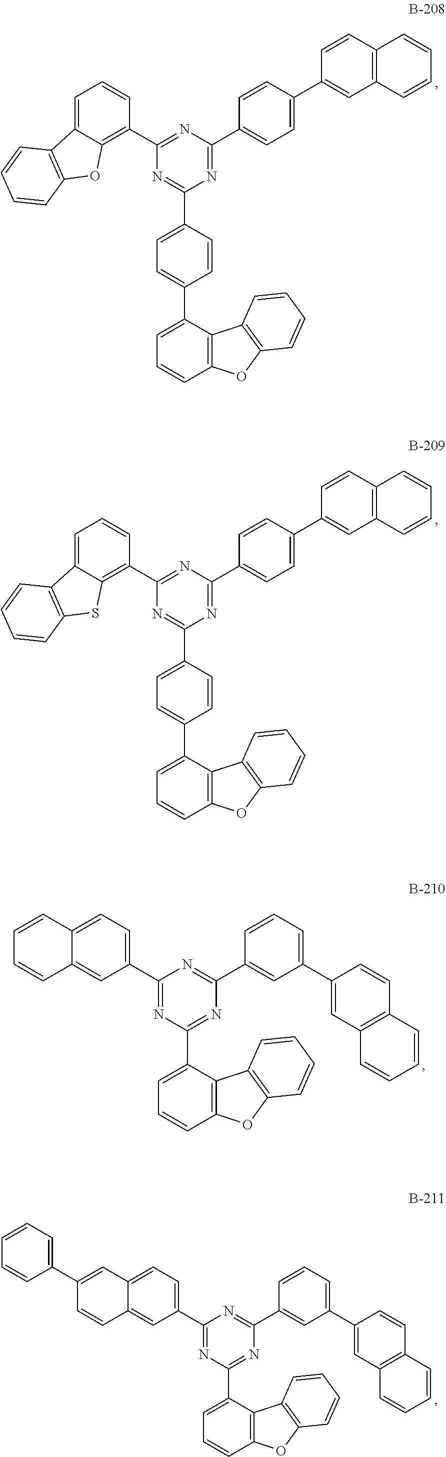 [SMILES: c1ccc2cc(-c3ccc(-c4nc(-c5ccc(-c6cccc7oc8ccccc8c67)cc5)nc(-c5cccc6c5oc5ccccc56)n4)cc3)ccc2c1 ; c1ccc2cc(-c3ccc(-c4nc(-c5ccc(-c6cccc7oc8ccccc8c67)cc5)nc(-c5cccc6c5sc5ccccc56)n4)cc3)ccc2c1 ; c1cc(-c2ccc3ccccc3c2)cc(-c2nc(-c3ccc4ccccc4c3)nc(-c3cccc4oc5ccccc5c34)n2)c1 ; c1ccc(-c2ccc3cc(-c4nc(-c5cccc(-c6ccc7ccccc7c6)c5)nc(-c5cccc6oc7ccccc7c56)n4)ccc3c2)cc1] 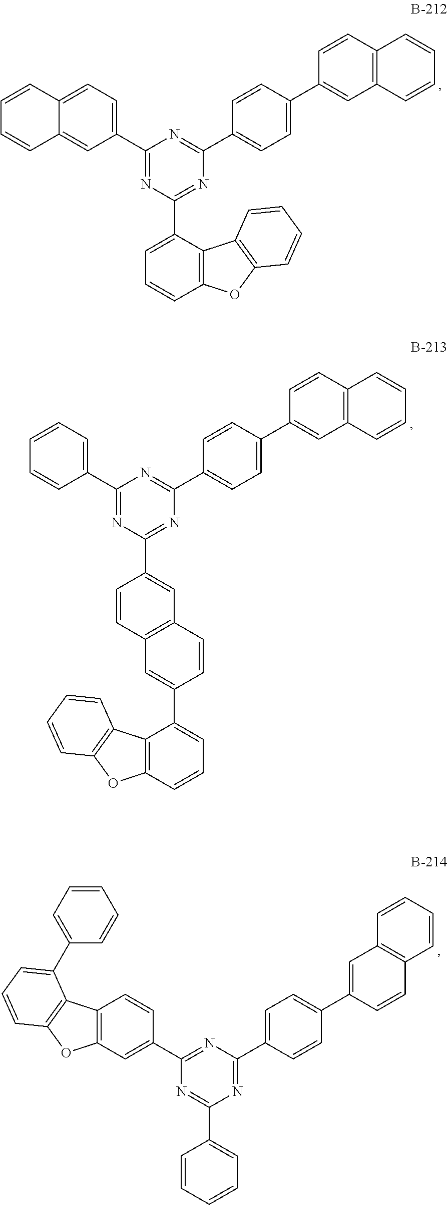 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2nc(-c3ccc(-c4ccc5ccccc5c4)cc3)nc(-c3ccc4cc(-c5cccc6oc7ccccc7c56)ccc4c3)n2)cc1 ; c1ccc(-c2nc(-c3ccc(-c4ccc5ccccc5c4)cc3)nc(-c3ccc4c(c3)oc3cccc(-c5ccccc5)c34)n2)cc1] 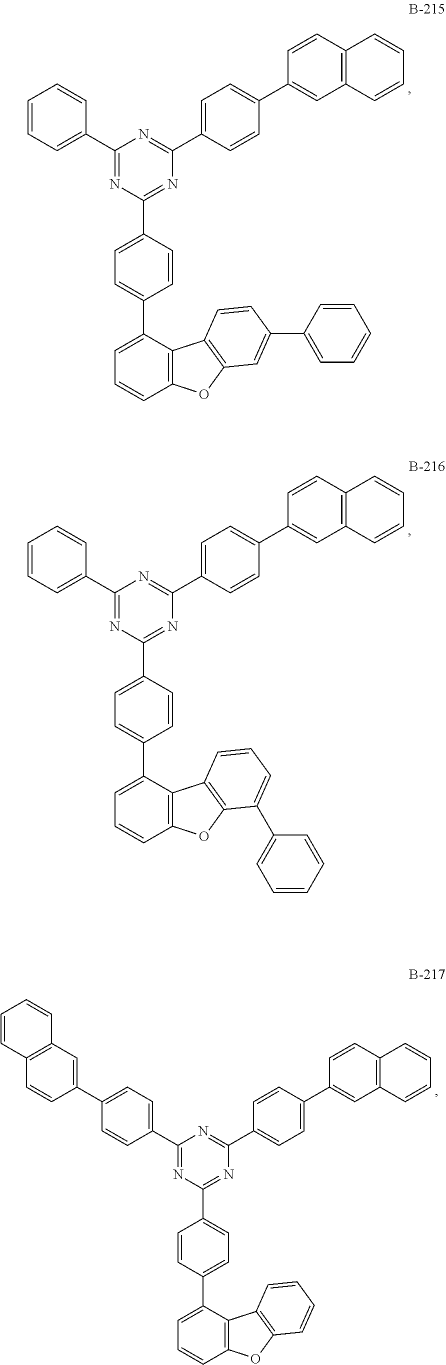 [SMILES: c1ccc(-c2ccc3c(c2)oc2cccc(-c4ccc(-c5nc(-c6ccccc6)nc(-c6ccc(-c7ccc8ccccc8c7)cc6)n5)cc4)c23)cc1 ; c1ccc(-c2nc(-c3ccc(-c4ccc5ccccc5c4)cc3)nc(-c3ccc(-c4cccc5oc6c(-c7ccccc7)cccc6c45)cc3)n2)cc1 ; c1ccc2cc(-c3ccc(-c4nc(-c5ccc(-c6ccc7ccccc7c6)cc5)nc(-c5ccc(-c6cccc7oc8ccccc8c67)cc5)n4)cc3)ccc2c1] 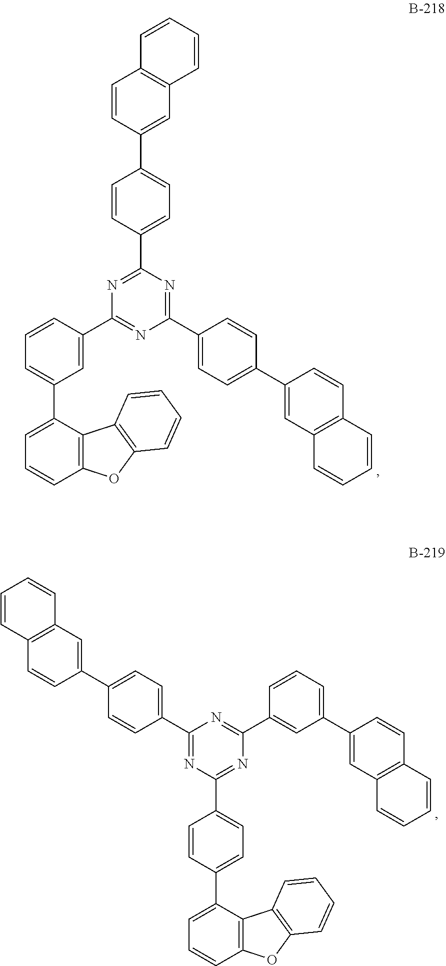 [SMILES: c1cc(-c2nc(-c3ccc(-c4ccc5ccccc5c4)cc3)nc(-c3ccc(-c4ccc5ccccc5c4)cc3)n2)cc(-c2cccc3oc4ccccc4c23)c1 ; c1cc(-c2ccc3ccccc3c2)cc(-c2nc(-c3ccc(-c4ccc5ccccc5c4)cc3)nc(-c3ccc(-c4cccc5oc6ccccc6c45)cc3)n2)c1] 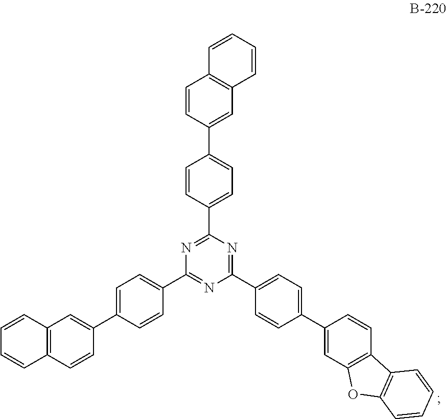 [SMILES: c1ccc2cc(-c3ccc(-c4nc(-c5ccc(-c6ccc7ccccc7c6)cc5)nc(-c5ccc(-c6ccc7c(c6)oc6ccccc67)cc5)n4)cc3)ccc2c1]
wherein optionally, hydrogens in Compound B-1 to Compound B-220 can be partially or fully substituted with deuterium.

13. The electroluminescent device according to claim 1, wherein the ligand Lₐ has a structure represented by Formula 4: 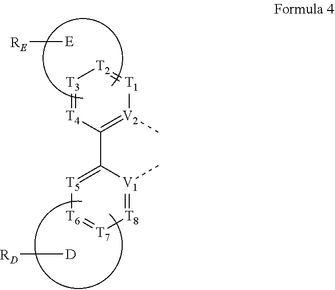
wherein
the ring D and the ring E are, at each occurrence identically or differently, selected from an aromatic ring having 6 to 30 ring atoms, a heteroaromatic ring having 5 to 30 ring atoms or a combination thereof;
R_{D} and R_{E} represent, at each occurrence identically or differently, mono-substitution, multiple substitutions or non-substitution;
T₁ to T₈ are, at each occurrence identically or differently, selected from C, CR_{T} or N, any adjacent two of T₁ to T₄ are C and fused to the ring E, and any adjacent two of T₅ to T₈ are C and fused to the ring D;
V₁ and V₂ are each independently selected from C or N, and V₁ is different from V₂;
R_{D}, R_{E} and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 4, adjacent substituents R_{D}, R_{E} and R_{T} can be optionally joined to form a ring.

14. The electroluminescent device according to claim 13, wherein the ligand Lₐ has a structure represented by any one of Formula 4-1 to Formula 4-3: 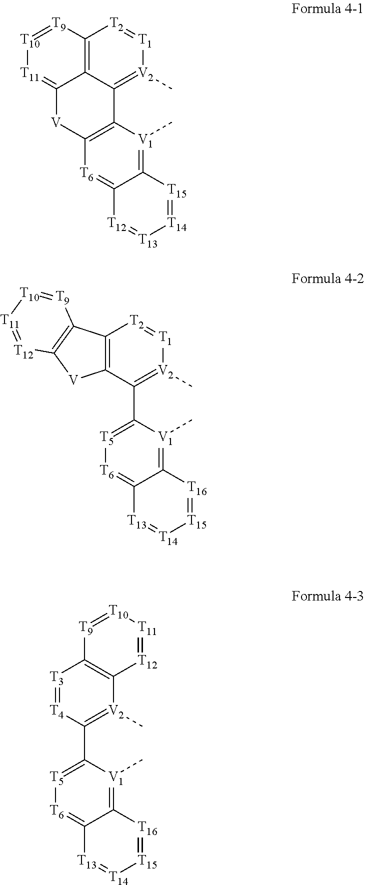
wherein V₁ and V₂ are each independently selected from C or N, and V₁ is different from V₂;
T₁ to T₆ and T₉ to T₁₆ are, at each occurrence identically or differently, selected from CR_{T} or N;
V is selected from the group consisting of: O, S, Se, NR′, CR′R′, SiR′R′ and GeR′R′, wherein when two R′ are present at the same time, the two R′ are identical or different;
R′ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
in Formula 4-1 to Formula 4-3, adjacent substituents R′ and R_{T} can be optionally joined to form a ring;
preferably, the ligand Lₐ has a structure represented by any one of Formula 4-4 to Formula 4-7: 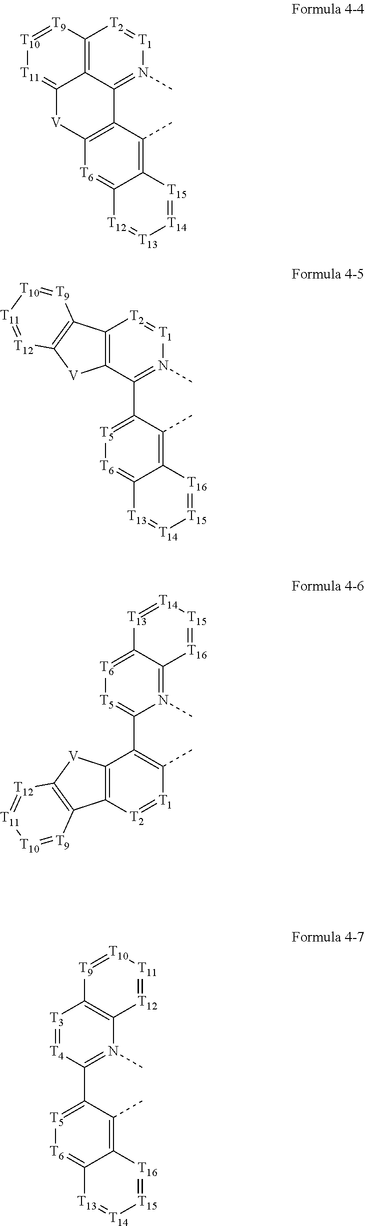
wherein T₁ to T₆ and T₉ to T₁₆ are, at each occurrence identically or differently, selected from CR_{T};
V is selected from the group consisting of: O, S, Se, NR′, CR′R′, SiR′R′ and GeR′R′, wherein when two R′ are present at the same time, the two R′ are identical or different;
R′ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 4-4 to Formula 4-7, adjacent substituents R′ and R_{T} can be optionally joined to form a ring.

15. The electroluminescent device according to claim 14, wherein T₁ to T₆ and T₉ to T₁₆ are, at each occurrence identically or differently, selected from CR_{T}, and R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof; and
more preferably, at least one, two or three of R_{T} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

16. The electroluminescent device according to claim 14, wherein in Formula 4-1, at least one of T₁, T₂ and T₉ to T₁₁ is selected from CR_{T}, and at least one of T₆ and T₁₂ to T₁₅ is selected from CR_{T}; in Formula 4-2, at least one of T₁, T₂ and T₉ to T₁₂ is selected from CR_{T}, and at least one of T₅, T₆ and T₁₃ to T₁₆ is selected from CR_{T}; in Formula 4-3, at least one of T₃, T₄ and T₉ to T₁₂ is selected from CR_{T}, and at least one of T₅, T₆ and T₁₃ to T₁₆ is selected from CR_{T}; R_{T} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof; and
preferably, in Formula 4-1, T₁, T₂, T₆, T₁₀ and T₁₄ are selected from CR_{T}; in Formula 4-2, T₆, T₁₁ and T₁₂ are selected from CR_{T}; in Formula 4-3, T₃, T₆ and T₉ are selected from CR_{T}; R_{T} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

17. The electroluminescent device according to claim 13, wherein the ligand Lₐ is, at each occurrence identically or differently, selected from the group consisting of the following structures:

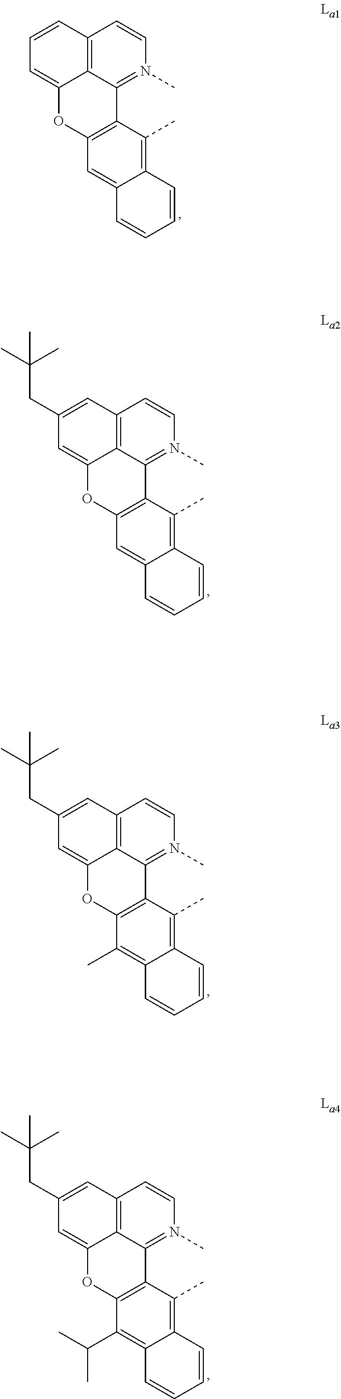

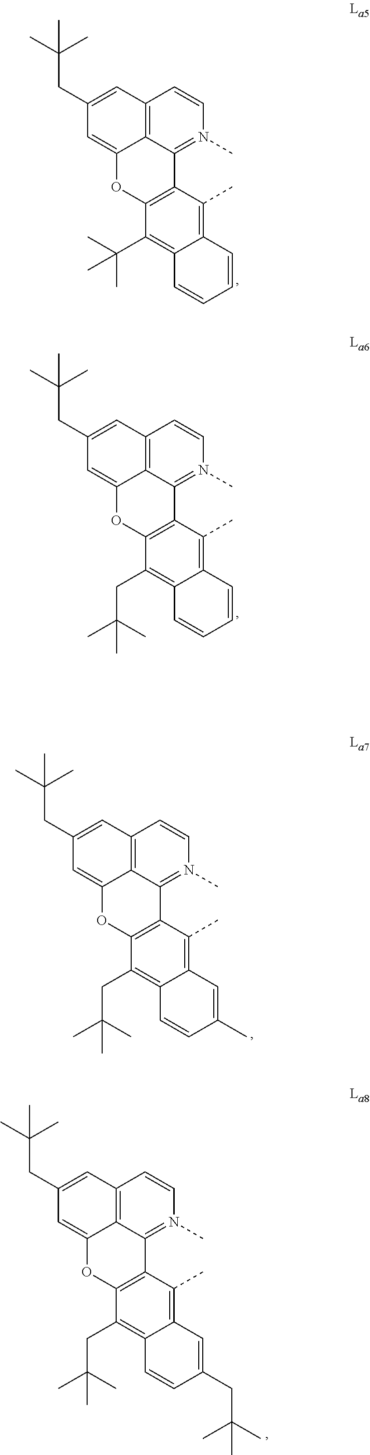

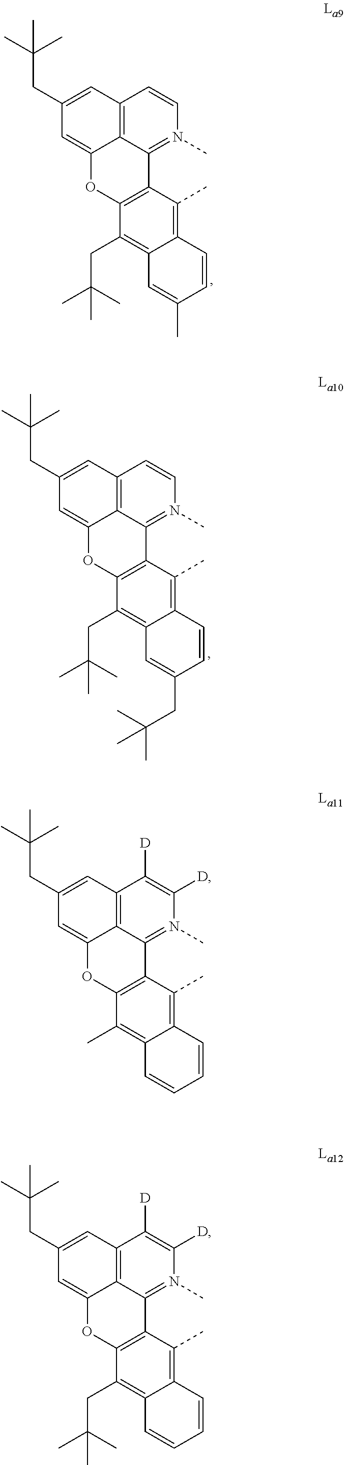

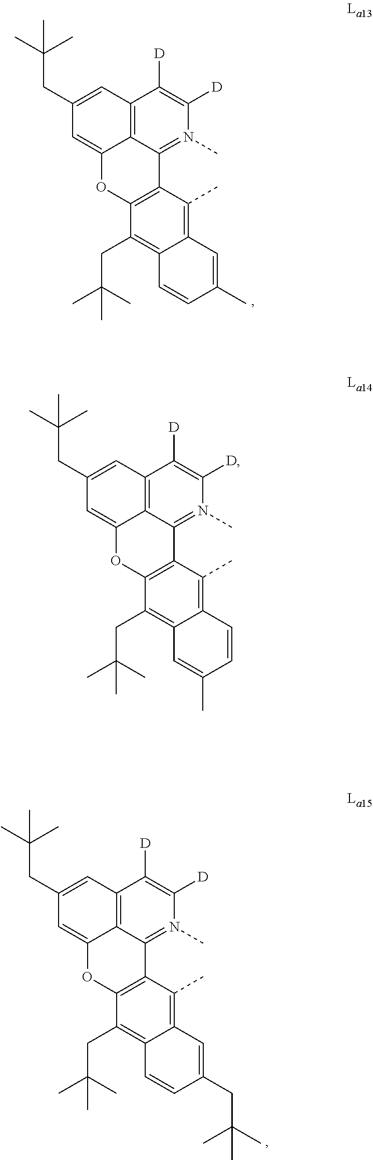

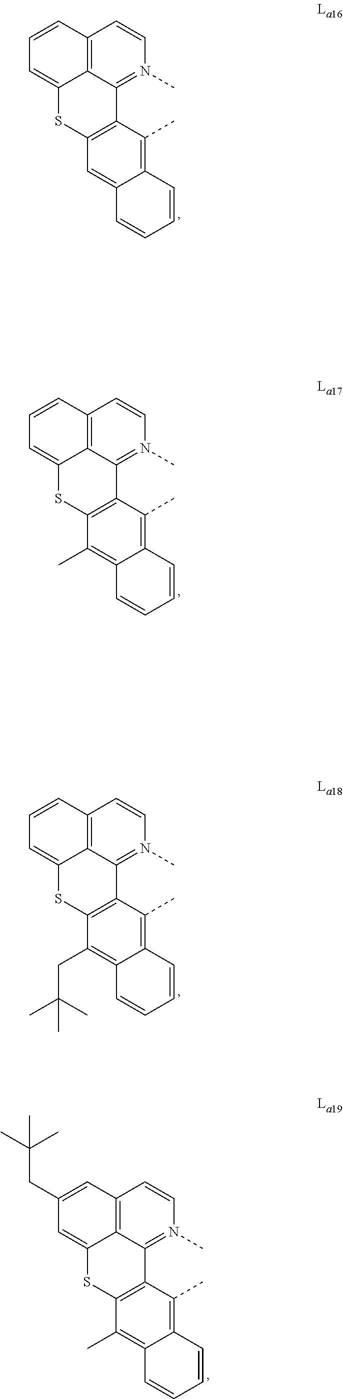

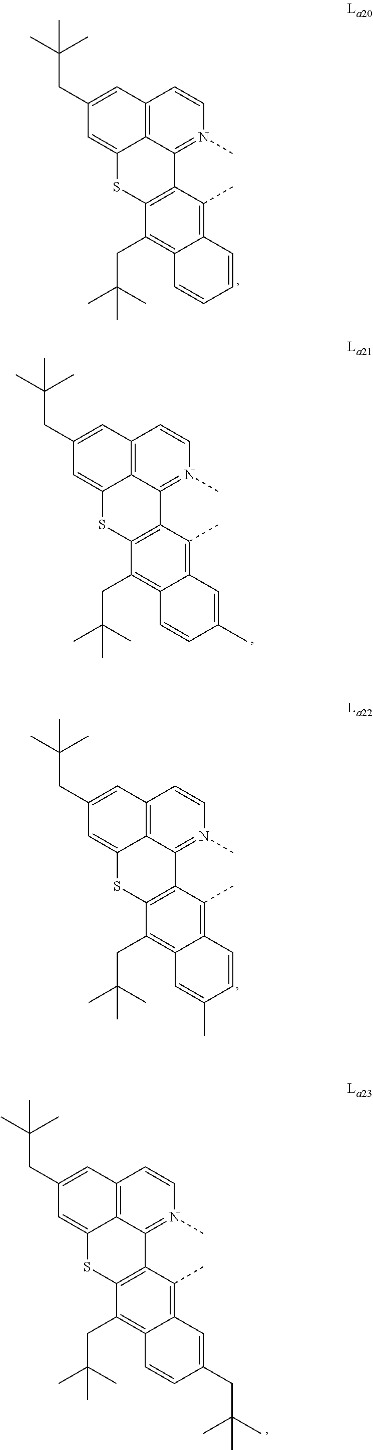

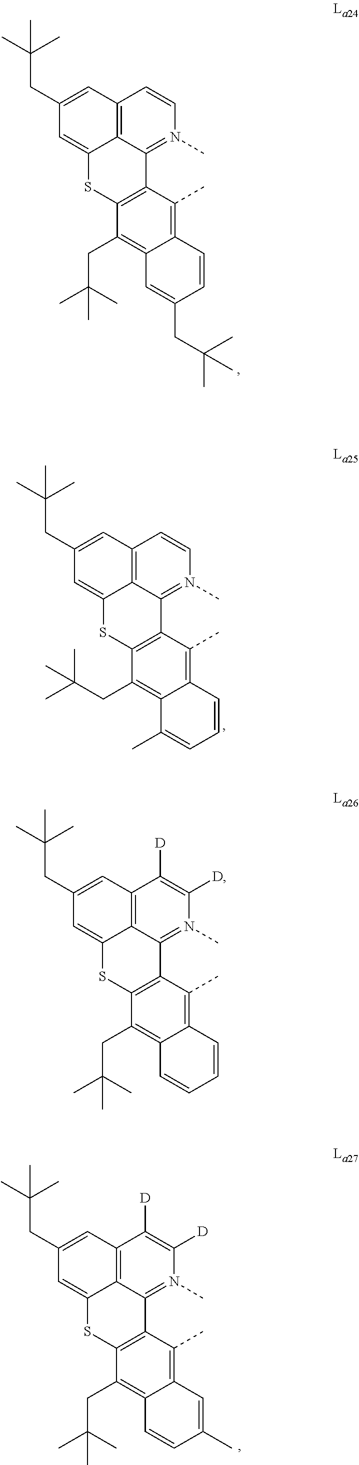

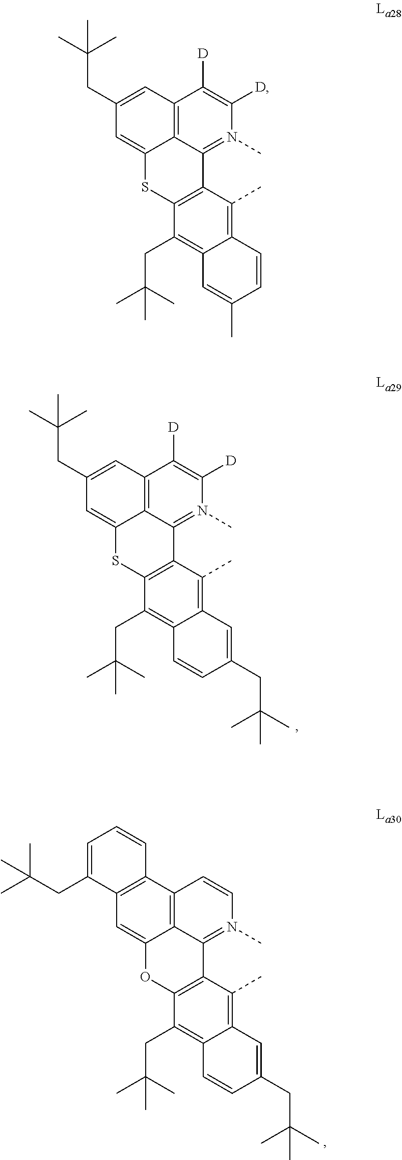

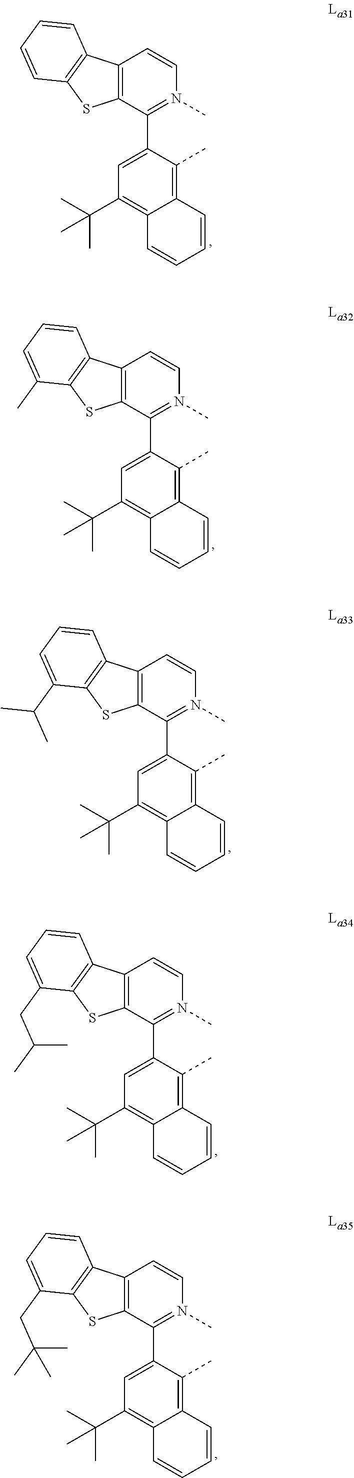

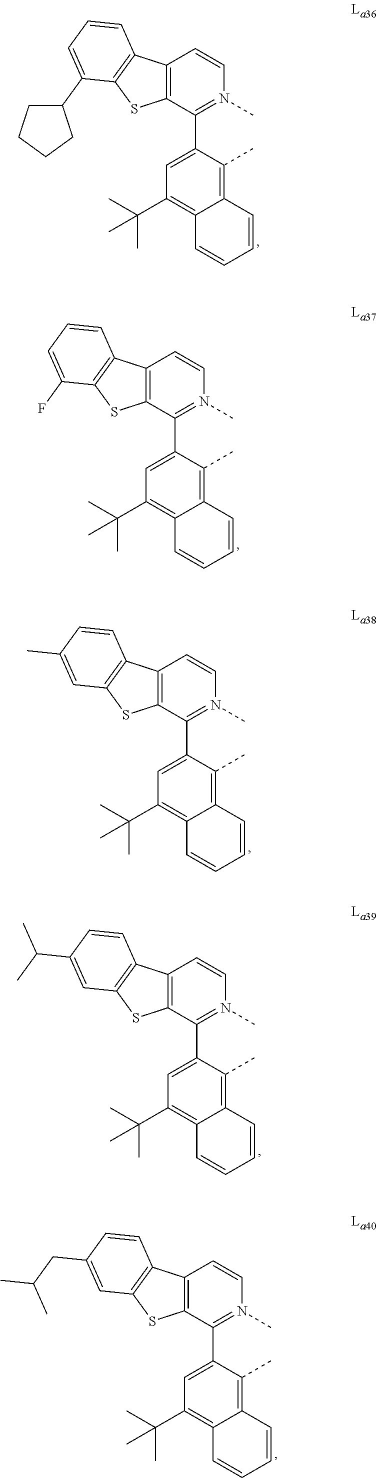

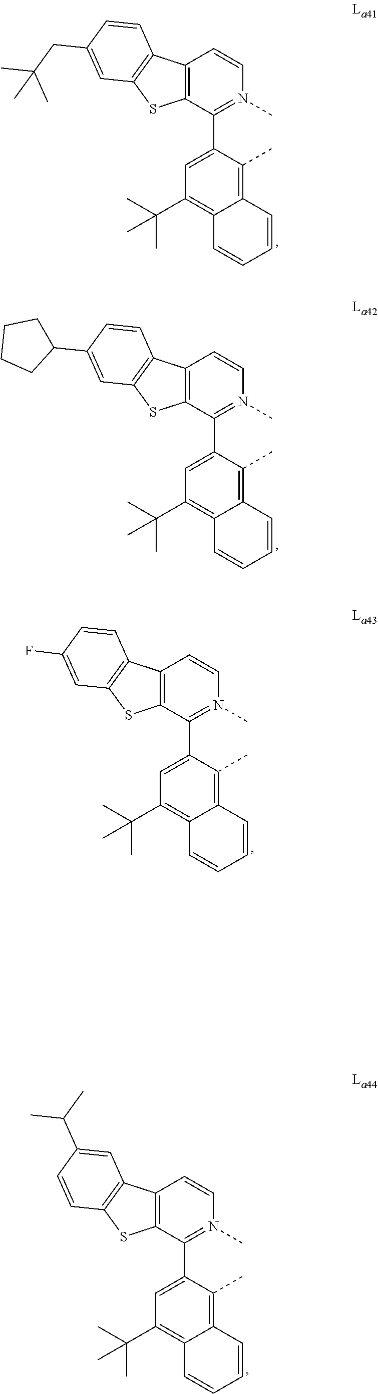

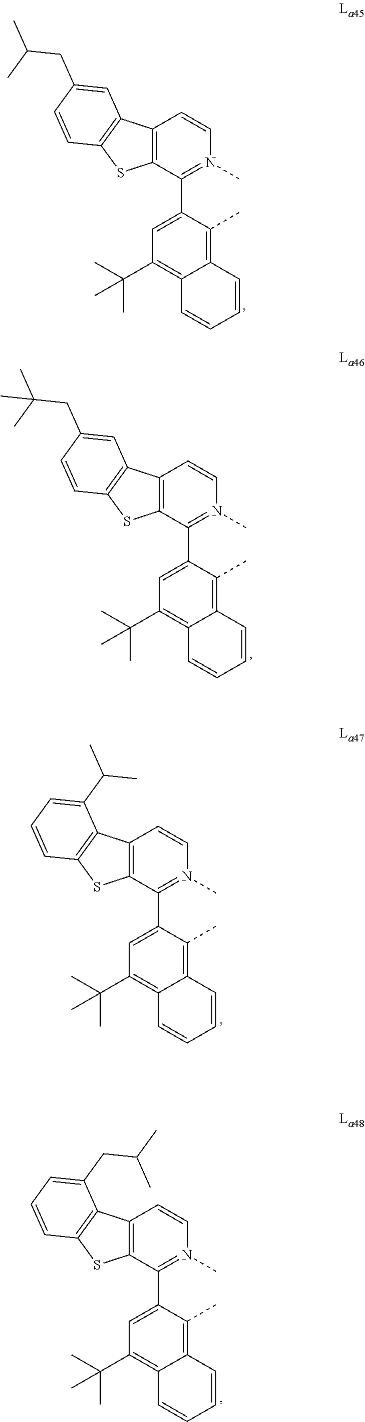

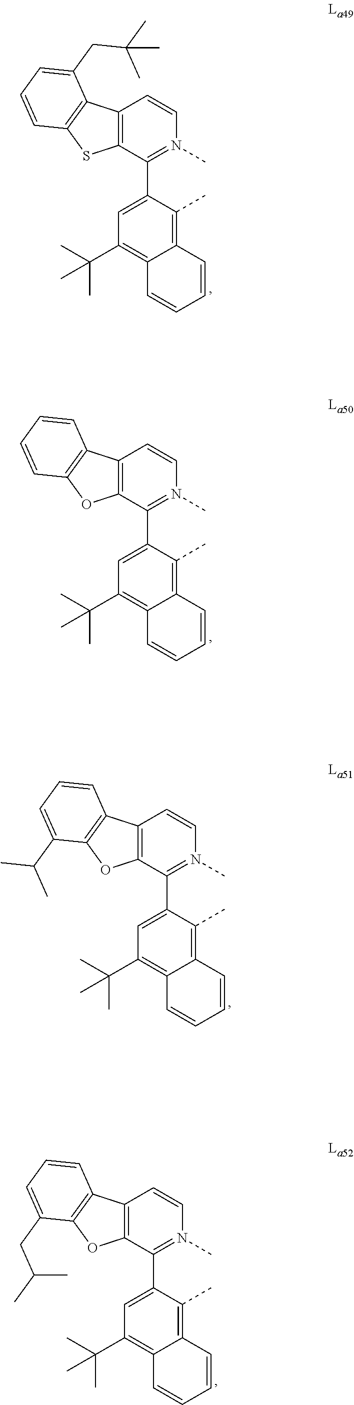

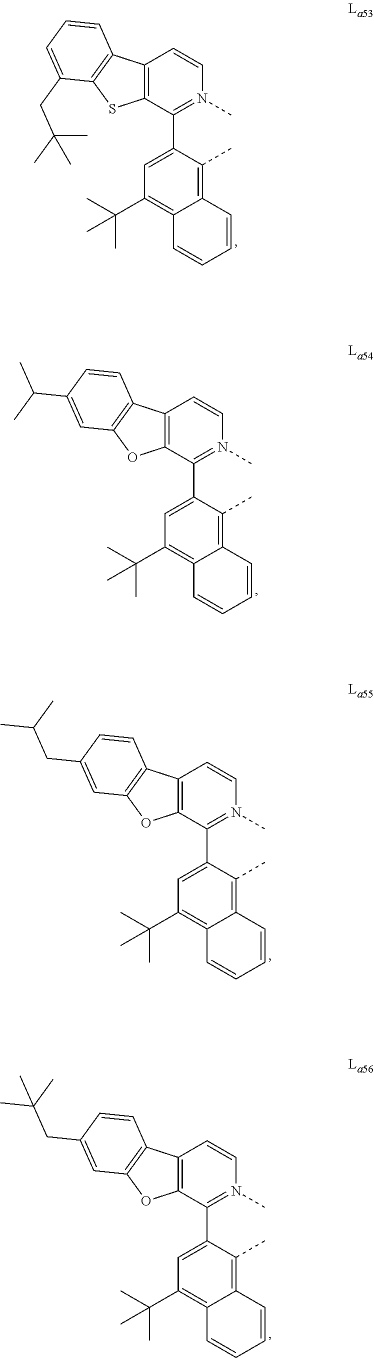

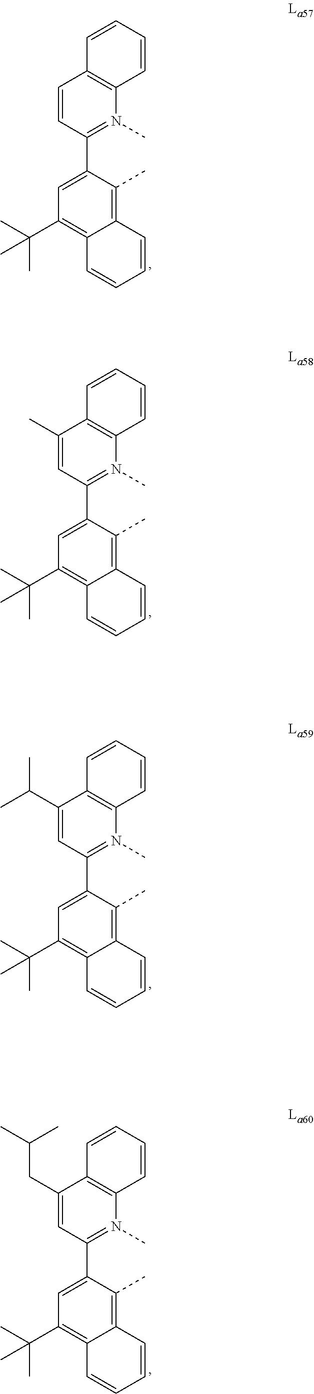

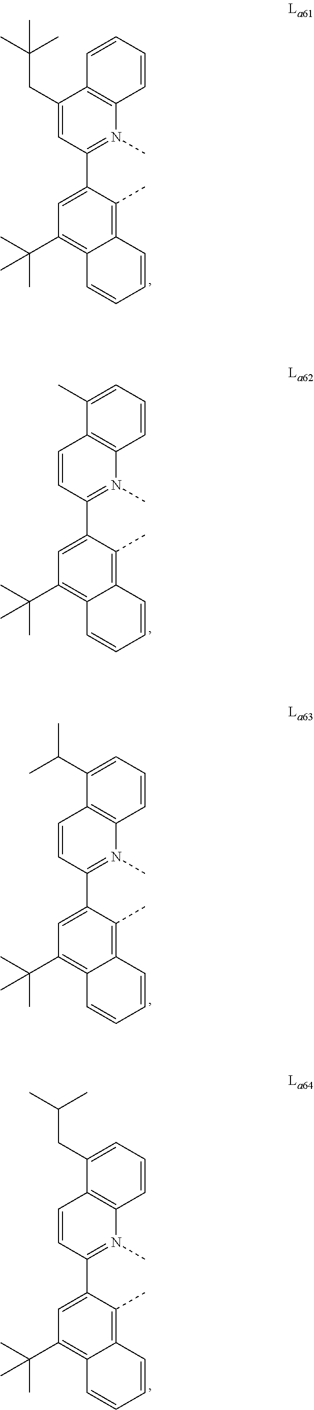

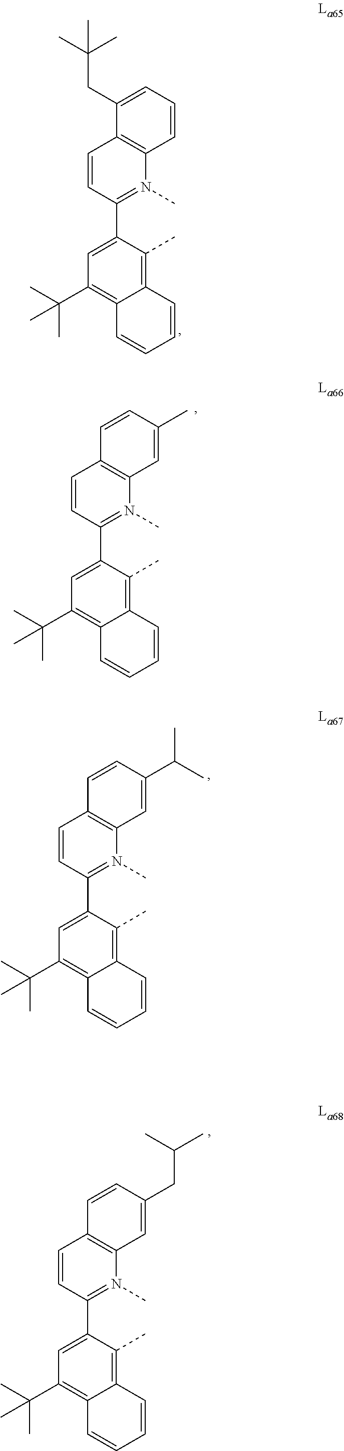

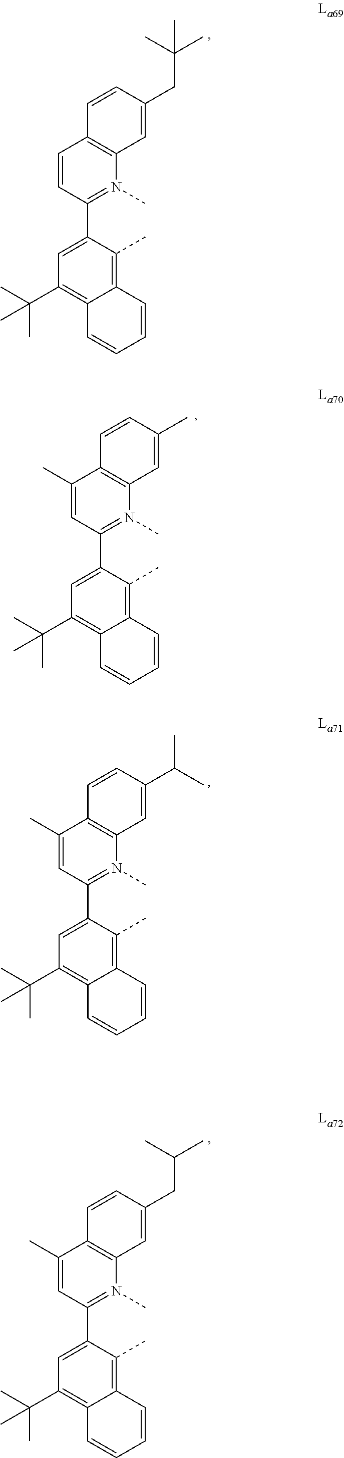

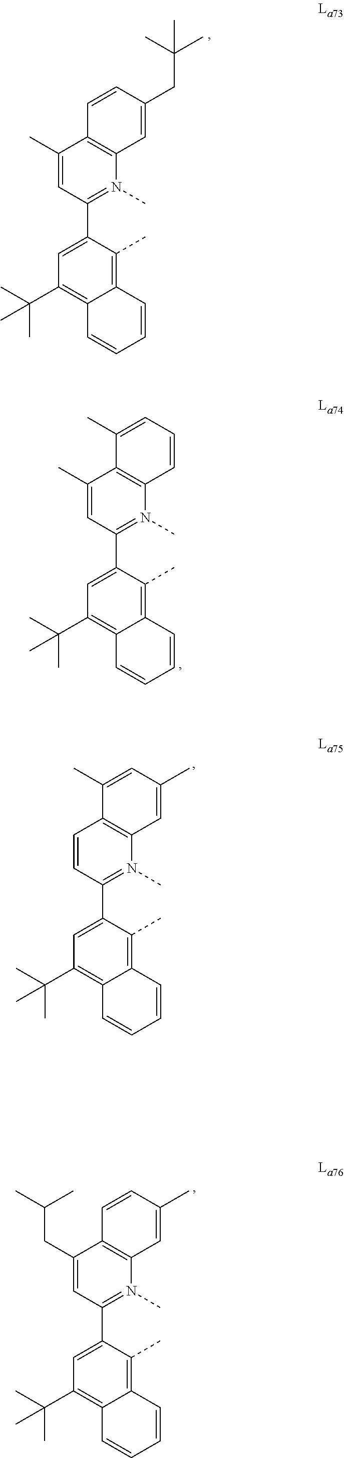

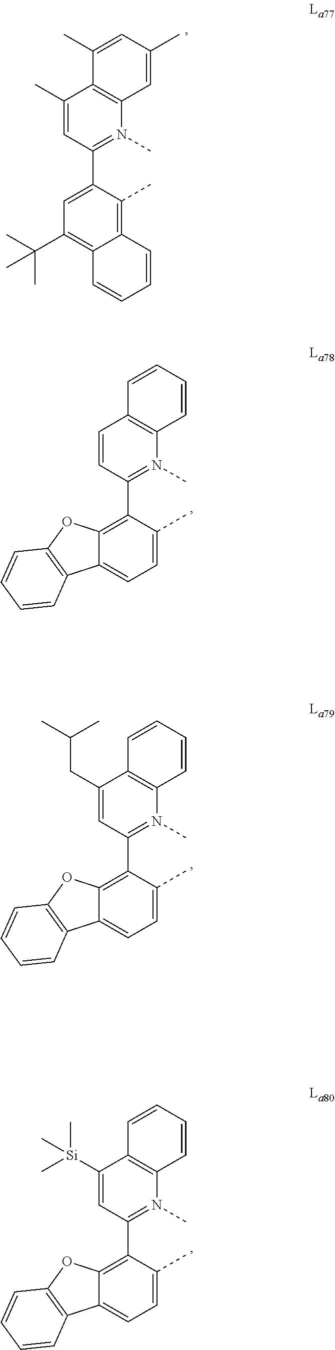

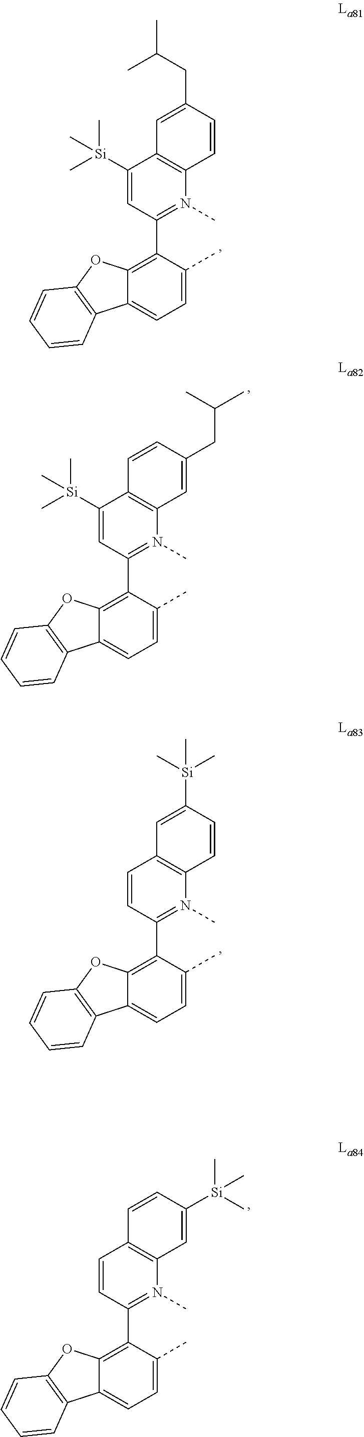

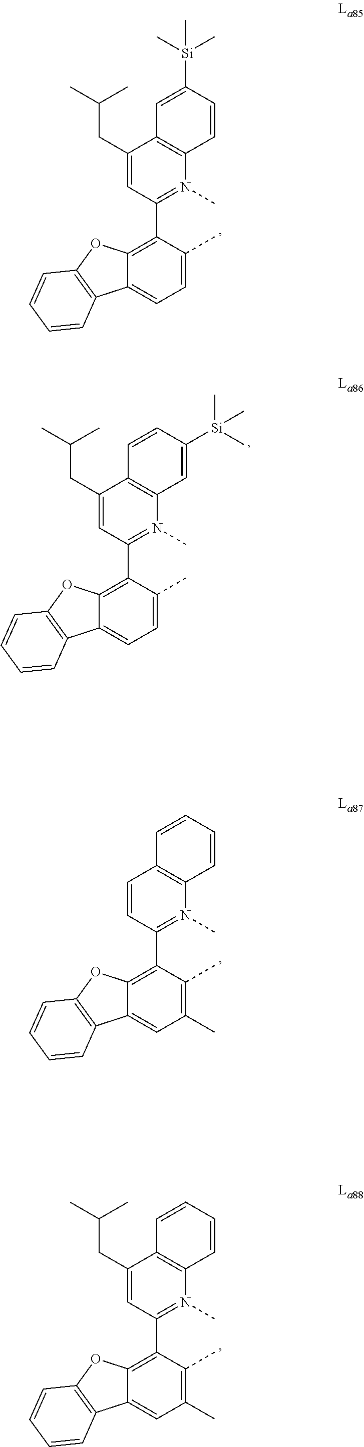

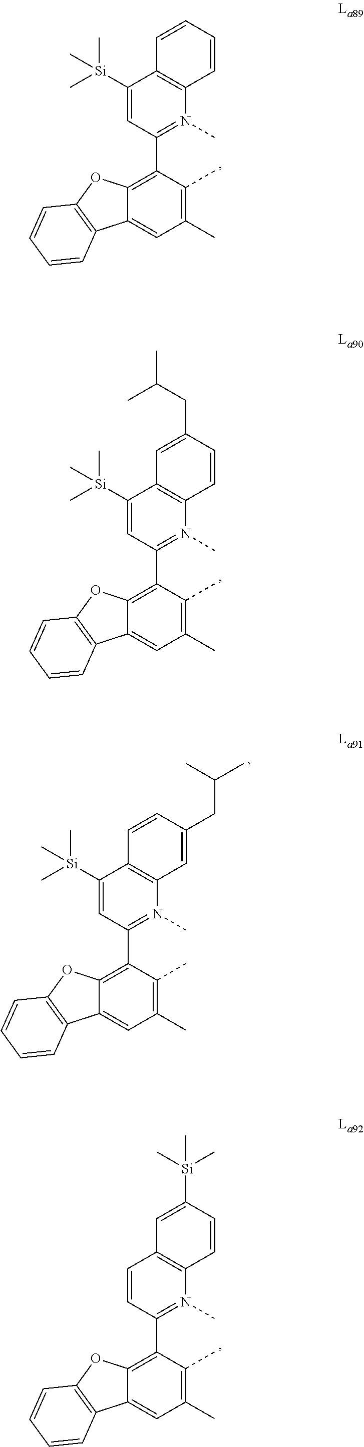

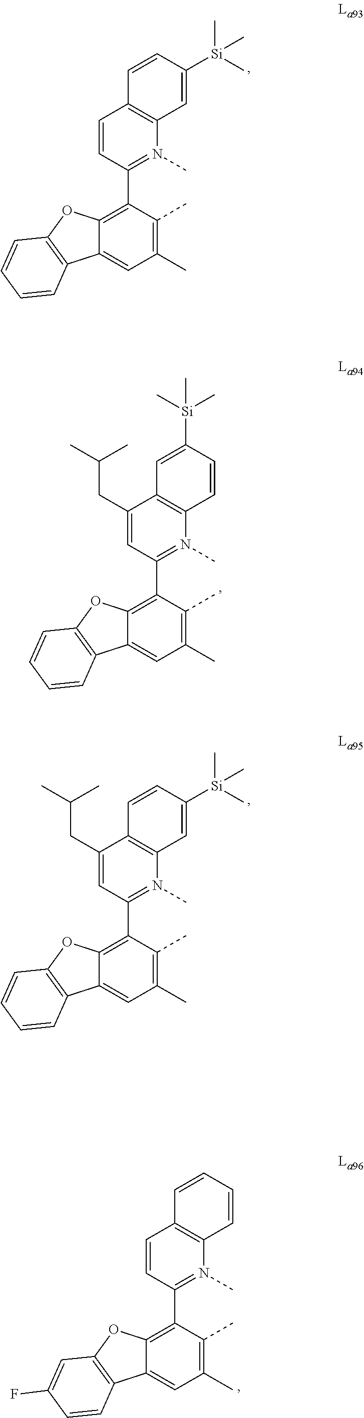

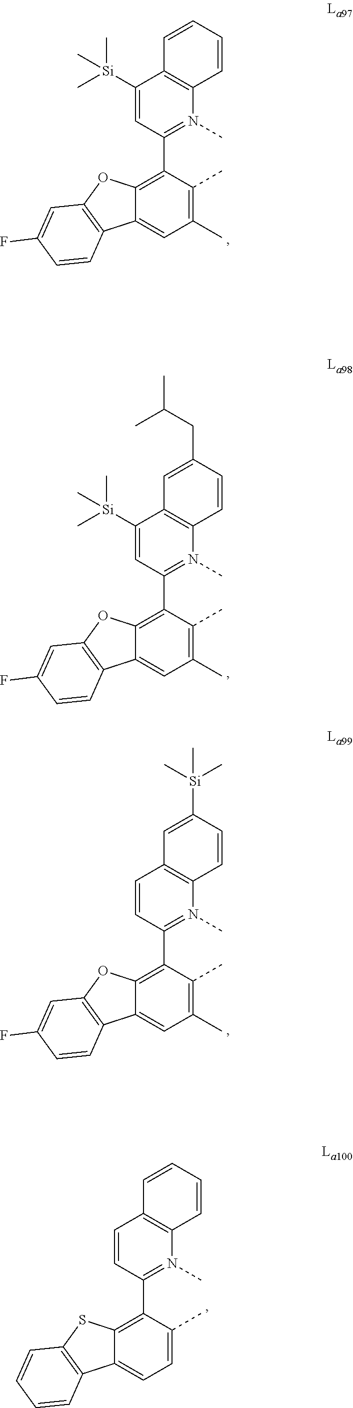

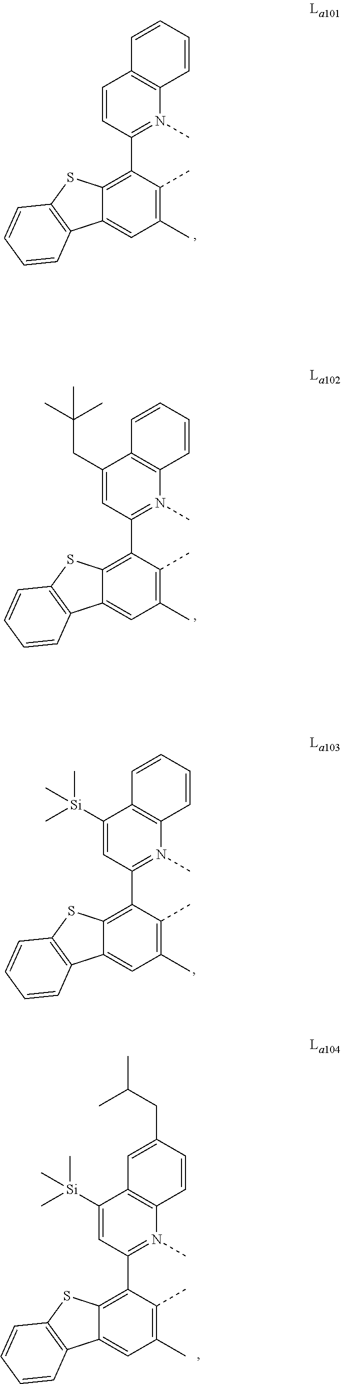

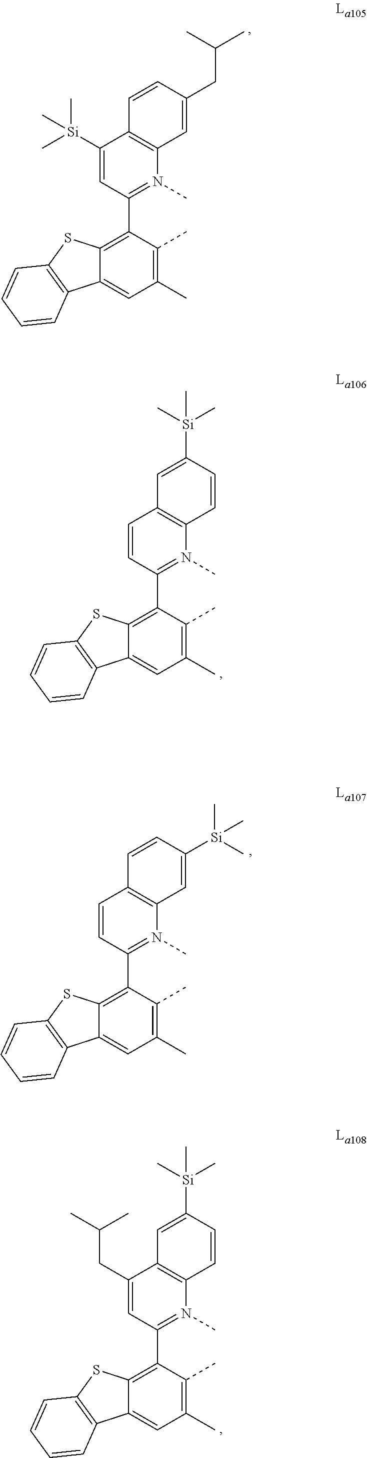

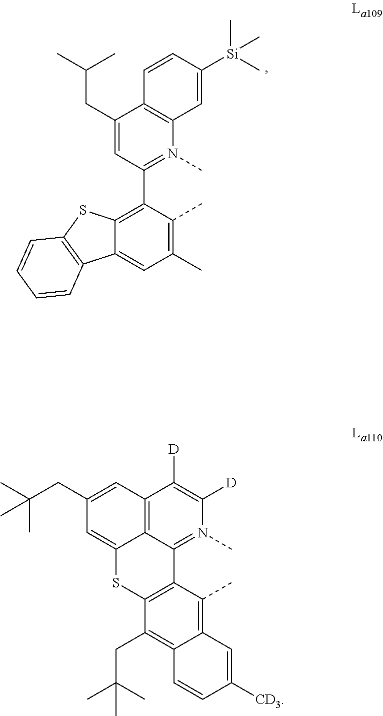

18. The electroluminescent device according to claim 1, wherein the third compound has a general formula of M(Lₐ)ₘ(L_{b})ₙ(L_{c})_{q}, wherein the metal M is selected from a metal with a relative atomic mass greater than 40, Lₐ, L_{b} and L_{c} are a first ligand, a second ligand and a third ligand coordinated to the metal M, respectively, and the ligands Lₐ, L_{b} and L_{c} may be identical or different;
m is 1, 2 or 3, n is 0, 1 or 2, q is 0, 1 or 2, and m+n+q is equal to an oxidation state of the metal M; when m is greater than or equal to 2, a plurality of Lₐ are identical or different; when n is 2, two L_{b} are identical or different; when q is 2, two L_{c} are identical or different;
the ligands Lₐ, L_{b} and L_{c} can be optionally joined to form a multidentate ligand;
the ligands L_{b} and L_{c} are, at each occurrence identically or differently, selected from the group consisting of the following structures: 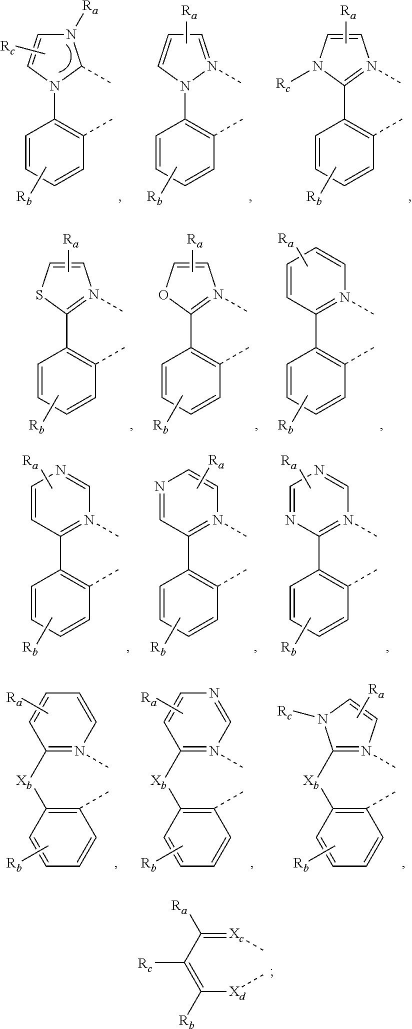
wherein Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

19. The electroluminescent device according to claim 18, wherein the metal M is selected from Ir, Rh, Re, Os, Pt, Au or Cu; and
preferably, the metal M is selected from Ir or Pt; more preferably, the metal M is Ir.

20. The electroluminescent device according to claim 18, wherein the ligand L_{b} is, at each occurrence identically or differently, selected from the following structure: 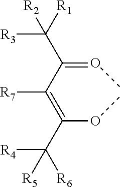
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₁ to R₇ can be optionally joined to form a ring;
preferably, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

21. The electroluminescent device according to claim 18, wherein the ligand L_{b} is, at each occurrence identically or differently, selected from the group consisting of the following structures: 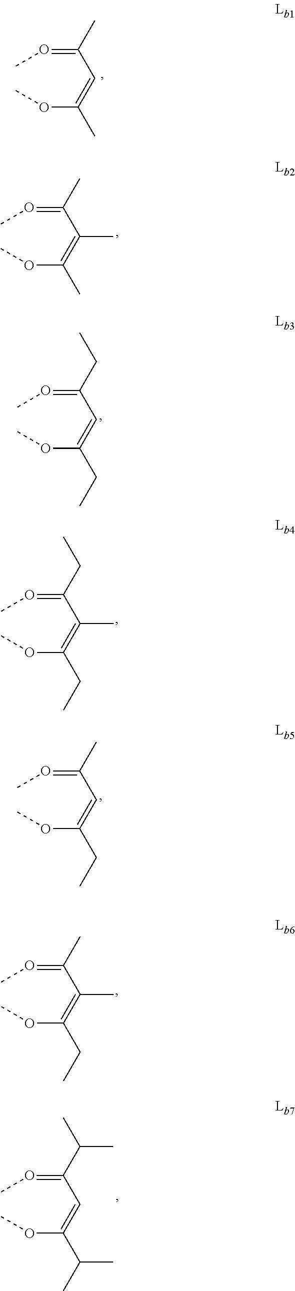 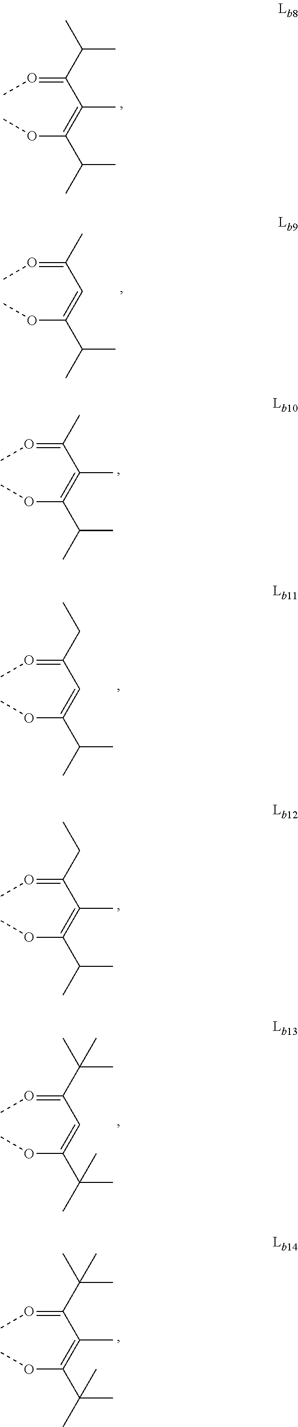 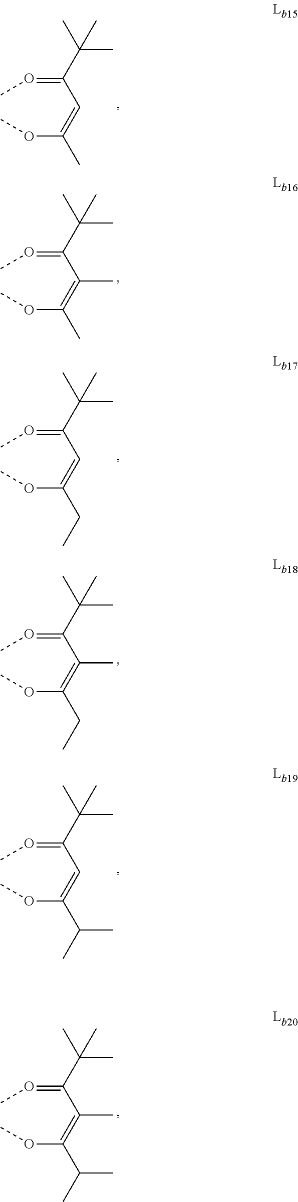 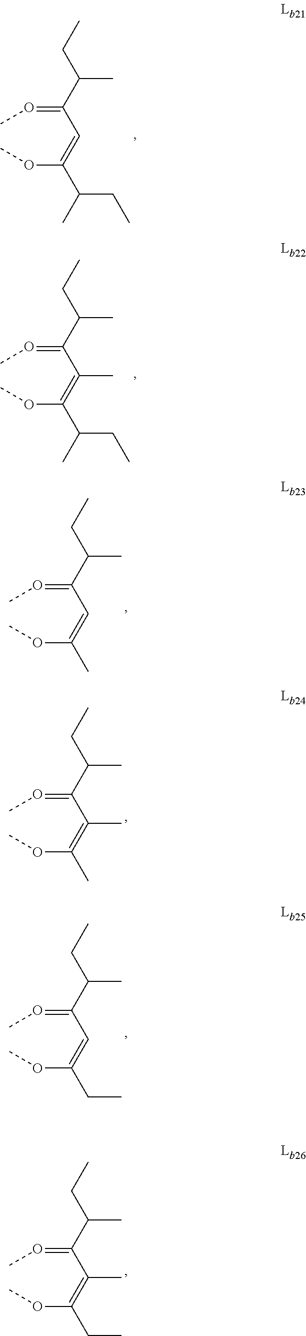 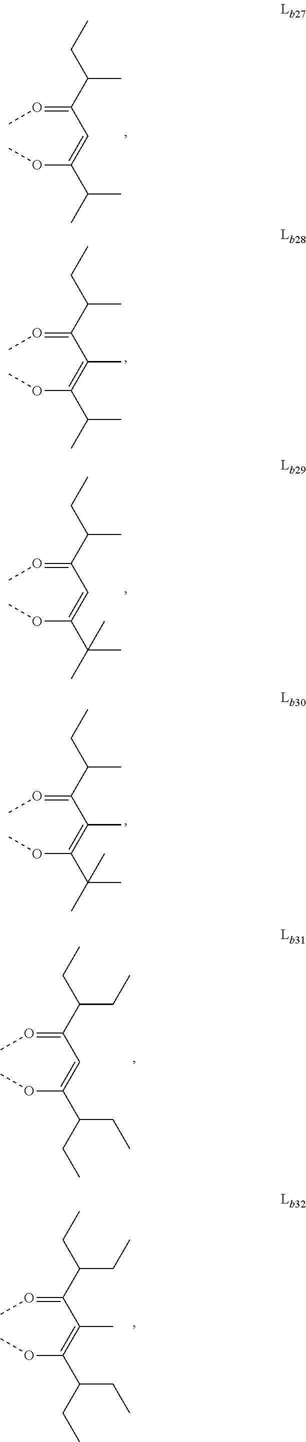 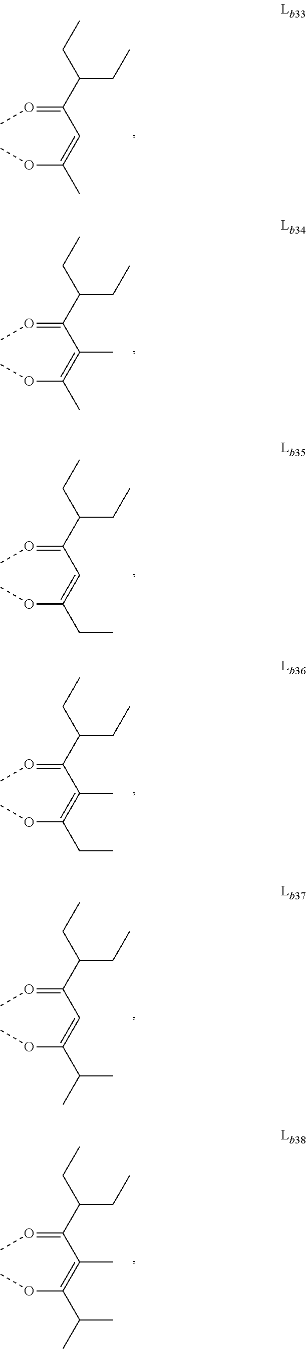 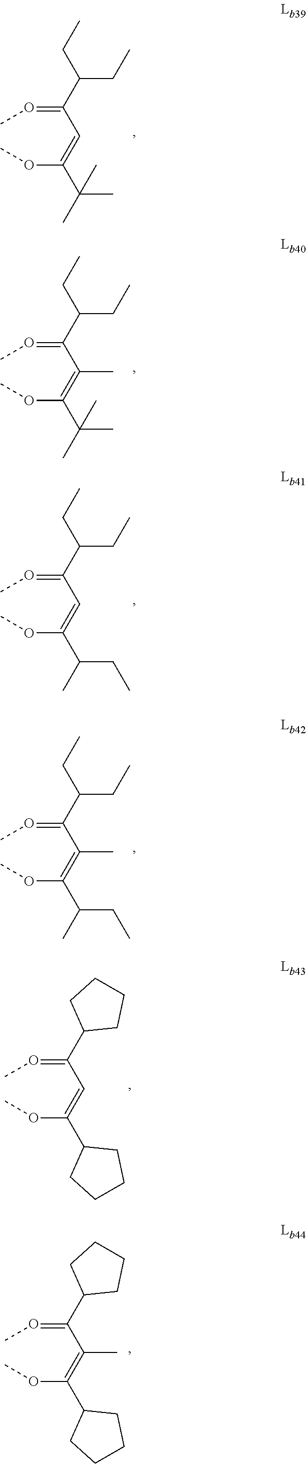 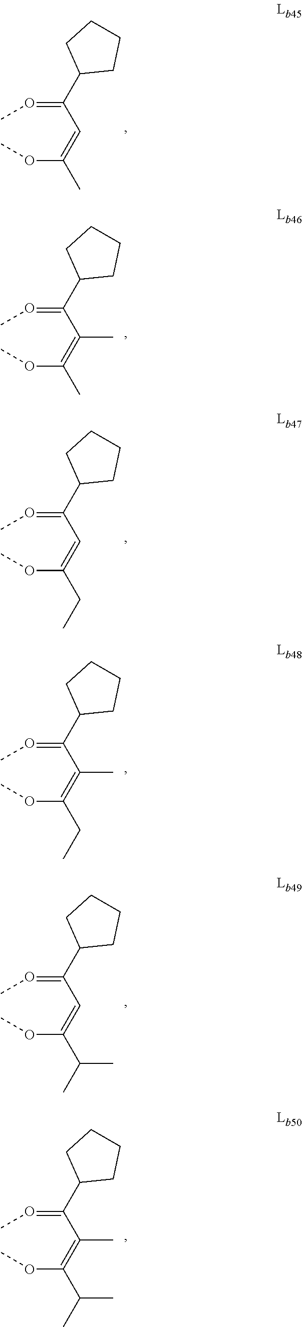 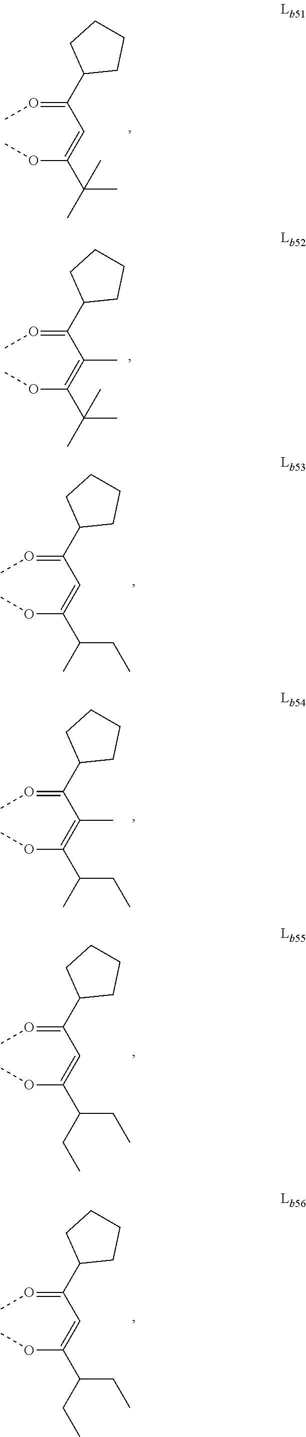 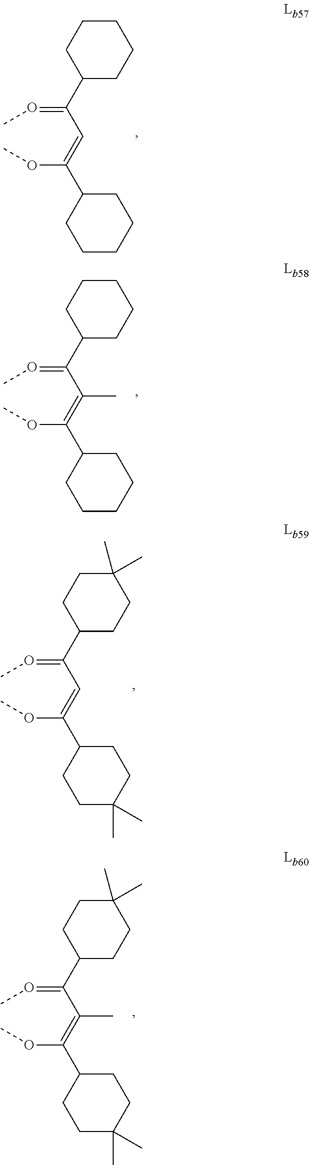 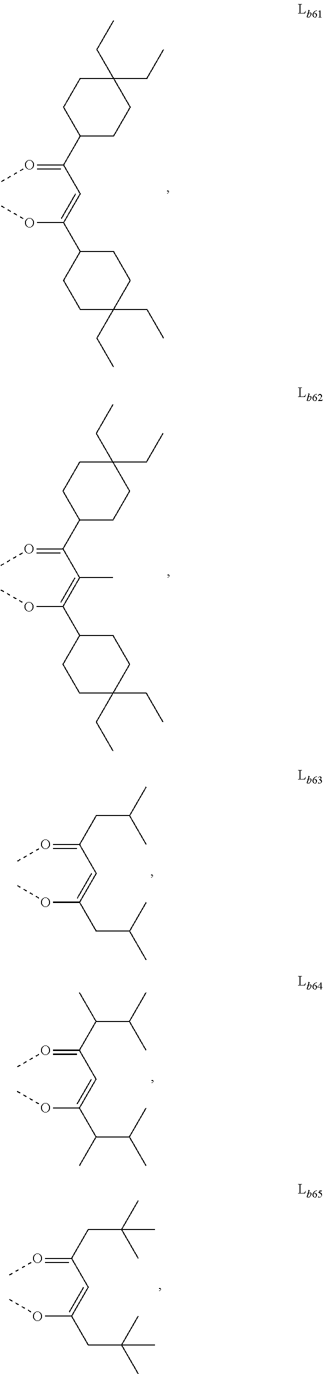 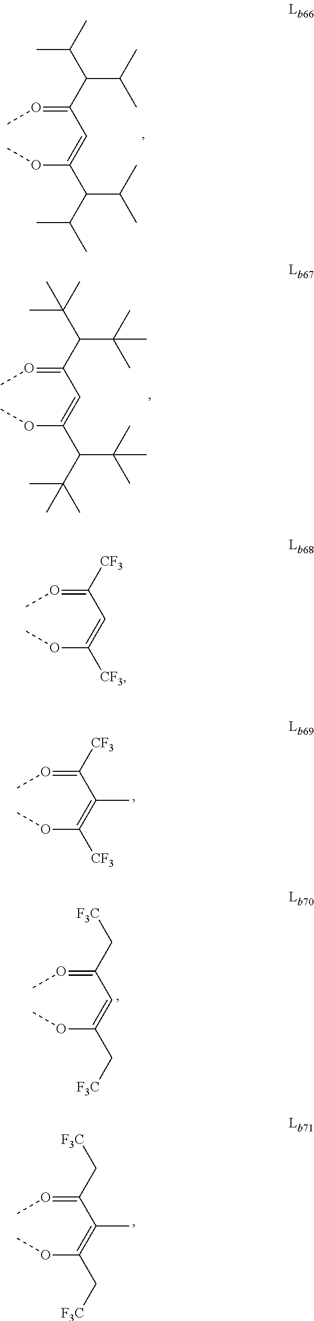 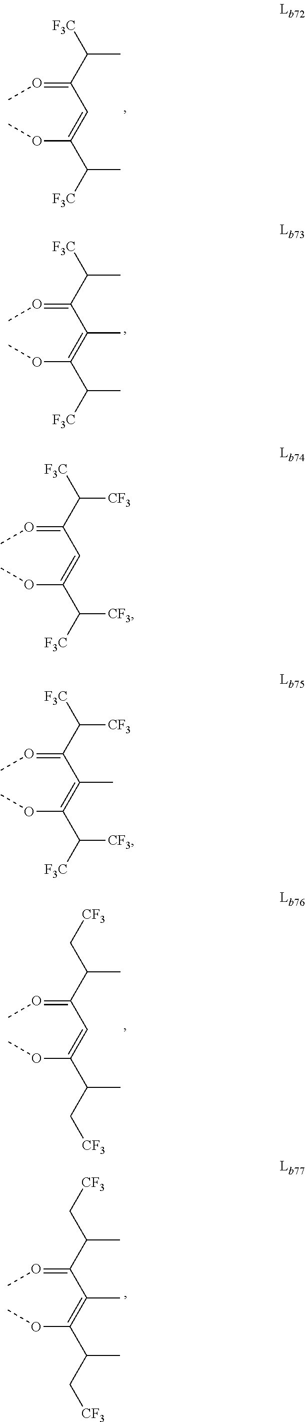 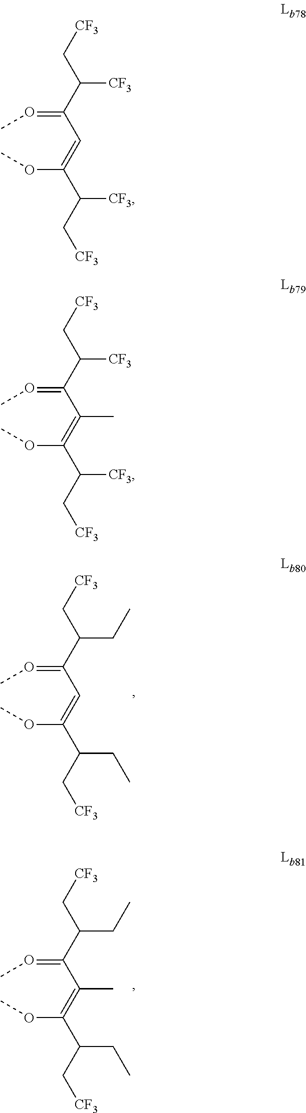 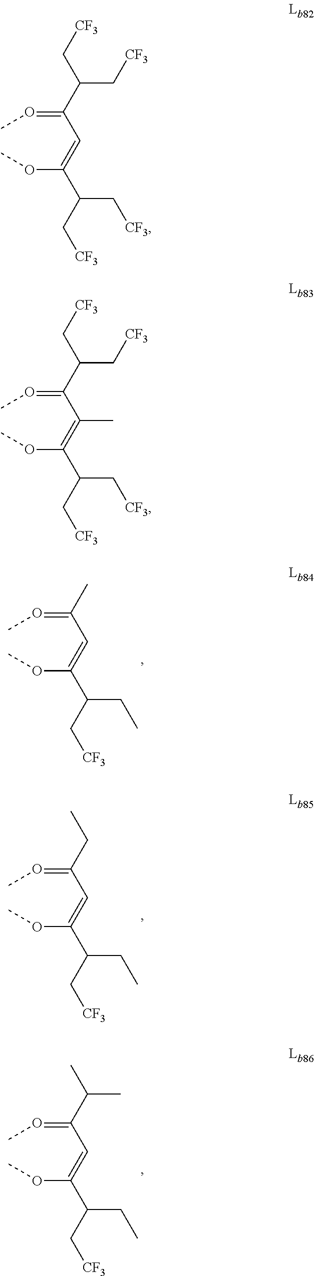 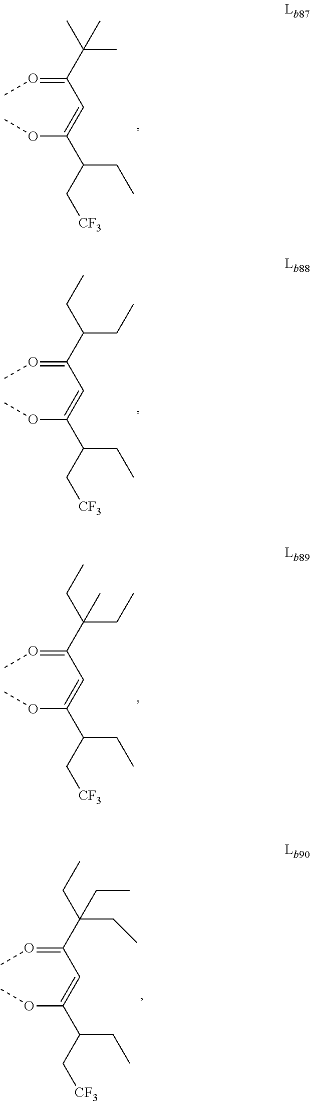 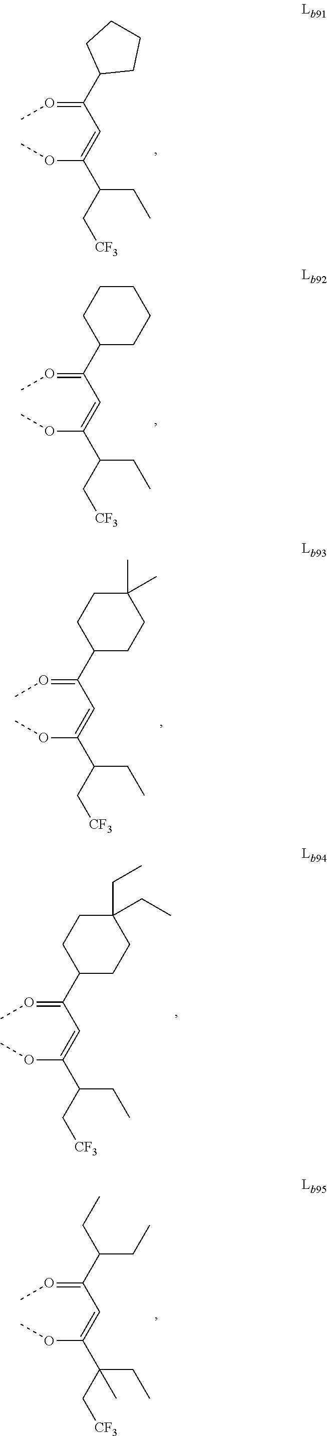 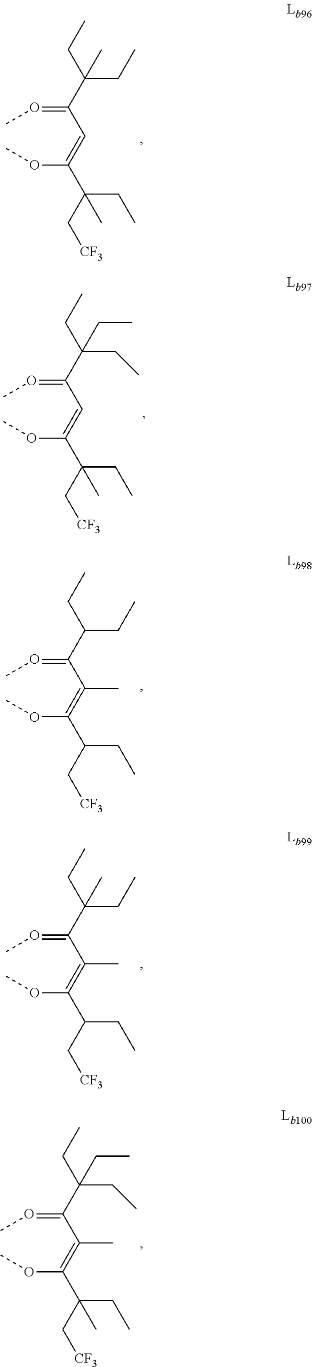 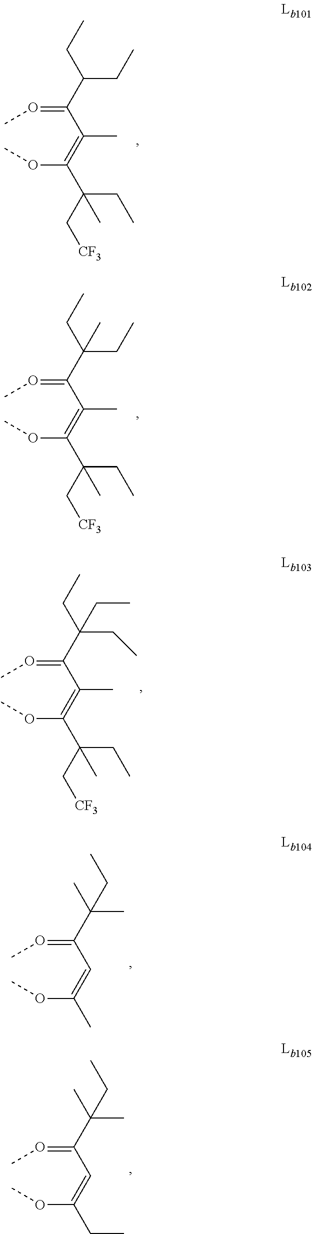 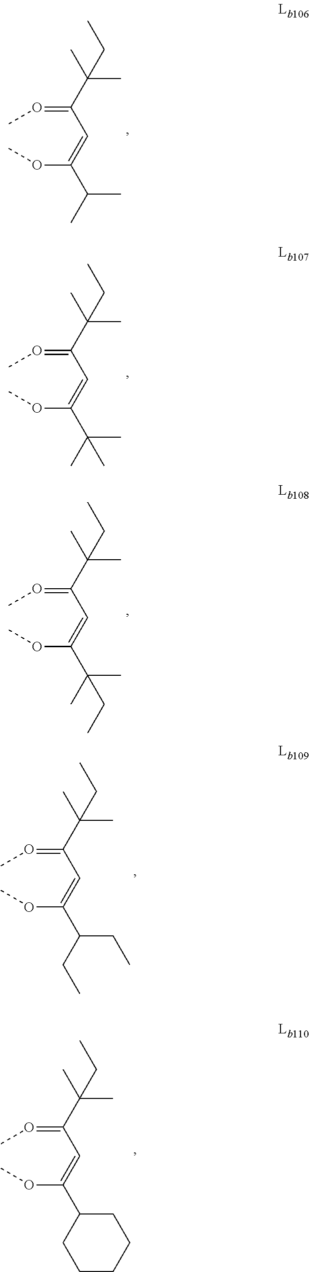 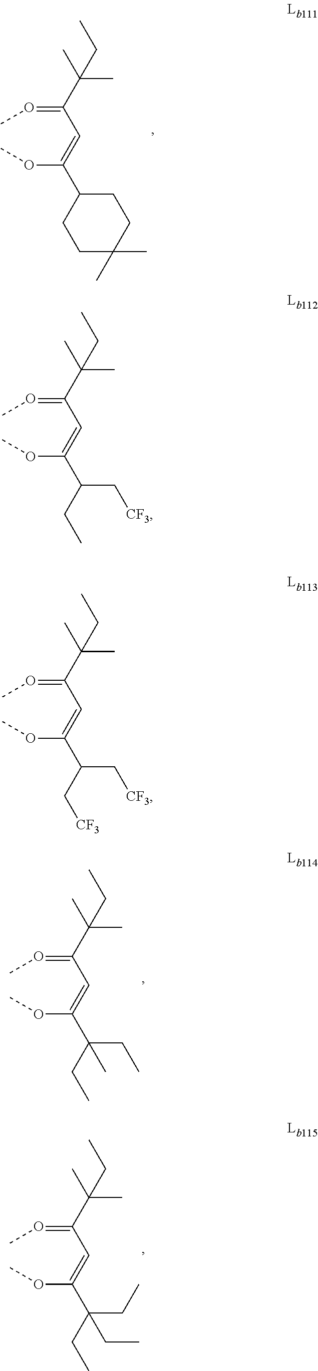 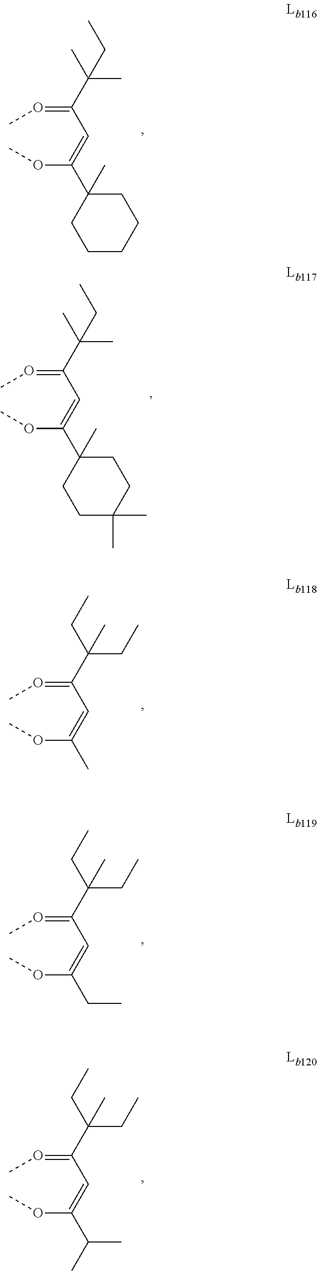 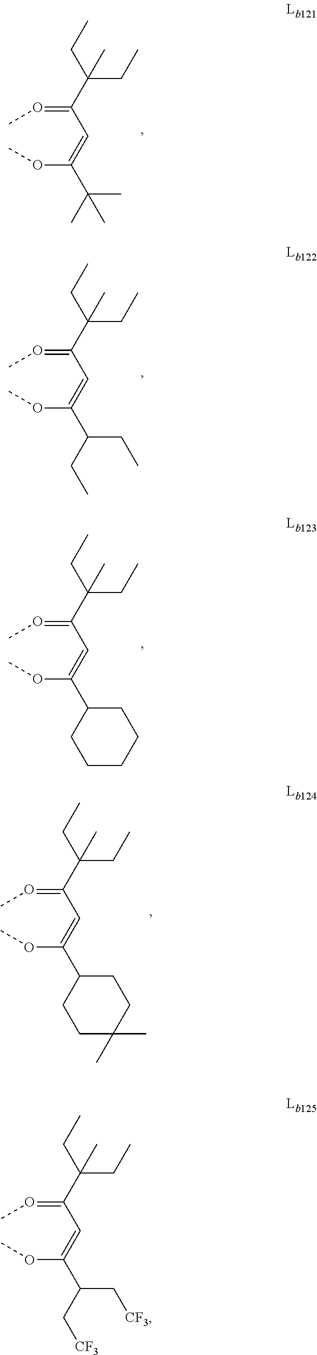 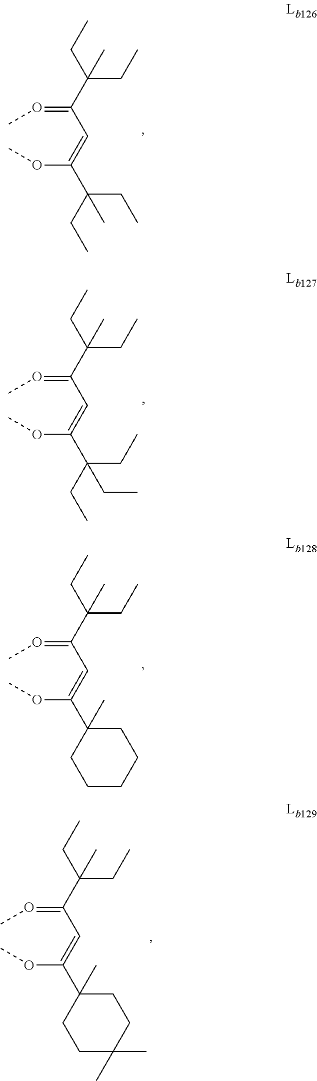 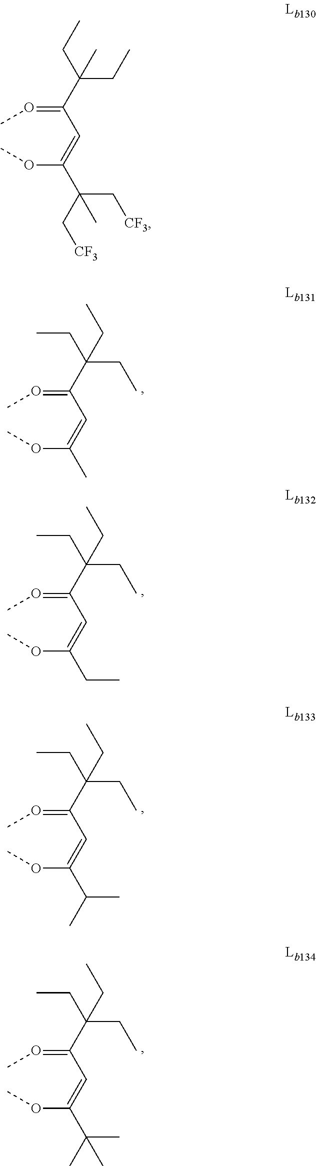 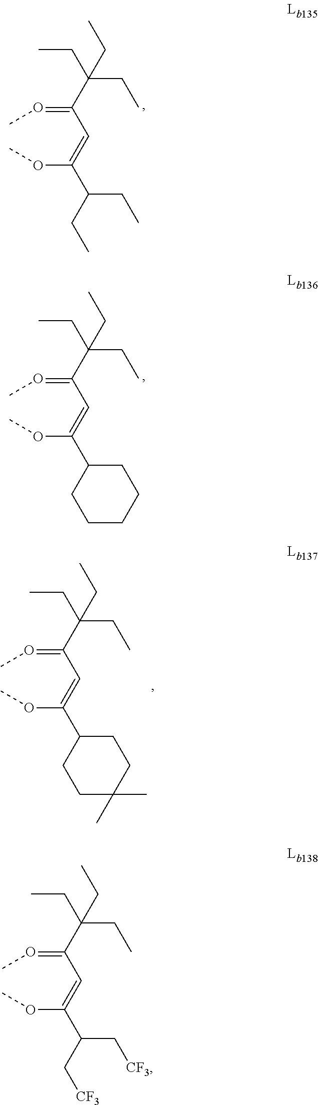 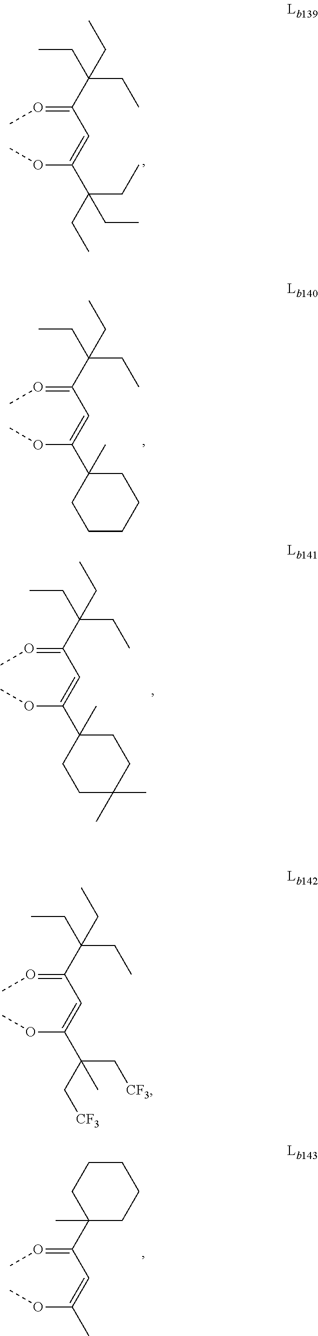 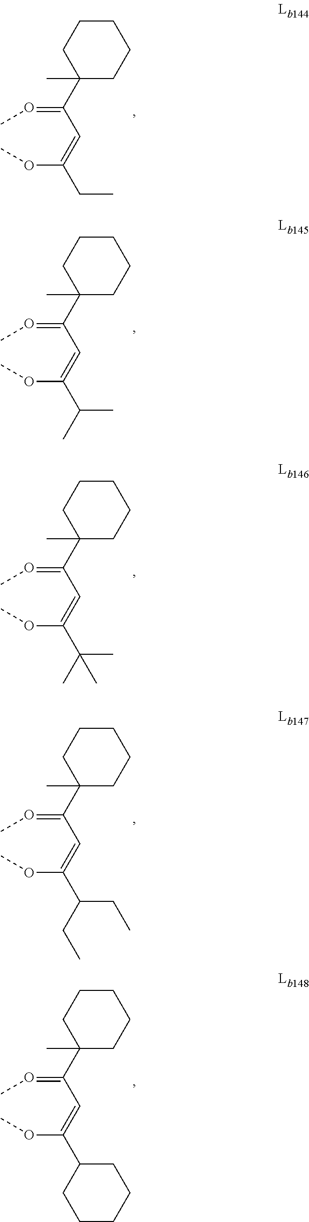 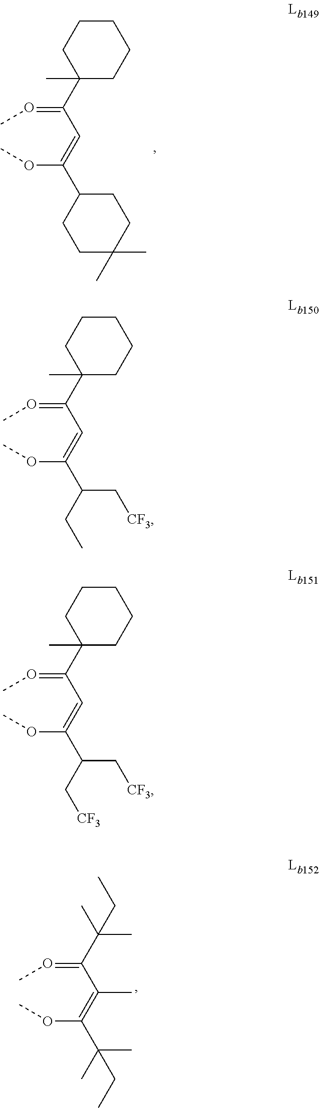 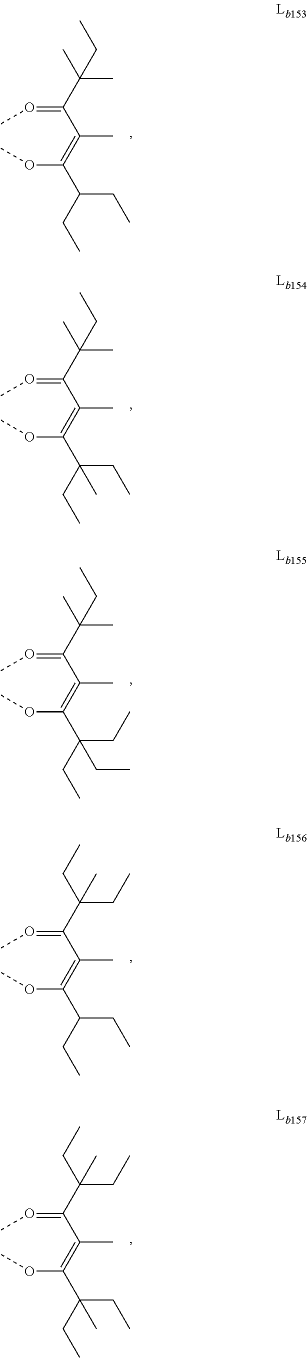 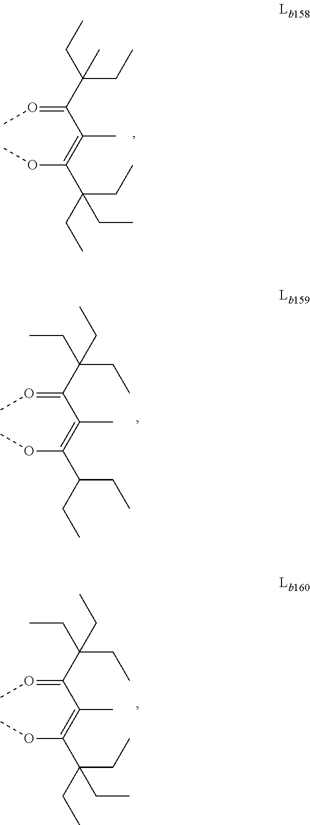 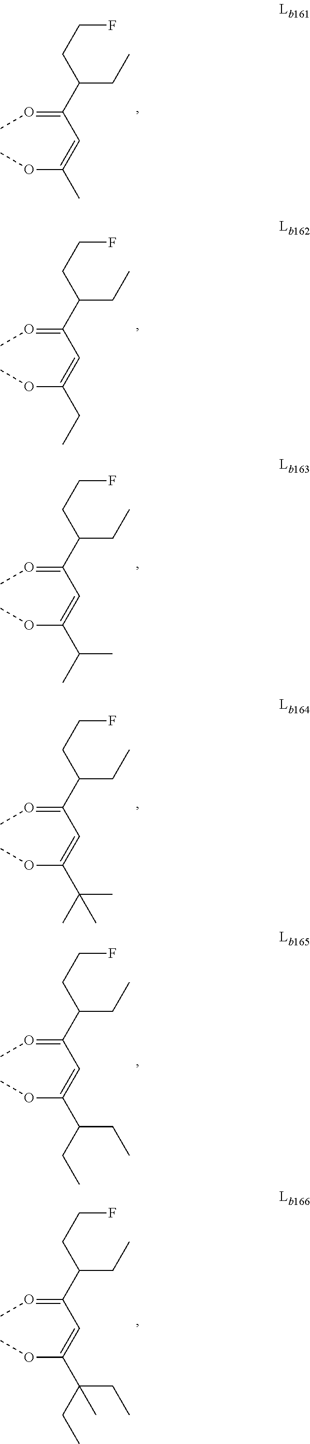 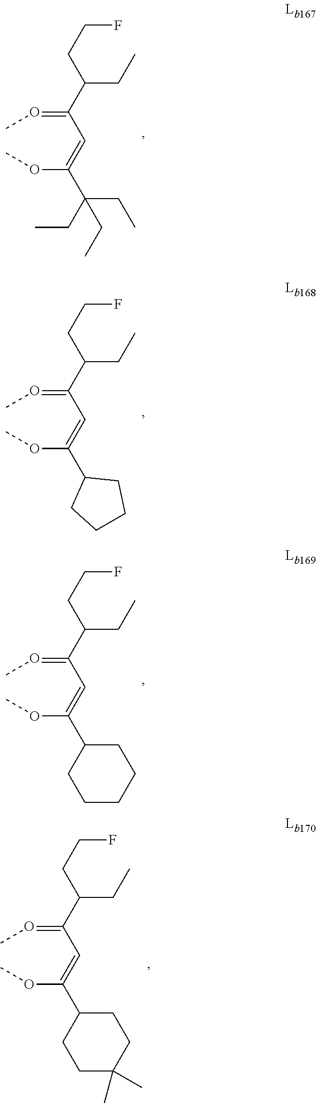 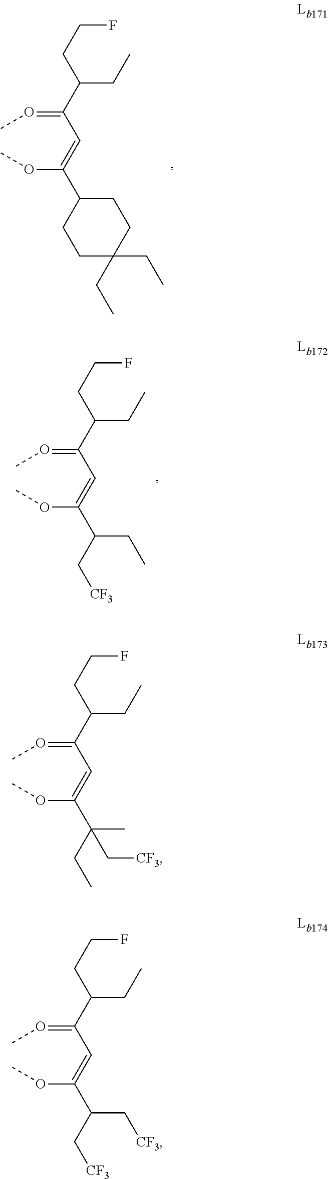 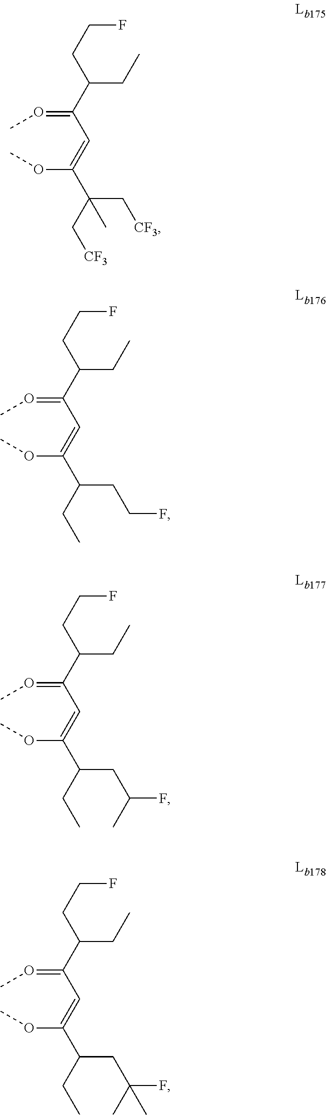 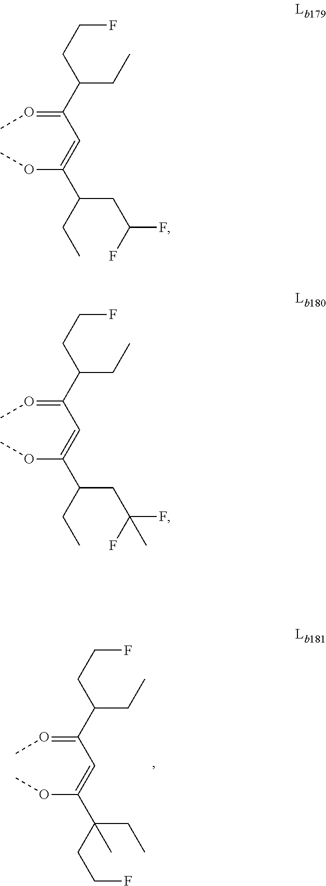 [chemical structure] [chemical structure] [chemical structure] [chemical structure] [chemical structure] [chemical structure] [chemical structure] [chemical structure]
wherein the ligand L_{c} is, at each occurrence identically or differently, selected from the group consisting of the following structures:

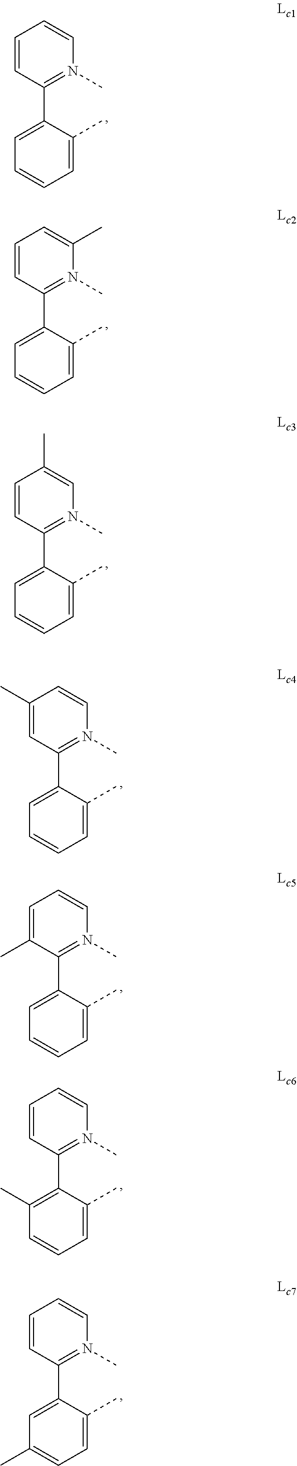

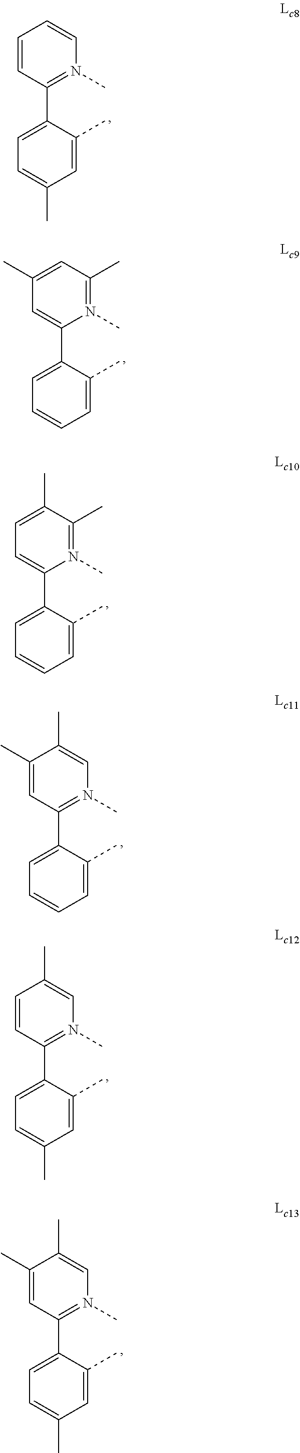

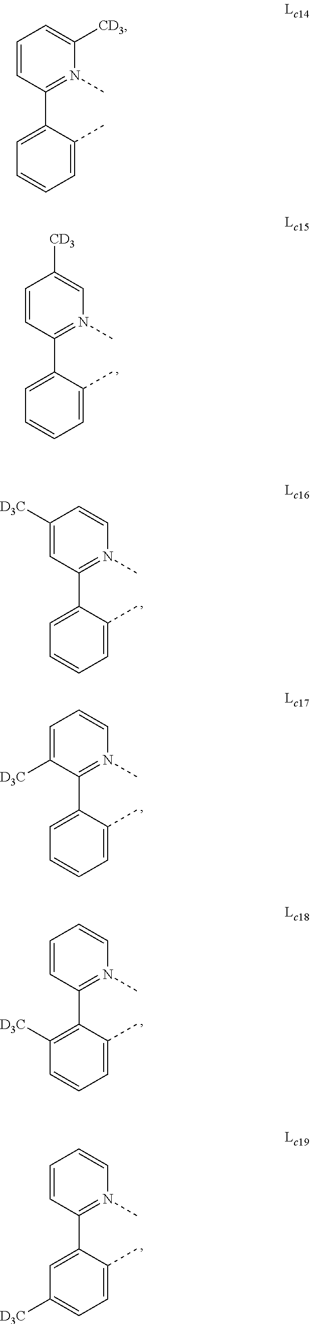

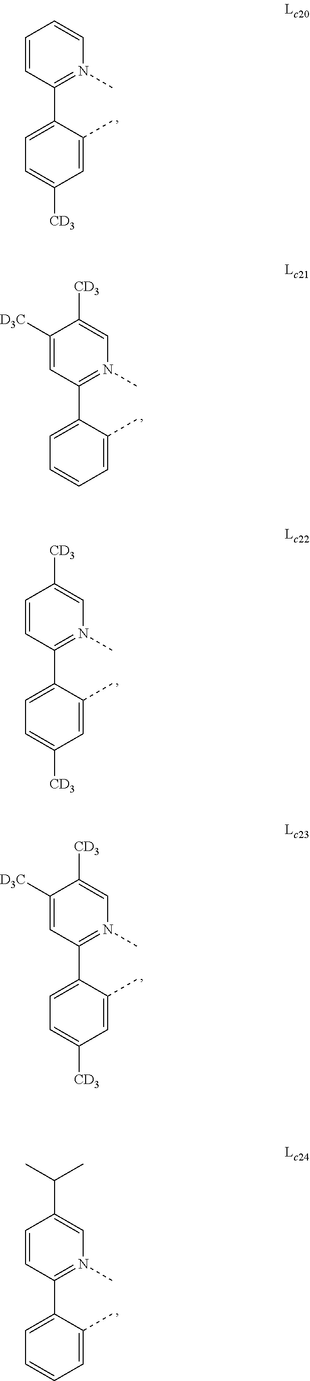

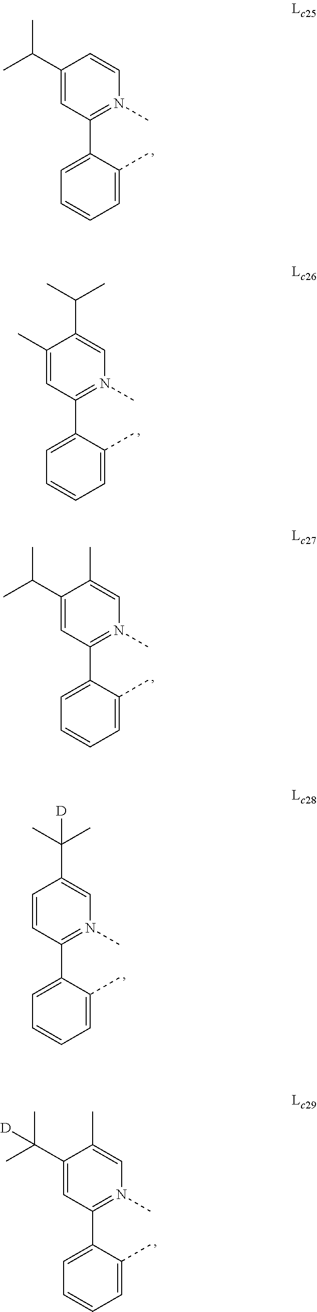

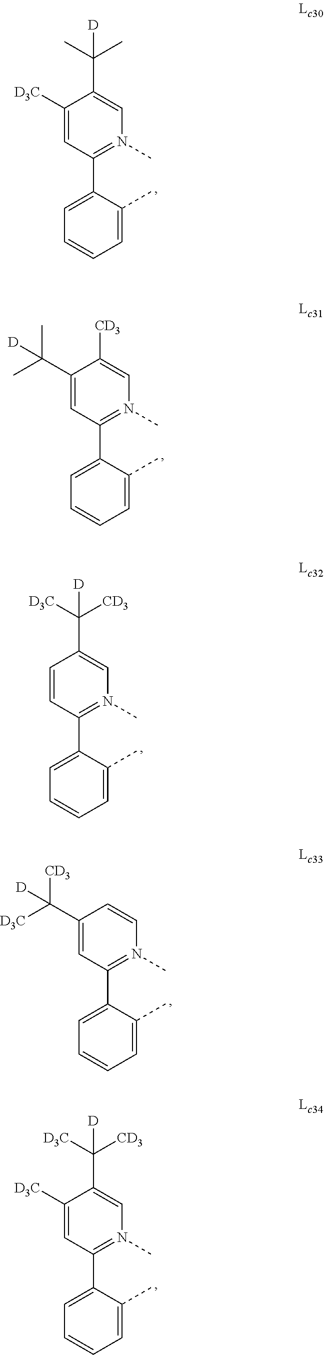

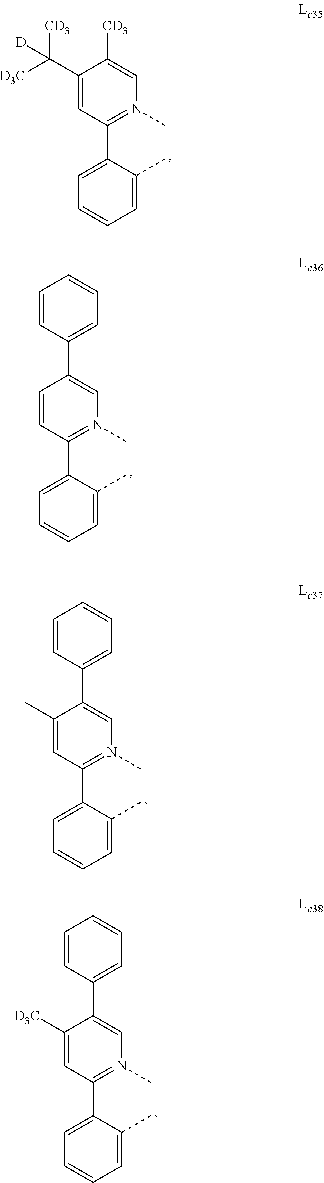

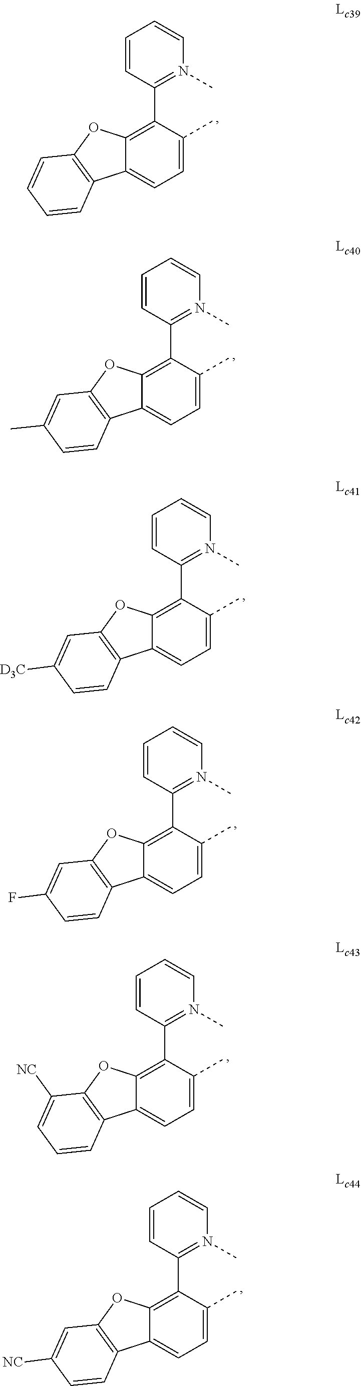

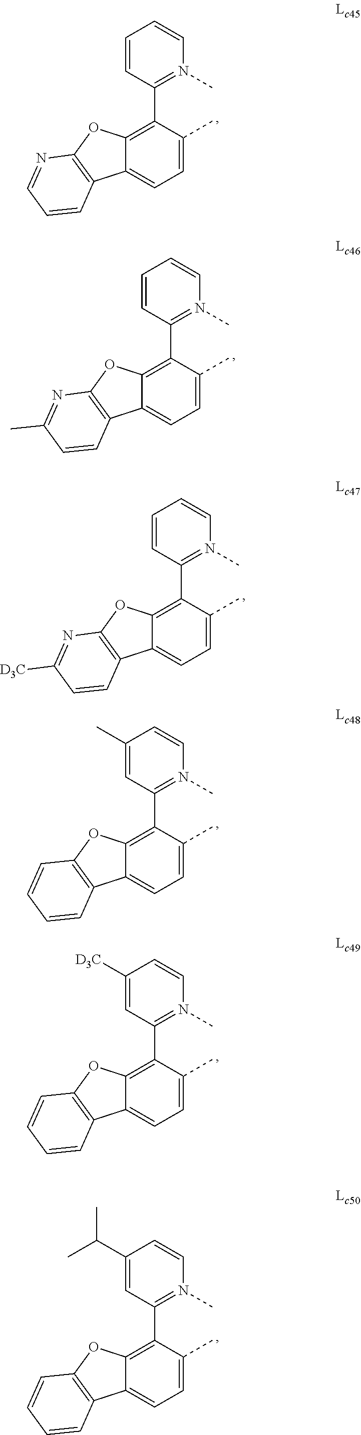

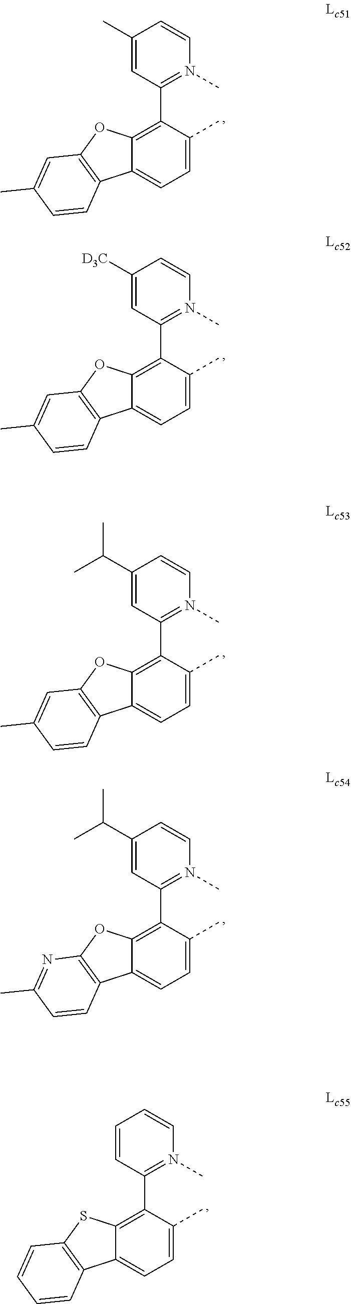

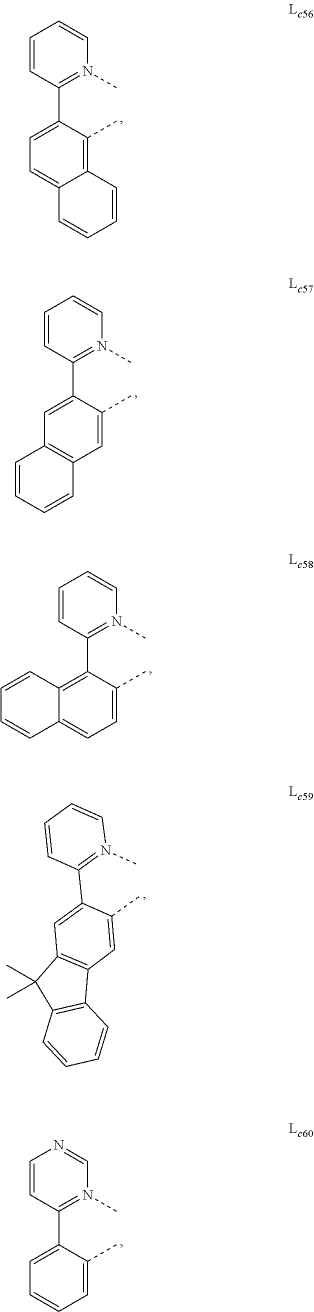

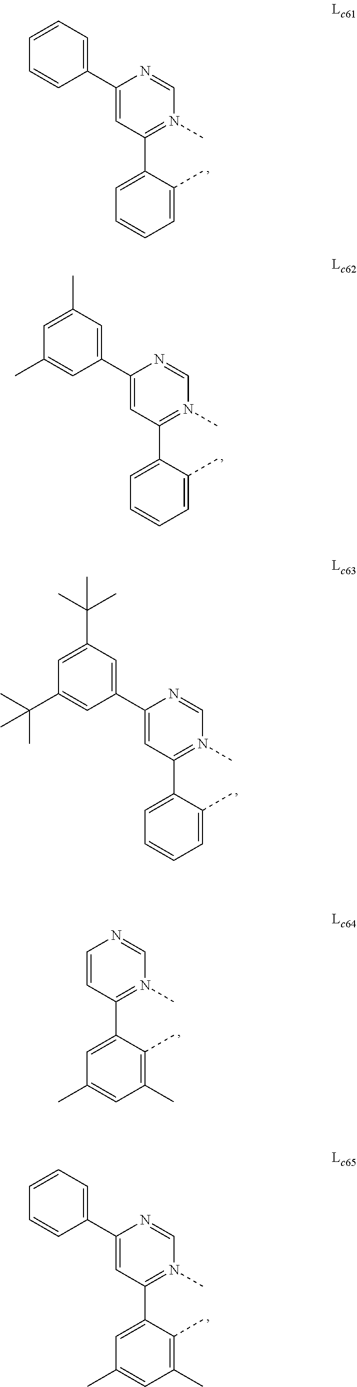

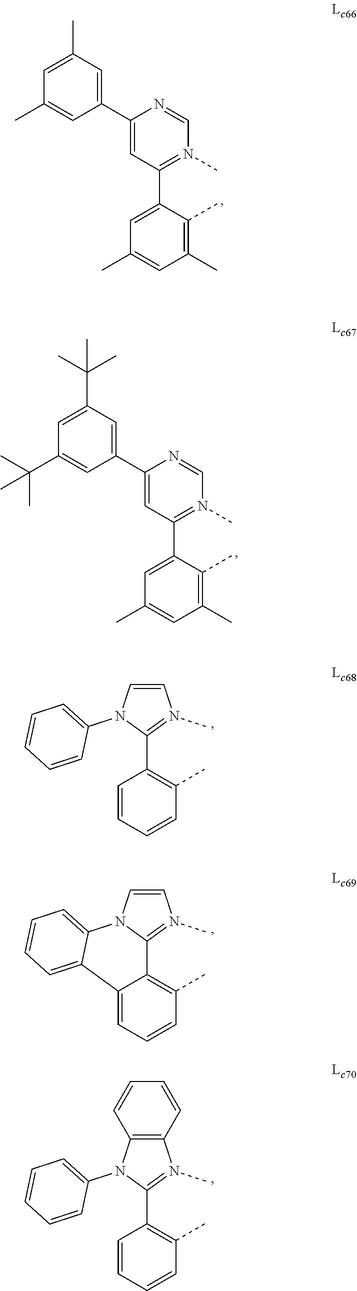

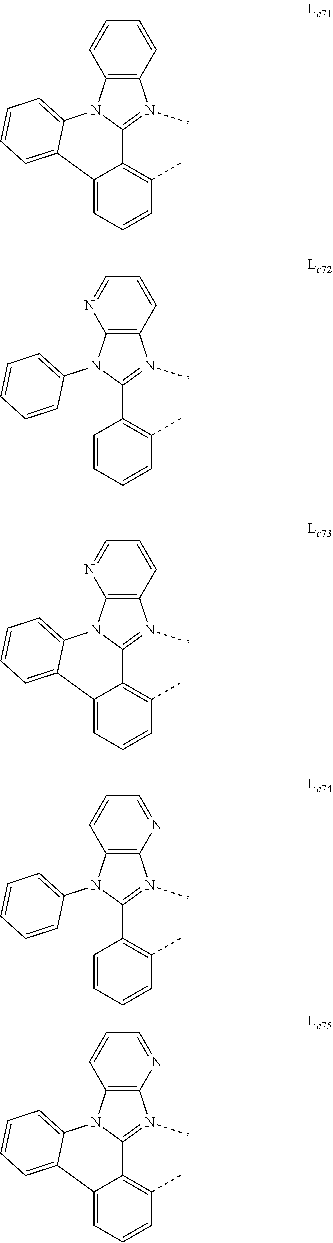

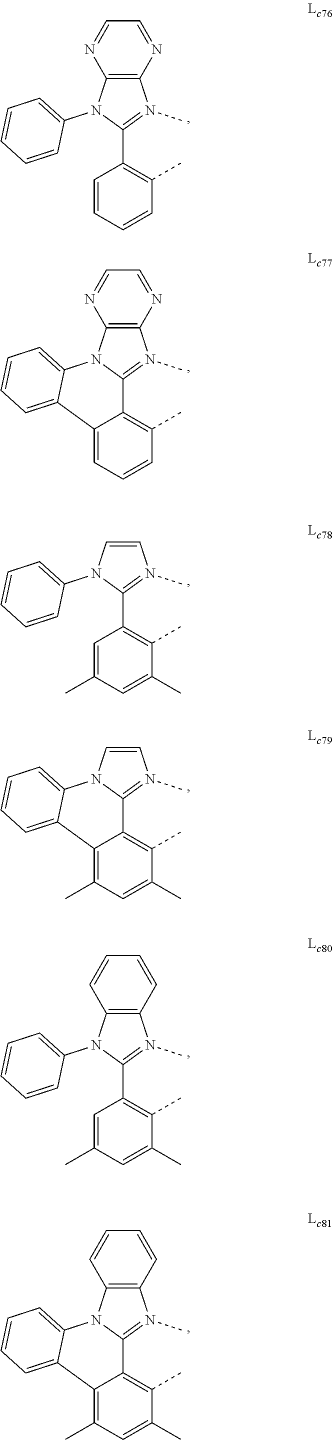

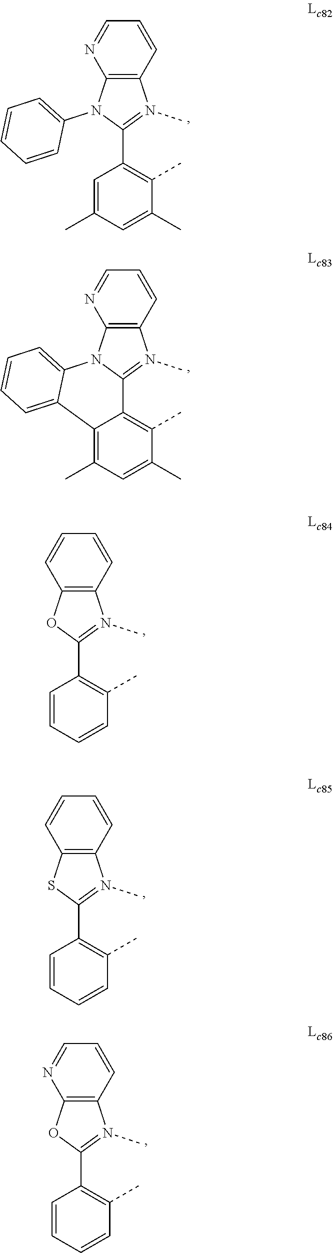

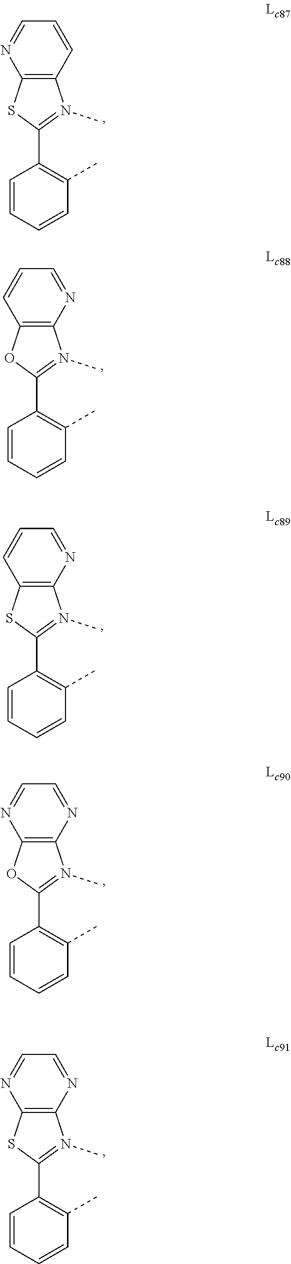

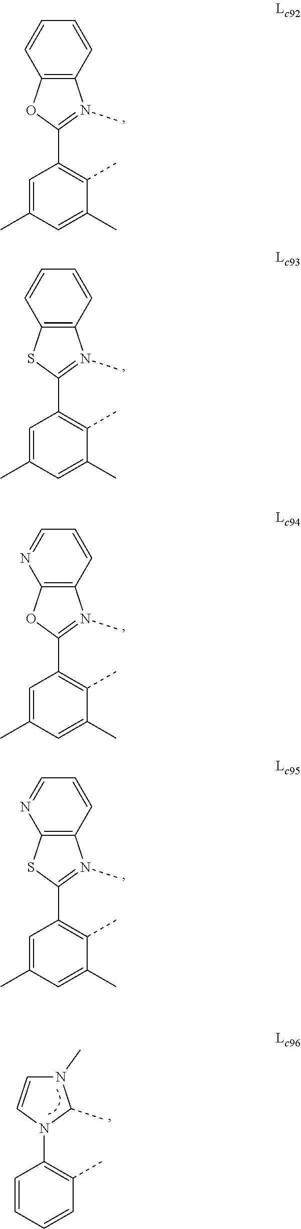

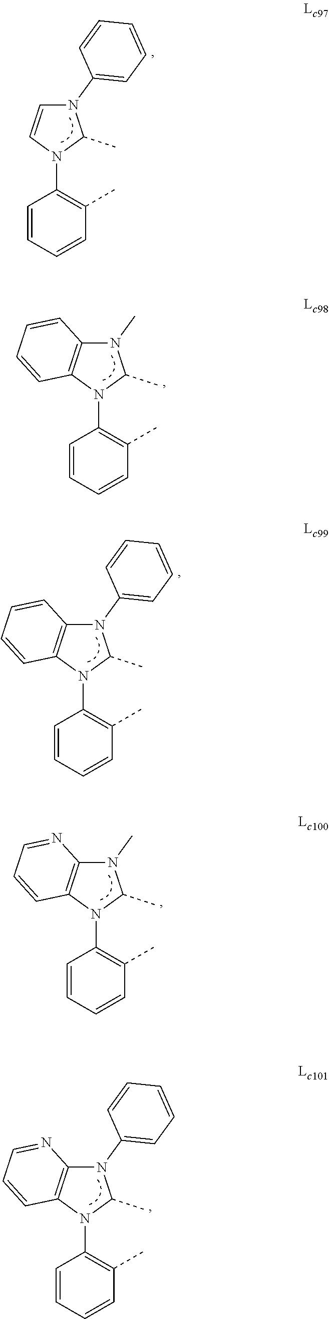

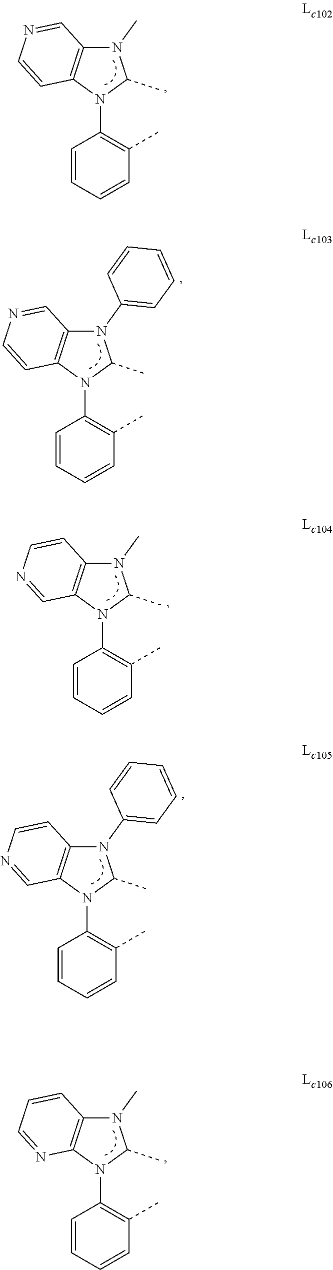

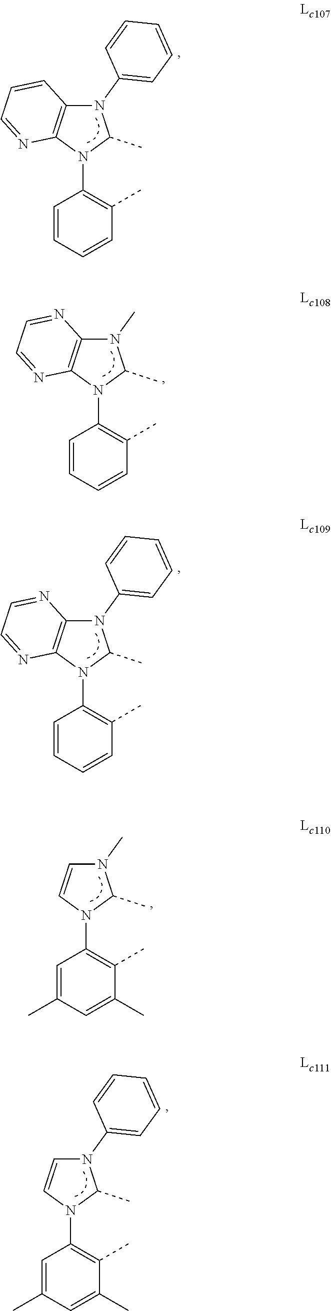

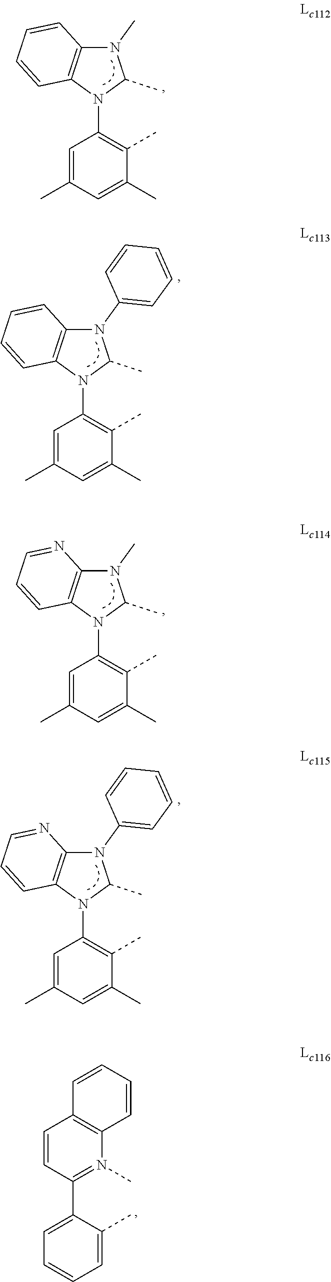

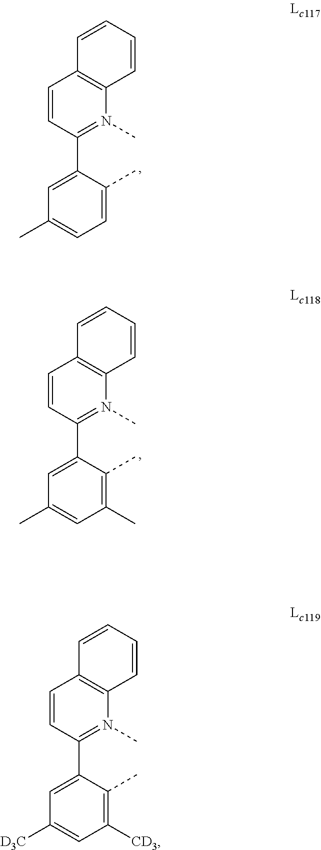

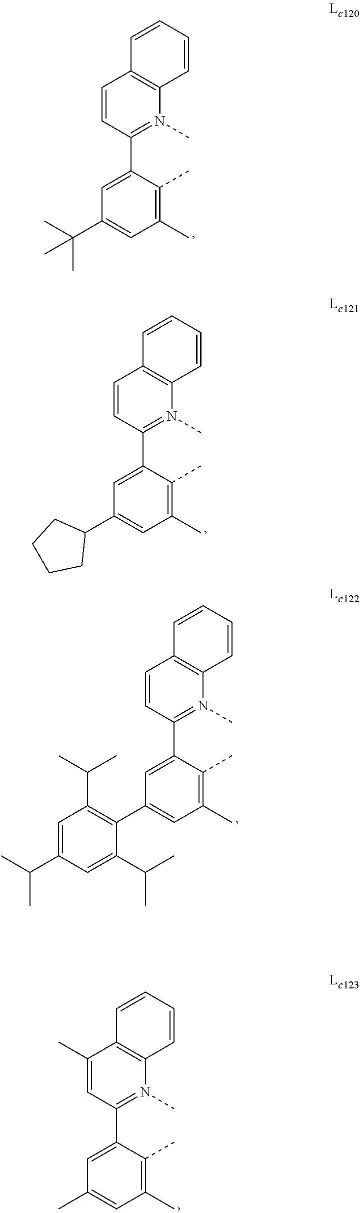

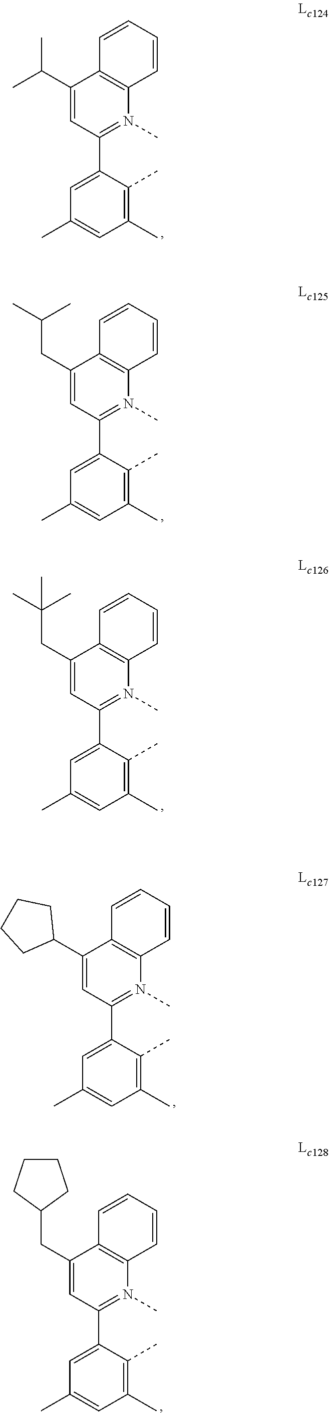

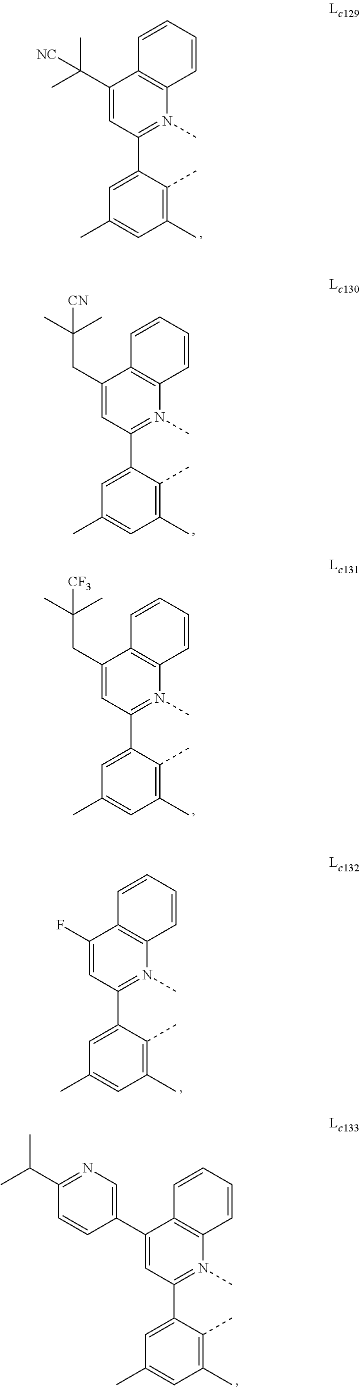

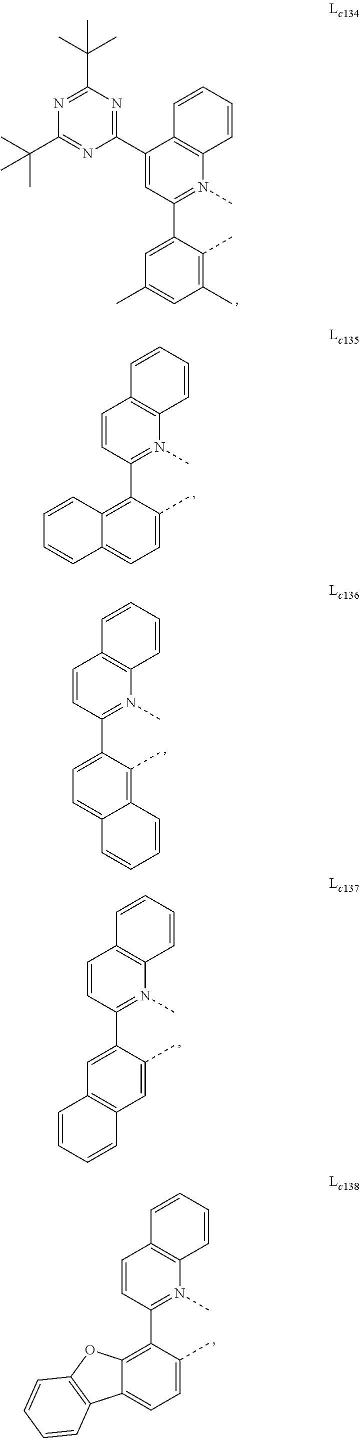

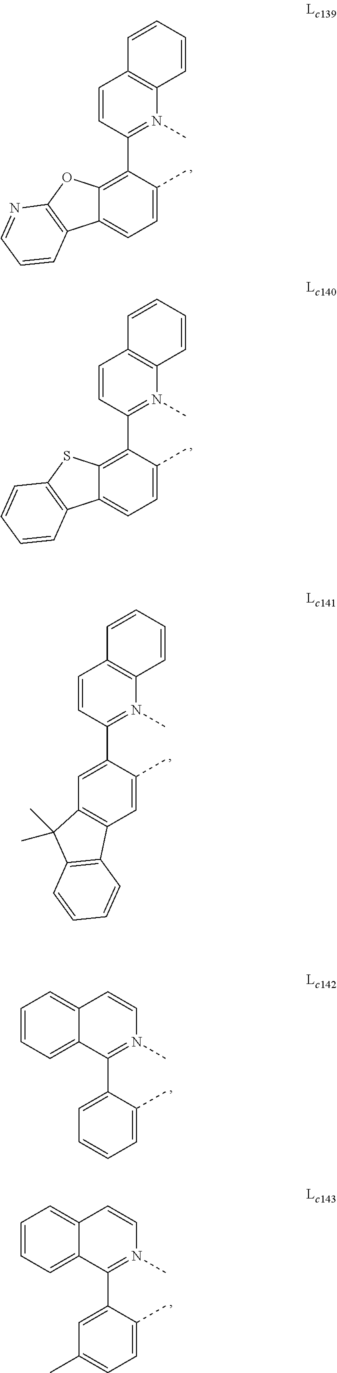

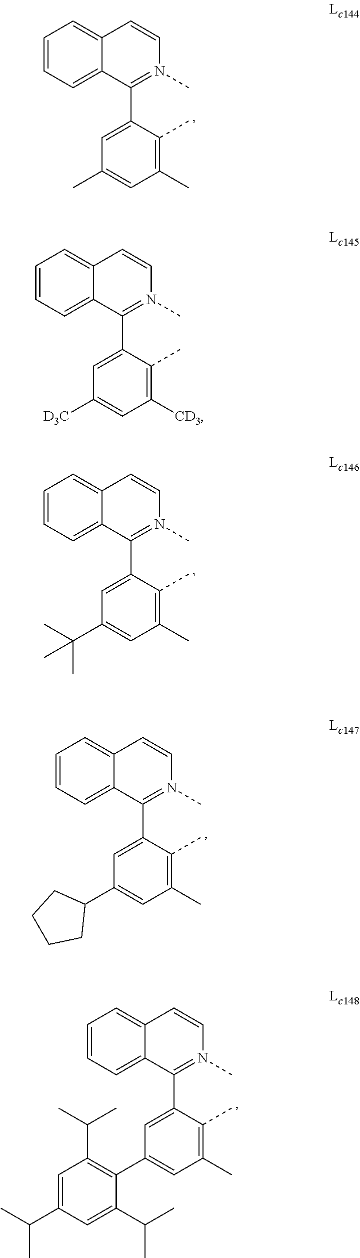

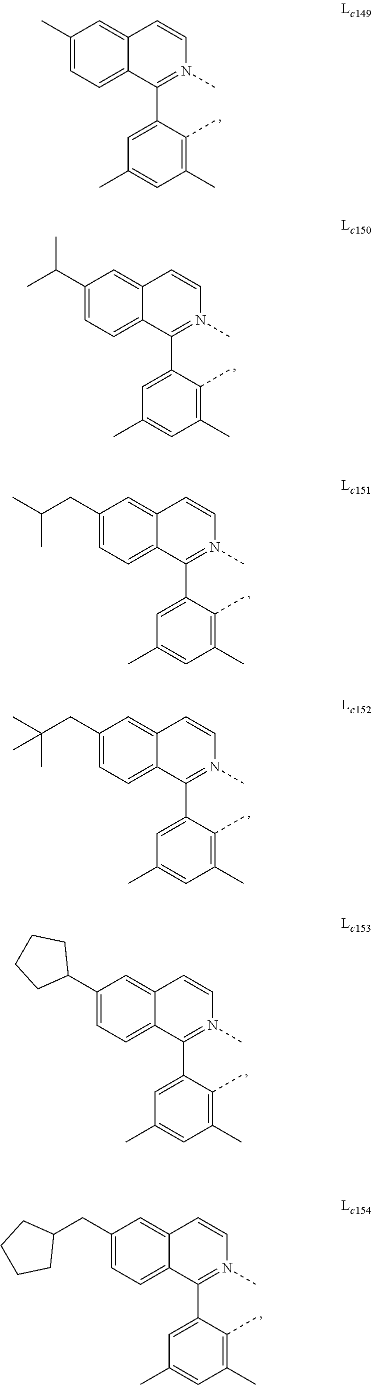

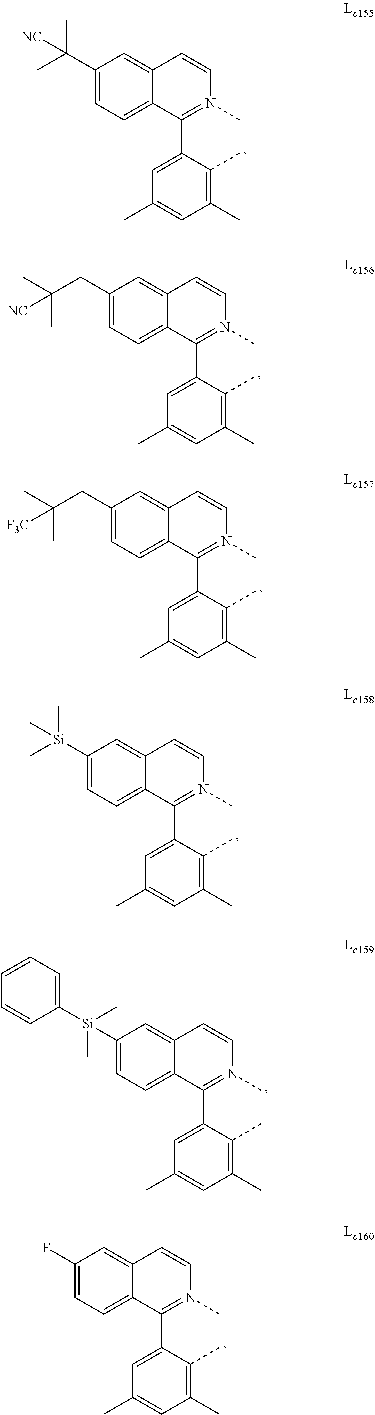

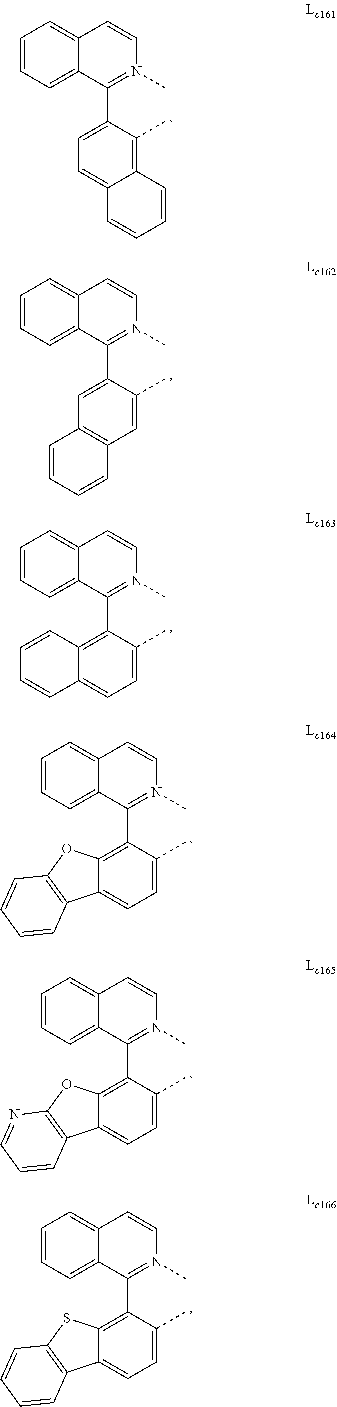

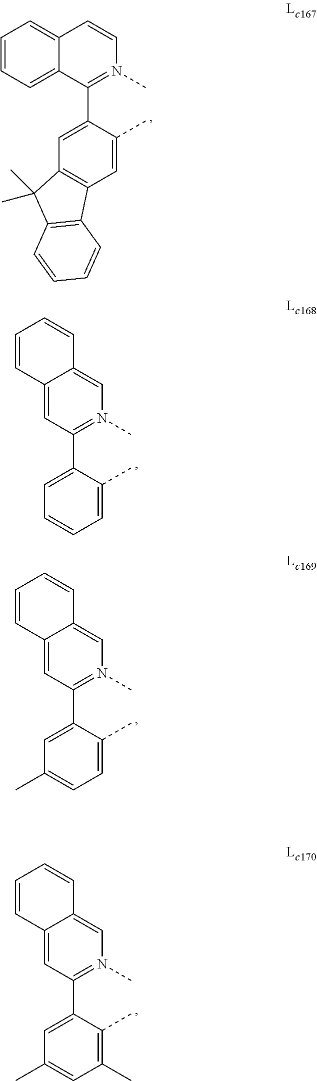

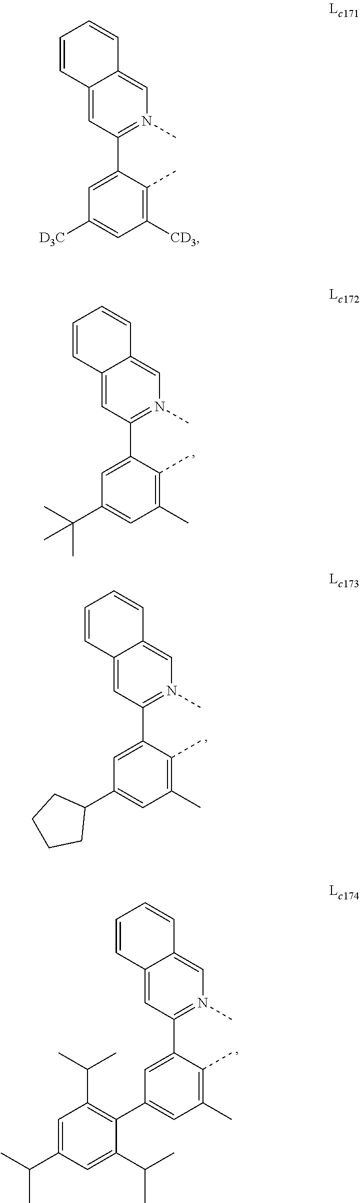

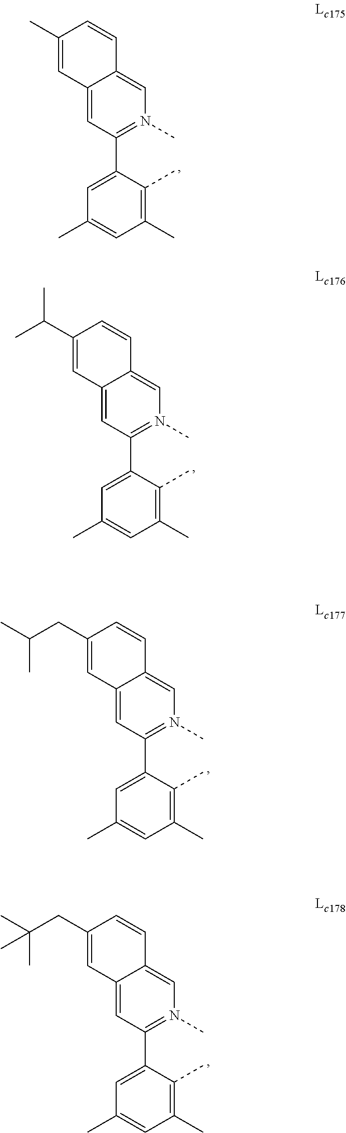

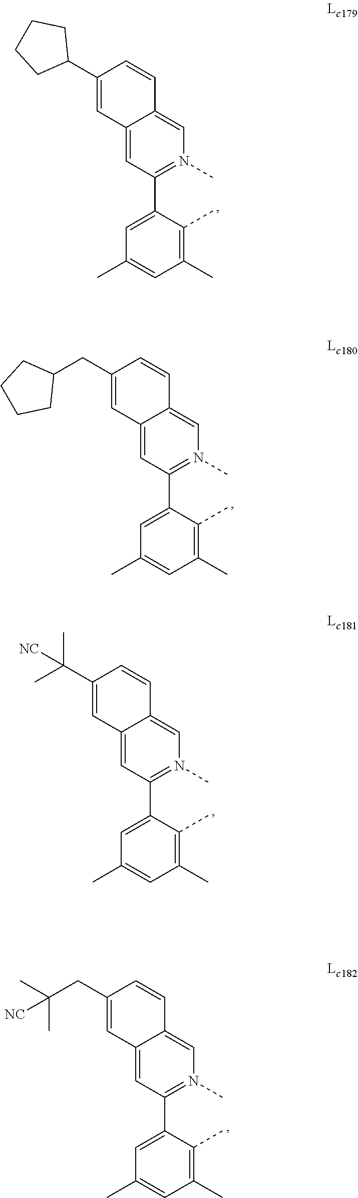

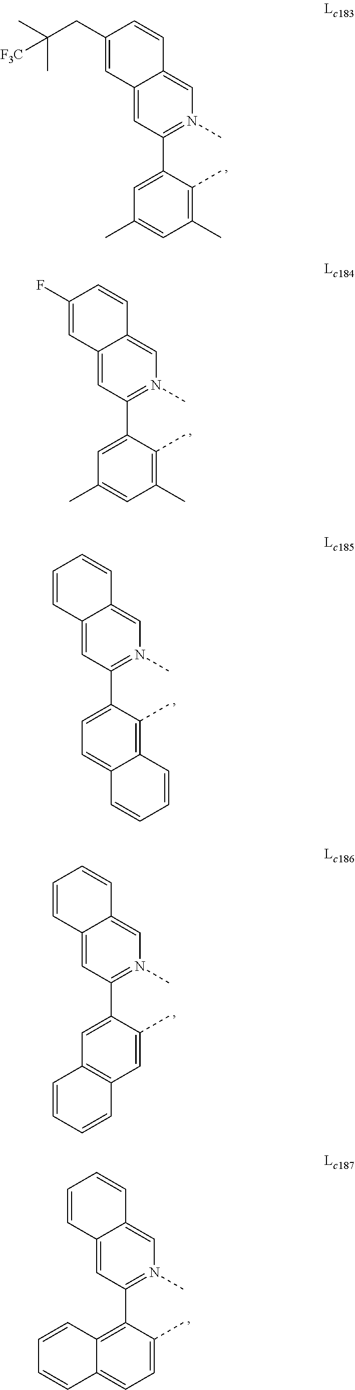

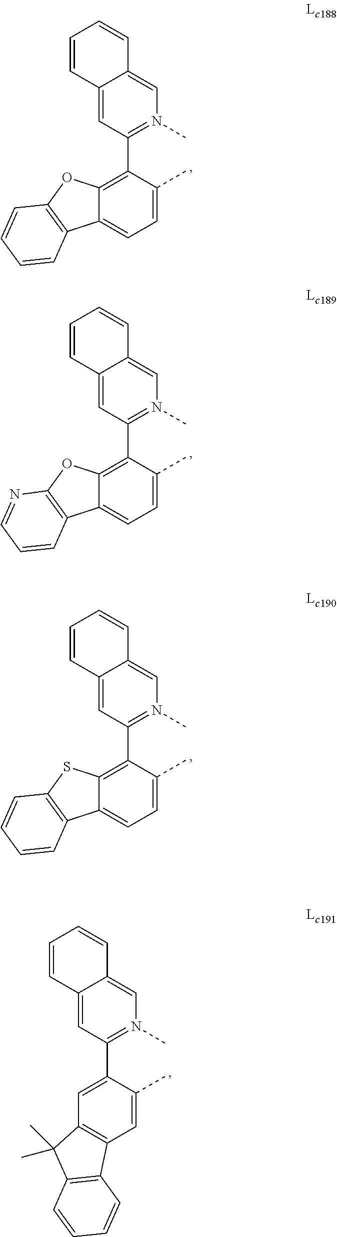

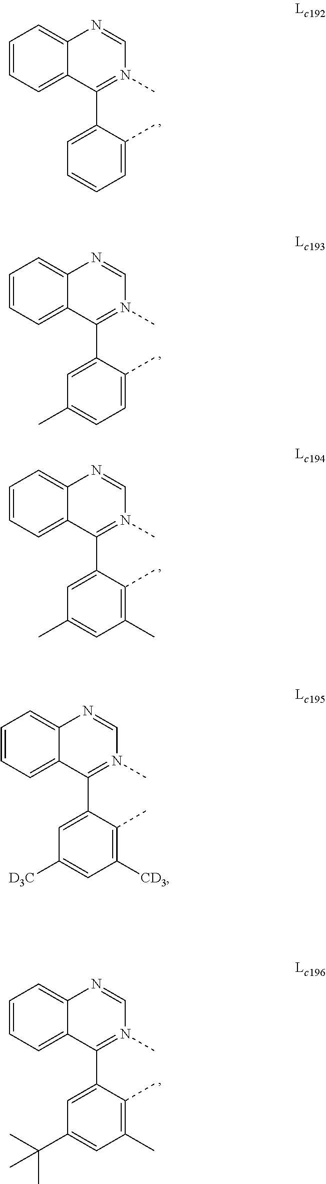

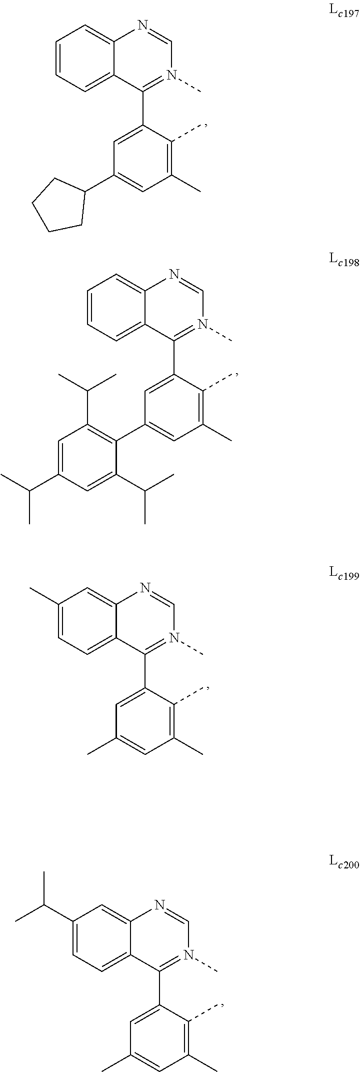

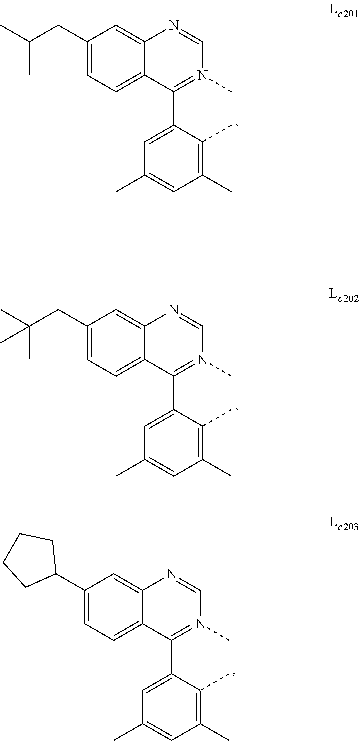

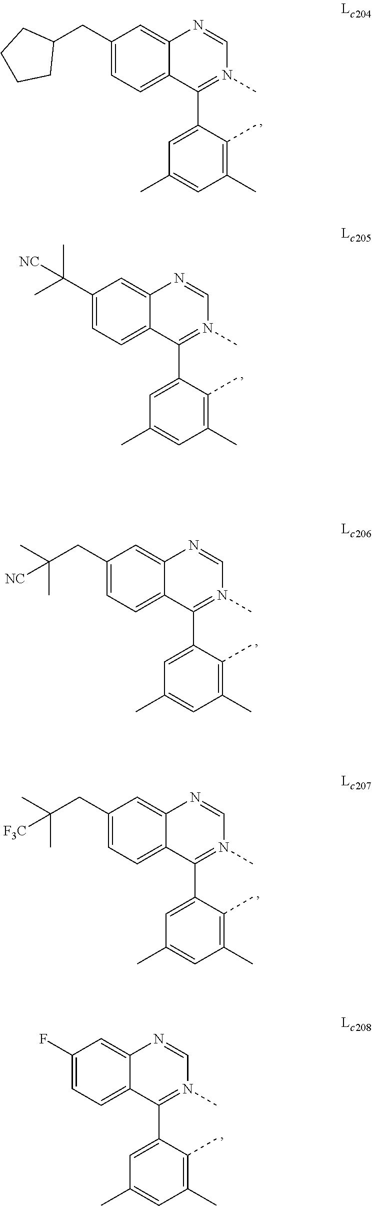

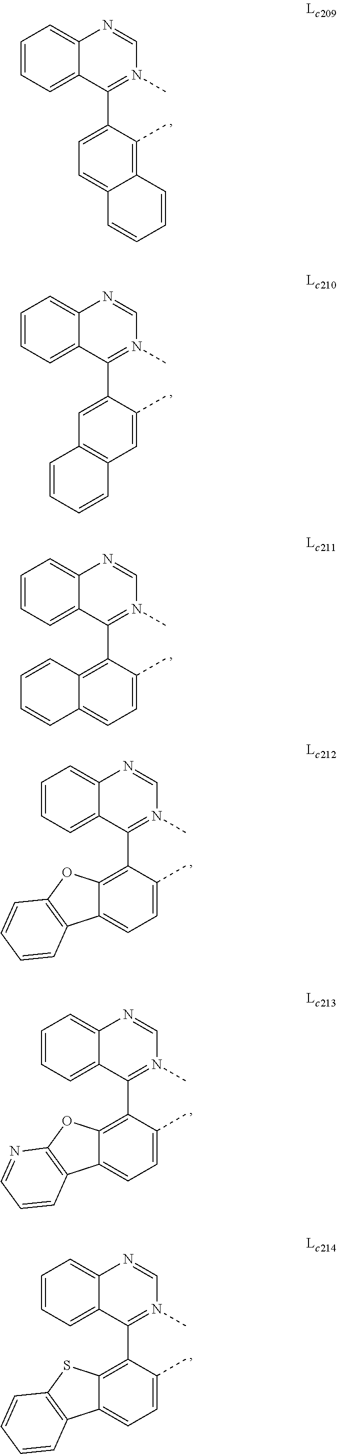

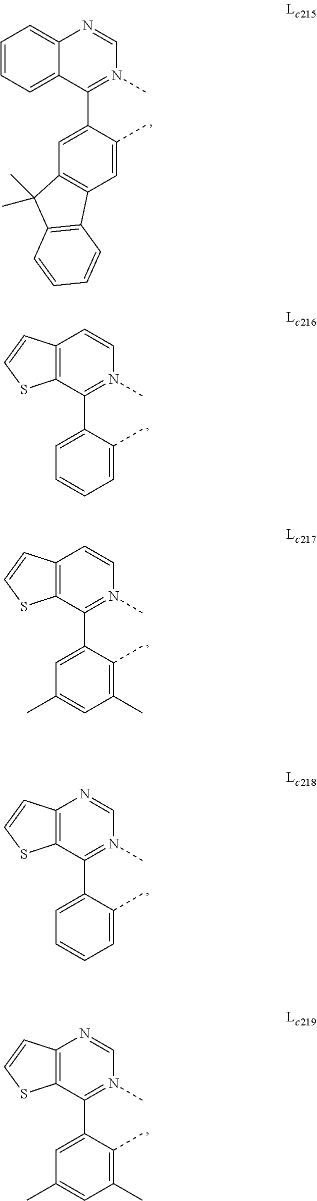

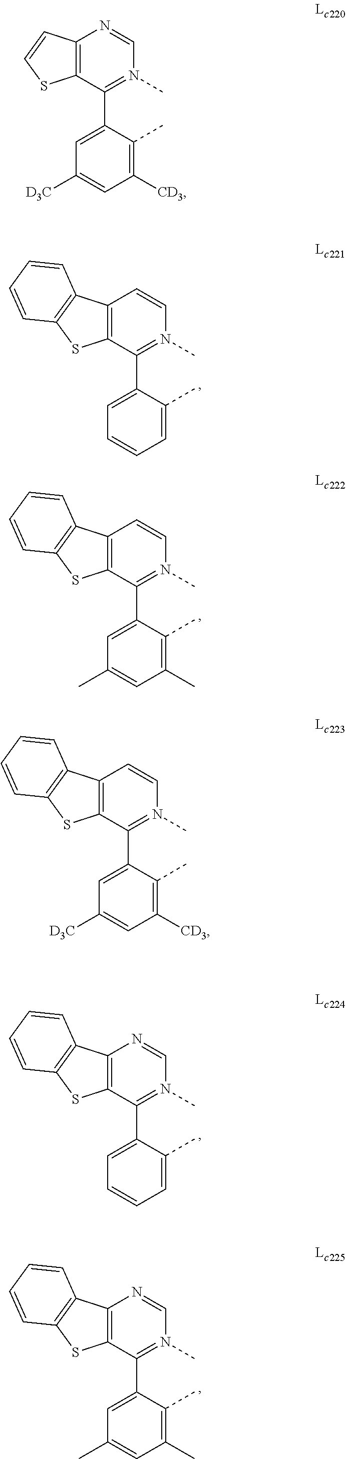

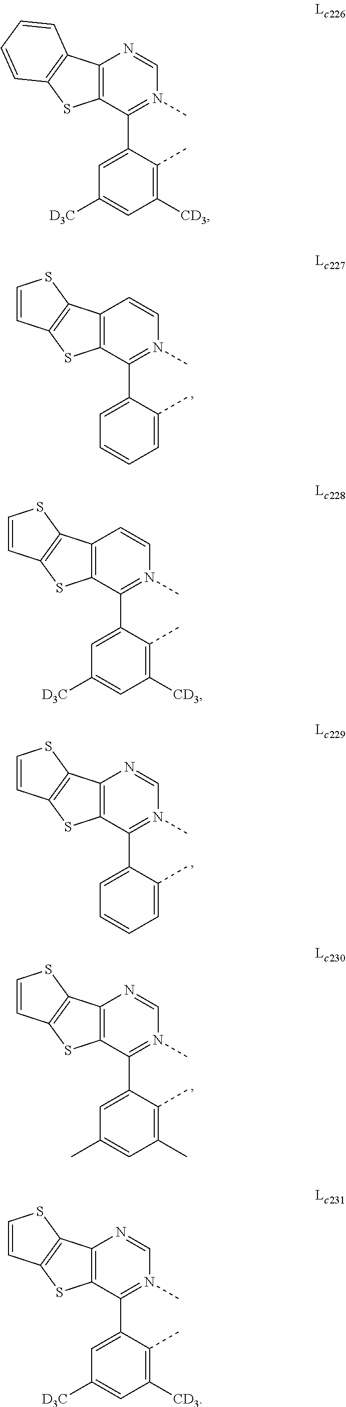

22. The electroluminescent device according to claim 21, wherein the third compound is an Ir complex and has a structure of Ir(Lₐ)₂(L_{b}) or Ir(Lₐ)₂(L_{c}) or Ir(Lₐ)(L_{c})₂ or Ir(Lₐ)(L_{b})(L_{c});
wherein when the third compound has a structure of Ir(Lₐ)₂(L_{b}), Lₐ is, at each occurrence identically or differently, selected from any one or any two of the group consisting of Lₐ₁ to Lₐ₁₁₀, and L_{b} is selected from any one of the group consisting of L_{b1} to L_{b322}; when the third compound has a structure of Ir(Lₐ)₂(L_{c}), Lₐ is, at each occurrence identically or differently, selected from any one or any two of the group consisting of Lₐ₁ to Lₐ₁₁₀, and L_{c} is selected from any one of the group consisting of L_{c1} to L_{c231}; when the third compound has a structure of Ir(Lₐ)(L_{c})₂, Lₐ is selected from any one of the group consisting of Lₐ₁ to Lₐ₁₁₀, and L_{c} is, at each occurrence identically or differently, selected from any one or any two of the group consisting of L_{c1} to L_{c231}; when the third compound has a structure of Ir(Lₐ)(L_{b})(L_{c}), Lₐ is selected from any one of the group consisting of Lₐ₁ to Lₐ₁₁₀, L_{b} is selected from any one of the group consisting of L_{b1} to L_{b322}, and L_{c} is selected from any one of the group consisting of L_{c1} to L_{c231}; and
preferably, the third compound is selected from the group consisting of the following structures:

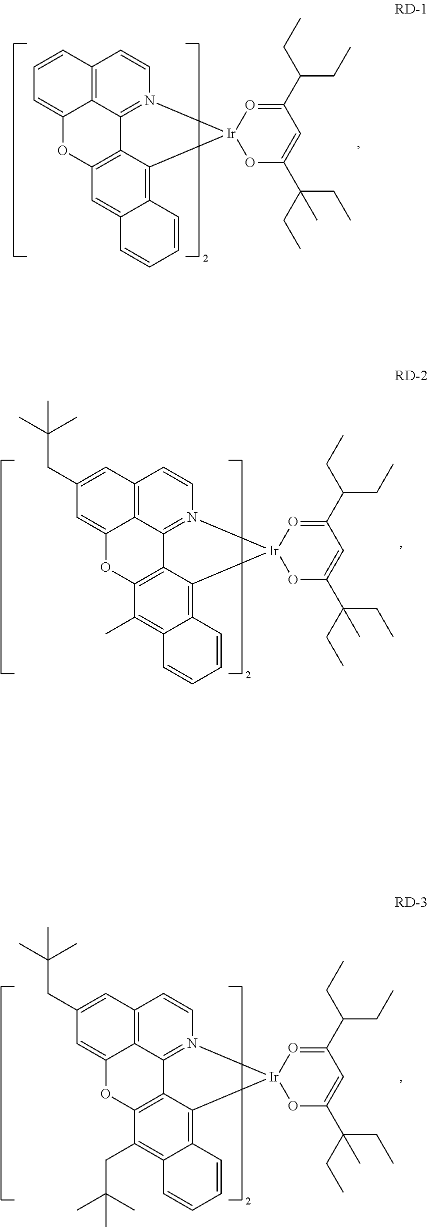

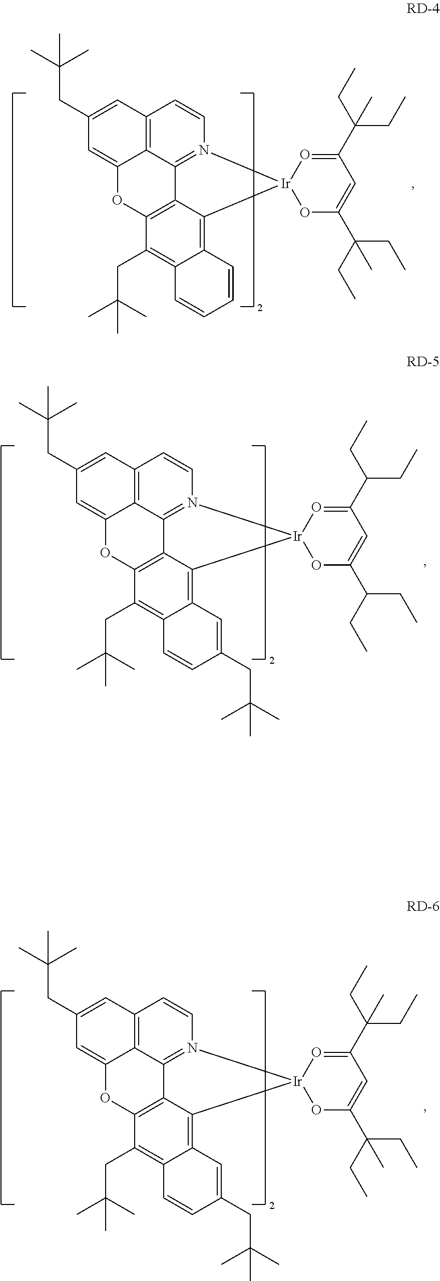

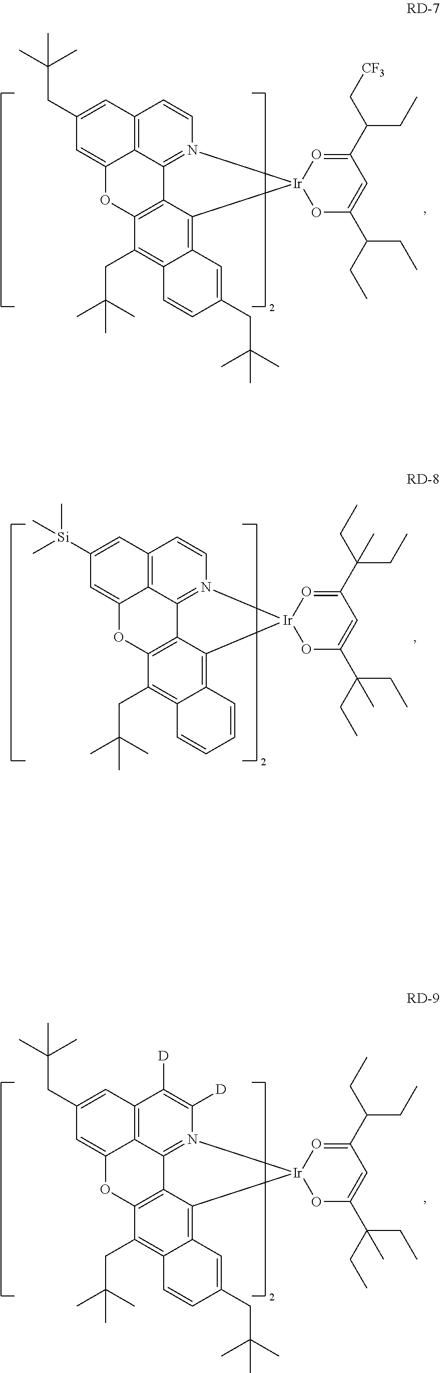

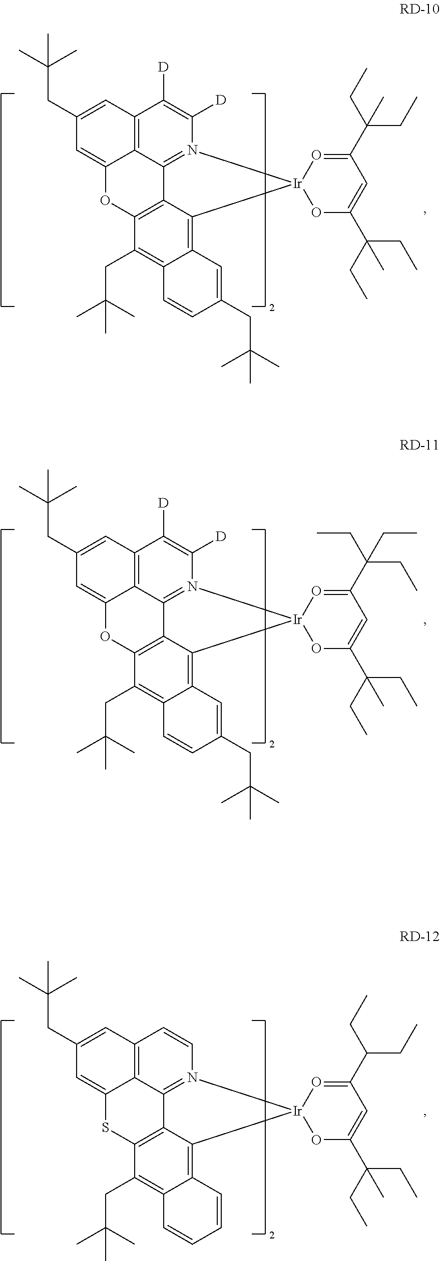

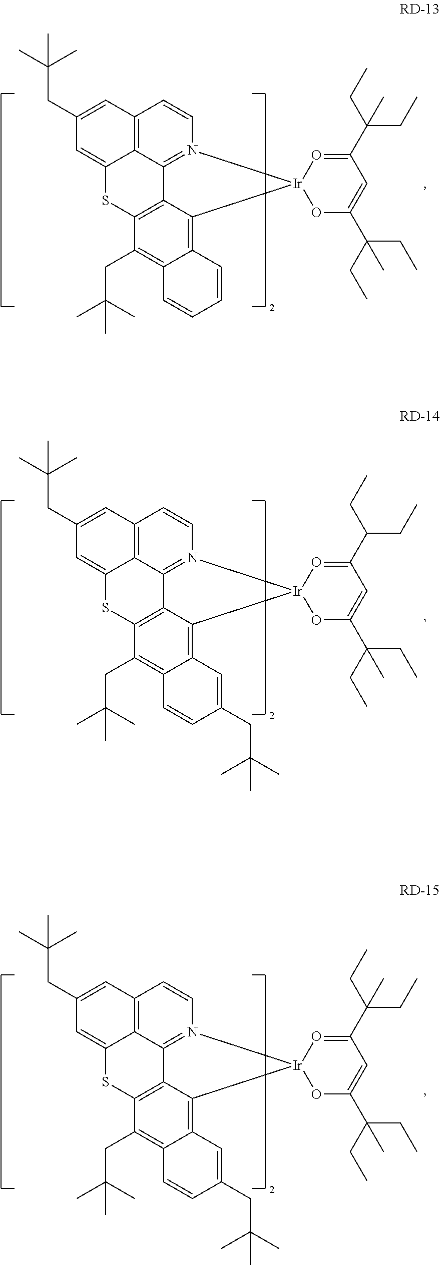

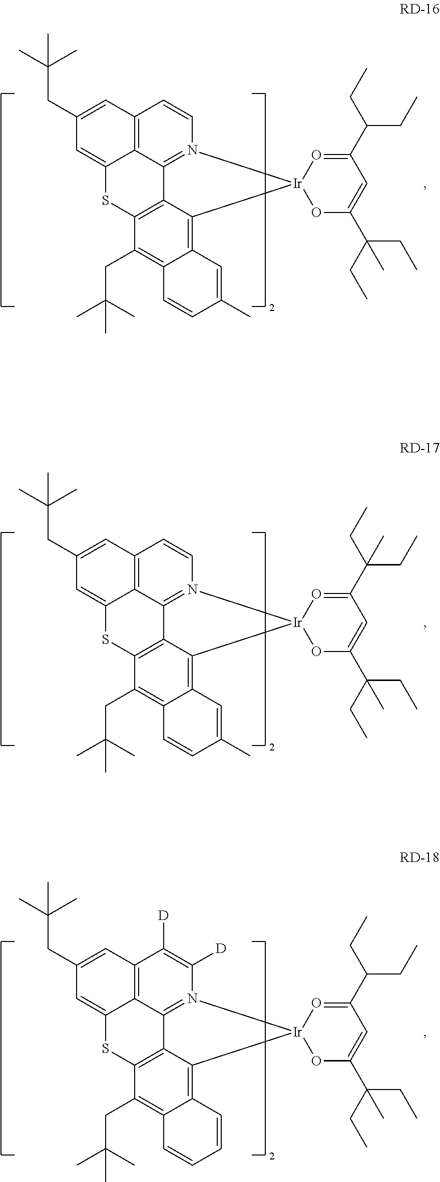

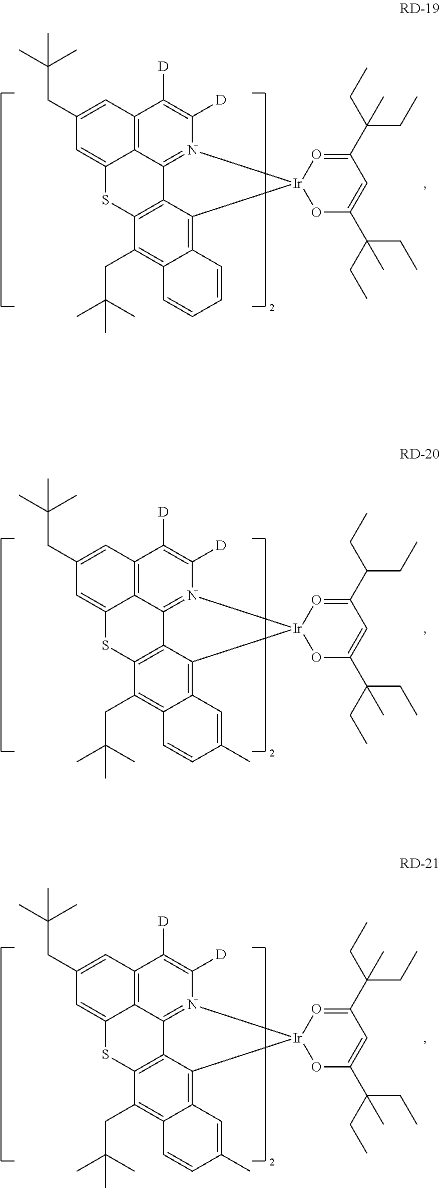

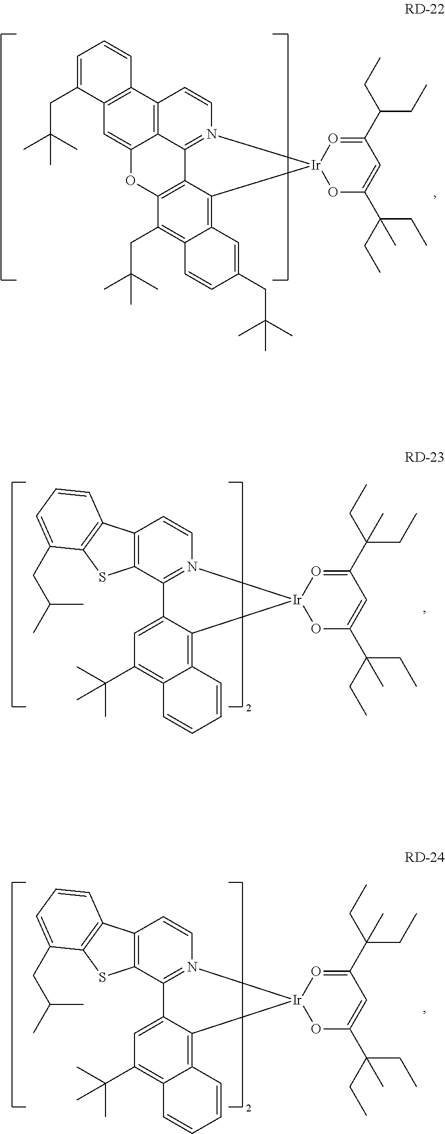

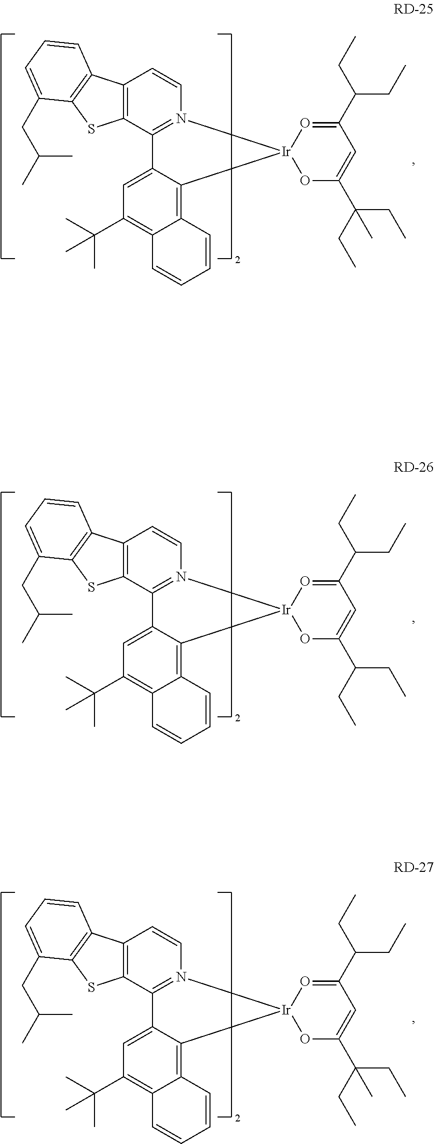

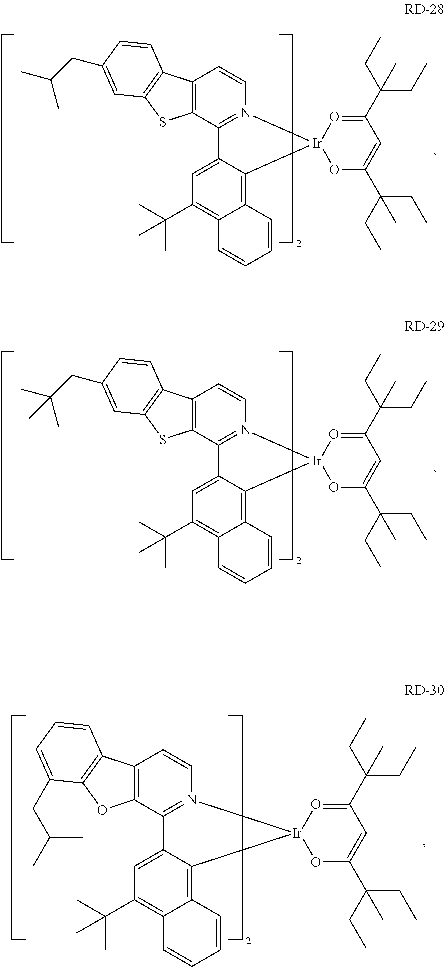

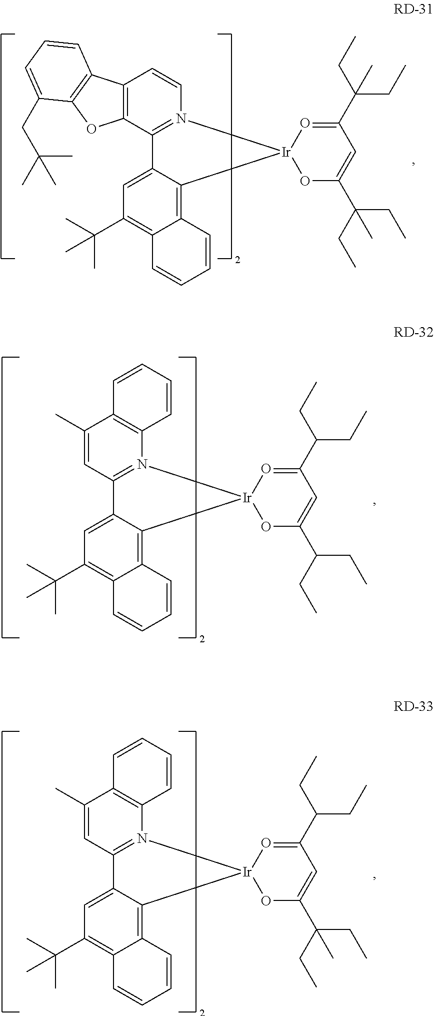

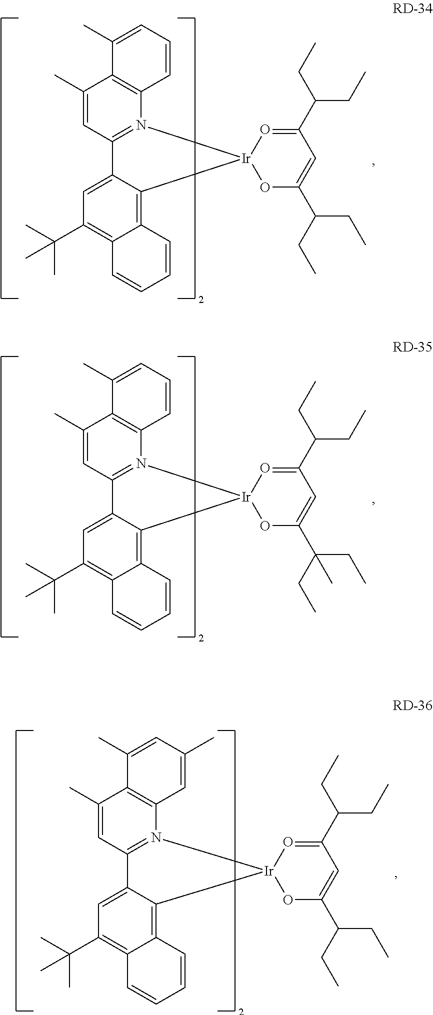

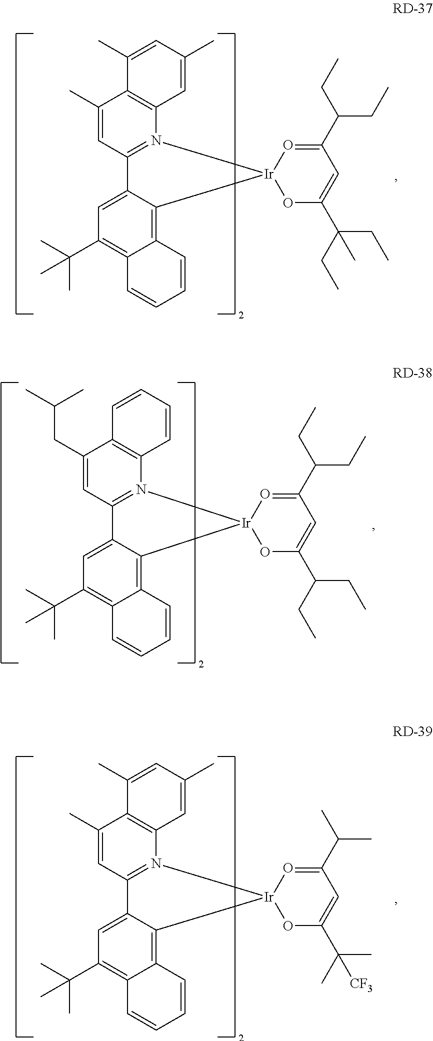

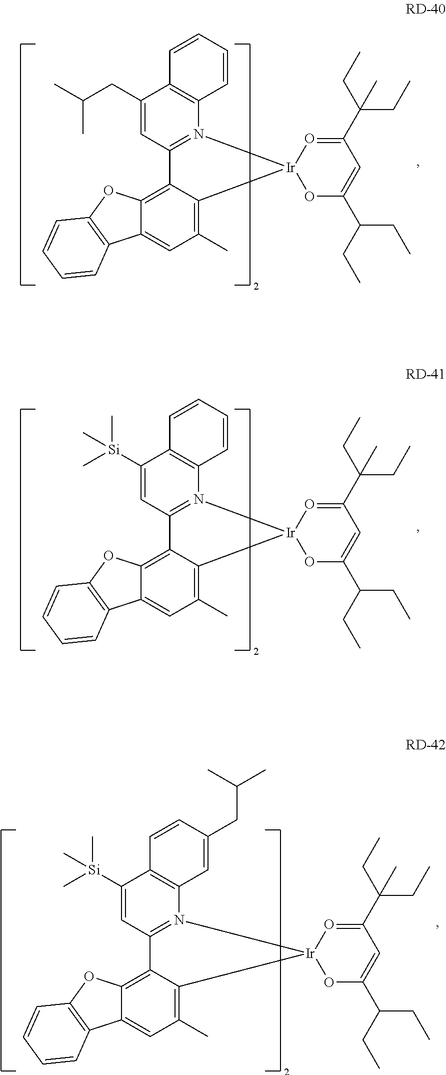

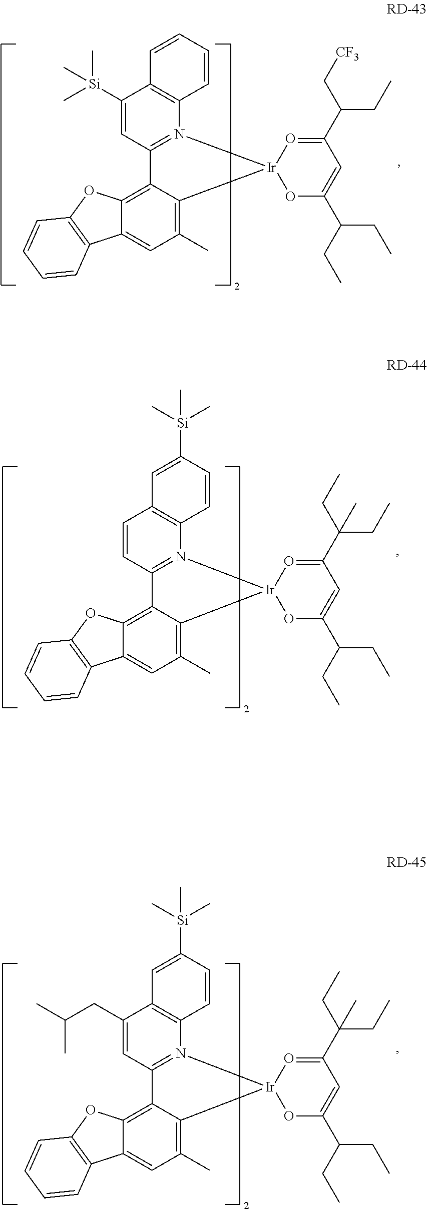

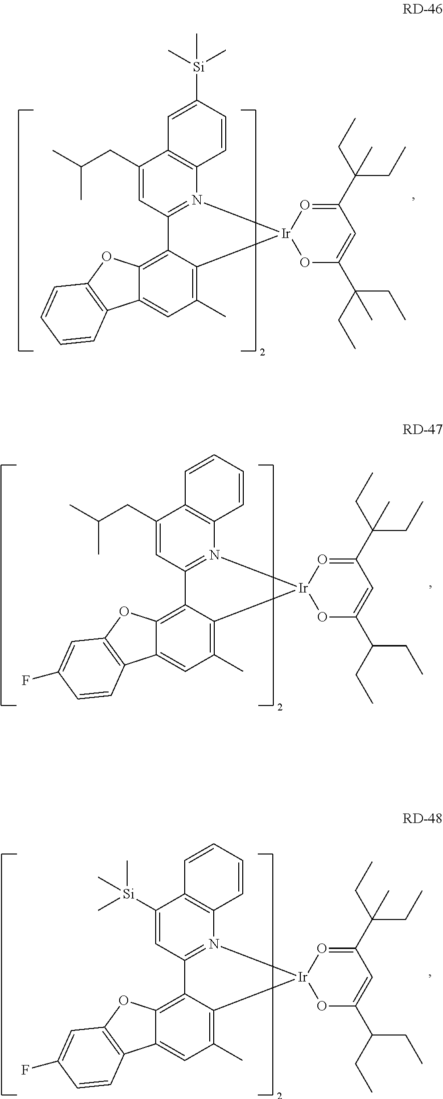

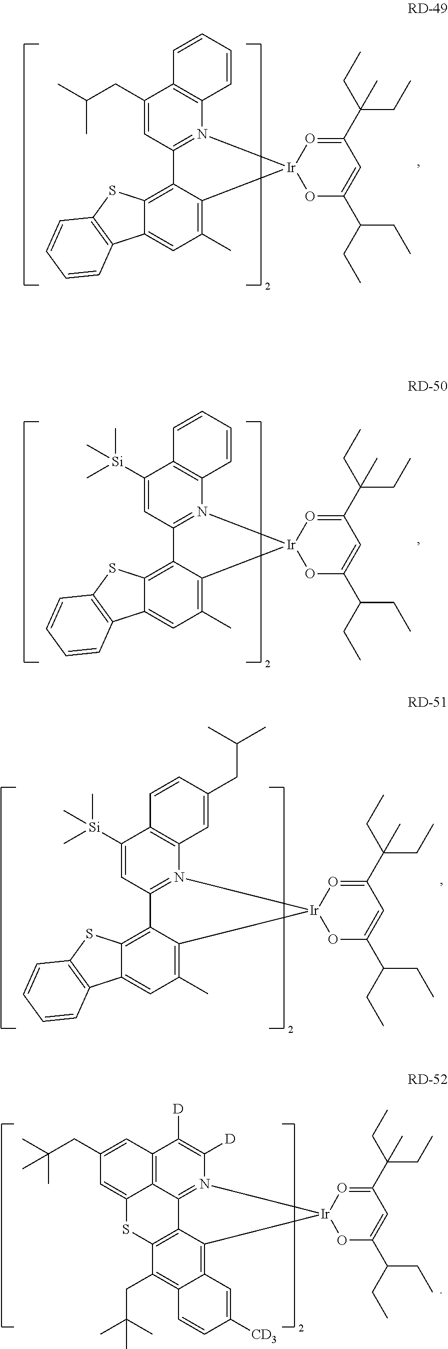

23. An electronic apparatus, comprising the electroluminescent device according to claim 1.

24. A composition, comprising a first compound, a second compound and a third compound;
wherein the first compound has a structure represented by Formula 1: 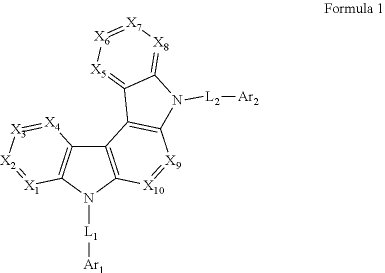
wherein in Formula 1,
X₁ to X₁₀ are, at each occurrence identically or differently, selected from CRₓ or N;
L₁ and L₂ are selected from a single bond, substituted or unsubstituted arylene having 6 to 30 carbon atoms, substituted or unsubstituted heteroarylene having 3 to 30 carbon atoms or a combination thereof;
Ar₁ and Ar₂ are selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 1, adjacent substituents Rₓ can be optionally joined to form a ring;
wherein the second compound has a structure represented by Formula 2: 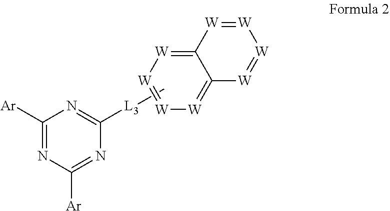
wherein in Formula 2,
W is, at each occurrence identically or differently, selected from C, CR_{w} or N, and one W is selected from C and joined to L₃;
Ar is, at each occurrence identically or differently, selected from substituted or unsubstituted aryl having 6 to 30 carbon atoms, substituted or unsubstituted heteroaryl having 3 to 30 carbon atoms, substituted or unsubstituted alkyl having 1 to 20 carbon atoms, substituted or unsubstituted cycloalkyl having 3 to 20 ring carbon atoms or a combination thereof;
L₃ is, at each occurrence identically or differently, selected from substituted or unsubstituted arylene having 6 to 30 carbon atoms, substituted or unsubstituted heteroarylene having 3 to 30 carbon atoms or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 2, adjacent substituents R_{w} can be optionally joined to form a ring;
wherein the third compound is a metal complex, wherein the metal complex comprises a metal with a relative atomic mass greater than 40 and a ligand Lₐ, wherein the ligand Lₐ has a structure represented by Formula 3: 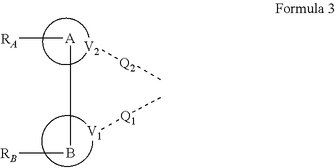
wherein in Formula 3,
the ring A and the ring B are, at each occurrence identically or differently, selected from a substituted or unsubstituted fused aromatic ring having 9 to 50 ring atoms, a substituted or unsubstituted fused heteroaromatic ring having 9 to 50 ring atoms or a combination thereof;
V₁ and V₂ are each independently selected from C or N, and V₁ is different from V₂;
Q₁ and Q₂ are, at each occurrence identically or differently, selected from a single bond, O, S, Se or NR_{Q};
when both Q₁ and Q₂ are single bonds, the monocyclic ring in the ring A and the ring B that is directly joined to the metal through carbon is a six-membered ring;
R_{A} and R_{B} represent, at each occurrence identically or differently, mono-substitution, multiple substitutions or non-substitution;
R_{Q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in Formula 3, adjacent substituents R_{A} and R_{B} can be optionally joined to form a ring.
